(19) United States
(12) Patent Application Publication
(10) Pub. No.: US 2015/0053944 A1
(43) Pub. Date: Feb. 26, 2015

(54) ORGANIC LIGHT-EMITTING DEVICE

(71) Applicants: SAMSUNG DISPLAY CO., LTD., Yongin-City (KR); Gyeongsang National University Industry-Academic Cooperation Foundation, Gyeongnam (KR)

(72) Inventors: Se-Hun KIM, Yongin-City (KR); Dong-Hyun KIM, Yongin-City (KR); Hwan-Hee CHO, Yongin-City (KR); Mi-Kyung KIM, Yongin-City (KR); Chang-Woong CHU, Yongin-City (KR); Yun-Ji LEE, Gyeongnam (KR); Yun-Hi KIM, Gyeongnam (KR); Soon-Ki KWON, Gyeongnam (KR)

(21) Appl. No.: 14/309,298

(22) Filed: Jun. 19, 2014

(30) Foreign Application Priority Data
Aug. 22, 2013 (KR) 10-2013-0099918

(51) Int. Cl. H01L 51/00

(52) U.S. Cl. CPC H01L 51/0053; H01L 51/0072; H01L 51/0054; H01L 51/5012
USPC 257/40

(57) ABSTRACT

An organic light-emitting device includes a first electrode; a second electrode opposite to the first electrode; and an organic layer between the first electrode and the second electrode, and the organic layer including an emission layer that includes at least one silane-based compound represented by Formula 1 below and at least one anthracene-based compound represented by Formula 20 below.

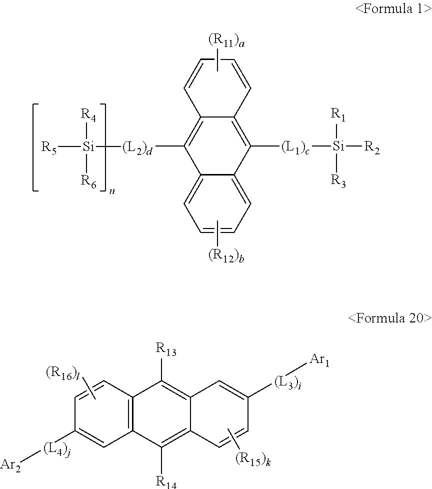

wherein, in Formulae 1 and 20 above, R₁ to R₆, R₁₁ to R₁₆, L₁ to L₄, Ar₁, Ar₂, a, b, c, d, i, j, l, k, and n are further defined.

### CROSS-REFERENCE TO RELATED APPLICATION

Korean Patent Application No. 10-2013-0099918, filed on Aug. 22, 2013, in the Korean Intellectual Property Office, and entitled: “Organic Light-Emitting Device,” is incorporated by reference herein in its entirety.

### BACKGROUND

1. Field

One or more embodiments relate to an organic light-emitting device.

2. Description of the Related Art

Organic light-emitting devices (OLEDs), which are self-emitting devices, have advantages such as wide viewing angles, excellent contrast, quick response, high brightness, excellent driving voltage characteristics, and can provide multicolored images.

A typical OLED has a structure including an anode, a hole transport layer (HTL), an emission layer (EML), an electron transport layer (ETL), and a cathode which are sequentially stacked on a substrate. In this regard, the HTL, the EML, and the ETL are organic thin films formed of organic compounds.

An operating principle of an OLED having the above-described structure is as follows. When a voltage is applied between the anode and the cathode, holes injected from the anode move to the EML via the HTL, and electrons injected from the cathode move to the EML via the ETL. The holes and electrons recombine in the EML to generate excitons. When the excitons drop from an excited state to a ground state, light is emitted.

### SUMMARY

Embodiments are directed to an organic light-emitting device that includes a first electrode; a second electrode opposite to the first electrode; and an organic layer between the first electrode and the second electrode, the organic layer including an emission layer that includes at least one silane-based compound represented by Formula 1 below and at least one anthracene-based compound represented by Formula 20 below.

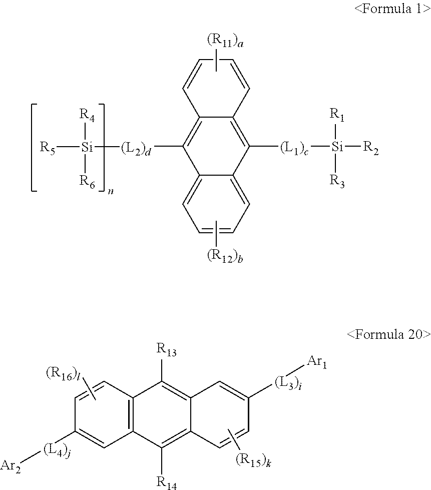

wherein, in Formulae 1 and 20 above,

n is 0 or 1;

R₁ to R₆ are each independently selected from a substituted or unsubstituted C₁-C₆₀ alkyl group, a 3- to 10-membered substituted or unsubstituted non-condensed ring group, and a substituted or unsubstituted condensed ring group in which at least two rings are fused to each other, wherein when n is 0, at least one of R₁ to R₃ is a substituted or unsubstituted condensed ring group in which at least two rings are fused to each other, and when n is 1 at least one of R₁ to R₆ is a substituted or unsubstituted condensed ring group in which at least two rings are fused to each other;

L₁ to L₄ are each independently selected from a substituted or unsubstituted C₃-C₁₀ cycloalkylene group, a substituted or unsubstituted C₃-C₁₀ cycloalkenylene group, a substituted or unsubstituted C₃-C₁₀ heterocycloalkylene group, a substituted or unsubstituted C₃-C₁₀ heterocycloalkenylene group, a substituted or unsubstituted C₆-C₆₀ arylene group, and a substituted or unsubstituted C₂-C₆₀ heteroarylene group;

c and d are each independently an integer from 1 to 3;

R₁₁ to R₁₆ are each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthiol group, a substituted or unsubstituted C₂-C₆₀ heteroaryl group, —N(Q₁)(Q₂), and —Si(Q₃)(Q₄)(Q₅) (where Q₁ to Q₅ are each independently selected from a hydrogen atom, a C₁-C₁₀ alkyl group, a C₆-C₂₀ aryl group, and a C₂-C₂₀ heteroaryl group);

a and b are each independently an integer from 1 to 4;

l and k are each independently an integer from 1 to 3;

i and j are each independently an integer from 0 to 3; and

Ar₁ and Ar₂ are each independently one of the groups represented by Formulae 7A to 7F below:

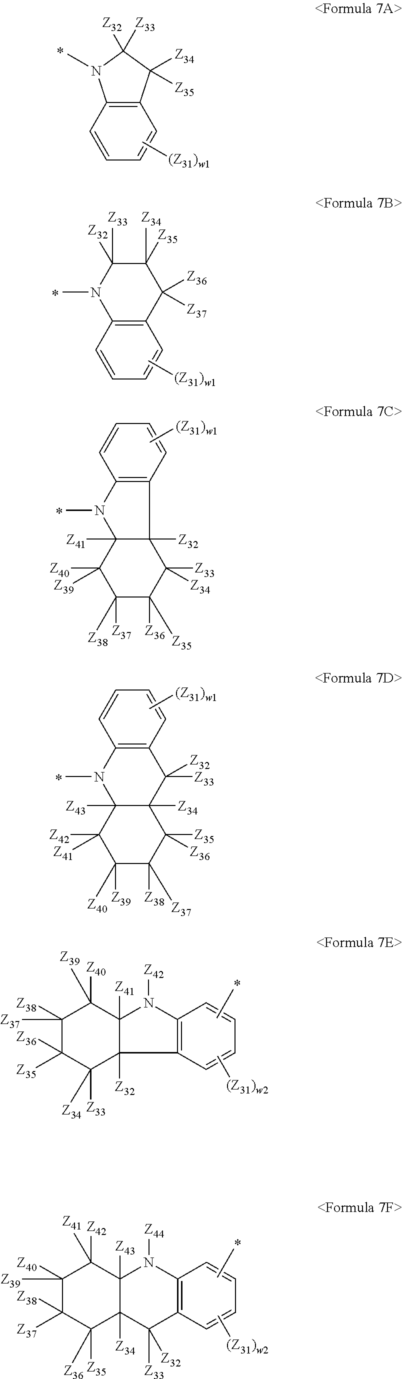

wherein, in Formulae 7A to 7F above,

Z₃₁ to Z₄₄ are each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthiol group, a substituted or unsubstituted C₂-C₆₀ heteroaryl group, —N(Q₅₁)(Q₅₂), and —Si(Q₅₃)(Q₅₄)(Q₅₅) (where Q₅₁ to Q₅₅ are each independently selected from a hydrogen atom, a C₁-C₁₀ alkyl group, a C₆-C₂₀ aryl group, and a C₂-C₂₀ heteroaryl group), wherein at least two of Z₃₁ to Z₄₄ are optionally linked to form a C₆-C₂₀ saturated ring or a C₆-C₂₀ unsaturated ring;

w1 is an integer from 1 to 4;

w2 is an integer from 1 to 5; and

* indicates a binding site to L₃ or L₄, or to an anthracene core when i or j is 0.

According to one or more embodiments, an organic light-emitting device includes: a first electrode; a second electrode; and an organic layer disposed between the first electrode and the second electrode and including an emission layer, wherein the emission layer includes at least one of Compounds 1 to 60 and at least one of Compounds 61 to 136, the formulae of Compounds 1 to 136 being represented in the detailed description of the specification.

### BRIEF DESCRIPTION OF THE DRAWING

Features will become apparent to those of ordinary skill in the art by describing in detail exemplary embodiments with reference to the attached drawing in which:

FIG. 1 illustrates a schematic cross-sectional view of a structure of an organic light-emitting device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figure, the dimensions of layers and regions may be exaggerated for clarity of illustration. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

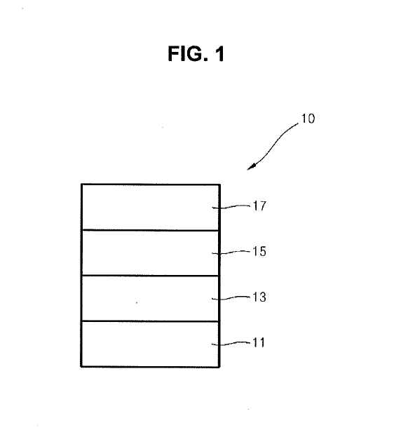

FIG. 1 illustrates a schematic sectional view of an organic light-emitting device 10 according to an embodiment. Hereinafter, a structure of an organic light-emitting device according to an embodiment and a method of manufacturing the same will now be described with reference to FIG. 1.

Referring to FIG. 1, the organic light-emitting device 10 according to the present embodiment includes a substrate 11, a first electrode 13, an organic layer 15, and a second electrode 17.

The substrate 11 may be a suitable substrate for use in an organic light-emitting device. In some embodiments the substrate 11 may be a glass substrate or a transparent plastic substrate with strong mechanical strength, thermal stability, transparency, surface smoothness, ease of handling, and water resistance.

The first electrode 13 may be formed by depositing or sputtering a first electrode-forming material on the substrate 11. When the first electrode 13 constitutes an anode, a material having a high work function may be used as the first electrode-forming material to facilitate hole injection. The first electrode 13 may be a reflective electrode or a transmission electrode. Transparent and conductive materials such as ITO, IZO, SnO₂, and ZnO may be used to form the first electrode. The first electrode 13 may be formed as a reflective electrode using magnesium (Mg), aluminum (Al), aluminum-lithium (Al—Li), calcium (Ca), magnesium-indium (Mg—In), magnesium-silver (Mg—Ag), or the like.

The first electrode 13 may have a single-layer structure or a multi-layer structure including at least two layers. For example, the first electrode 13 may have a three-layered structure of ITO/Ag/ITO.

The organic layer 15 may be disposed on the first electrode 13.

The term “organic layer 15” indicates a plurality of layers disposed between the first electrode 13 and the second electrode 17 of the organic light-emitting device 10. The organic layer 15 may include at least one of a hole injection layer (HIL), a hole transport layer (HTL), a functional layer having both hole injection and hole transport capabilities, a buffer layer, an electron blocking layer (EBL), an emission layer (EML), a hole blocking layer (HBL), an electron transport layer (ETL), an electron injection layer (EIL), and a functional layer having both electron injection and electron transport capabilities.

In some embodiments, the organic layer 15 may include a HIL, a HTL, a buffer layer, an EML, an ETL, and an EIL that are stacked upon one another in this order.

The HIL may be formed on the first electrode 13 by a suitable method, such as vacuum deposition, spin coating, casting, Langmuir-Blodgett (LB) deposition, or the like.

When the HIL is formed using vacuum deposition, vacuum deposition conditions may vary depending on the compound that is used to form the HIL, and the desired structure and thermal properties of the HIL to be formed. For example, vacuum deposition may be performed at a temperature of about 100° C. to about 500° C., a pressure of about 10⁻⁸ torr to about 10⁻³ torr, and a deposition rate of about 0.01 to about 100 Å/sec.

When the HIL is formed using spin coating, the coating conditions may vary depending on the compound that is used to form the HIL, and the desired structure and thermal properties of the HIL to be formed. For example, the coating rate may be in the range of about 2,000 rpm to about 5,000 rpm, and a temperature at which heat treatment is performed to remove a solvent after coating may be in the range of about 80° C. to about 200° C.

A material for forming the HIL may be a known hole injecting material. Examples of the hole injecting material include N,N′-diphenyl-N,N′-bis-[4-(phenyl-m-tolyl-amino)-phenyl]-biphenyl-4,4′-diamine, (DNTPD), a phthalocyanine compound such as copper phthalocyanine, 4,4′,4″-tris(3-methylphenylphenylamino)triphenylamine (m-MTDATA), N,N′-di(1-naphthyl)-N,N′-diphenylbenzidine (NPB), TDATA, 2-TNATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonic acid (Pani/CSA), and polyaniline)/poly(4-styrenesulfonate (PANI/PSS).

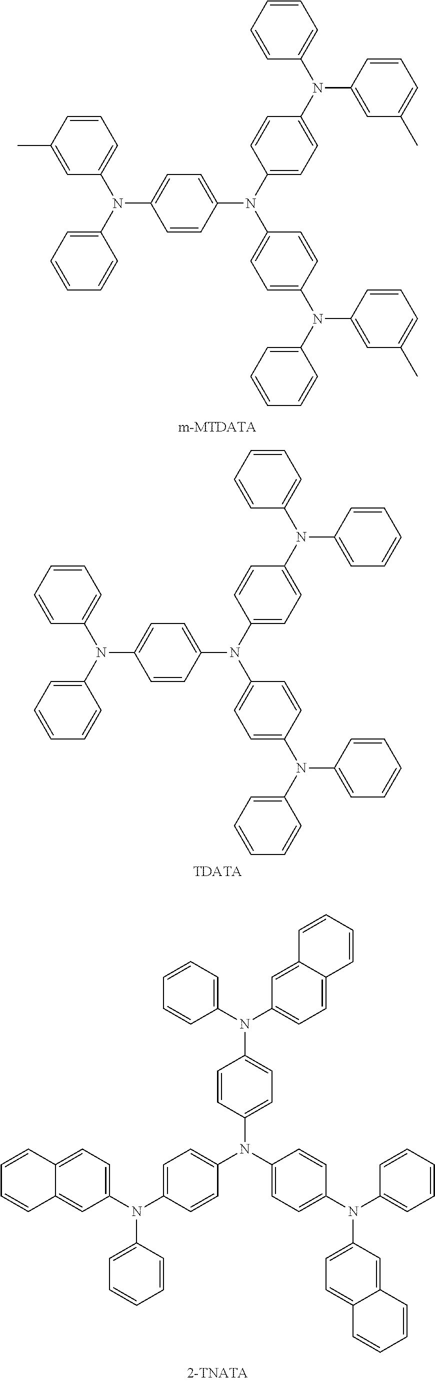

The thickness of the HIL may be about 100 Å to about 10,000 Å, and in some embodiments, may be from about 100 Å to about 1,000 Å. When the thickness of the HIL is within these ranges, the HIL may have good hole injecting ability without a substantial increase in driving voltage.

Then, a HTL may be formed on the HIL by using vacuum deposition, spin coating, casting, Langmuir-Blodgett (LB) deposition, or the like. When the HTL is formed using vacuum deposition or spin coating, the conditions for deposition and coating may be similar to those for the formation of the HIL, though the conditions for the deposition and coating may vary depending on the material that is used to form the HTL.

Examples of suitable HTL forming materials include carbazole derivatives, such as N-phenylcarbazole or polyvinylcarbazole, N,N′-bis(3-methylphenyl)-N,N-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine) (NPB).

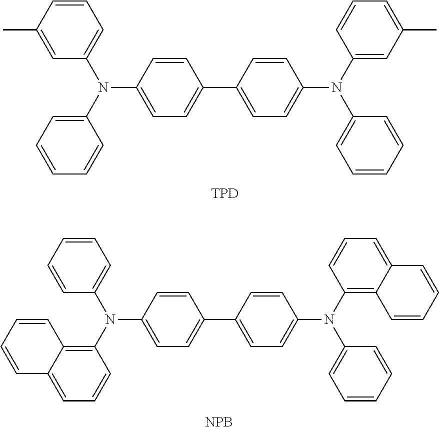

The thickness of the HTL may be from about 50 Å to about 2,000 Å, and in some embodiments, may be from about 100 Å to about 1,500 Å. When the thickness of the HTL is within these ranges, the HTL may have good hole transporting ability without a substantial increase in driving voltage.

The H-functional layer (having both hole injection and hole transport capabilities) may contain at least one material from each group of the hole injection layer materials and hole transport layer materials. The thickness of the H-functional layer may be from about 100 Å to about 10,000 Å, and in some embodiments, may be from about 100 Å to about 1,000 Å. When the thickness of the H-functional layer is within these ranges, the H-functional layer may have good hole injection and transport capabilities without a substantial increase in driving voltage.

In some embodiments, at least one of the HIL, the HTL, and the H-functional layer may include at least one of a compound of Formula 300 below and a compound of Formula 301 below:

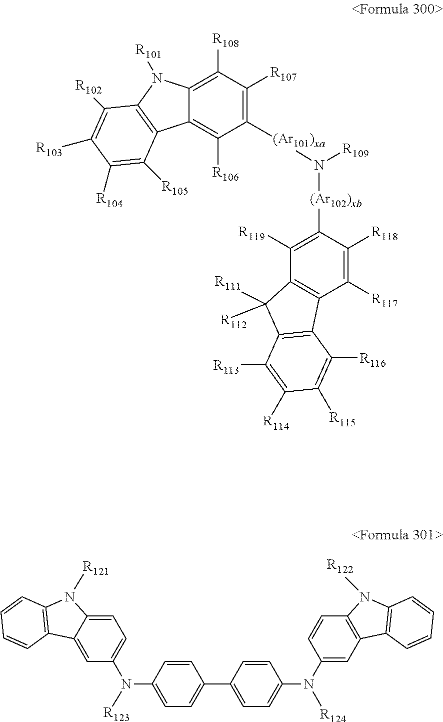

In Formula 300, Ar₁₀₁ and Ar₁₀₂ may be each independently a substituted or unsubstituted C₆-C₆₀ arylene group. In some embodiments, Ar₁₀₁ and Ar₁₀₂ may be each independently one of a phenylene group, a pentalenylene group, an indenylene group, a naphthylene group, an azulenylene group, a heptalenylene group, a substituted or unsubstituted an acenaphthylene group, a fluorenylene group, a phenalenylene group, a phenanthrenylene group, an anthracenylene group, a fluoranthenylene group, a triphenylenylene group, a pyrenylenylene group, a chrysenylene group, a naphthacenylene group, a picenylene group, a perylenylene group, and a pentacenylene group; and a phenylene group, a pentalenylene group, an indenylene group, a naphthylene group, an azulenylene group, a heptalenylene group, a substituted or unsubstituted an acenaphthylene group, a fluorenylene group, a phenalenylene group, a phenanthrenylene group, an anthracenylene group, a fluoranthenylene group, a triphenylenylene group, a pyrenylenylene group, a chrysenylene group, a naphthacenylene group, a picenylene group, a perylenylene group, and a pentacenylene group that are substituted with at least one of a deuterium atom, a halogen atom, a hydroxyl group, a nitro group, a cyano group, an amino group, an amidino group, a hydrazine, a hydrazone, a carboxyl group or salt thereof, a sulfuric acid group or salt thereof, a phosphoric acid group or salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthio group, and a C₂-C₆₀ heteroaryl group.

In Formula 300, xa and xb may be each independently an integer from 0 to 5, for example, may be 0, 1, or 2. For example, xa may be 1, and xb may be 0.

In Formulae 300 and 301 above, R₁₀₁ to R₁₀₈, R₁₁₁ to R₁₁₉, and R₁₂₁ to R₁₂₄ may be each independently a hydrogen atom, a deuterium atom, a halogen atom, a hydroxyl group, a cyano group, a nitro group, an amino group, an amidino group, a hydrazine group, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₅-C₆₀ aryloxy group, or a substituted or unsubstituted C₅-C₆₀ arylthio group. In some embodiments, R₅₁ to R₅₈, R₆₁ to R₆₉, R₇₁, and R₇₂ may be each independently one of a hydrogen atom; a deuterium atom; a halogen atom; a hydroxyl group; a cyano group; a nitro group; an amino group; an amidino group; a hydrazine; a hydrazone; a carboxyl group or a salt thereof; a sulfonic acid group or a salt thereof; a phosphoric acid group or a salt thereof; a C₁-C₁₀ alkyl group (for example, a methyl group, an ethyl group, a propyl group, a butyl group, a pentyl group, a hexyl group, or the like); a C₁-C₁₀ alkoxy group (for example, a methoxy group, an ethoxy group, a propoxy group, a butoxy group, a pentoxy group, or the like); a C₁-C₁₀ alkyl group and a C₁-C₁₀ alkoxy group that are substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; a phenyl group; a naphthyl group; an anthryl group; a fluorenyl group; a pyrenyl group; and a phenyl group, a naphthyl group, an anthryl group, a fluorenyl group, and a pyrenyl group that are substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, and a C₁-C₁₀ alkoxy group.

In Formula 300, R109 may be one of a phenyl group, a naphthyl group, an anthryl group, a biphenyl group, a pyridyl group; and a phenyl group, a naphthyl group, an anthryl group, a biphenyl group, and a pyridyl group that are substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

In an embodiment the compound of Formula 300 may be a compound represented by Formula 300A below:

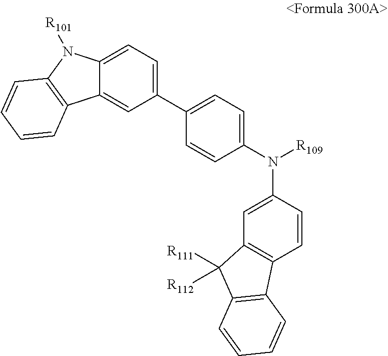

In Formula 300A, R₁₀₁, R₁₁₁, R₁₁₂, and R₁₀₉ may be as defined above.

In some implementations, at least one of the HIL, the HTL, and the H-functional layer may include at least one of compounds represented by Formulae 301 to 320 below:

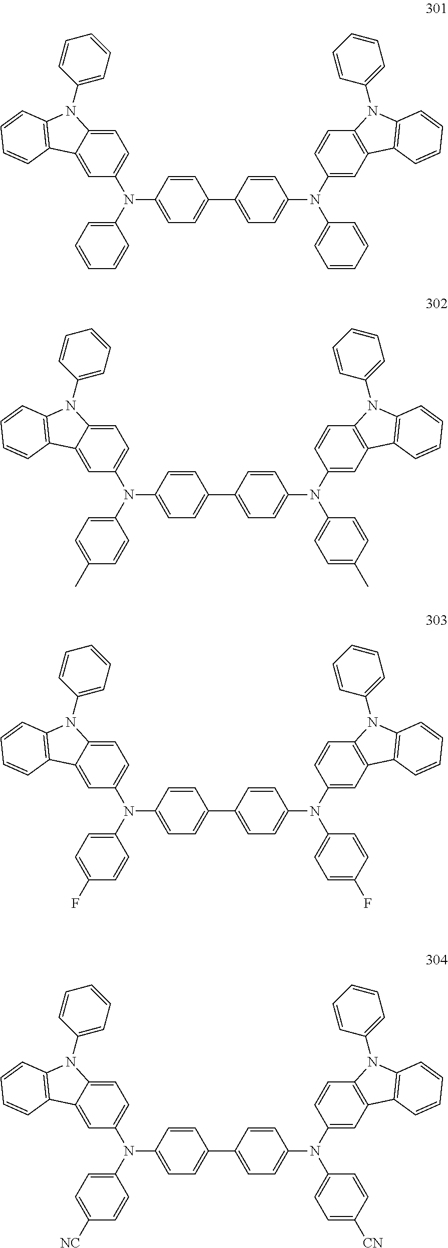 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

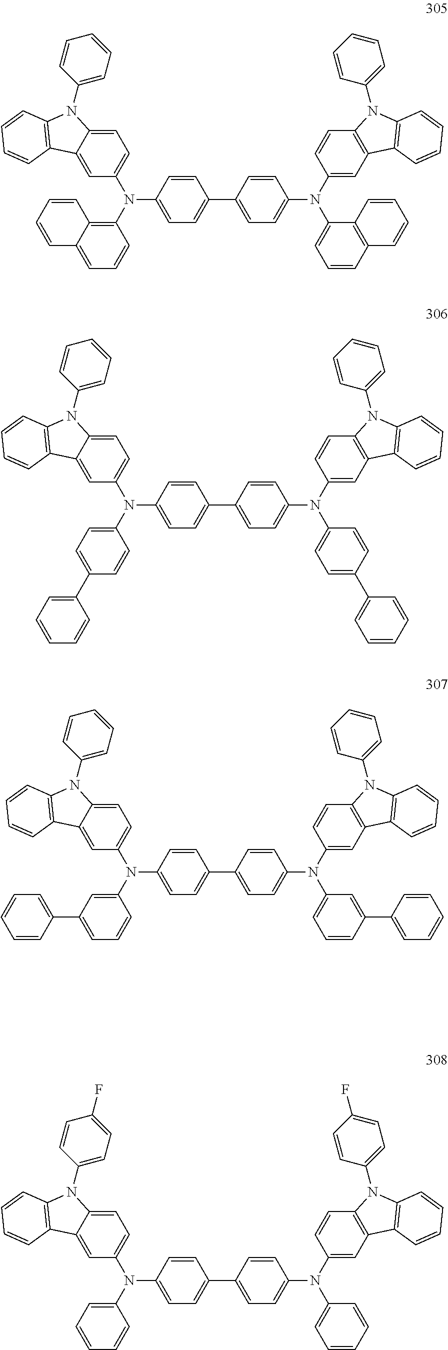 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

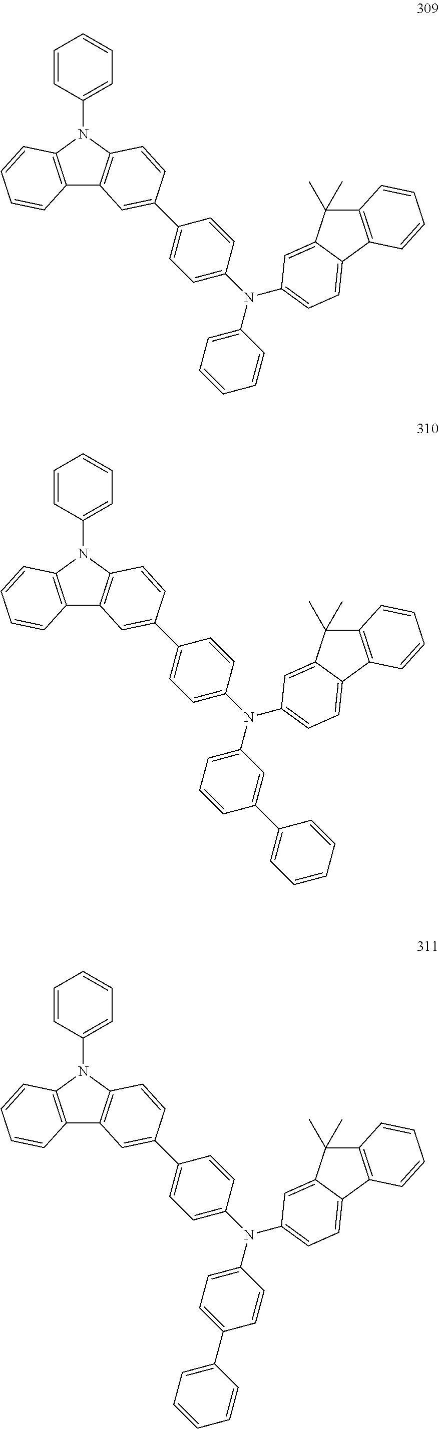 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

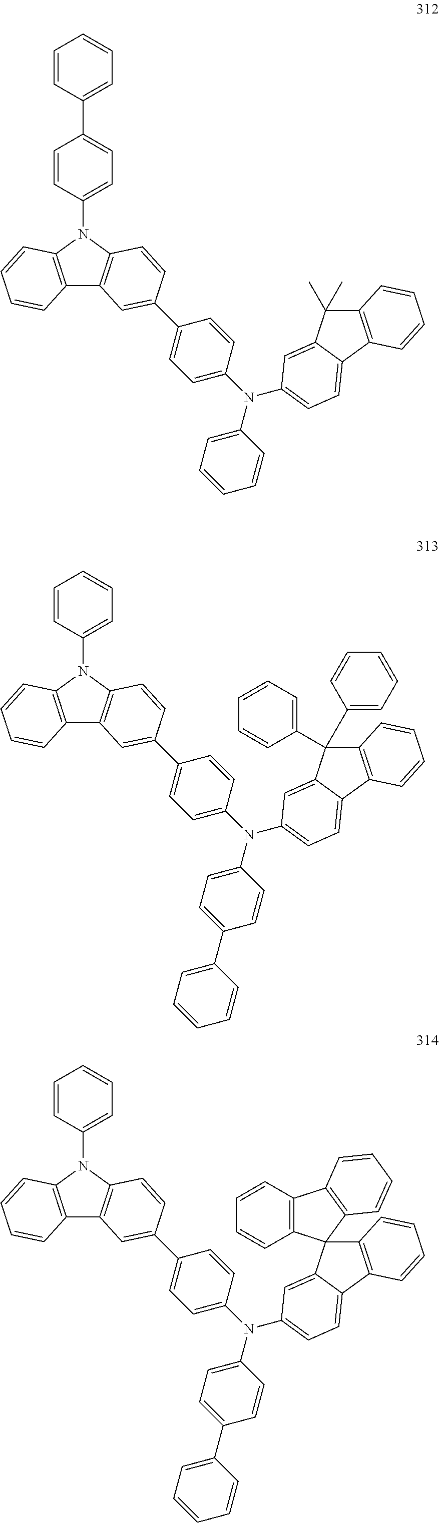 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

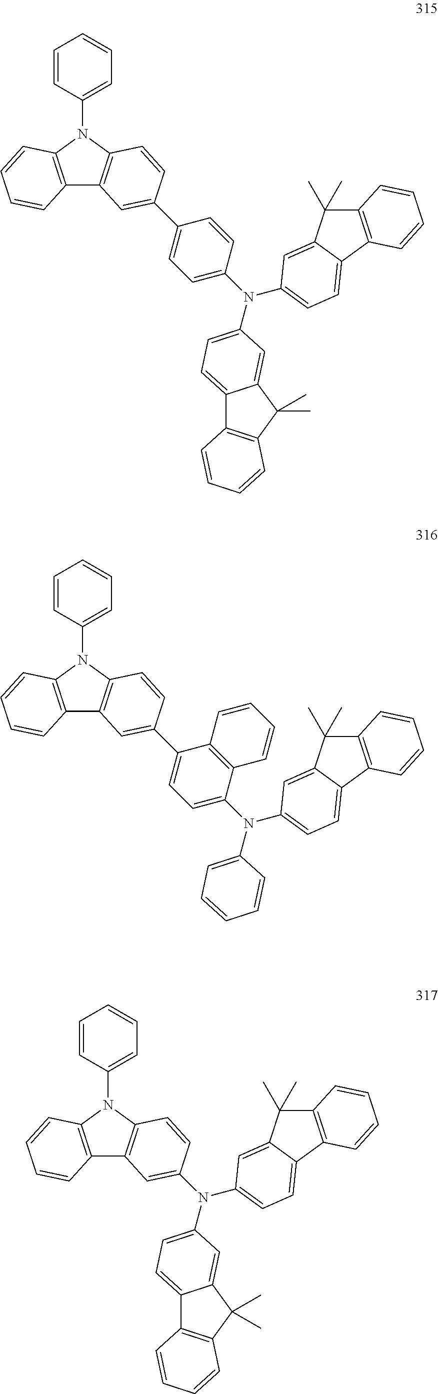 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

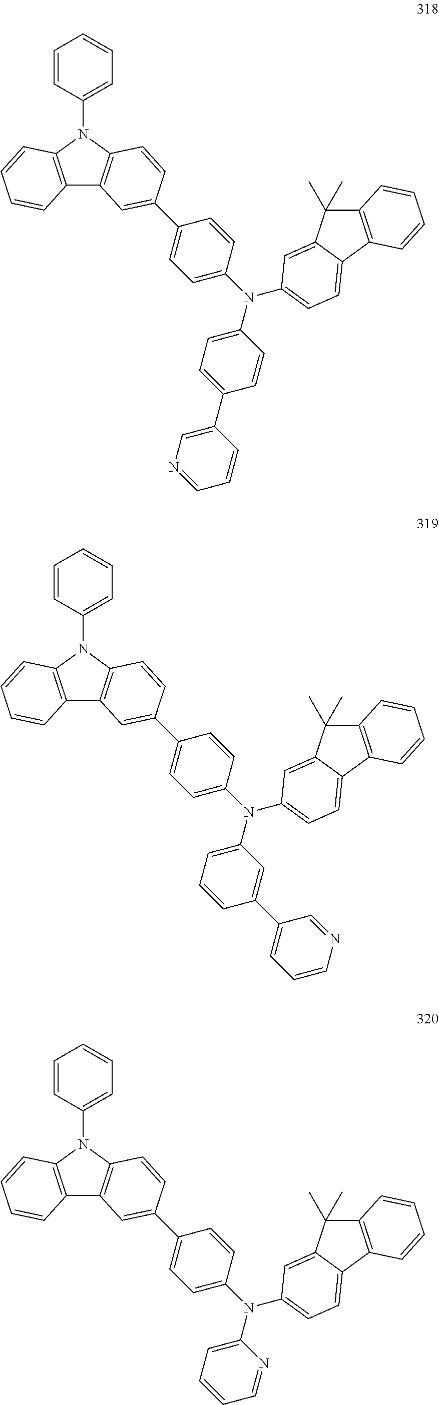 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

At least one of the HIL, the HTL, and the H-functional layer may further include a charge-generating material for improved layer conductivity, in addition to a known hole injecting material, hole transport material, and/or material having both hole injection and hole transport capabilities as described above.

The charge-generating material may be, for example, a p-dopant. The p-dopant may be one of a quinine derivative, a metal oxide, and a compounds with a cyano group, as examples. Examples of the p-dopant include quinone derivatives such as tetracyanoquinonedimethane (TCNQ), 2,3,5,6-tetrafluoro-tetracyano-1,4-benzoquinonedimethane (F4-TCNQ), or the like; metal oxides such as tungsten oxide, molybdenum oxide, or the like; and cyano-containing compounds such as Compound 200 below.

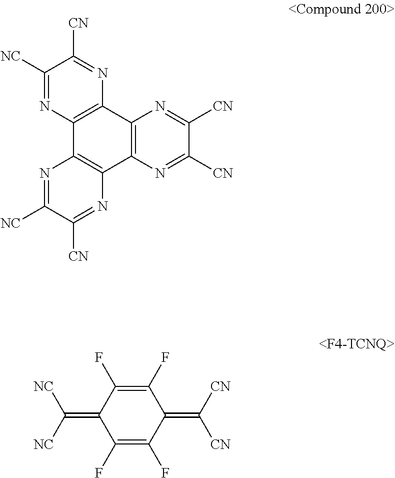 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the hole injection layer, hole transport layer, or H-functional layer further includes a charge-generating material, the charge-generating material may be homogeneously dispersed or inhomogeneously distributed in the layer.

The buffer layer may be disposed between at least one of the HIL, the HTL, and the H-functional layer, and the EML. The buffer layer may compensate for an optical resonance distance of light according to a wavelength of the light emitted from the EML, and thus may increase efficiency. The butter layer may include a suitable hole injecting material or hole transporting material. In some other embodiments, the buffer layer may include the same material as one of the materials included in the HIL, the HTL, and the H-functional layer that underlie the buffer layer.

An EML may be formed on the HTL, H-functional layer, or buffer layer by vacuum deposition, spin coating, casting, Langmuir-Blodgett (LB) deposition, or the like. When the EML is formed using vacuum deposition or spin coating, the deposition and coating conditions may be similar to those for the formation of the HIL, though the conditions for deposition and coating may vary depending on the material that is used to form the EML.

The EML may include a silane-based compound represented by Formula 1 below and an anthracene-based compound represented by Formula 20 below.

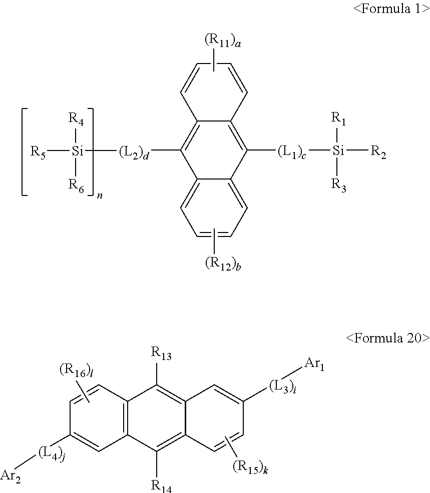

The silane-based compound of Formula 1 may serve as a host, and the anthracene-based compound of Formula 20 may serve as a dopant. The anthracene-based compound of Formula 20 may also serve as a green fluorescent dopant emitting green light based on a fluorescence mechanism. A weight ratio of the silane-based compound to the anthracene-based compound in the EML may be from about 99.9:0.01 to about 80:20.

In Formula 1 above, n may be 0 or 1. When n is 0, the substituent —Si(R₄)(R₅)(R₆) is not present in the compound represented by Formula 1.

In Formula 1, R₁ to R₆ may be each independently selected from a substituted or unsubstituted C₁-C₆₀ alkyl group, a 3- to 10-membered substituted or unsubstituted non-condensed ring group, and a substituted or unsubstituted condensed ring group in which at least two rings are fused to each other, wherein when n is 0, at least one of R₁ to R₃ may be a substituted or unsubstituted condensed ring group in which at least two rings are fused to each other, and when n is 1, at least one of R₁ to R₆ may be a substituted or unsubstituted condensed ring group in which at least two rings are fused to each other.

As used herein, the terms “the 3- to 10-membered substituted or unsubstituted non-condensed ring group” refers to a 3- to 10-membered cyclic group with one ring usable to form a condensed ring. Ring-member atoms of “the 3- to 10-membered substituted or unsubstituted non-condensed ring group” may be selected from among C, N, O, P, S, and Si. This will be understood with reference to Formulae 2A to 2T described below.

As used herein, the terms “condensed ring group with condensed at least two substituted or unsubstituted rings” refers to a group with at least two rings that are fused to each other. The “condensed ring group with condensed at least two substituted or unsubstituted rings” may be an aromatic or non-aromatic group, and may include 3 to 60 ring-member atoms, wherein these ring-member atoms may be selected from among C, N, O, P, S, and Si. The “condensed ring group with condensed at least two substituted or unsubstituted rings” will be understood with reference to, for example, Formulae 3A to 3R and Formulae 4A to 4J described below.

In Formula 1 above, R₁ to R₆ may be each independently selected from

i) a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexcenyl group, a cyclohexadienyl group, a cyclocycloheptadienyl group, a thiophenyl group, a furanyl group, a pyrrolyl group, an imidazolyl group, a pyrazolyl group, an isothiazolyl group, an isoxazolyl group, a thiazolyl group, an oxazolyl group, an oxadiazolyl group, a thiadiazolyl group, a triazolyl group, a phenyl group, a pyridinyl group, a pyrazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthylenyl group, a fluorenyl group, a spiro-fluorenyl group, a carbazolyl group, an anthryl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxatinyl group, and a phenanthridinyl group; and

ii) a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexcenyl group, a cyclohexadienyl group, a cyclocycloheptadienyl group, a thiophenyl group, a furanyl group, a pyrrolyl group, an imidazolyl group, a pyrazolyl group, an isothiazolyl group, an isoxazolyl group, a thiazolyl group, an oxazolyl group, an oxadiazolyl group, a thiadiazolyl group, a triazolyl group, a phenyl group, pyridinyl group, a pyrazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthylenyl group, a fluorenyl group, a spiro-fluorenyl group, a carbazolyl group, an anthryl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxatinyl group, and a phenanthridinyl group, each substituted with at least one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₁₁)(Q₁₂) (where Q₁₁ and Q₁₂ are each independently a hydrogen atom, a C₁-C₁₀ alkyl group, a C₆-C₂₀ aryl group, or a C₂-C₂₀ heteroaryl group),

wherein at least one of R₁ to R₃ when n is 0, or at least one of R₁ to R₆ when n is 1 may be each independently selected from

i) a pentalenyl group, an indenyl group, a naphthyl group, an azulenyl group, a heptalenyl group, a biphenylenyl group, an indacenyl group, an acenaphthylenyl group, a fluorenyl group, a spiro-fluorenyl group, a carbazolyl group, an anthryl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxatinyl group, and a phenanthridinyl group; and

ii) a pentalenyl group, an indenyl group, a naphthyl group, an azulenyl group, a heptalenyl group, a biphenylenyl group, an indacenyl group, an acenaphthylenyl group, a fluorenyl group, a spiro-fluorenyl group, a carbazolyl group, an anthryl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxatinyl group, and a phenanthridinyl group, each substituted with at least one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₁₁)(Q₁₂) (where Q₁₁ and Q₁₂ are each independently a hydrogen atom, a C₁-C₁₀ alkyl group, a C₆-C₂₀ aryl group, or a C₂-C₂₀ heteroaryl group).

For example, in Formula 1, R₁ to R₆ may be each independently selected from

i) a methyl group, an ethyl group, a n-propyl group, an i-propyl group, a n-butyl group, an i-butyl group, a t-butyl group, a pentyl group, a hexyl group, a heptyl group, an octyl group, a nonyl group, and a decyl group;

ii) a methyl group, an ethyl group, a n-propyl group, an i-propyl group, a n-butyl group, an i-butyl group, a t-butyl group, a pentyl group, a hexyl group, a heptyl group, an octyl group, a nonyl group, and a decyl group, each substituted with at least one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₁₁)(Q₁₂) (where Q₁₁ and Q₁₂ are each independently, a hydrogen atom, a C₁-C₁₀ alkyl group, a C₆-C₂₀ aryl group or a C₂-C₂₀ heteroaryl group);

iii) groups represented by Formulae 2A to 2T below; and

iv) groups represented by Formulae 3A to 3R below,

wherein at least one of R₁ to R₃ when n is 0, or at least one of R₁ to R₆ when n is 1 are each independently selected from groups represented by Formulae 3A to 3R below:

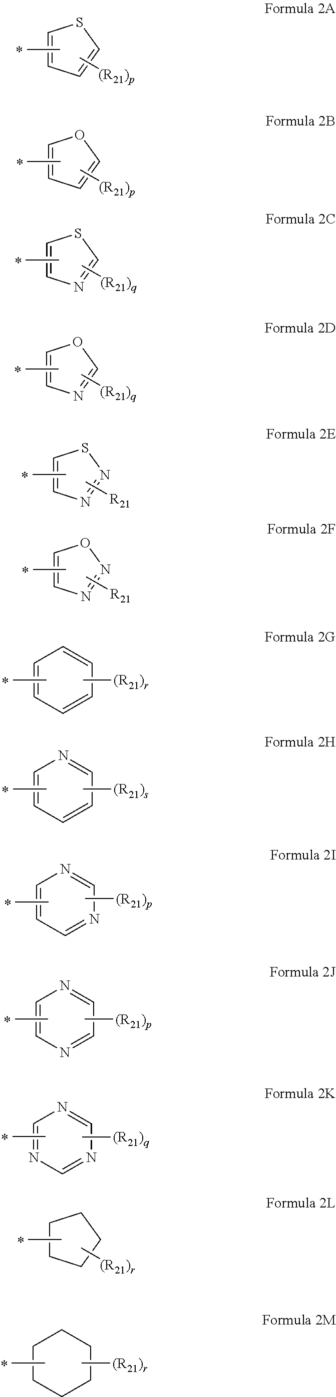

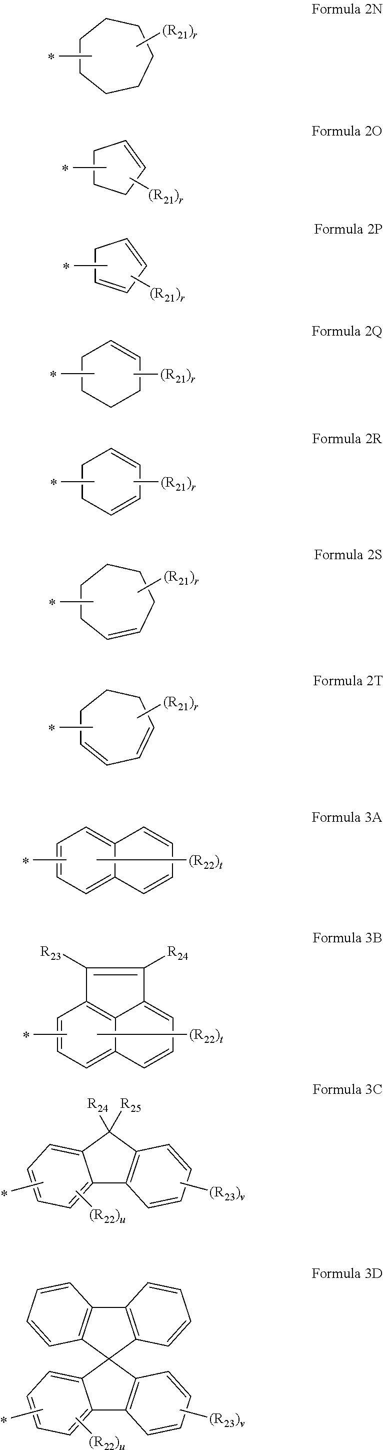

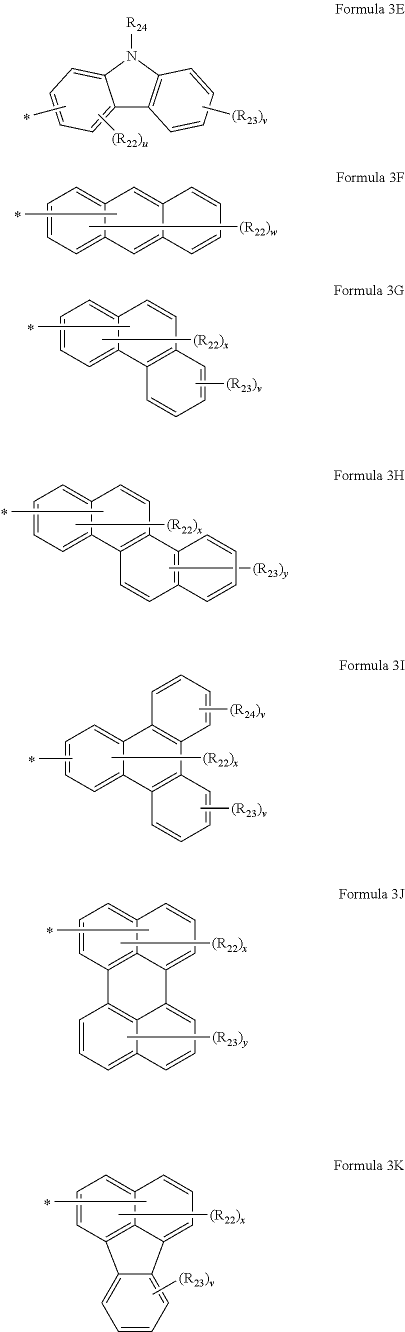

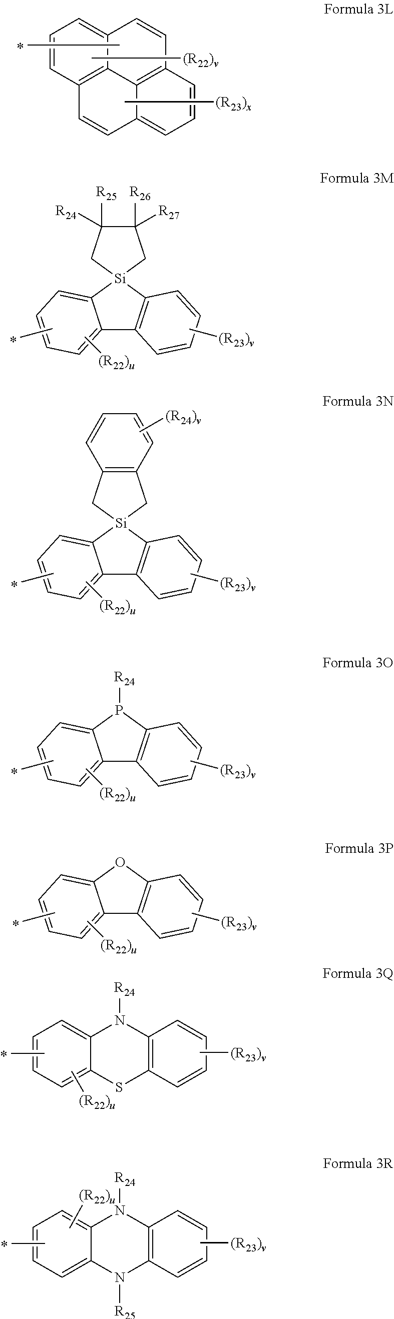

In Formulae 2A to 2T, and Formulae 3A to 3R above,

R₂₁ to R₂₇ may be each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₂₁)(Q₂₂) (where Q₂₁ and Q₂₂ are each independently a hydrogen atom, a C₁-C₁₀ alkyl group, a C₆-C₂₀ aryl group, or a C₂-C₂₀ heteroaryl group);

p and u may be each independently an integer from 1 to 3;

q may be 1 or 2;

r and x may be each independently an integer from 1 to 5;

s and v may be each independently an integer from 1 to 4;

t may be an integer from 1 to 7;

w may be an integer from 1 to 9;

y may be an integer from 1 to 6; and

* indicates a binding site to a Si atom.

For example, in Formulae 2A to 2T, and Formulae 3A to 3R above, R₂₁ to R₂₇ may be each independently selected from a hydrogen atom, a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthryl group, a dimethyl-fluorenyl group, a phenyl-carbazolyl group, a pyrenyl group, a chrysenyl group, a benzothiazolyl group, a benzoxazolyl group, a phenyl-benzoimidazolyl group, and —N(Q₂₁)(Q₂₂), wherein Q₂₁ and Q₂₂ may be each independently selected from a hydrogen atom, a C₁-C₁₀ alkyl group, a phenyl group, a naphthyl group, and an anthryl group.

In some embodiments, R₁ to R₆ in Formula 1 may be each independently one selected from

a methyl group, an ethyl group, an n-propyl group, an i-propyl group, an n-butyl group, an i-butyl group, a t-butyl group, a pentyl group, a hexyl group, a heptyl group, an octyl group, a nonyl group, and a decyl group; and

a methyl group, an ethyl group, an n-propyl group, an i-propyl group, an n-butyl group, an i-butyl group, a t-butyl group, a pentyl group, a hexyl group, a heptyl group, an octyl group, a nonyl group, and a decyl group, each substituted with at least one of a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a phenyl group, a naphthyl group, and an anthryl group;

a group represented by Formula 2G below; and

groups represented by Formulae 4A to 4J below,

wherein at least one of R₁ to R₃ when n is 0, or at least one of R₁ to R₆ when n is 1 may be each independently selected from groups represented by Formulae 4A to 4J below:

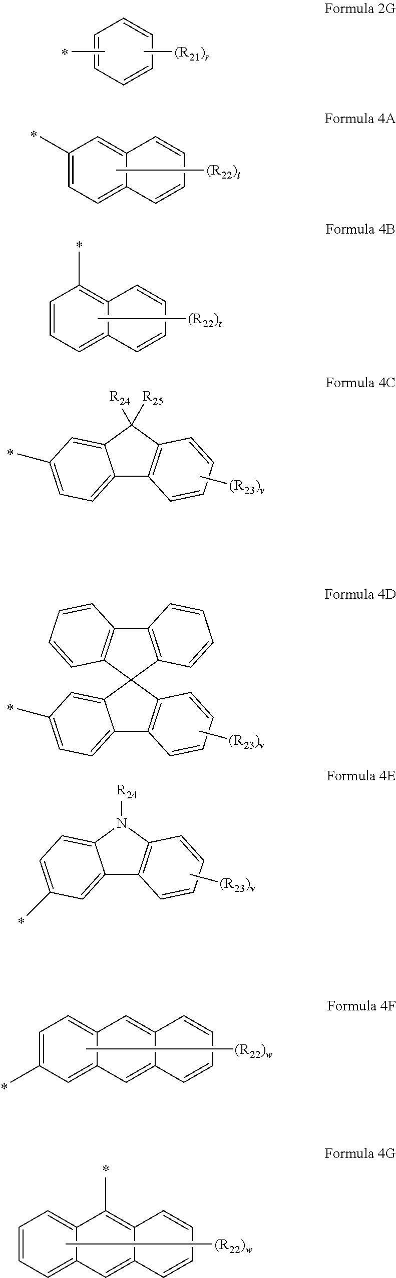

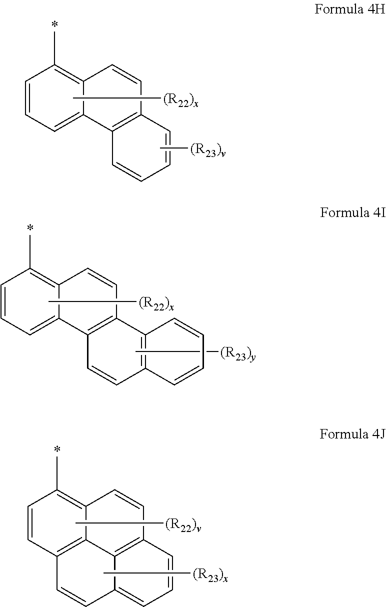

In some embodiments, in Formula 2G and Formulae 4A to 4J above,

R₂₁ to R₂₅ may be each independently selected from a hydrogen atom, a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid or a salt thereof, a C₁-C₂₀ alkyl group, a C₁-C₂₀ alkoxy group, a phenyl group, a naphthyl group, an anthryl group, a dimethyl-fluorenyl group, a phenyl-carbazolyl group, a pyrenyl group, a chrysenyl group, a benzothiazolyl group, a benzoxazolyl group, a phenyl-benzoimidazolyl group, or —N(Q₂₁)(Q₂₂), wherein Q₂₁ and Q₂₂ are each independently a hydrogen atom, a C₁-C₁₀ alkyl group, a phenyl group, a naphthyl group, or an anthryl group;

r and x may be each independently an integer from 1 to 5;

v may be an integer from 1 to 4;

t may be an integer from 1 to 7;

w may be an integer from 1 to 9;

y may be an integer from 1 to 6; and

* indicates a binding site to a Si atom.

For example, L₁ to L₄ in Formulae 1 and 20 may be each independently selected from a substituted or unsubstituted C₃-C₁₀ cycloalkylene group, a substituted or unsubstituted C₃-C₁₀ cycloalkenylene group, a substituted or unsubstituted C₃-C₁₀ heterocycloalkylene group, a substituted or unsubstituted C₃-C₁₀ heterocycloalkenylene group, a substituted or unsubstituted C₆-C₆₀ arylene group, and a substituted or unsubstituted C₂-C₆₀ heteroarylene group.

In some embodiments, L₁ to L₄ in Formulae 1 and 20 may be each independently selected from

i) a cyclopropylene group, a cyclobutylene group, a cyclopentylene group, a cyclohexylene group, a cycloheptylene group, a cyclooctylene group, a cyclopentenylene group, a cyclopentadienylene group, a cyclohexcenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylene group, an indacenylene group, an acenaphthylenylene group, a fluorenylene group, a spiro-fluorenylene group, a carbazolylene group, an anthrylene group, a phenalenylene group, a phenanthrenylene group, a perylenylene group, a fluoranthenylene group, a naphthacenylene group, a picenylene group, a pentaphenylene group, a hexacenylene group, a dibenzofuranylene group, a dibenzothiophenylene group, a phenothiazinylene group, a phenoxazinylene group, a dihydrophenazinylene group, a phenoxathiinylene group, and a phenanthridinylene group; and

ii) a cyclopropylene group, a cyclobutylene group, a cyclopentylene group, a cyclohexylene group, a cycloheptylene group, a cyclooctylene group, a cyclopentenylene group, a cyclopentadienylene group, a cyclohexcenylene group, a cyclohexadienylene group, a cycloheptadienylene group, a thiophenylene group, a furanylene group, a pyrrolylene group, an imidazolylene group, a pyrazolylene group, an isothiazolylene group, an isoxazolylene group, a thiazolylene group, an oxazolylene group, an oxadiazolylene group, a thiadiazolylene group, a triazolylene group, a phenylene group, a pyridinylene group, a pyrazinylene group, a pyrimidinylene group, a pyridazinylene group, a triazinylene group, a pentalenylene group, an indenylene group, a naphthylene group, an azulenylene group, a heptalenylene group, a biphenylene group, an indacenylene group, an acenaphthylenylene group, a fluorenylene group, a spiro-fluorenylene group, a carbazolylene group, an anthrylene group, a phenalenylene group, a phenanthrenylene group, a perylenylene group, a fluoranthenylene group, a naphthacenylene group, a picenylene group, a pentaphenylene group, a hexacenylene group, a dibenzofuranylene group, dibenzothiophenylene group, a phenothiazinylene group, a phenoxazinylene group, a dihydrophenazinylene group, a phenoxathiinylene group, and a phenanthridinylene group, each substituted with at least one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₁₁)(Q₁₂) (where Q₁₁ and Q₁₂ may be each independently a hydrogen atom, a C₁-C₁₀ alkyl group, a C₆-C₂₀ aryl group, or a C₂-C₂₀ heteroaryl group).

In some other embodiments, L₁ to L₄ in Formulae 1 and 20 above may be each independently selected from groups represented by Formulae 5A to 5J below:

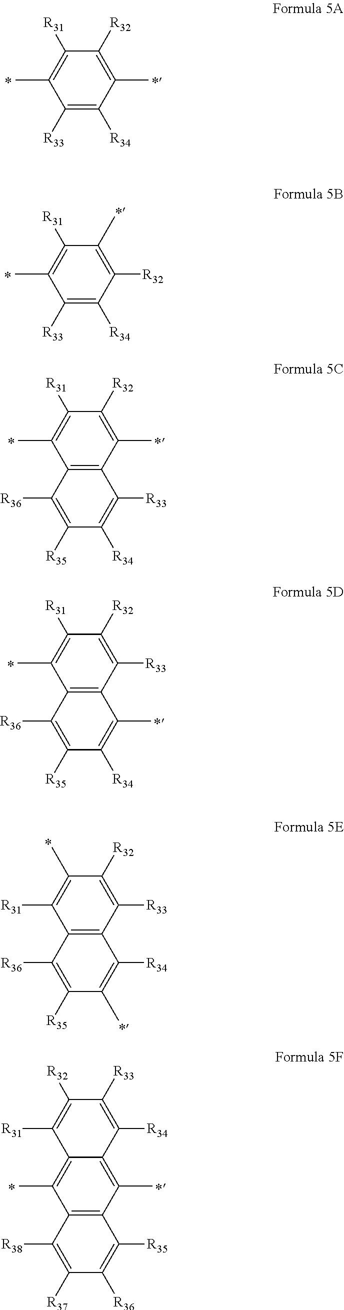

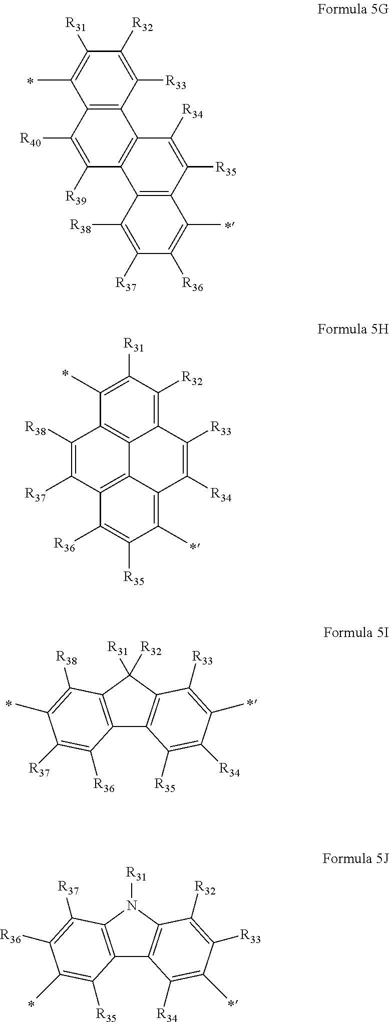

In Formulae 5A to 5J above,

R₃₁ to R₄₀ may be each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₃₁)(Q₃₂) (where Q₃₁ and Q₃₂ are each independently a hydrogen atom, a C₁-C₁₀ alkyl group, a C₆-C₂₀ aryl group, or a C₂-C₂₀ heteroaryl group); and

* may indicate a binding site to an anthracene core in Formulae 1 and 20. In Formula 1, *¹ may indicate a binding site to Si. When c or d are 2 or 3, either * or *¹ may indicate a binding site to another L₁ or L₂. In Formula 20, *¹ may indicate a binding site to Ar₁ or Ar₂. When i or j are 2 or 3, either * or *¹ may indicate a binding site to another L₃ or L₄

For example, R₃₁ to R₄₀ in Formulae 5A to 5J may be each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthryl group, a dimethyl-fluorenyl group, a phenyl-carbazolyl group pyrenyl group, a chrysenyl group, a benzothiazolyl group, a benzoxazolyl group, and a phenyl-benzoimidazolyl group.

In Formula 1 above, c, which indicates the number of L₁s, may be an integer from 1 to 3. When c is 2 or greater, at least two of L₁s may be identical to or different from each other. In Formula 1 above, d, which indicates the number of L₂s, may be an integer from 1 to 3. When d is 2 or greater, at least two of L₂s may be identical to or different from each other. In Formula 1 above, c and d may be both 1.

For example, in Formulae 1 and 20 above, R₁₁ to R₁₆ may be each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthiol group, a substituted or unsubstituted C₂-C₆₀ heteroaryl group, —N(Q₁)(Q₂), and —Si(Q₃)(Q₄)(Q₅), where Q₁ to Q₅ may be each independently selected from a hydrogen atom, a C₁-C₁₀ alkyl group, a C₆-C₂₀ aryl group, and a C₂-C₂₀ heteroaryl group.

In some embodiments, R₁₁ to R₁₆ in Formulae 1 and 20 may be each independently selected from a hydrogen atom, a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, and an anthryl group.

In some other embodiments, R₁₁ to R₁₆ in Formulae 1 and 20 may be hydrogen atoms.

In some embodiments, in Formula 1 above, n may be 1; R₁, R₃, R₄, and R₆ may be each independently a substituted or unsubstituted C₁-C₆₀ alkyl group; and R₂ and R₅ are each independently a 3- to 10-membered substituted or unsubstituted non-condensed ring group, or a condensed ring group with condensed at least two substituted or unsubstituted rings.

In some embodiments, in Formula 1 above, n may be 0; R₁ and R₃ may be each independently a substituted or unsubstituted C₁-C₆₀ alkyl group; and R₂ may be a condensed ring group with condensed at least two substituted or unsubstituted rings.

In some embodiments, the silane-based compound of Formula 1 above may be one of Compounds 1 to 60 below:

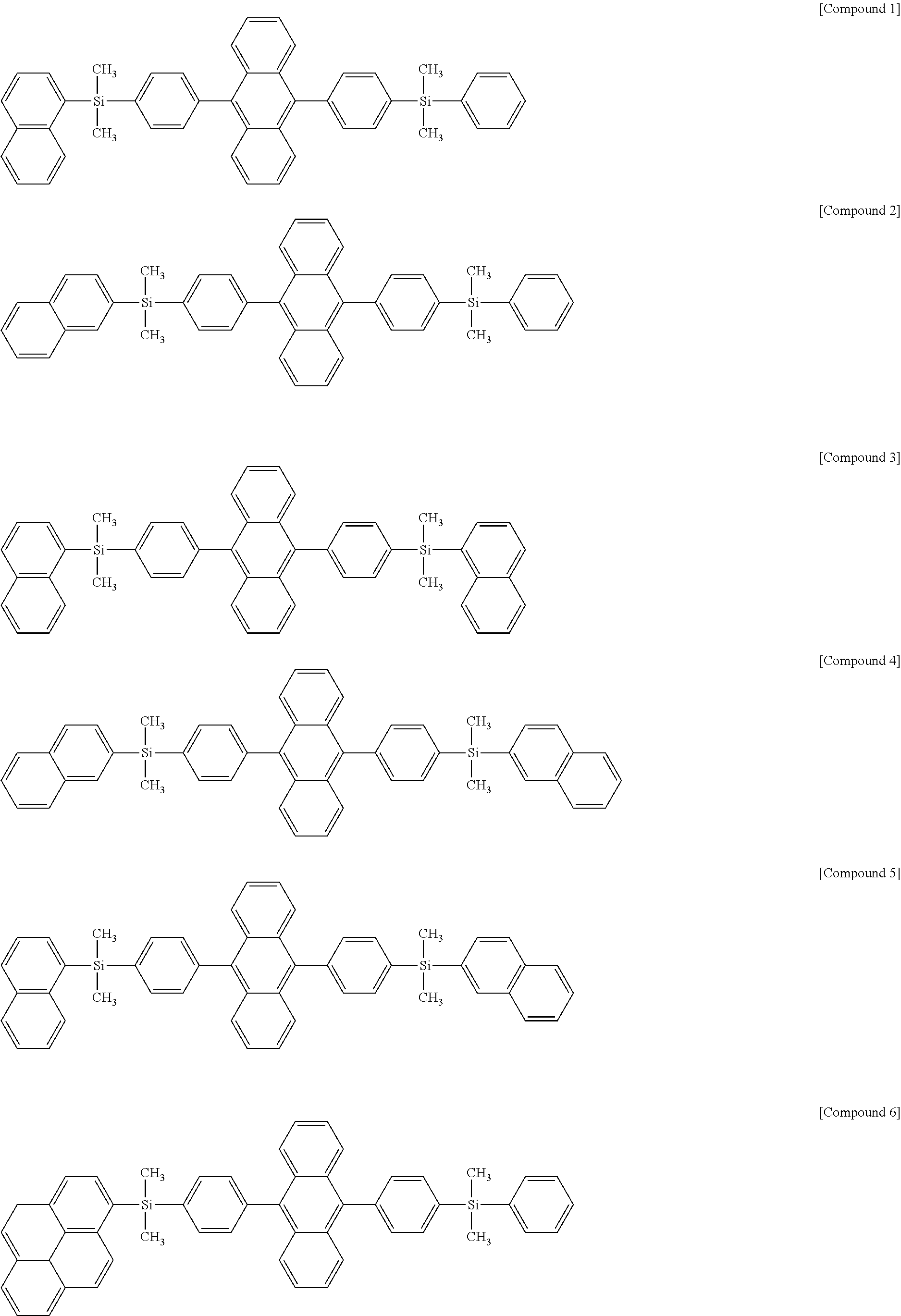

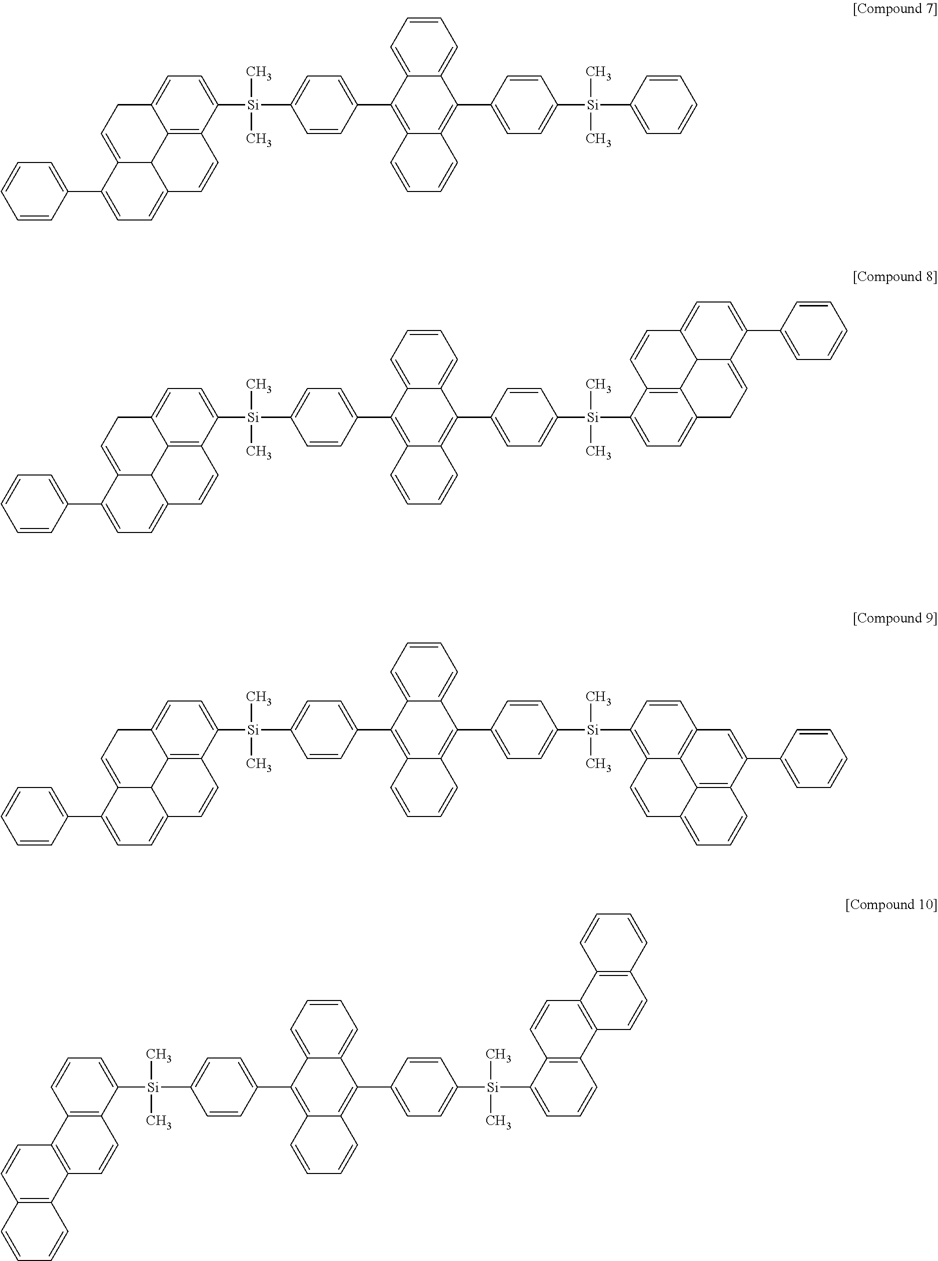

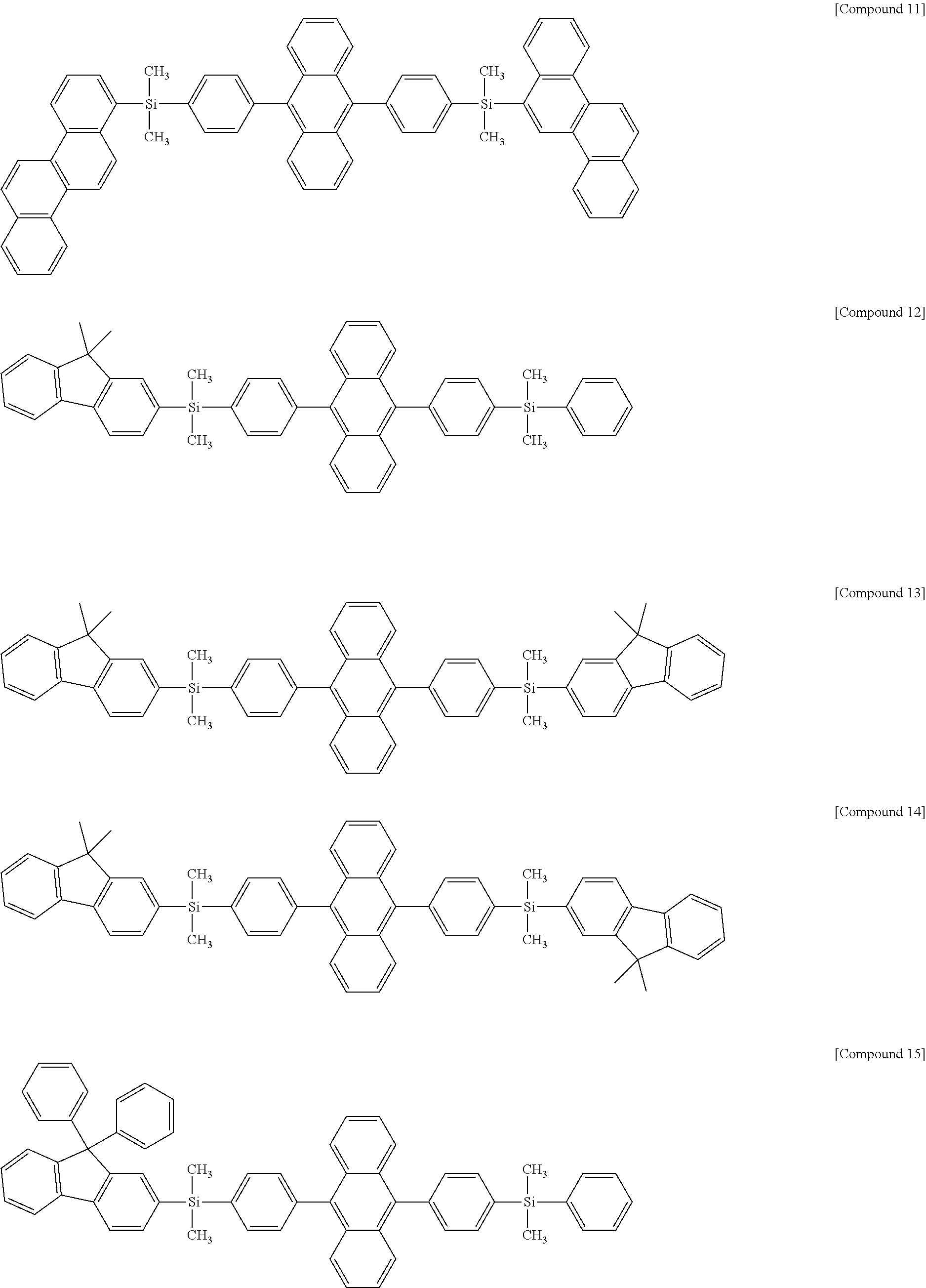

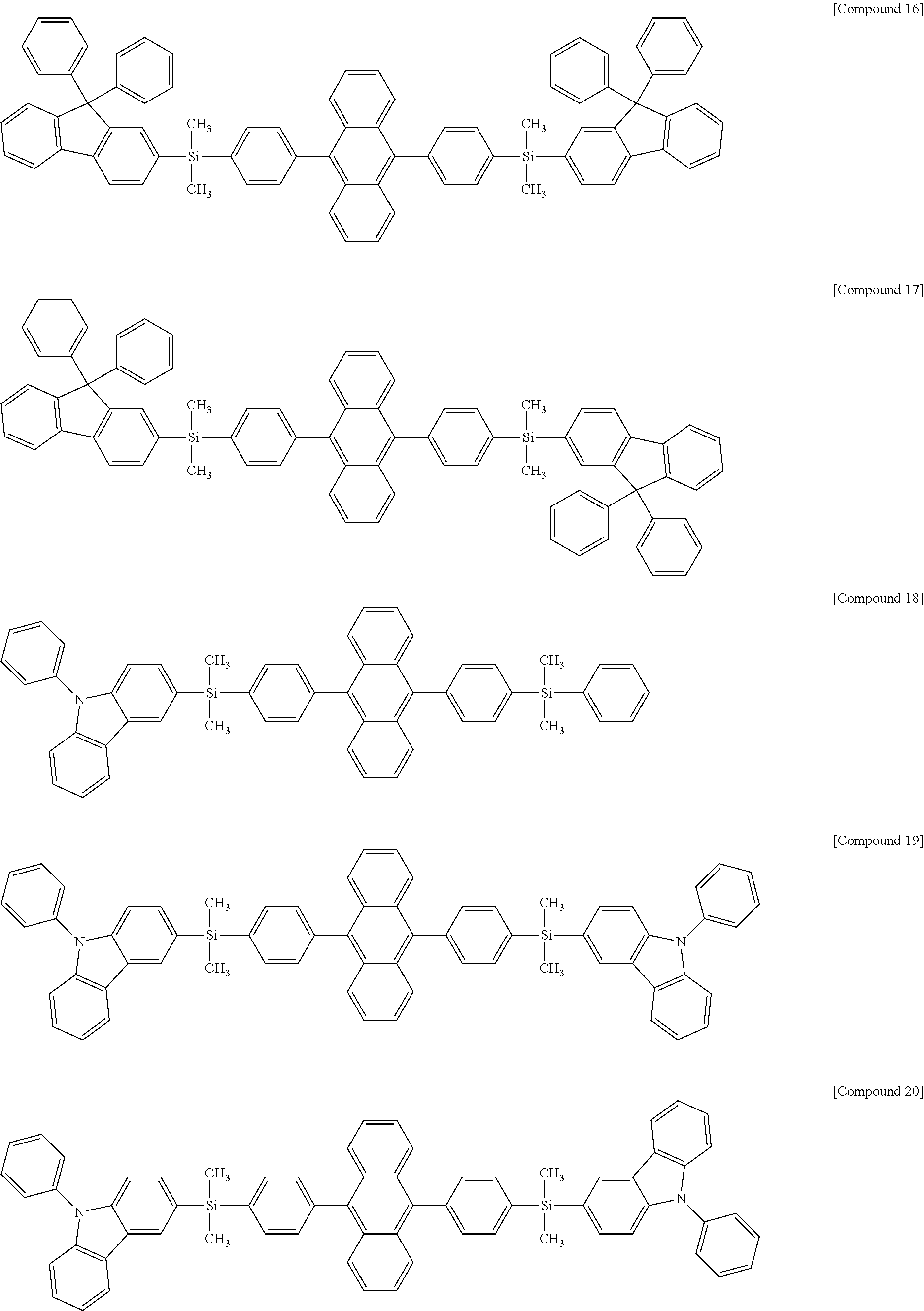

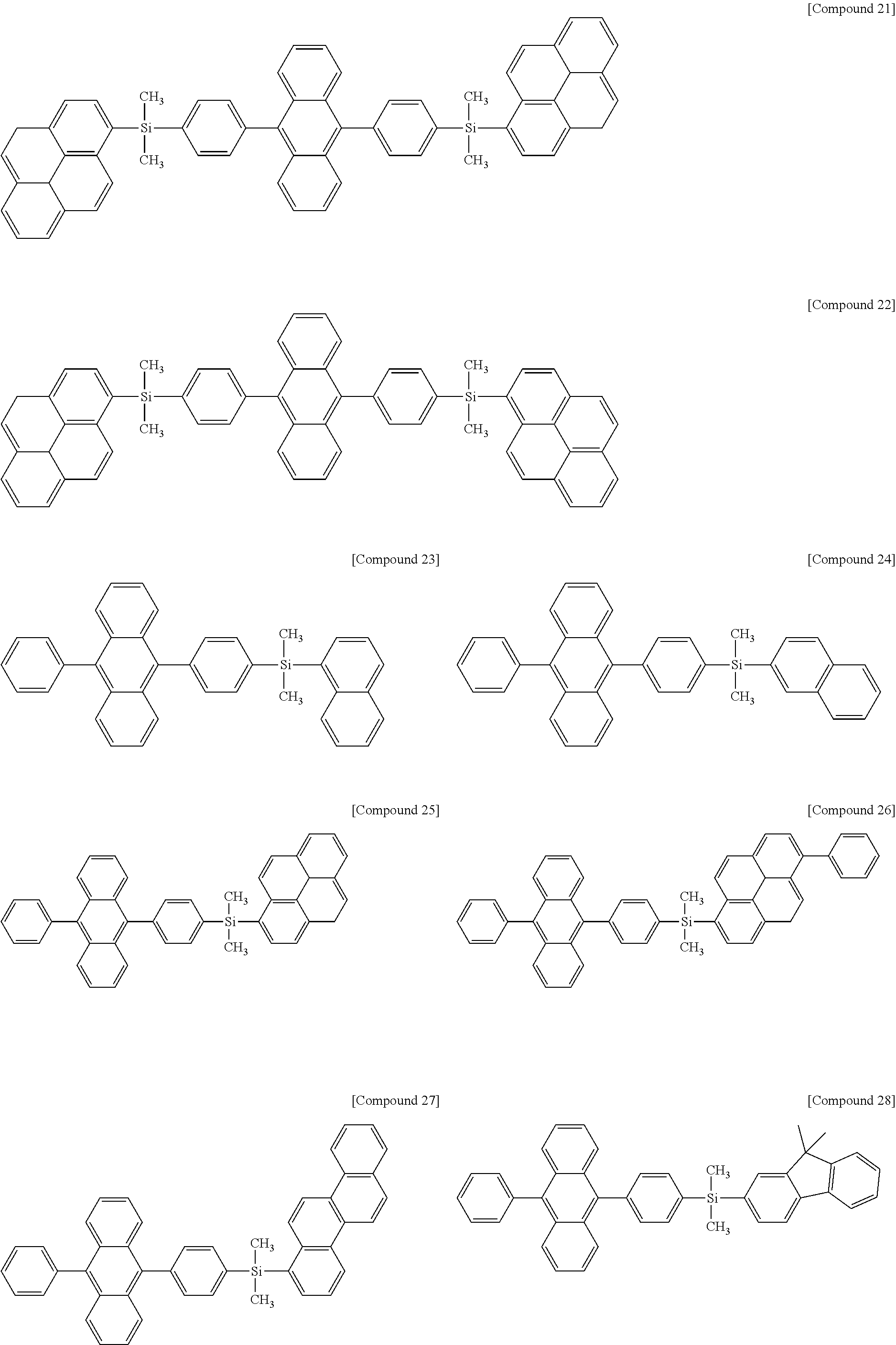

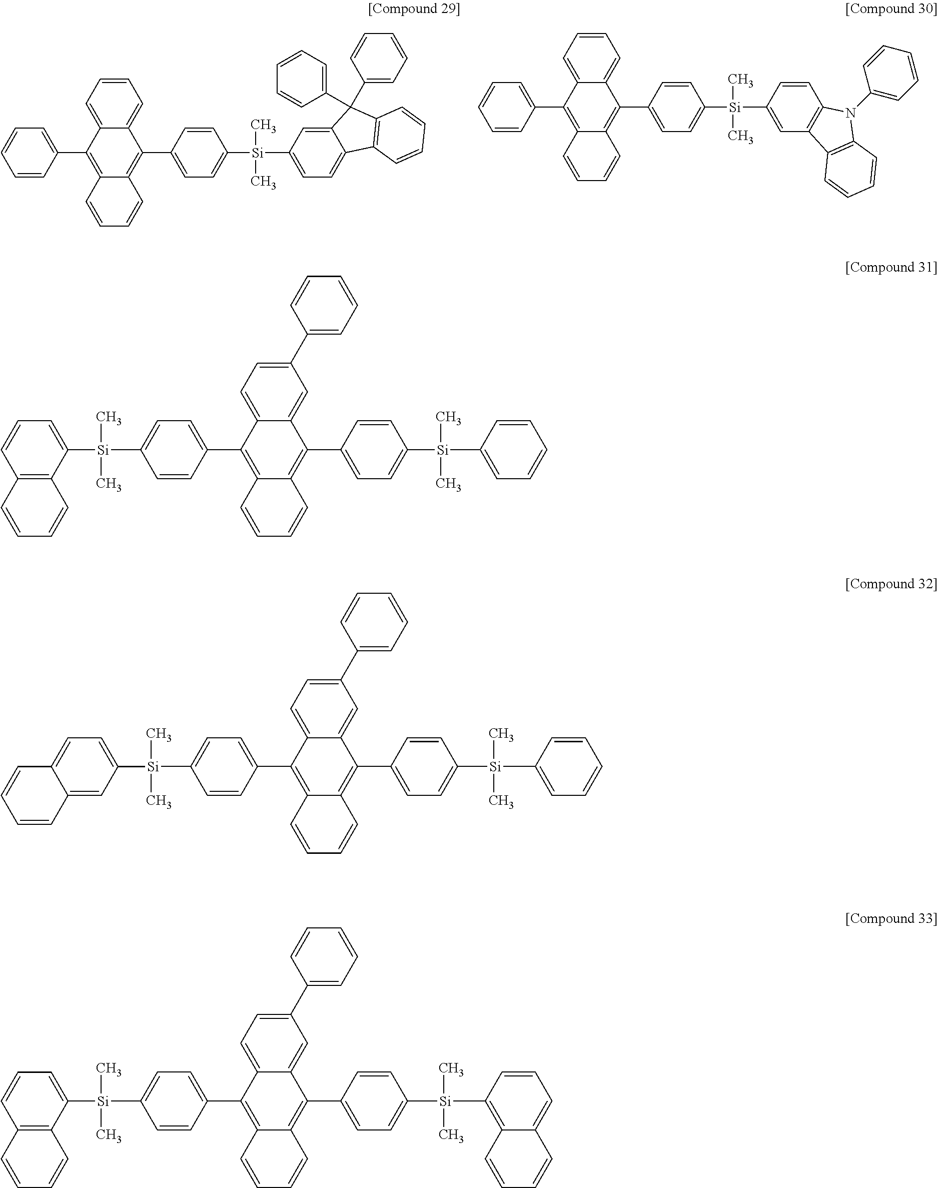 [SMILES: C[Si](C)(c1ccc(-c2c3ccccc3c(-c3ccccc3)c3ccccc23)cc1)c1ccc2c(c1)C(c1ccccc1)(c1ccccc1)c1ccccc1-2 ; C[Si](C)(c1ccc(-c2c3ccccc3c(-c3ccccc3)c3ccccc23)cc1)c1ccc2c(c1)c1ccccc1n2-c1ccccc1 ; C[Si](C)(c1ccccc1)c1ccc(-c2c3ccccc3c(-c3ccc([Si](C)(C)c4cccc5ccccc45)cc3)c3ccc(-c4ccccc4)cc23)cc1 ; C[Si](C)(c1ccccc1)c1ccc(-c2c3ccccc3c(-c3ccc([Si](C)(C)c4ccc5ccccc5c4)cc3)c3ccc(-c4ccccc4)cc23)cc1 ; C[Si](C)(c1ccc(-c2c3ccccc3c(-c3ccc([Si](C)(C)c4cccc5ccccc45)cc3)c3cc(-c4ccccc4)ccc23)cc1)c1cccc2ccccc12]

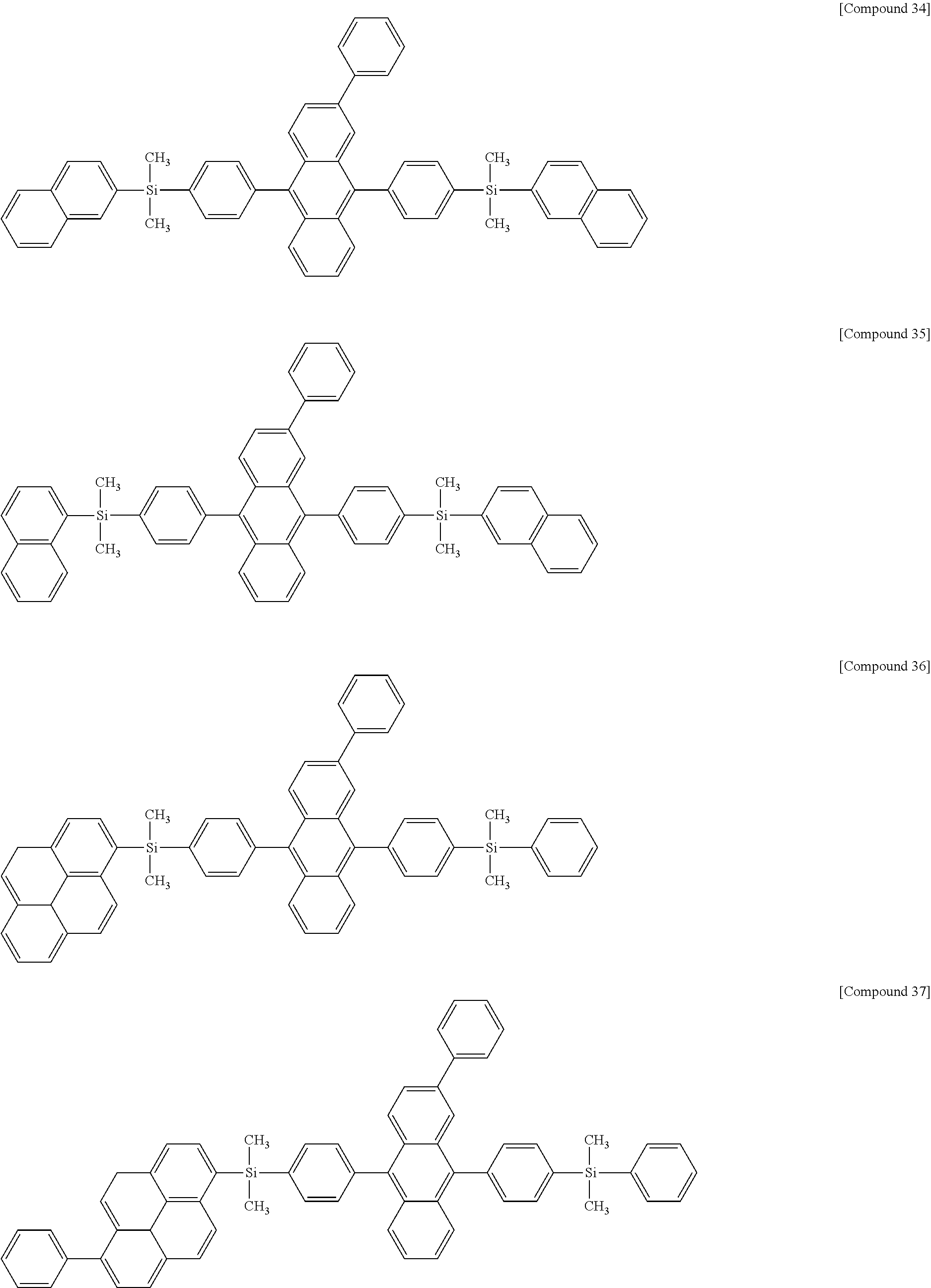 [SMILES: C[Si](C)(c1ccc(-c2c3ccccc3c(-c3ccc([Si](C)(C)c4ccc5ccccc5c4)cc3)c3cc(-c4ccccc4)ccc23)cc1)c1ccc2ccccc2c1 ; C[Si](C)(c1ccc(-c2c3ccccc3c(-c3ccc([Si](C)(C)c4cccc5ccccc45)cc3)c3ccc(-c4ccccc4)cc23)cc1)c1ccc2ccccc2c1 ; C[Si](C)(c1ccccc1)c1ccc(-c2c3ccccc3c(-c3ccc([Si](C)(C)c4ccc5c6c4C=CC4=CC=CC(=CC5)C46)cc3)c3ccc(-c4ccccc4)cc23)cc1 ; C[Si](C)(c1ccccc1)c1ccc(-c2c3ccccc3c(-c3ccc([Si](C)(C)c4ccc5c6c4C=CC4=CC=C(c7ccccc7)C(=CC5)C46)cc3)c3ccc(-c4ccccc4)cc23)cc1]

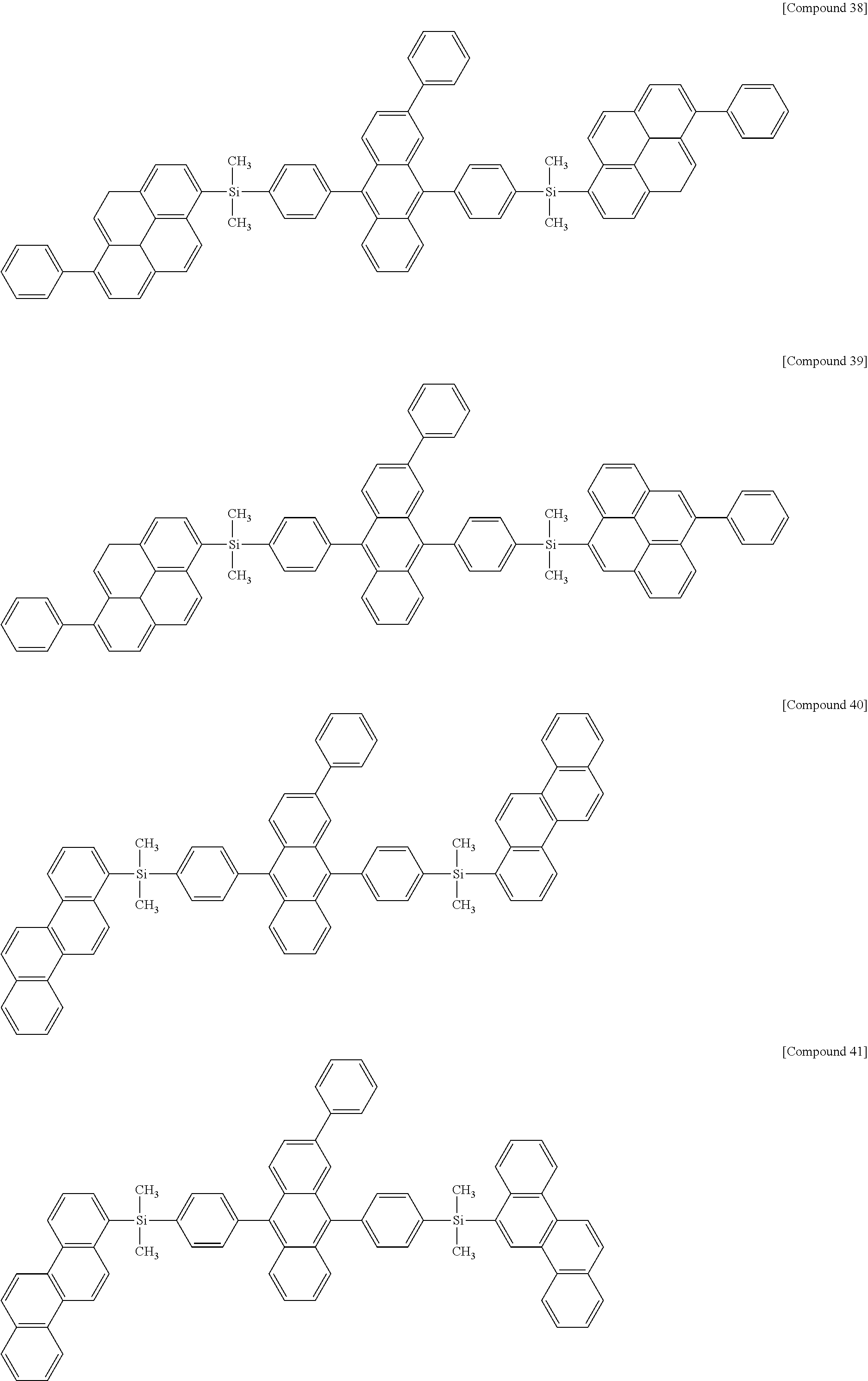

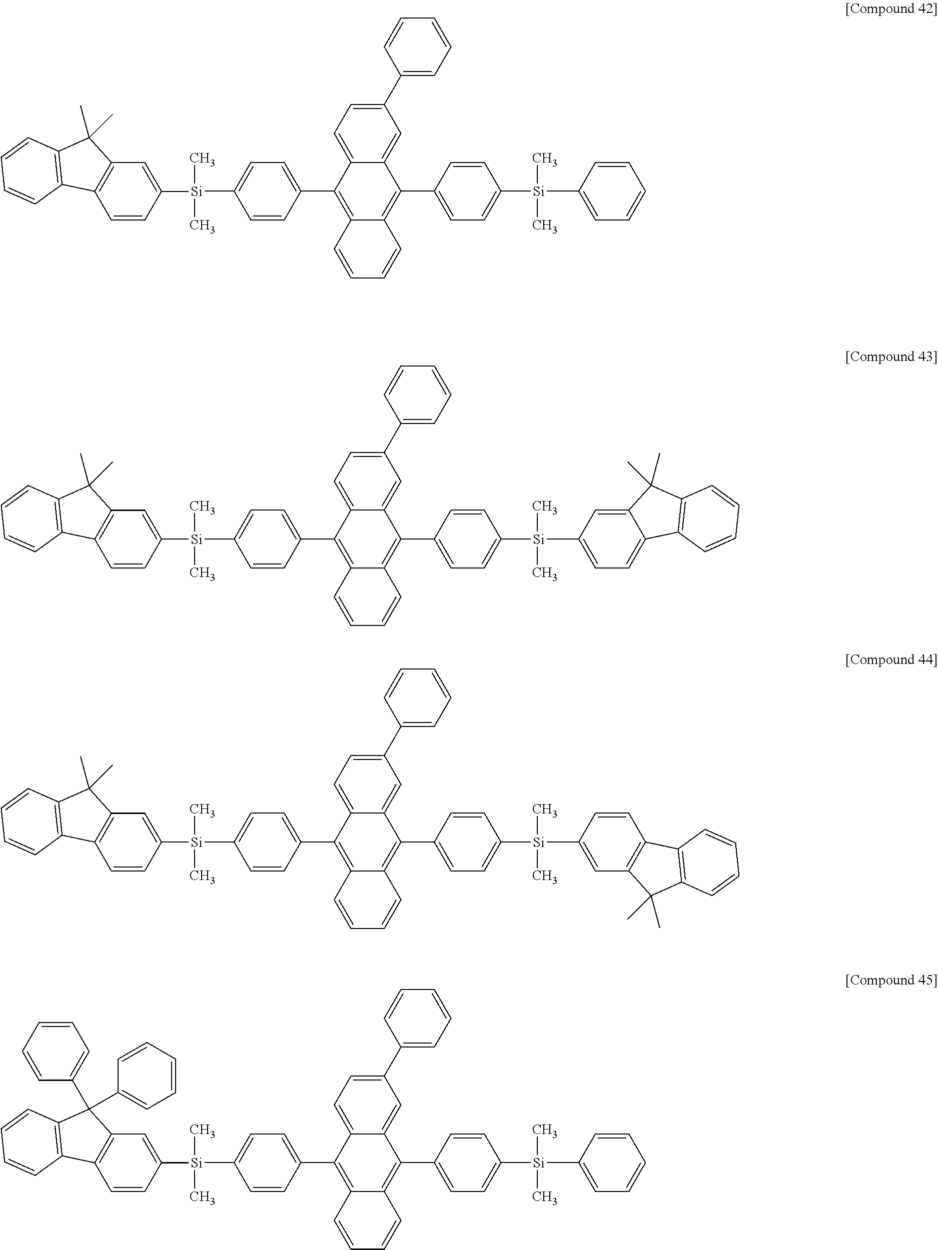

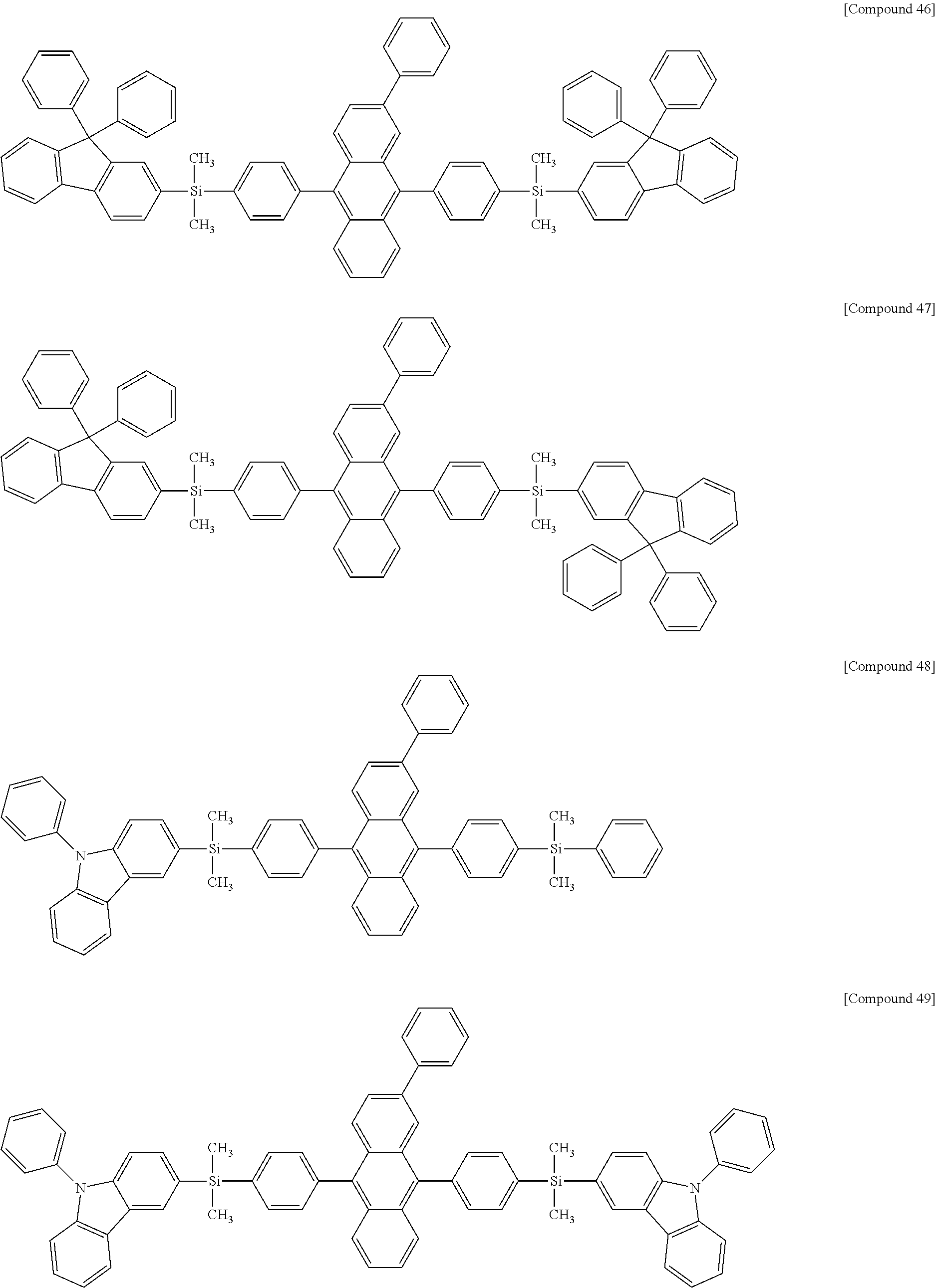

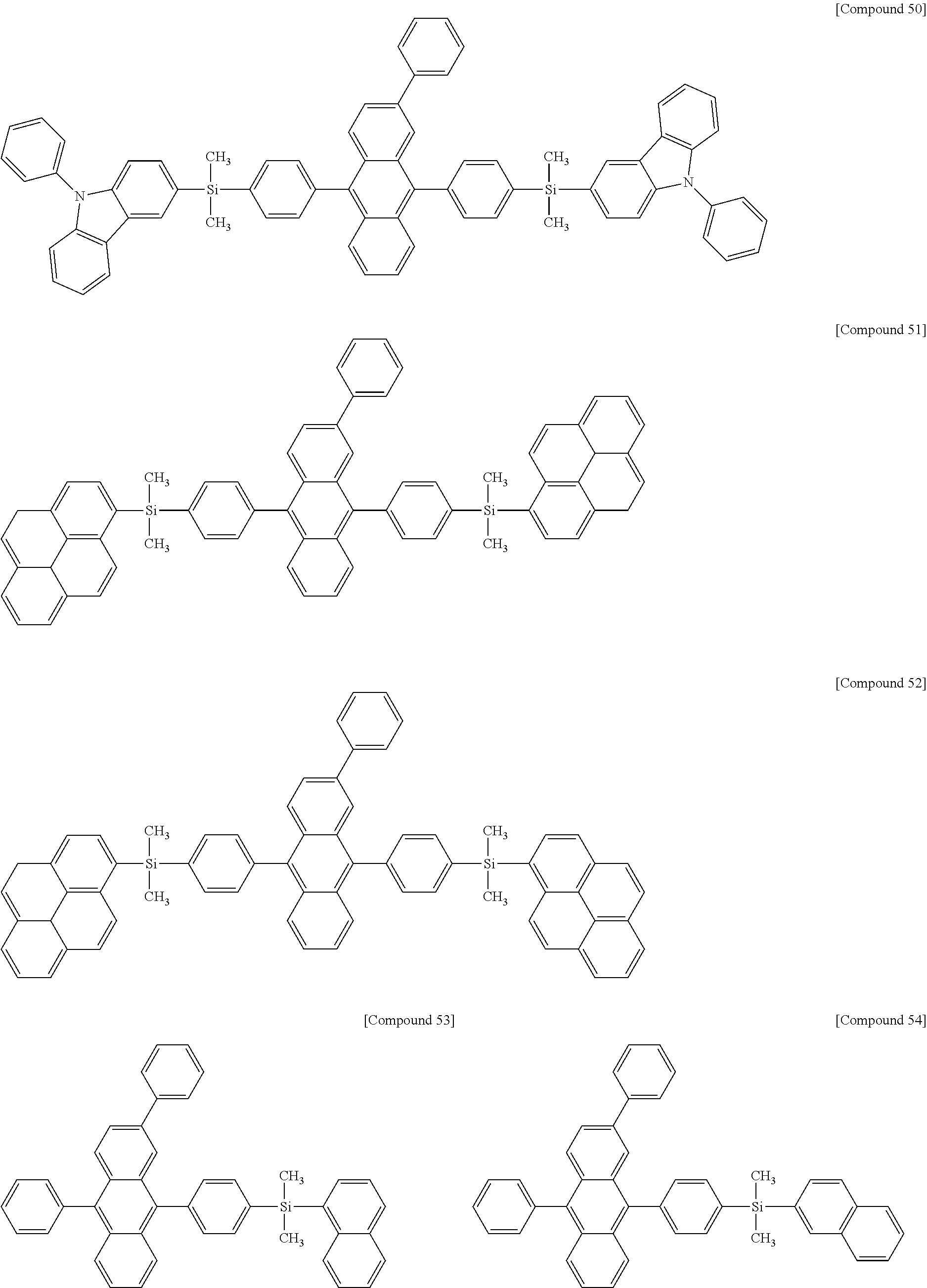

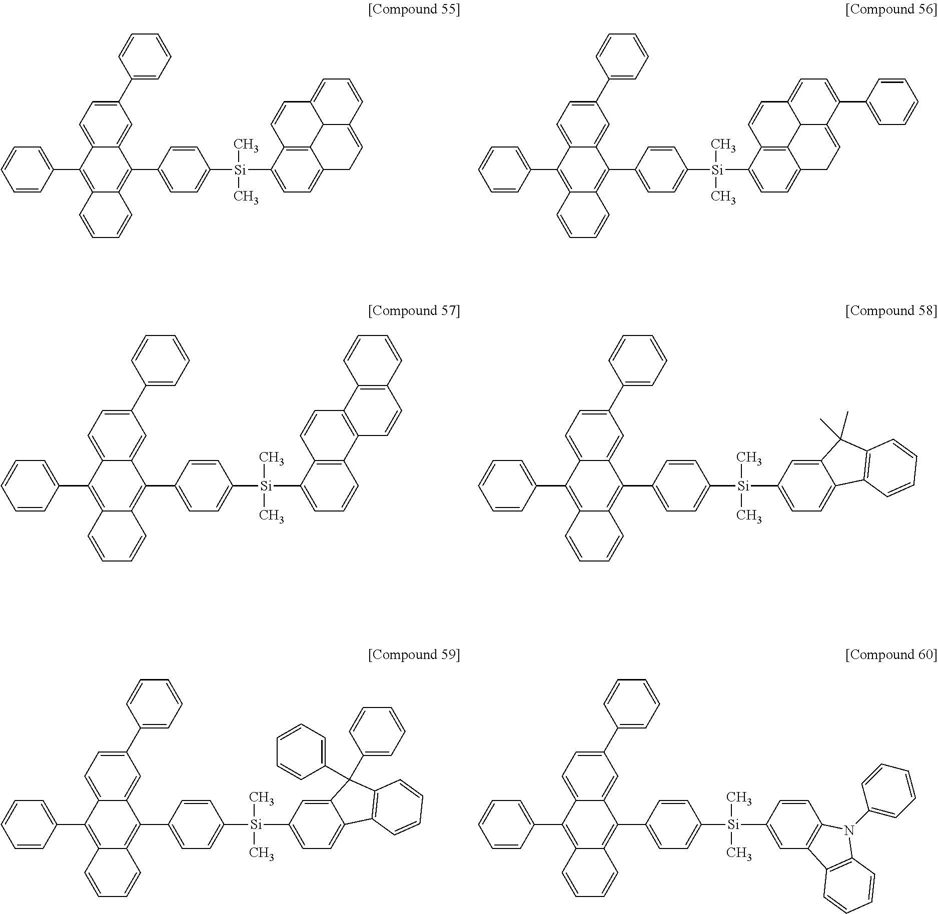

In Formula 20 above, i, which indicates the number of L₃s, may be an integer from 0 to 3. When i is 0, Ar₃ is bonded directly to a core of the anthracene-based compound of Formula 20. When i is 2 or greater, at least two of L₃s may be identical to or different from each other. In Formula 20 above, j, which indicates the number of L₄s, may be an integer from 0 to 3. When j is 0, Ar₄ may be bonded directly to the core of the anthracene-based compound of Formula 20. When j is 2 or greater, at least two of L₄s may be identical to or different from each other.

In some embodiments, in Formula 20 above, i and j may be each independently an integer from 0 or 1.

In some other embodiments, in Formula 20 above, i may be 0 and j may be 0; i may be 1 and j may be 0; i may be 0 and j may be 1; or i may be 1 and j may be 1.

In still other embodiments, in Formula 20 above, i may be 0, and j may be 0.

In Formula 20 above, Ar₁ and Ar₂ may be each independently selected from groups represented by Formulae 7A to 7F below:

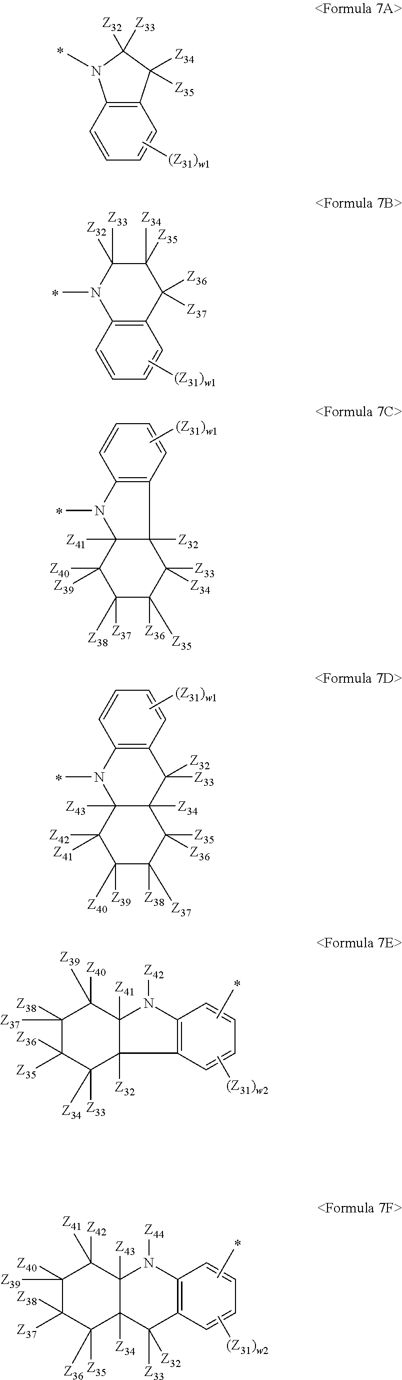

In Formulae 7A to 7F above,

Z₃₁ to Z₄₄ may be each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthiol group, a substituted or unsubstituted C₂-C₆₀ heteroaryl group, —N(Q₅₁)(Q₅₂), and —Si(Q₅₃)(Q₅₄)(Q₅₅) (where Q₅₁ to Q₅₅ may be each independently selected from a hydrogen atom, a C₁-C₁₀ alkyl group, a C₆-C₂₀ aryl group, and a C₂-C₂₀ heteroaryl group), wherein at least two of Z₃₁ to Z₄₄ may be optionally linked to form a C₆-C₂₀ saturated ring or a C₆-C₂₀ unsaturated ring;

w1 may be an integer from 1 to 4;

w2 may be an integer from 1 to 5; and

* may indicate a binding site to L₃ or L₄, or directly to the anthracene core when i or j are 0.

In some embodiments, Z₃₁ to Z₄₄ in Formulae 7A to 7F above may be each independently selected from

i) a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and —Si(Q₅₃)(Q₅₄)(Q₅₅) (where Q₅₃ to Q₅₅ may be each independently a C₁-C₁₀ alkyl group or a C₆-C₂₀ aryl group);

ii) a C₁-C₂₀ alkyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

iii) a phenyl group, a pentalenyl group, an indenyl group, a naphthyl group, an azulenyl group, a heptalenyl group, an indacenyl group, an acenaphthyl group, a fluorenyl group, a spiro-fluorenyl group, a phenalenyl group, a phenanthrenyl group, an anthryl group, a fluoranthenyl group, a triphenylenylene group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzoimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a benzoxazolyl group, a dibenzofuranyl group, a dibenzothiophenyl group, and a benzocarbazolyl group;

iv) a phenyl group, a pentalenyl group, an indenyl group, a naphthyl group, an azulenyl group, a heptalenyl group, an indacenyl group, acenaphthyl group, a fluorenyl group, a spiro-fluorenyl group, a phenalenyl group, a phenanthrenyl group, an anthryl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzoimidazolyl group, a furanyl group, a benzofuranyl group, a thiophenylene group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a benzoxazolyl group, a dibenzofuranyl group, a dibenzothiophenyl group, and benzocarbazolyl group, each substituted with at least one C₁-C₂₀ alkyl group substituted with at least one of a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; and

v) a phenyl group, a pentalenyl group, an indenyl group, a naphthyl group, an azulenyl group, a heptalenyl group, an indacenyl group, acenaphthyl group, a fluorenyl group, a spiro-fluorenyl group, a phenalenyl group, a phenanthrenyl group, an anthryl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoxazolyl group, a benzoimidazolyl group, a furanyl group, a benzofuranyl group, a thiophenylene group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a benzoxazolyl group, a dibenzofuranyl group, a dibenzothiophenyl group, and benzocarbazolyl group, each substituted with at least one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₁-C₆₀ alkoxy group, a C₆-C₆₀ aryl group, a C₂-C₆₀ heteroaryl group, and —Si(Q₆₁)(Q₆₂)(Q₆₃) (where Q₆₁ to Q₆₃ may be each independently a C₁-C₁₀ alkyl group or a C₆-C₂₀ aryl group).

In some other embodiments, Z₃₁ to Z₄₄ in Formulae 7A to 7F may be each independently selected from

i) a hydrogen atom, a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and —Si(Q₅₃)(Q₅₄)(Q₅₅) (where Q₅₃ to Q₅₅ may be each independently a methyl group or a phenyl group);

ii) a C₁-C₂₀ alkyl group substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

iii) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group;

iv) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one of a methyl group, an ethyl group, a n-propyl group, an iso-propyl group, and a tert-butyl group that are each substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; and

v) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one selected from a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a n-propyl group, an iso-propyl group, a tert-butyl group, a phenyl group, a naphthyl group, an anthryl group, a fluorenyl group, a carbazolyl group, a pyridinyl group, a pyrimidinyl group, a pyrazinyl group, a triazinyl group, and —Si(Q₅₃)(Q₅₄)(Q₅₅) (where Q₅₃ to Q₅₅ may be each independently a methyl group or a phenyl group).

In Formula 20 above, Ar₁ and Ar₂ may be each independently selected from groups represented by Formulae 7A(1) to 7A(3), 7B(1) to 7B(3), 7C(1) to 7C(6), 7D(1), 7D(2), 7E(1), and 7F(1):

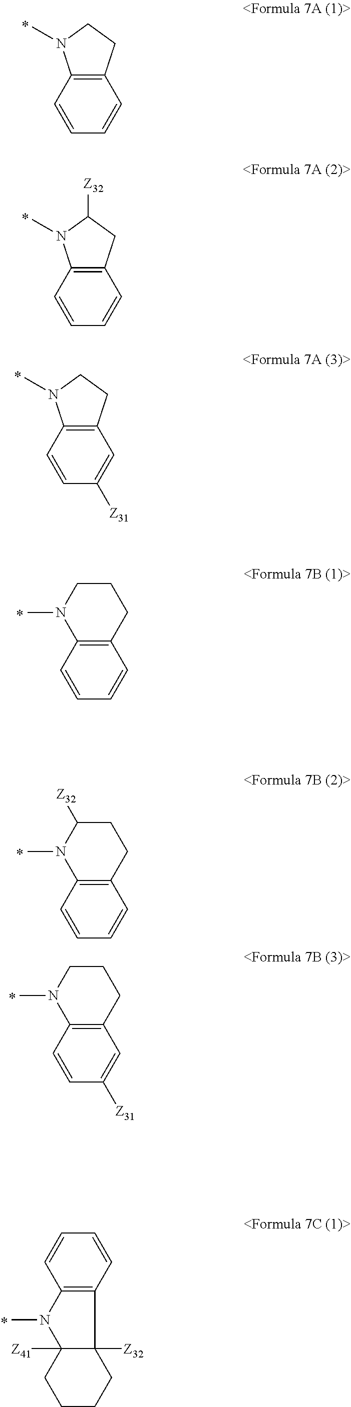

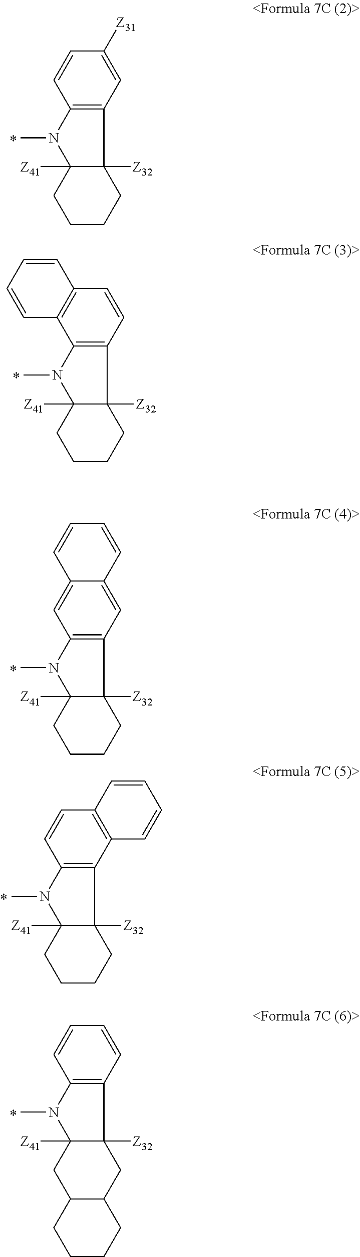

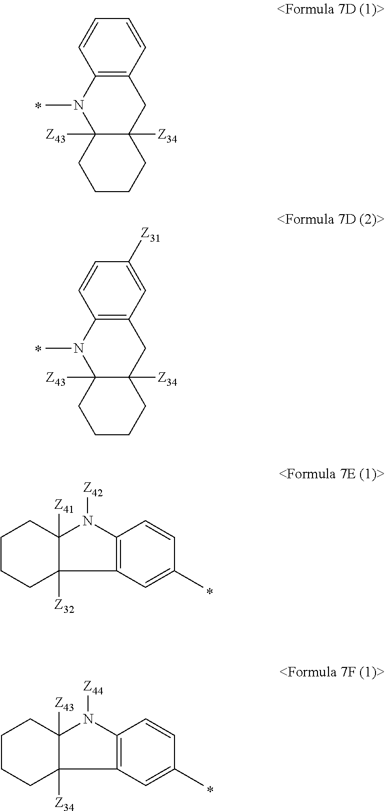

In Formulae 7A(1) to 7A(3), 7B(1) to 7B(3), 7C(1) to 7C(6), 7D(1), 7D(2), 7E(1), and 7F(1) above, Z₃₁, Z₃₂, Z₃₄, and Z₄₁ to Z₄₄ may be each independently defined as described above.

For example, in Formulae 7A(1) to 7A(3), 7B(1) to 7B(3), 7C(1) to 7C(6), 7D(1), 7D(2), 7E(1), and 7F(1) above, Z₃₁, Z₃₂, Z₃₄, and Z₄₁ to Z₄₄ may be each independently selected from

i) a hydrogen atom, a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and —Si(Q₅₃)(Q₅₄)(Q₅₅) (where Q₅₃ to Q₅₅ may be each independently a methyl group or a phenyl group);

ii) a C₁-C₂₀ alkyl group substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

iii) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group;

iv) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one of a methyl group, an ethyl group, a n-propyl group, an iso-propyl group, and a tert-butyl group that are each substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; and

v) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one selected from a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a n-propyl group, an iso-propyl group, a tert-butyl group, a phenyl group, a naphthyl group, an anthryl group, a fluorenyl group, a carbazolyl group, a pyridinyl group, a pyrimidinyl group, a pyrazinyl group, a triazinyl group, and —Si(Q₅₃)(Q₅₄)(Q₅₅) (where Q₅₃ to Q₅₅ may be each independently a methyl group or a phenyl group).

For example, in Formula 20, Ar₁ and Ar₂ may be identical to or different from each other.

For example, in Formula 20, R₁₃ and R₁₄ may be identical to or different from each other.

For example, the anthracene-based compound of Formula 20 above may be a compound represented by Formula 20a below:

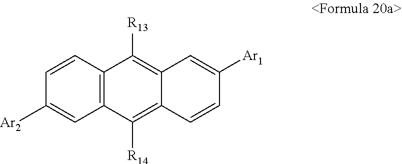

In Formula 20a above, R₁₃, R₁₄, Ar₁, and Ar₂ may be defined as described above.

For example, in Formula 20a above,

R₁₃ and R₁₄ may be each independently selected from

i) a phenyl group, and

ii) a phenyl group substituted with at least one selected from a deuterium atom, —F, a cyano group, a nitro group, a methyl group, an ethyl group, a tert-butyl group, and —Si(Q₄₁)(Q₄₂)(Q₄₃) (where Q₄₁ to Q₄₃ may be each independently a methyl group, an ethyl group, or a phenyl group); and

Ar₁ and Ar₂ may be each independently selected from groups represented by Formulae 7A(1) to 7A(3), 7B(1) to 7B(3), 7C(1) to 7C(6), 7D(1), 7D(2), 7E(1), and 7F(1):

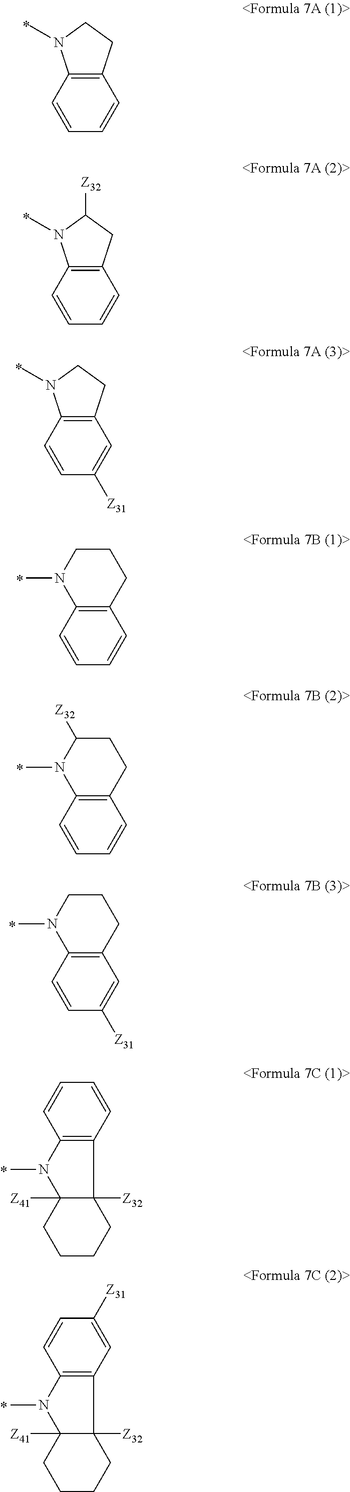

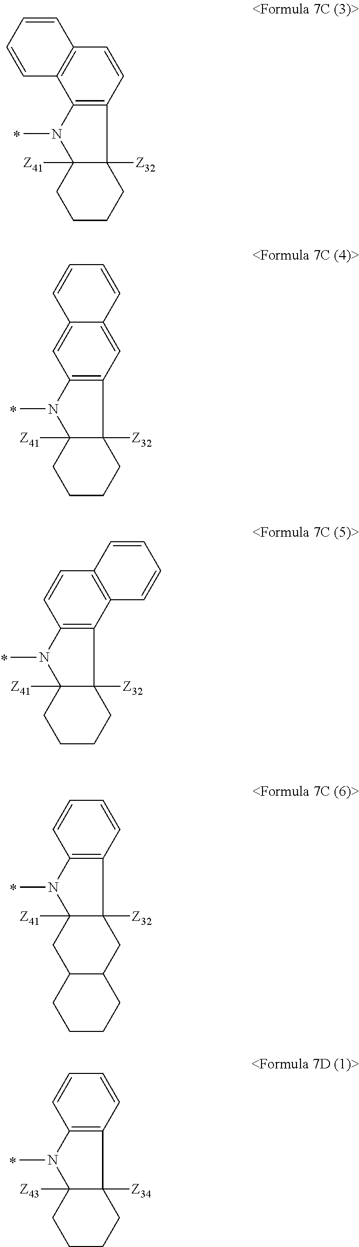

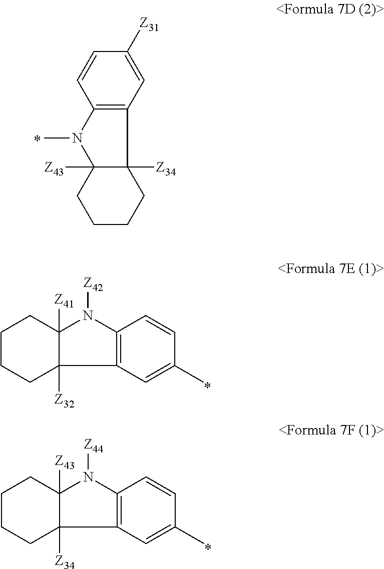

In Formulae 7A(1) to 7A(3), 7B(1) to 7B(3), 7C(1) to 7C(6), 7D(1), 7D(2), 7E(1), and 7F(1), Z₃₁, Z₃₂, Z₃₄, and Z₄₁ to Z₄₄ may be each independently selected from

i) a hydrogen atom, a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and —Si(Q₅₃)(Q₅₄)(Q₅₅) (where Q₅₃ to Q₅₅ may be each independently a methyl group or a phenyl group);

ii) a C₁-C₂₀ alkyl group substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;

iii) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group;

iv) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one of a methyl group, an ethyl group, a n-propyl group, an iso-propyl group, and a tert-butyl group that are each substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; and

v) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one selected from a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a n-propyl group, an iso-propyl group, a tert-butyl group, a phenyl group, a naphthyl group, an anthryl group, a fluorenyl group, a carbazolyl group, a pyridinyl group, a pyrimidinyl group, a pyrazinyl group, a triazinyl group, and —Si(Q₅₃)(Q₅₄)(Q₅₅) (where Q₅₃ to Q₅₅ may be each independently a methyl group or a phenyl group).

In some embodiments, the anthracene-based compound of Formula 20 above may be one of Compounds 61 to 136 below:

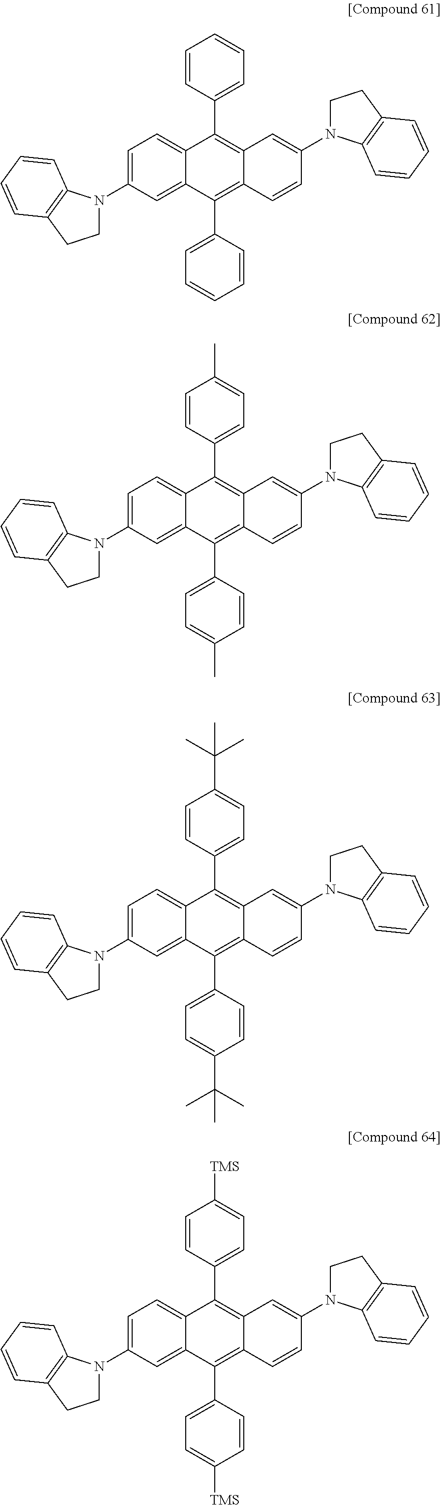

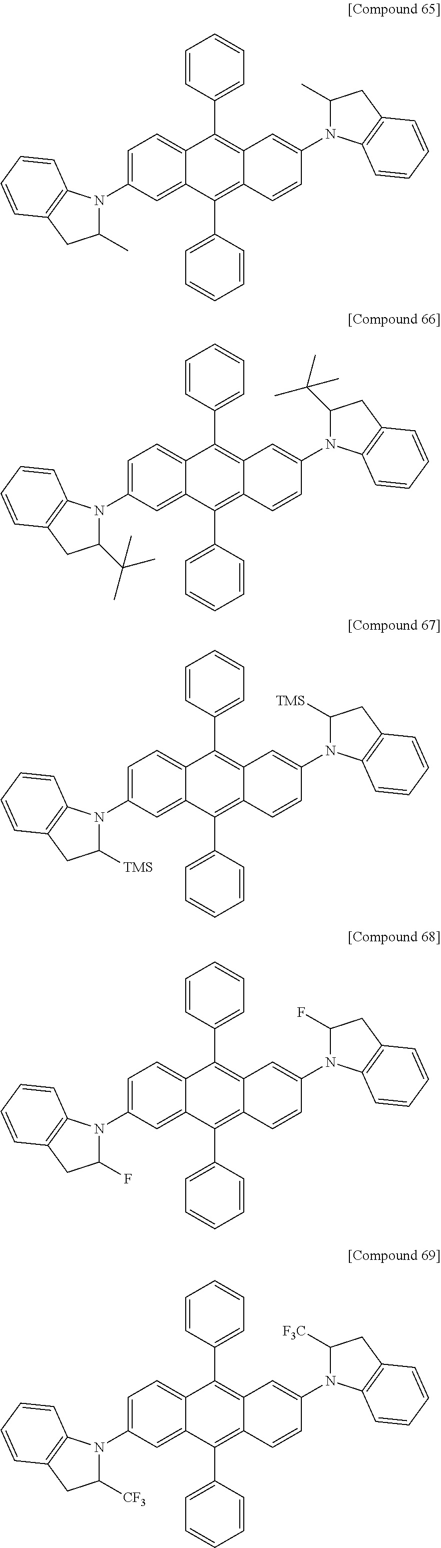

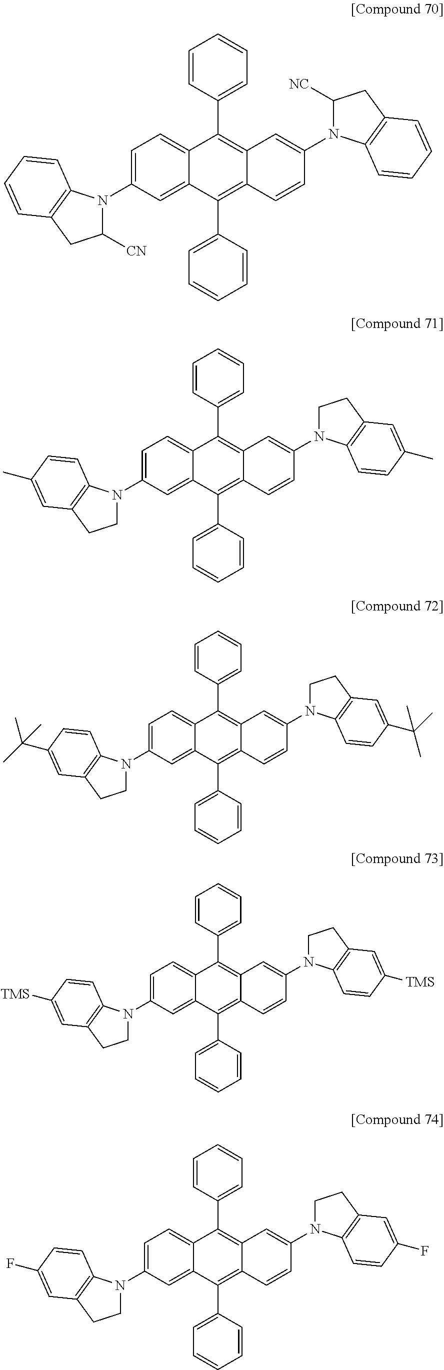

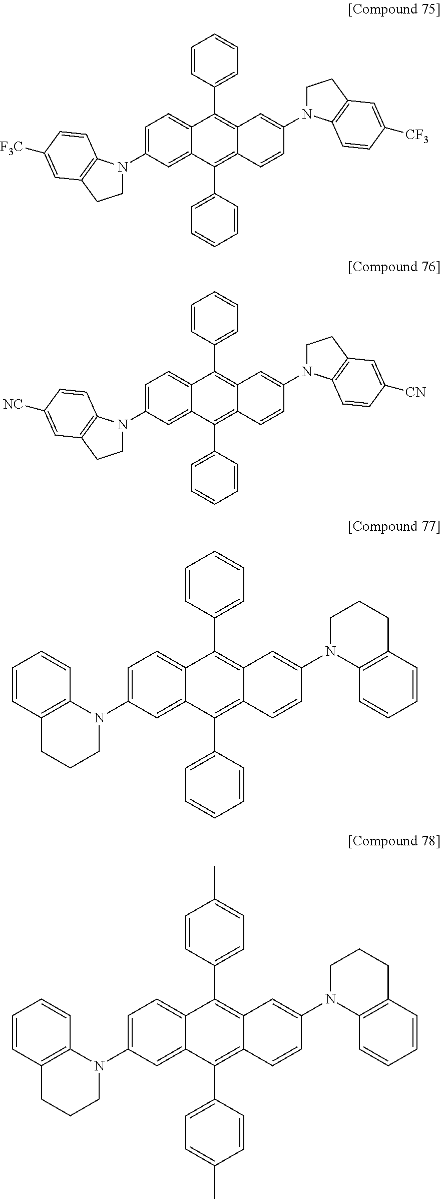

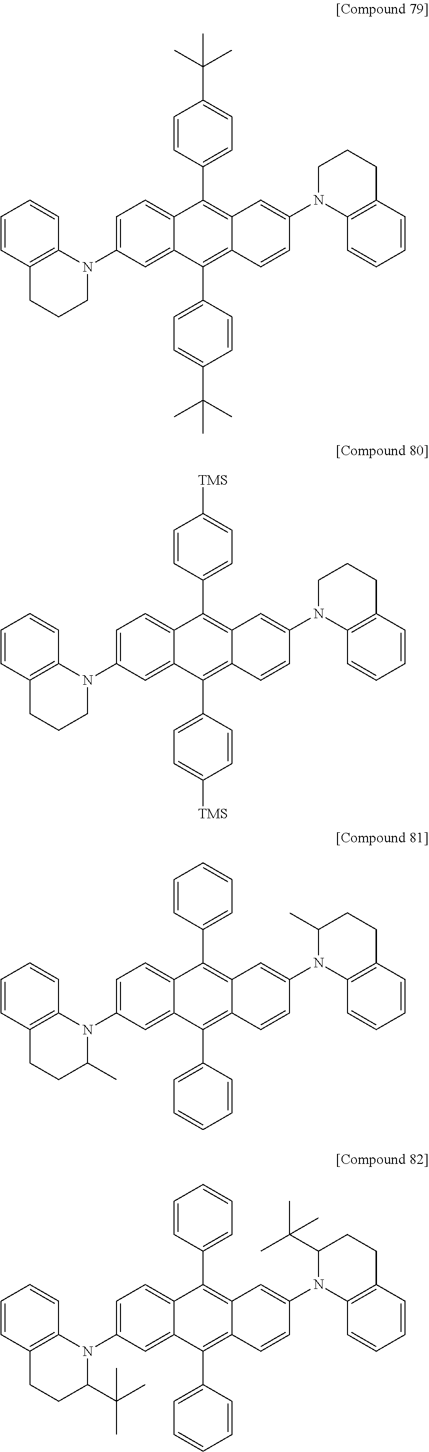

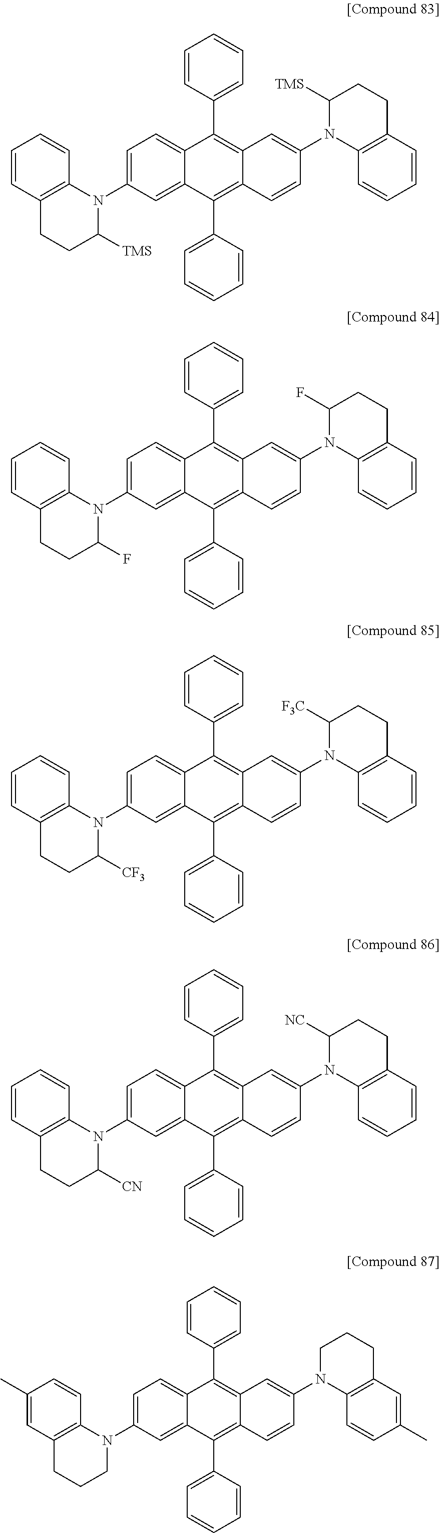

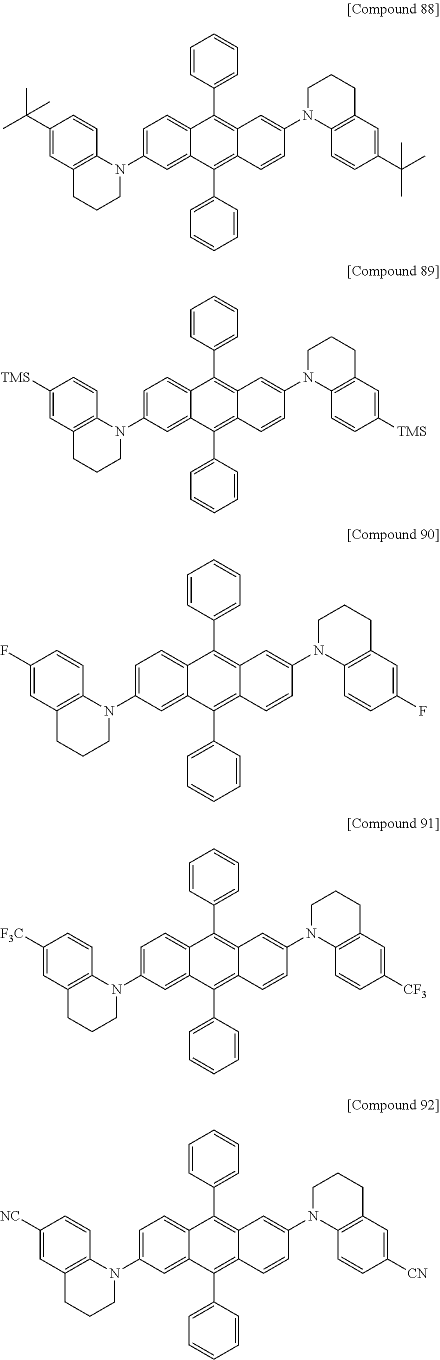 [SMILES: CC(C)(C)c1ccc2c(c1)CCCN2c1ccc2c(-c3ccccc3)c3cc(N4CCCc5cc(C(C)(C)C)ccc54)ccc3c(-c3ccccc3)c2c1 ; C[Si](C)(C)c1ccc2c(c1)CCCN2c1ccc2c(-c3ccccc3)c3cc(N4CCCc5cc([Si](C)(C)C)ccc54)ccc3c(-c3ccccc3)c2c1 ; Fc1ccc2c(c1)CCCN2c1ccc2c(-c3ccccc3)c3cc(N4CCCc5cc(F)ccc54)ccc3c(-c3ccccc3)c2c1 ; FC(F)(F)c1ccc2c(c1)CCCN2c1ccc2c(-c3ccccc3)c3cc(N4CCCc5cc(C(F)(F)F)ccc54)ccc3c(-c3ccccc3)c2c1 ; N#Cc1ccc2c(c1)CCCN2c1ccc2c(-c3ccccc3)c3cc(N4CCCc5cc(C#N)ccc54)ccc3c(-c3ccccc3)c2c1]

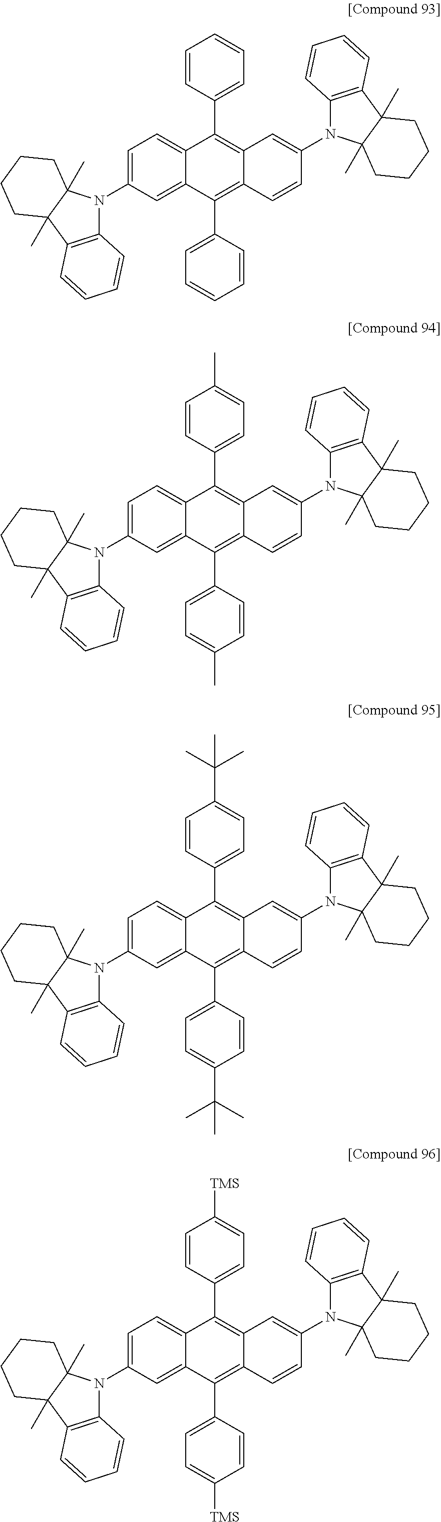 [SMILES: CC12CCCCC1(C)N(c1ccc3c(-c4ccccc4)c4cc(N5c6ccccc6C6(C)CCCCC56C)ccc4c(-c4ccccc4)c3c1)c1ccccc12 ; Cc1ccc(-c2c3ccc(N4c5ccccc5C5(C)CCCCC45C)cc3c(-c3ccc(C)cc3)c3ccc(N4c5ccccc5C5(C)CCCCC45C)cc23)cc1 ; CC(C)(C)c1ccc(-c2c3ccc(N4c5ccccc5C5(C)CCCCC45C)cc3c(-c3ccc(C(C)(C)C)cc3)c3ccc(N4c5ccccc5C5(C)CCCCC45C)cc23)cc1 ; CC12CCCCC1(C)N(c1ccc3c(-c4ccc([Si](C)(C)C)cc4)c4cc(N5c6ccccc6C6(C)CCCCC56C)ccc4c(-c4ccc([Si](C)(C)C)cc4)c3c1)c1ccccc12]

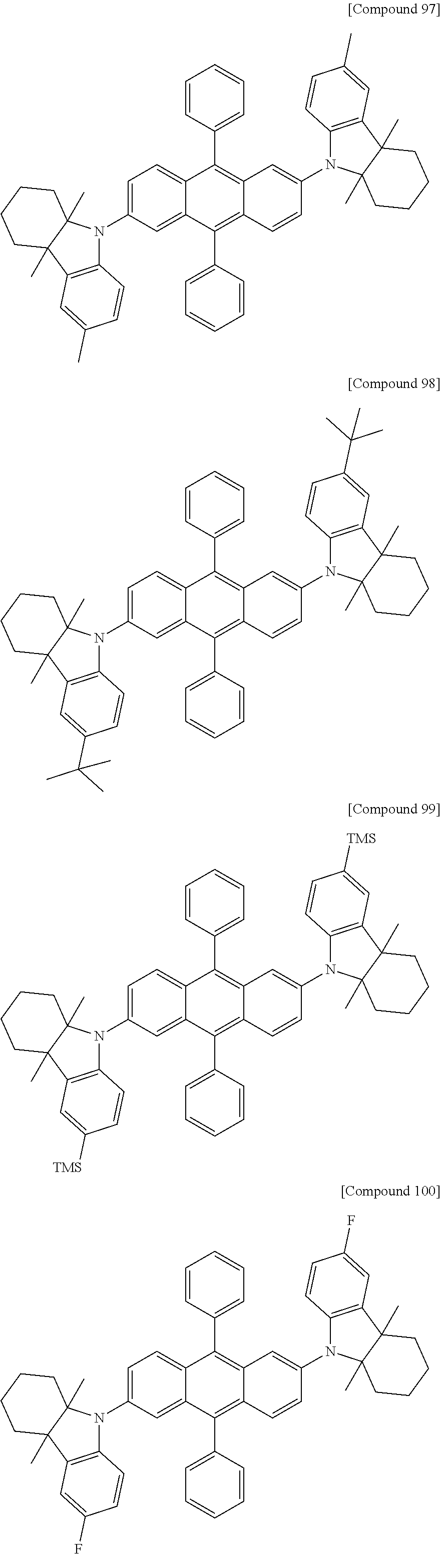 [SMILES: Cc1ccc2c(c1)C1(C)CCCCC1(C)N2c1ccc2c(-c3ccccc3)c3cc(N4c5ccc(C)cc5C5(C)CCCCC45C)ccc3c(-c3ccccc3)c2c1 ; CC(C)(C)c1ccc2c(c1)C1(C)CCCCC1(C)N2c1ccc2c(-c3ccccc3)c3cc(N4c5ccc(C(C)(C)C)cc5C5(C)CCCCC45C)ccc3c(-c3ccccc3)c2c1 ; CC12CCCCC1(C)N(c1ccc3c(-c4ccccc4)c4cc(N5c6ccc([Si](C)(C)C)cc6C6(C)CCCCC56C)ccc4c(-c4ccccc4)c3c1)c1ccc([Si](C)(C)C)cc12 ; CC12CCCCC1(C)N(c1ccc3c(-c4ccccc4)c4cc(N5c6ccc(F)cc6C6(C)CCCCC56C)ccc4c(-c4ccccc4)c3c1)c1ccc(F)cc12]

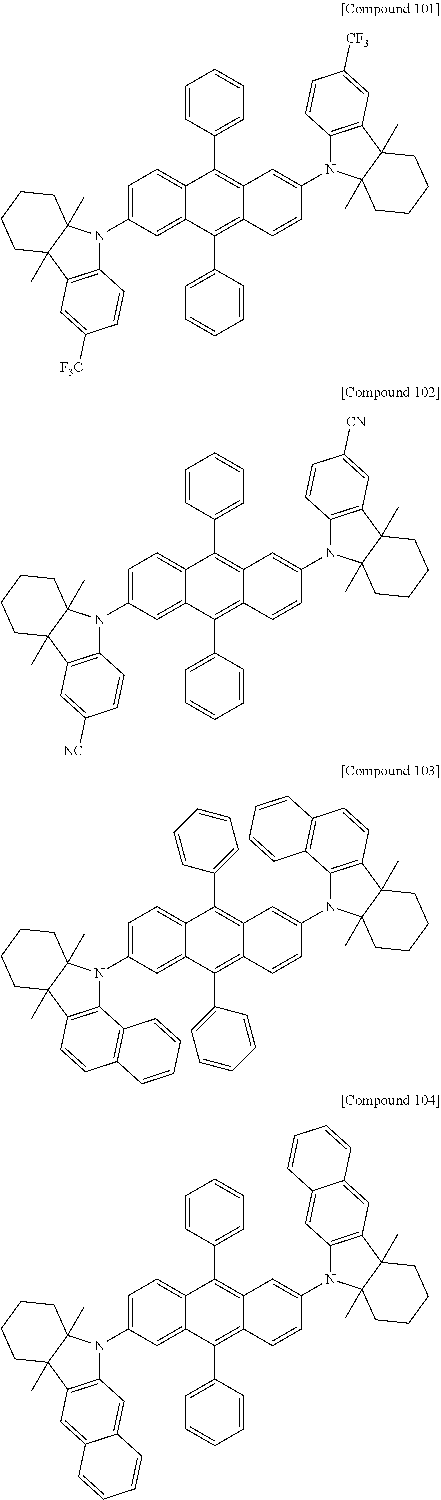 [SMILES: CC12CCCCC1(C)N(c1ccc3c(-c4ccccc4)c4cc(N5c6ccc(C(F)(F)F)cc6C6(C)CCCCC56C)ccc4c(-c4ccccc4)c3c1)c1ccc(C(F)(F)F)cc12 ; CC12CCCCC1(C)N(c1ccc3c(-c4ccccc4)c4cc(N5c6ccc(C#N)cc6C6(C)CCCCC56C)ccc4c(-c4ccccc4)c3c1)c1ccc(C#N)cc12 ; CC12CCCCC1(C)N(c1ccc3c(-c4ccccc4)c4cc(N5c6c(ccc7ccccc67)C6(C)CCCCC56C)ccc4c(-c4ccccc4)c3c1)c1c2ccc2ccccc12 ; CC12CCCCC1(C)N(c1ccc3c(-c4ccccc4)c4cc(N5c6cc7ccccc7cc6C6(C)CCCCC56C)ccc4c(-c4ccccc4)c3c1)c1cc3ccccc3cc12]

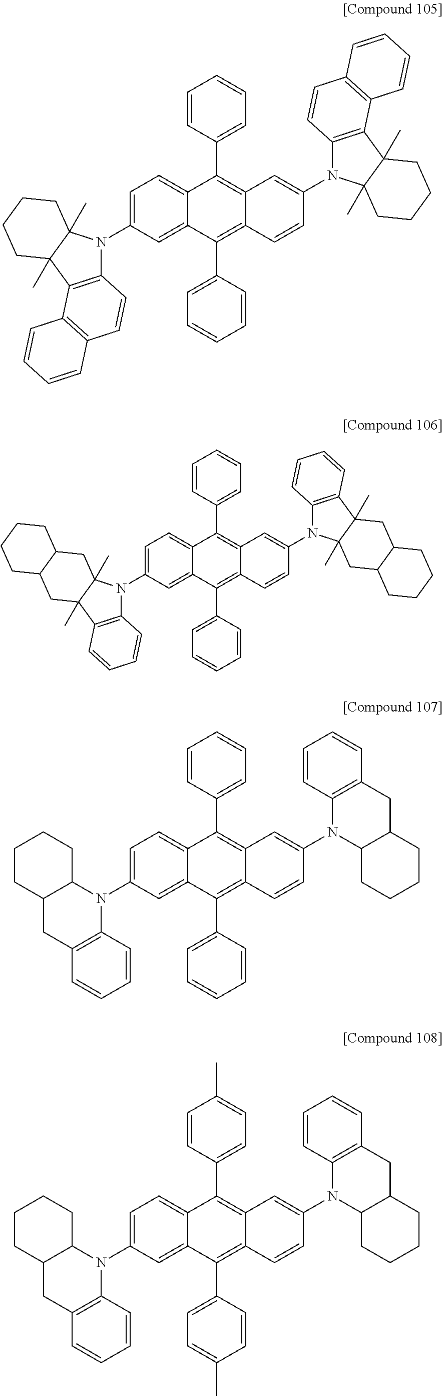 [SMILES: CC12CCCCC1(C)N(c1ccc3c(-c4ccccc4)c4cc(N5c6ccc7ccccc7c6C6(C)CCCCC56C)ccc4c(-c4ccccc4)c3c1)c1ccc3ccccc3c12 ; CC12CC3CCCCC3CC1(C)N(c1ccc3c(-c4ccccc4)c4cc(N5c6ccccc6C6(C)CC7CCCCC7CC56C)ccc4c(-c4ccccc4)c3c1)c1ccccc12 ; c1ccc(-c2c3ccc(N4c5ccccc5CC5CCCCC54)cc3c(-c3ccccc3)c3ccc(N4c5ccccc5CC5CCCCC54)cc23)cc1 ; Cc1ccc(-c2c3ccc(N4c5ccccc5CC5CCCCC54)cc3c(-c3ccc(C)cc3)c3ccc(N4c5ccccc5CC5CCCCC54)cc23)cc1]

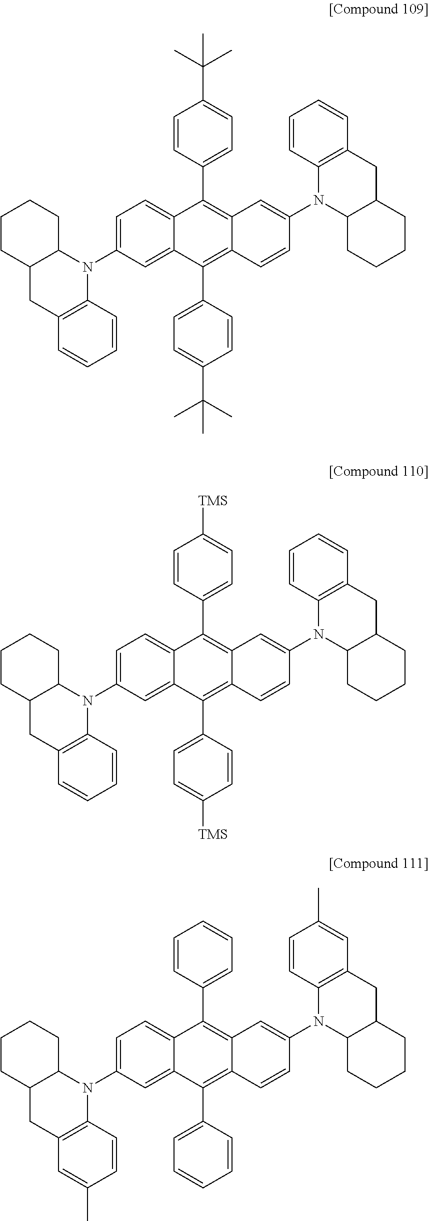 [SMILES: CC(C)(C)c1ccc(-c2c3ccc(N4c5ccccc5CC5CCCCC54)cc3c(-c3ccc(C(C)(C)C)cc3)c3ccc(N4c5ccccc5CC5CCCCC54)cc23)cc1 ; C[Si](C)(C)c1ccc(-c2c3ccc(N4c5ccccc5CC5CCCCC54)cc3c(-c3ccc([Si](C)(C)C)cc3)c3ccc(N4c5ccccc5CC5CCCCC54)cc23)cc1 ; Cc1ccc2c(c1)CC1CCCCC1N2c1ccc2c(-c3ccccc3)c3cc(N4c5ccc(C)cc5CC5CCCCC54)ccc3c(-c3ccccc3)c2c1]

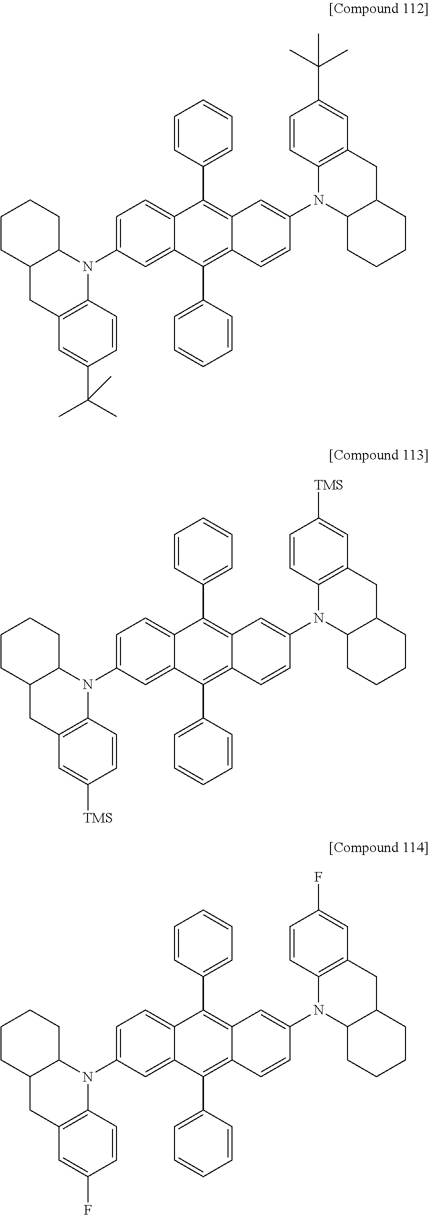 [SMILES: CC(C)(C)c1ccc2c(c1)CC1CCCCC1N2c1ccc2c(-c3ccccc3)c3cc(N4c5ccc(C(C)(C)C)cc5CC5CCCCC54)ccc3c(-c3ccccc3)c2c1 ; C[Si](C)(C)c1ccc2c(c1)CC1CCCCC1N2c1ccc2c(-c3ccccc3)c3cc(N4c5ccc([Si](C)(C)C)cc5CC5CCCCC54)ccc3c(-c3ccccc3)c2c1 ; Fc1ccc2c(c1)CC1CCCCC1N2c1ccc2c(-c3ccccc3)c3cc(N4c5ccc(F)cc5CC5CCCCC54)ccc3c(-c3ccccc3)c2c1]

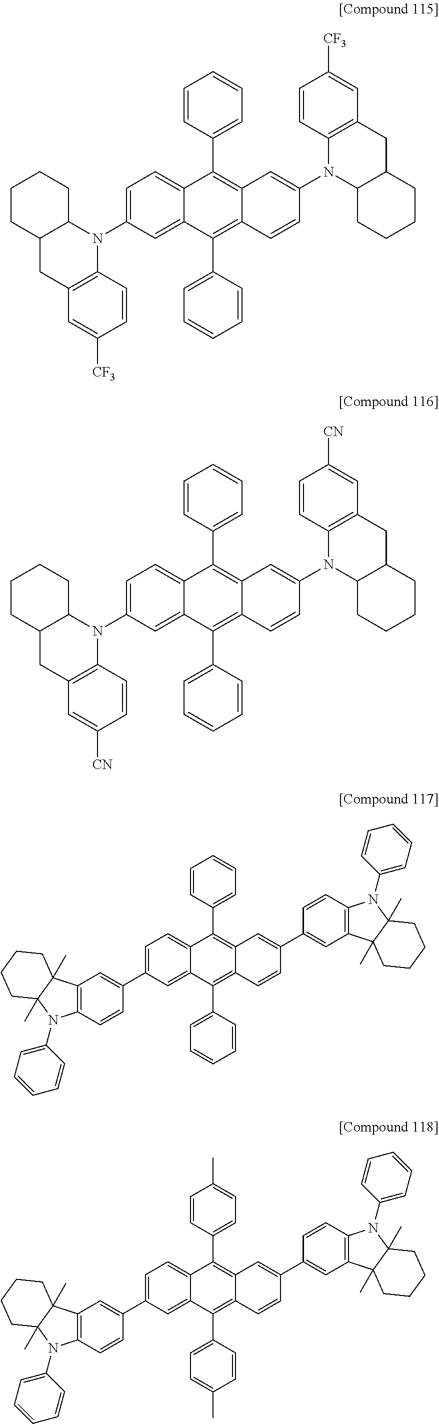 [SMILES: FC(F)(F)c1ccc2c(c1)CC1CCCCC1N2c1ccc2c(-c3ccccc3)c3cc(N4c5ccc(C(F)(F)F)cc5CC5CCCCC54)ccc3c(-c3ccccc3)c2c1 ; N#Cc1ccc2c(c1)CC1CCCCC1N2c1ccc2c(-c3ccccc3)c3cc(N4c5ccc(C#N)cc5CC5CCCCC54)ccc3c(-c3ccccc3)c2c1 ; CC12CCCCC1(C)N(c1ccccc1)c1ccc(-c3ccc4c(-c5ccccc5)c5cc(-c6ccc7c(c6)C6(C)CCCCC6(C)N7c6ccccc6)ccc5c(-c5ccccc5)c4c3)cc12 ; Cc1ccc(-c2c3ccc(-c4ccc5c(c4)C4(C)CCCCC4(C)N5c4ccccc4)cc3c(-c3ccc(C)cc3)c3ccc(-c4ccc5c(c4)C4(C)CCCCC4(C)N5c4ccccc4)cc23)cc1]

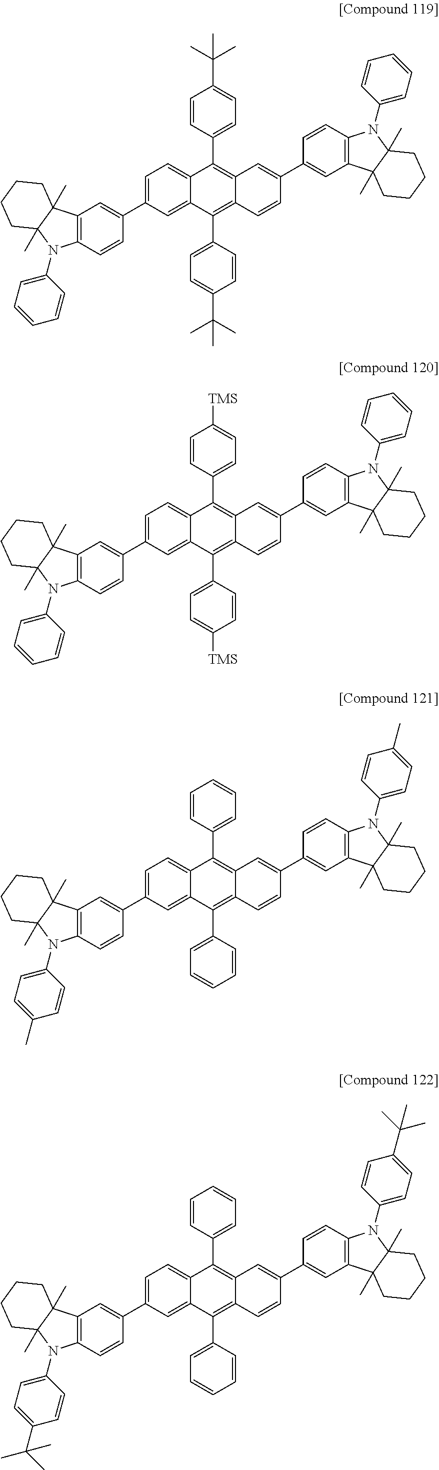

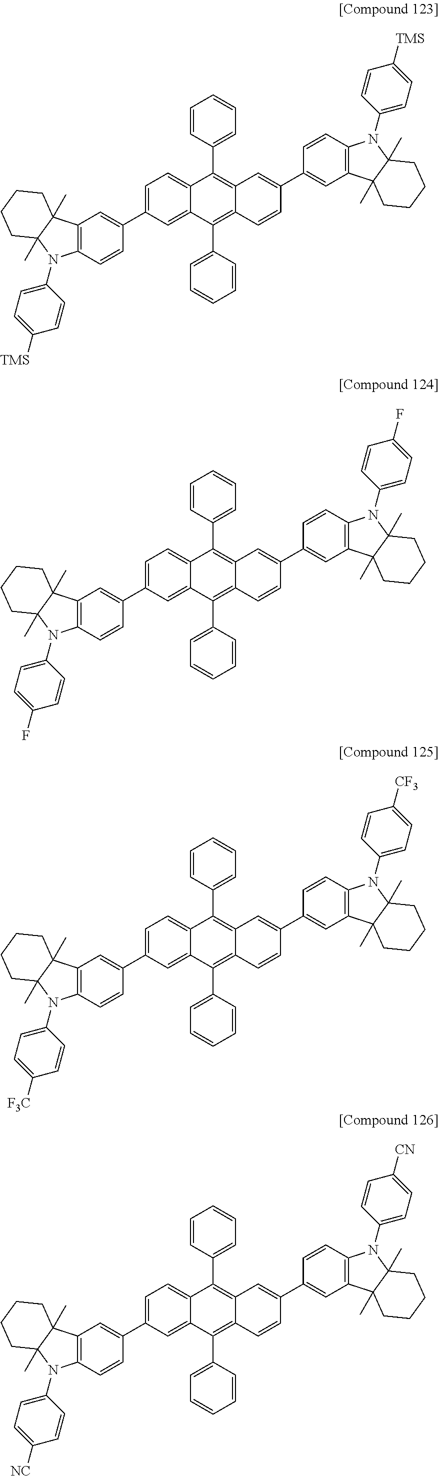

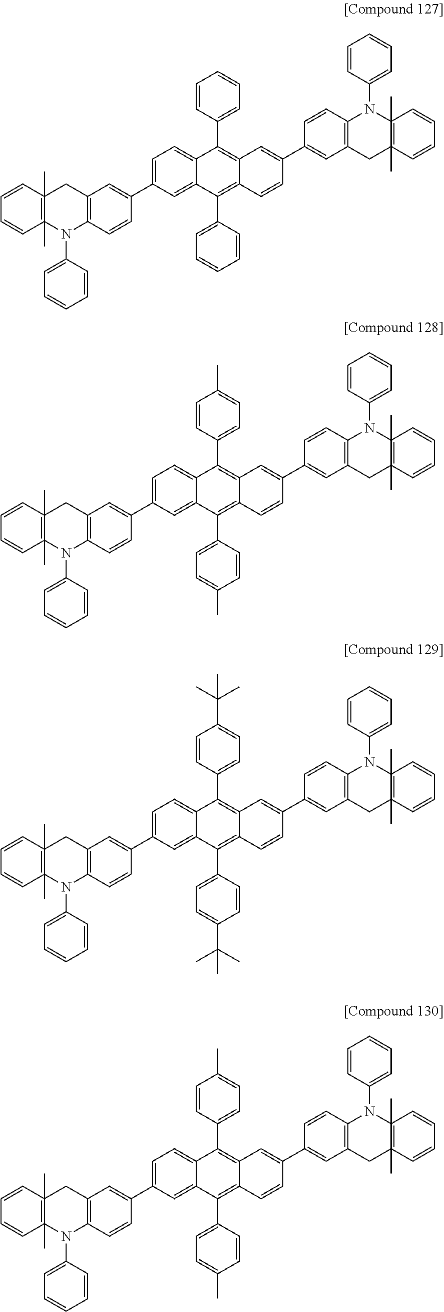

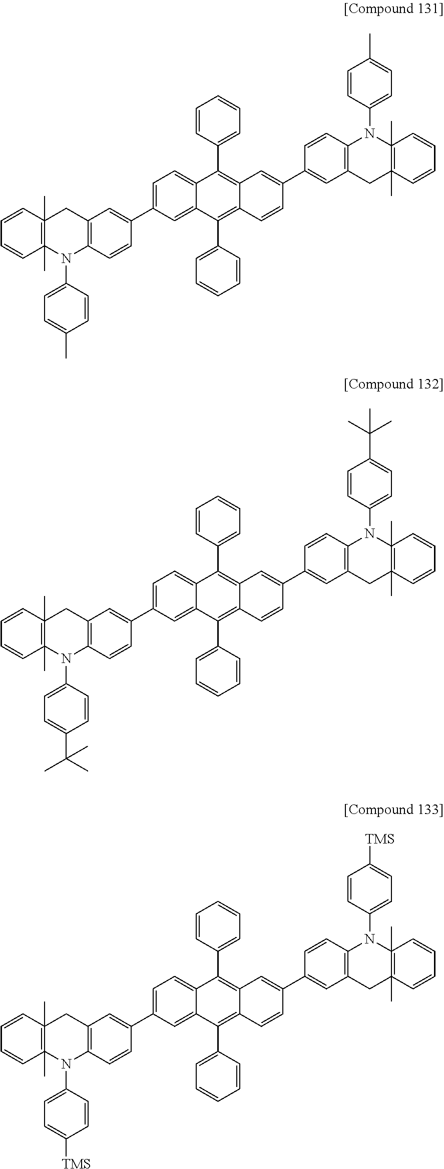

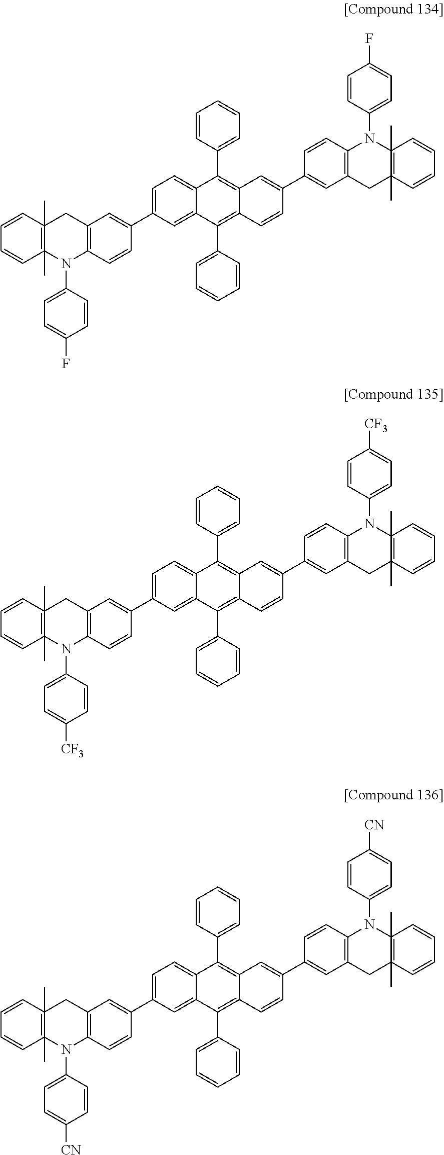

Herein, TMS refers to trimethylsilyl.

In some embodiments, the EML of the organic light-emitting device may include at least one selected from Compounds 1 to 60 above, and at least one selected from Compounds 61 to 136 above.

The silane-based compound represented by Formula 1 above may include “a condensed ring group with condensed at least two substituted or unsubstituted rings” as a Si substituent, and thus may have a cascade structure with high light-emitting efficiency. When the silane-based compound of Formula 1 above is used as a host in an EML of an organic light-emitting device, the organic light-emitting device may have improved efficiency and an improved lifetime. When the silane-based compound of Formula 1 above is used as a host in an EML of an organic light-emitting device and the anthracene-based compound of Formula 20 above is used as a dopant in the EML, these two compounds may have a very high energy transfer efficiency, and thus may provide improved light-emitting efficiency and improved lifetime characteristics to the organic light-emitting device.

When the organic light-emitting device is a full color organic light-emitting device, the emission layer may be patterned into a red emission layer, a green emission layer, and a blue emission layer. In some embodiments, the emission layer may include at least two of the red emission layer, the green emission layer, and the blue emission layer that are stacked upon one another, and thus may emit white light. The blue emission layer may include a host and a dopant as described above.

At least one of the red emission layer and the green emission layer may include a dopant below (ppy=phenylpyridine).

Examples of the red dopant include compounds represented by the following formulae. For example, the red dopant may be DCM or DCJTB, represented below.

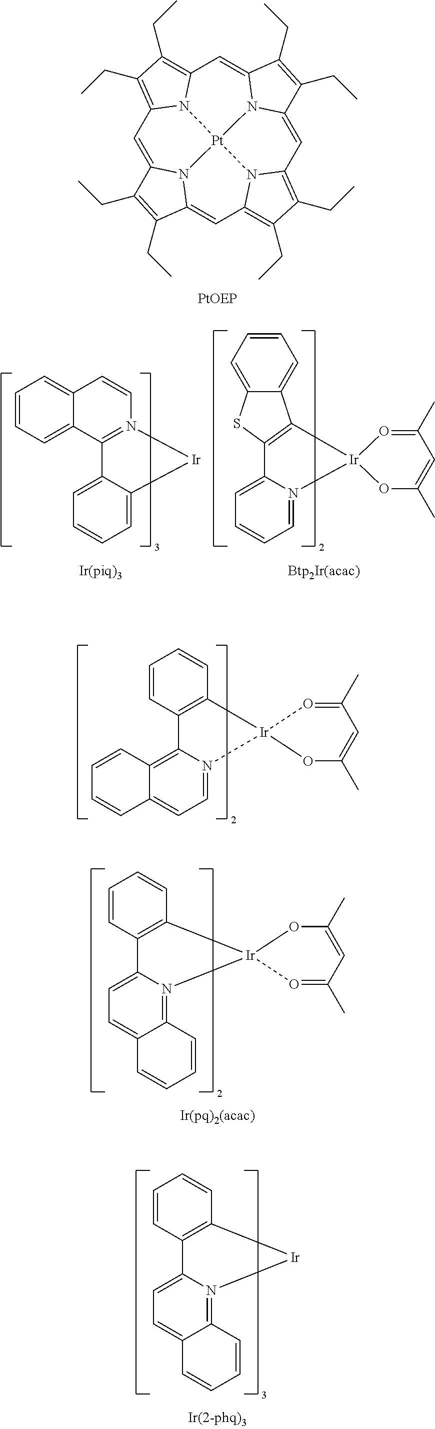

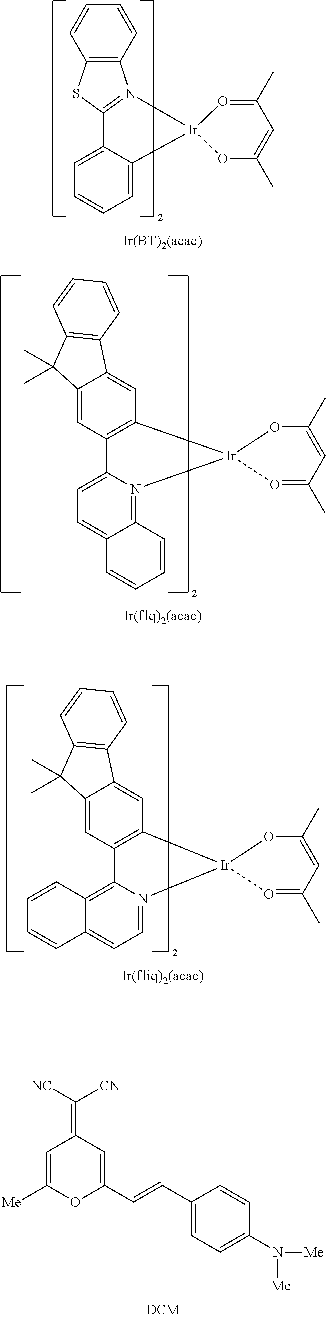

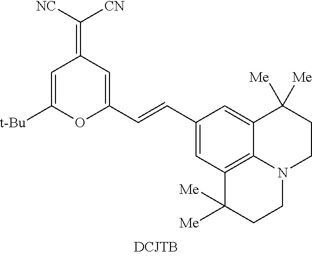 [SMILES: CC(C)(C)C1=CC(=C(C#N)C#N)C=C(/C=C/c2cc3c4c(c2)C(C)(C)CCN4CCC3(C)C)O1]

Examples of the green dopant include compounds represented by the following formulae. For example, the green dopant may be C545T represented below.

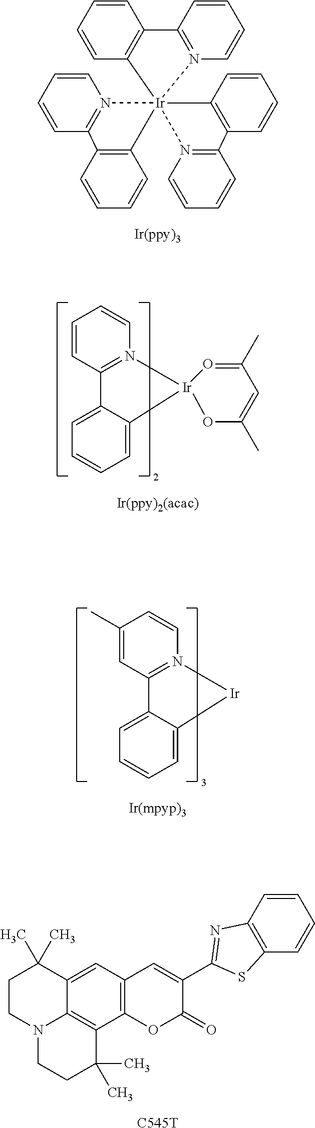

The thickness of the EML may be about 100 Å to about 1,000 Å, and in some embodiments, may be from about 200 Å to about 600 Å. When the thickness of the EML is within these ranges, the EML may have good light emitting ability without a substantial increase in driving voltage.

An ETL may be formed on the EML by vacuum deposition, spin coating, casting, or the like. When the ETL is formed using vacuum deposition or spin coating, the deposition and coating conditions may be similar to those for the formation of the HIL, though the deposition and coating conditions may vary depending on the compound that is used to form the ETL. A material for forming the ETL may be a suitable material that can stably transport electrons injected from an electron injecting electrode (cathode). Examples of materials for forming the ETL include a quinoline derivative, such as tris(8-quinolinorate)aluminum (Alq₃), TAZ, BAlq, beryllium bis(benzoquinolin-10-olate (Bebq₂), 9,10-di(naphthalene-2-yl)anthracene (ADN), Compound 201, and Compound 202.

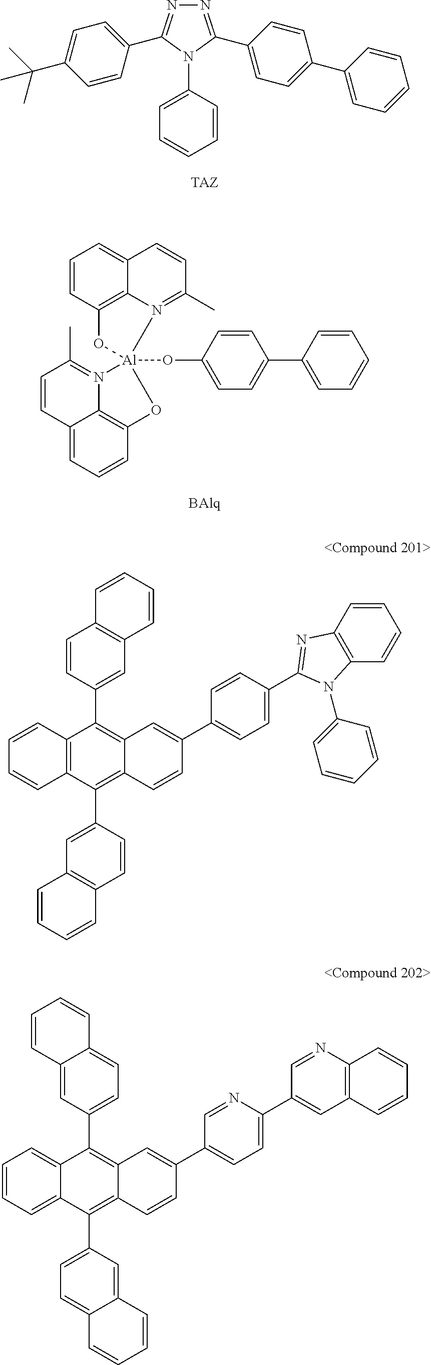

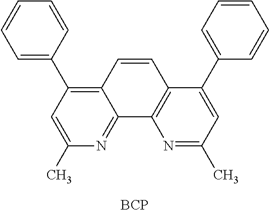 [SMILES: Cc1cc(-c2ccccc2)c2ccc3c(-c4ccccc4)cc(C)nc3c2n1 ; "BCP"]

The thickness of the ETL may be from about 100 Å to about 1,000 Å, and in some implementations, may be from about 150 Å to about 500 Å. When the thickness of the ETL is within these ranges, the ETL may have satisfactory electron transporting ability without a substantial increase in driving voltage.

In some implementations, the ETL may further include a metal-containing material, in addition to a suitable electron-transporting organic compound.

The metal-containing material may be a lithium (Li) complex. Examples of the Li complex include lithium quinolate (LiQ) and Compound 203 below:

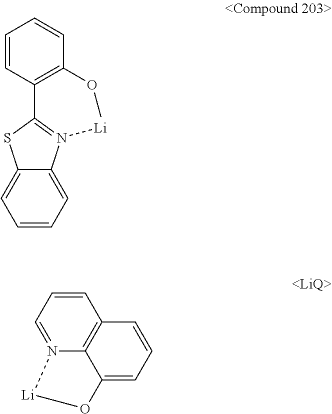

An EIL, which facilitates injection of electrons from the cathode, may be formed on the ETL. A suitable electron-injecting material may be used to form the EIL.

Examples of materials for forming the EIL include LiF, NaCl, CsF, Li₂O, and BaO. The deposition and coating conditions for forming the EIL may be similar to those for the formation of the HIL, though the deposition and coating conditions may vary depending on the material that is used to form the EIL.

The thickness of the EIL may be from about 1 Å to about 100 Å, and in some implementations, may be from about 3 Å to about 90 Å. When the thickness of the EIL is within these ranges, the EIL may have satisfactory electron injection ability without a substantial increase in driving voltage.

The second electrode 17 may be disposed on the organic layer 15. The second electrode 17 may be a cathode that is an electron injection electrode. A material for forming the second electrode 17 may be a metal, an alloy, an electro-conductive compound, which have a low work function, or a combination thereof. In this regard, the second electrode 17 may be formed of lithium (Li), magnesium (Mg), aluminum (Al), aluminum (Al)-lithium (Li), calcium (Ca), magnesium (Mg)-indium (In), magnesium (Mg)-silver (Ag), or the like, and may be formed as a thin film type transmission electrode. In some implementations, to manufacture a top-emission light-emitting device, the transmission electrode may be formed of indium tin oxide (ITO) or indium zinc oxide (IZO).

When a phosphorescent dopant is used in the EML, a HBL may be formed between the HTL and the EML or between the H-functional layer and the EML by using vacuum deposition, spin coating, casting, Langmuir-Blodgett (LB) deposition, or the like, in order to prevent diffusion of triplet excitons or holes into the ETL. When the HBL is formed using vacuum deposition or spin coating, the conditions for deposition and coating may be similar to those for the formation of the HIL, although the conditions for deposition and coating may vary depending on the material that is used to form the HBL. Any known hole-blocking material may be used. Examples of hole-blocking materials include oxadiazole derivatives, triazole derivatives, and phenanthroline derivatives. For example, bathocuproine (BCP) represented by the following formula may be used as a material for forming the HBL.

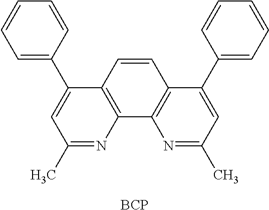 [SMILES: Cc1cc(-c2ccccc2)c2ccc3c(-c4ccccc4)cc(C)nc3c2n1 ; "BCP"]

The thickness of the HBL may be from about 20 Å to about 1,000 Å, and in some embodiments, may be from about 30 Å to about 300 Å. When the thickness of the HBL is within these ranges, the HBL may have improved hole blocking ability without a substantial increase in driving voltage.

As used herein, the unsubstituted C₁-C₆₀ alkyl group (or a C₁-C₆₀ alkyl group) may be a linear or branched C₁-C₆₀ alkyl group, such as a methyl group, an ethyl group, a propyl group, an isopropyl group, a sec-butyl group, a pentyl group, an iso-amyl group, and a hexyl group. The substituted C₁-C₆₀ alkyl group may be a C₁-C₆₀ alkyl group of which at least one hydrogen atoms is substituted with one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₁-C₆₀ fluoroalkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, —N(Q₁₁)(Q₁₂), and —Si(Q₁₃)(Q₁₄)(Q₁₅) (where Q₁₁ to Q₁₅ are each independently selected from a hydrogen atom, a C₁-C₆₀ alkyl group, a C₂-C₆₀ alkenyl group, a C₂-C₆₀ alkynyl group, a C₆-C₆₀ aryl group, and C₂-C₆₀ heteroaryl group).

As used herein, the unsubstituted C₁-C₆₀ alkoxy group (or a C₁-C₆₀ alkoxy group) may be a group represented by —OA, wherein A is an unsubstituted C₁-C₆₀ alkyl group described above. Examples of the unsubstituted C₁-C₆₀ alkoxy group are a methoxy group, an ethoxy group, and an isopropyloxy group. At least one of the hydrogen atoms in the alkoxy group may be substituted with the substituents described above in conjunction with the substituted C₁-C₆₀ alkyl group.

As used herein, the unsubstituted C₂-C₆₀ alkenyl group (or a C₂-C₆₀ alkenyl group) is a

C₂-C₆₀ alkyl group having at least one carbon-carbon double bond in the center or at a terminal thereof. Examples of the alkenyl group are an ethenyl group, a propenyl group, a butenyl group, and the like. At least one hydrogen atom in the unsubstituted C₂-C₆₀ alkenyl group may be substituted with those substituents described above in conjunction with the substituted C₁-C₆₀ alkyl group.

As used herein, the unsubstituted C₂-C₆₀ alkynyl group (or a C₂-C₆₀ alkynyl group) is a C₂-C₆₀ alkyl group having at least one carbon-carbon triple bond in the center or at a terminal thereof. Examples of the unsubstituted C₂-C₆₀ alkynyl group (or a C₂-C₆₀ alkynyl group) are an ethynyl group, a propynyl group, and the like. At least one hydrogen atom in the alkynyl group may be substituted with those substituents described above in conjunction with the substituted C₁-C₆₀ alkyl group.

As used herein, the unsubstituted C₆-C₆₀ aryl group is a monovalent group having a carbocyclic aromatic system having 6 to 60 carbon atoms including at least one aromatic ring. The unsubstituted C₅-C₆₀ arylene group is a divalent group having a carbocyclic aromatic system having 6 to 60 carbon atoms including at least one aromatic ring. When the aryl group and the arylene group have at least two rings, they may be fused to each other via a single bond. At least one hydrogen atom in the aryl group and the arylene group may be substituted with those substituents described above in conjunction with the C₁-C₆₀ alkyl group.

Examples of the substituted or unsubstituted C₆-C₆₀ aryl group include a phenyl group, a C₁-C₁₀ alkylphenyl group (e.g., an ethylphenyl group), a C₁-C₁₀ alkylbiphenyl group (e.g., an ethylbiphenyl group), a halophenyl group (e.g., an o-, m- or p-fluorophenyl group and a dichlorophenyl group), a dicyanophenyl group, a trifluoromethoxyphenyl group, an o-, m- or p-tolyl group, an o-, m- or p-cumenyl group, a mesityl group, a phenoxyphenyl group, a (α,α-dimethylbenzene)phenyl group, a (N,N-dimethyl)aminophenyl group, a (N,N′-diphenyl)aminophenyl group, a pentalenyl group, an indenyl group, a naphthyl group, a halonaphthyl group (e.g., a fluoronaphthyl group), a C₁-C₁₀ alkylnaphthyl group (e.g., a methylnaphthyl group), a C₁-C₁₀ alkoxynaphthyl group (e.g., a methoxynaphthyl group), an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylenyl group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, an ovalenyl group, and a spiro-fluorenyl group. Examples of the substituted C₆-C₆₀ aryl group may be inferred based on those of the unsubstituted C₆-C₆₀ aryl group and the substituted C₁-C₃₀ alkyl group described above. Examples of the substituted or unsubstituted C₆-C₆₀ arylene group may be inferred based on those examples of the substituted or unsubstituted C₆-C₆₀ aryl group described above.

As used herein, the unsubstituted C₂-C₆₀ heteroaryl group is a monovalent group having at least one aromatic ring having at least one of the heteroatoms selected from the group consisting of a nitrogen atom (N), an oxygen atom (O), a phosphorous atom (P), a sulfur atom (S) and a silicon atom (Si). The unsubstituted C₂-C₆₀ heteroarylene group is a divalent group having at least one aromatic ring having at least one of the heteroatoms selected from the group consisting of N, O, P, S and Si. In this regard, when the heteroaryl group and the heteroarylene group have at least two rings, they may be fused to each other via a single bond. At least one hydrogen atom in the heteroaryl group and the heteroarylene group may be substituted with those substituents described with reference to the C₁-C₆₀ alkyl group.

Examples of the unsubstituted C₂-C₆₀ heteroaryl group are a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoimidazolyl group, an imidazopyridinyl group, an imidazopyrimidinyl group. a furanyl group, a thiophenyl group, a benzofuranyl group, a benzothiophenyl group, a dibenzofuranyl group, and a dibenzothiophenyl group. Examples of the substituted or unsubstituted C₂-C₆₀ heteroarylene group may be inferred based on those examples of the substituted or unsubstituted C₂-C₆₀ arylene group described above.

The substituted or unsubstituted C₆-C₆₀ aryloxy group indicates —OA₂ (where A₂ is a substituted or unsubstituted C₆-C₆₀ aryl group described above). The substituted or unsubstituted C₆-C₆₀ arylthiol group indicates —SA₃ (where A₃ is a substituted or unsubstituted C₆-C₆₀ aryl group described above).

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

### Synthesis Example 1

### Synthesis of Compound 2

<Synthesis of Compound 2-1>

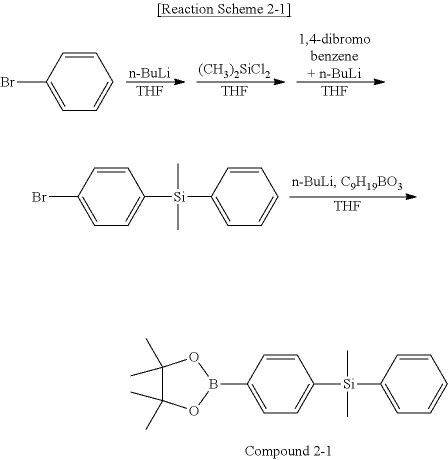

After 12 g (58.25 mmol) of 1-bromobenzene was dissolved in 200 ml of THF in a 500-ml 3-necked round flask (flask 1) in a nitrogen atmosphere, 23.65 ml (58.25 mmol) of 2.5M n-BuLi was slowly dropped into the solution at −78° C. and stirred for about 20 minutes while the temperature was maintained. Afterward, 6.93 g (54.17 mmol) of dimethyldichlorosilane was very slowly added dropwise into the mixture at −80° C. or less, and the temperature was slowly increased to about −10° C. or less, at which the mixture was further stirred for about 2 hours. After 18.97 g (80.39 mmol) of 1,4-dibromobenzene was dissolved in 200 ml of THF in a 250-ml 3-necked round flask (flask 2) in a nitrogen atmosphere, 32.63 ml (80.39 mmol) of n-BuLi was slowly dropped into the solution at −78° C. and stirred for about 20 minutes while the temperature was maintained. While the temperatures of the reaction products in flasks 1 and 2 were maintained at about −78° C., the reaction product in flask 2 was taken using a syringe, dropwise added into flask 1, and then stirred for about 12 hours. After termination of the reaction using water, the reaction product was extracted using chloroform. An organic layer was collected, and then dried to obtain a residue. The residue was purified by silica gel column chromatography using hexane as an eluent, followed by recrystallization using hexane to obtain (4-bromo-phenyl)-dimethyl-phenyl-yl-silane. After (4-bromo-phenyl)-dimethyl-phenyl-1-yl-silane and 250 ml of THF were put in a 500-ml 3-necked round flask, 14.21 ml (35 mmol) of 2.5M n-BuLi was slowly dropped into the solution at −78° C. and stirred for about 40 minutes while the temperature was maintained. Afterward, 6.55 g (35 mmol) of 2-isopropoxy-4,4,5,5,-tetramethyl-1,3,2-dioxaborane was slowly added into the mixture at −78° C. or less and stirred for about 30 minutes, and then further stirred for about 12 hours after the temperature was slowly increased. After termination of the reaction with a 10% HCl solution, the reaction product was extracted using ethylacetate. An organic layer was collected and dried to remove the solvent to obtain a residue. The residue was purified by silica gel column chromatography, followed by recrystallization using hexane to obtain Compound 2-1 (white solid, 3.94 g, 12.65 mmol, Yield: 20%). 1H NMR (300 MHz, a CDCl3) δ: 7.85 (2H), 7.55 (1H), 7.46 (4H), 7.37 (2H), 1.24 (12H), 0.66 (6H)

<Synthesis of Compound 2-2>

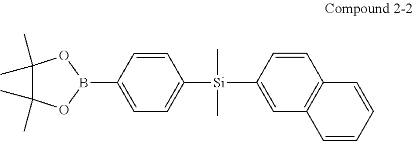 [SMILES: CC1(C)OB(c2ccc([Si](C)(C)c3ccc4ccccc4c3)cc2)OC1(C)C]

Compound 2-2 was synthesized in the same manner as in the synthesis of Compound 2-1, except that 2-bromonaphthalene, instead of 1-bromobenzene, was used (white solid, Yield: 22%).

1H NMR (300 MHz, a CDCl3) δ: 8.10 (1H), 8.00 (2H), 7.95 (1H), 7.85 (2H), 7.60 (1H), 7.59 (2H), 7.46 (2H), 1.24 (12H), 0.66 (6H)

<Synthesis of Compound 2>

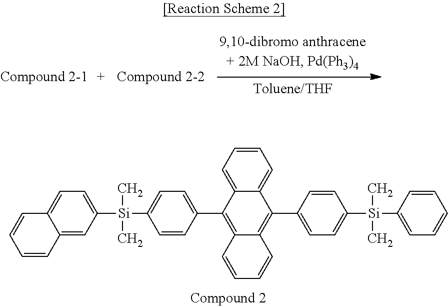 [SMILES: C[Si](C)(c1ccccc1)c1ccc(-c2c3ccccc3c(-c3ccc([Si](C)(C)c4ccc5ccccc5c4)cc3)c3ccccc23)cc1]

After 5 g (14.79 mmol) of Compound 2-1, 5.74 g (14.79 mmol) of Compound 2-2, and 4.28 g (12.86 mmol) of 9,10-dibromoanthracene were added to 300 ml of toluene in a 250-ml 3-necked flask with an addition of 100 ml of 2M NaOH, and reacted for about 30 minutes for nitrogen substitution, a catalytic amount of tetrakis(triphenylphosphine)palladium(0) was added thereto and reacted at about 100° C. for about 36 hours. After termination of the reaction with HCl, the reaction product was filtrated, washed several times with acetone, and then dried. The resulting product was subjected to soxhlet extraction with toluene to obtain Compound 2 (white solid, 4.10 g, 6.36 mmol, Yield: 43%)

1H NMR (300 MHz, a CDCl3) δ: 8.10 (1H), 8.00 (2H), 7.95 (1H), 7.91 (4H), 7.89 (4H), 7.60 (1H), 7.59 (2H), 7.55 (1H), 7.52 (4H), 7.46 (2H), 7.39 (4H), 7.37 (2H), 0.66 (12H).

HRMS(FAB): calcd for a C46H36Si2: 644.24, found: 644.95.

### Synthesis Example 2

### Synthesis of Compound 6

<Synthesis of Compound 6-1>

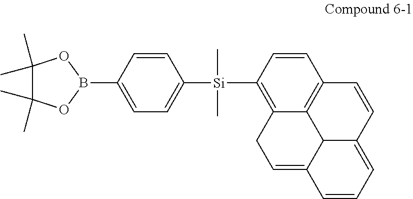 [SMILES: CC1(C)OB(c2ccc([Si](C)(C)c3ccc4c5c3CC=C3C=CC=C(C=C4)C35)cc2)OC1(C)C]

Compound 6-1 was synthesized in the same manner as in the synthesis of Compound 2-1, except that 1-bromopyrene, instead of 1-bromobenzene, was used (white solid, Yield: 20%).

1H NMR (300 MHz, a CDCl3) δ: 7.91 (1H), 7.85 (1H), 7.81 (1H), 7.46 (2H), 7.17 (1H), 7.10 (1H), 6.58 (1H), 6.44 (1H), 6.19 (1H), 6.00 (1H), 1.24 (12H), 0.66 (6H).

<Synthesis of Compound 6>

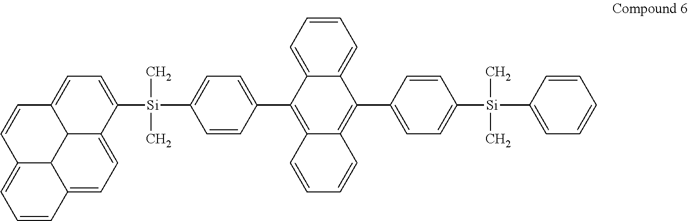 [SMILES: C[Si](C)(C1=CC=C2C=CC3=CC=CC4=CC=C1C2C34)c1ccc(-c2c3ccccc3c(-c3ccc([Si](C)(C)c4ccccc4)cc3)c3ccccc23)cc1]

Compound 6 was synthesized in the same manner as in the synthesis of Compound 2, except that Compound 6-1, instead of Compound 2-2, was used (Yield: 41%).

1H NMR (300 MHz, a CDCl3) δ: 7.98 (9H), 7.91 (4H), 7.89 (2H), 7.79 (2H), 7.55 (1H), 7.52 (2H), 7.46 (2H), 7.39 (4H), 7.37 (2H), 7.24 (2H), 4.82 (2H), 0.66 (12H).

HRMS(FAB): calcd for C52H40Si2: 720.27, found: 721.04.

### Synthesis Example 3

### Synthesis of Compound 13

<Synthesis of Compound 13-1>

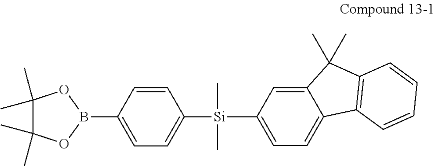 [SMILES: CC1(C)c2ccccc2-c2ccc([Si](C)(C)c3ccc(B4OC(C)(C)C(C)(C)O4)cc3)cc21]

Compound 13-1 was synthesized in the same manner as in the synthesis of Compound 2-1, except that 2-bromo-(9,9′-dimethyl)fluorene, instead of 1-bromobenzene, was used (white solid, Yield: 18%).

1H NMR (300 MHz, a CDCl3) δ: 7.97 (1H), 7.87 (1H), 7.85 (2H), 7.83 (1H), 7.66 (1H), 7.55 (1H), 7.46 (2H), 7.38 (1H), 7.28 (1H), 1.72 (6H), 1.24 (12H), 0.66 (6H).

<Synthesis of Compound 13>

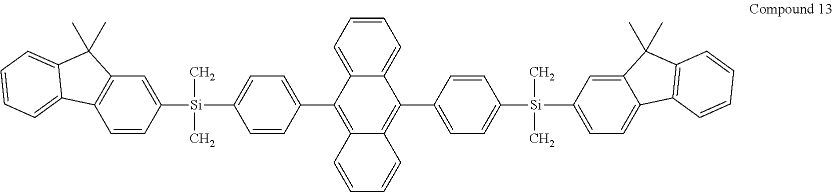 [SMILES: CC1(C)c2ccccc2-c2ccc([Si](C)(C)c3ccc(-c4c5ccccc5c(-c5ccc([Si](C)(C)c6ccc7c(c6)C(C)(C)c6ccccc6-7)cc5)c5ccccc45)cc3)cc21]

Compound 13 was synthesized in the same manner as in the synthesis of Compound 2, except that Compound 13-1, instead of Compound 2-1 and Compound 2-2, was used (Yield: 38%).

1H NMR (300 MHz, a CDCl3) δ: 7.97 (2H), 7.91 (4H), 7.89 (4H), 7.87 (2H), 7.83 (2H), 7.66 (2H), 7.55 (2H), 7.52 (4H), 7.39 (4H), 7.38 (2H), 7.28 (2H), 1.72 (12H), 0.66 (12H).

HRMS(FAB): calcd for C60H50Si2: 826.35, found: 827.21.

### Synthesis Example 4

### Synthesis of Compound 19

<Synthesis of Compound 19-1>

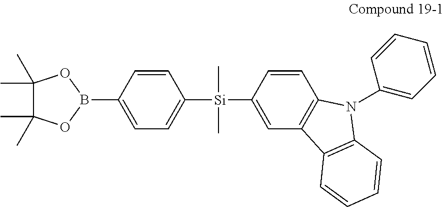 [SMILES: CC1(C)OB(c2ccc([Si](C)(C)c3ccc4c(c3)c3ccccc3n4-c3ccccc3)cc2)OC1(C)C]

Compound 19-1 was synthesized in the same manner as in the synthesis of Compound 2-1, except that 3-bromo-(9-phenyl)carbazole, instead of 3-bromobenzene, was used (white solid, Yield: 20%).

1H NMR (300 MHz, a CDCl3) δ: 8.55 (1H), 7.94 (1H), 7.85 (2H), 7.83 (1H), 7.73 (1H), 7.58 (2H), 7.50 (2H), 7.46 (2H), 7.45 (1H), 7.36 (1H), 7.33 (1H), 7.25 (1H), 1.24 (12H), 0.66 (6H).

<Synthesis of Compound 19>

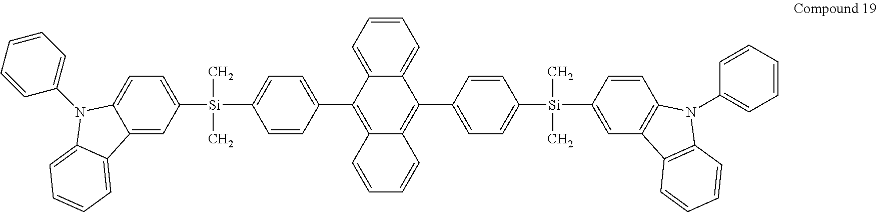 [SMILES: C[Si](C)(c1ccc(-c2c3ccccc3c(-c3ccc([Si](C)(C)c4ccc5c(c4)c4ccccc4n5-c4ccccc4)cc3)c3ccccc23)cc1)c1ccc2c(c1)c1ccccc1n2-c1ccccc1]

Compound 19 was synthesized in the same manner as in the synthesis of Compound 2, except that Compound 19-1, instead of Compound 2-1 and Compound 2-2, was used (Yield: 39%).

1H NMR (300 MHz, a CDCl3) δ: 8.55 (2H), 7.94 (2H), 7.91 (4H), 7.89 (4H), 7.83 (2H), 7.73 (2H), 7.58 (4H), 7.52 (4H), 7.50 (4H), 7.45 (2H), 7.39 (4H), 7.36 (2H), 7.33 (2H), 7.25 (2H), 0.66 (12H).

HRMS(FAB): calcd for C66H48N2Si2: 924.34, found: 925.27.

### Synthesis Example 5

### Synthesis of Compound 21

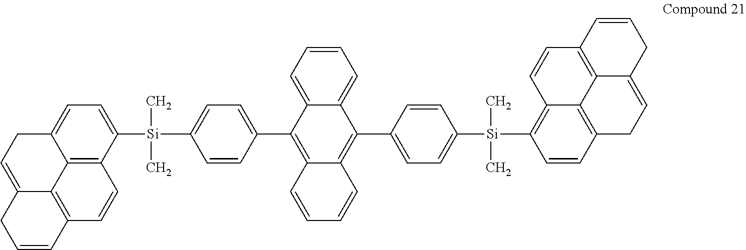 [SMILES: C[Si](C)(c1ccc(-c2c3ccccc3c(-c3ccc([Si](C)(C)c4ccc5c6c7c(ccc46)C=CCC7=CC5)cc3)c3ccccc23)cc1)c1ccc2c3c4c(ccc13)C=CCC4=CC2]

Compound 21 was synthesized in the same manner as in the synthesis of Compound 2, except that Compound 6-1, instead of Compound 2-1 and Compound 2-2, was used (Yield: 42%).

1H NMR (300 MHz, a CDCl3) δ: 8.37 (4H), 8.24 (6H), 8.12 (6H), 8.03 (2H), 7.81 (4H), 7.72 (4H), 7.46 (4H), 7.33 (4H), 0.98 (12H)

HRMS(FAB): calcd for C62H46Si2: 846.31, found: 847.20.

### Synthesis Example 6

### Synthesis of Compound 24

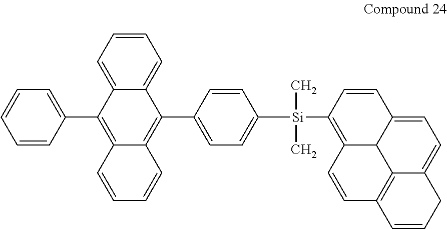 [SMILES: C[Si](C)(C1=C2C=CC3=C4C(=CC=C(C=C1)C24)CC=C3)c1ccc(-c2c3ccccc3c(-c3ccccc3)c3ccccc23)cc1]

Compound 24 was synthesized in the same manner as in the synthesis of Compound 2, except that 10-bromo-9-phenylanthracene, instead of 9,10-dibromoanthracene, and Compound 6-1, instead of Compound 2-1, were used, and Compound 2-2 was not used (Yield: 47%).

1H NMR (300 MHz, a CDCl3) δ: 7.98 (6H), 7.91 (4H), 7.79 (2H), 7.39 (4H), 7.24 (2H), 5.34 (1H), 3.22 (2H), 2.05 (6H), 0.66 (6H).

HRMS(FAB): calcd for C44H32Si: 588.23, found: 588.81.

### Synthesis Example 7

### Synthesis of Compound 32

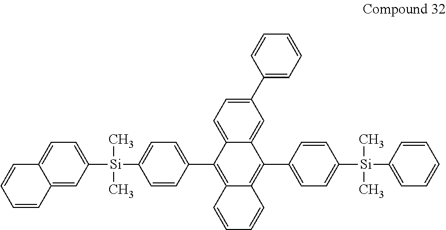 [SMILES: C[Si](C)(c1ccccc1)c1ccc(-c2c3ccccc3c(-c3ccc([Si](C)(C)c4ccc5ccccc5c4)cc3)c3ccc(-c4ccccc4)cc23)cc1]

Compound 32 was synthesized in the same manner as in the synthesis of Compound 2, except that 2-phenyl-9,10-dibromoanthracene, instead of 9,10-dibromoanthracene, was used.

1H NMR (300 MHz, a CDCl3) δ: 8.99 (1H), 8.42 (1H), 8.20 (2H), 8.12 (1H), 8.08 (1H), 8.02 (1H), 8.01 (1H), 7.87 (4H), 7.76 (1H), 7.75 (2H), 7.65 (4H), 7.59 (2H), 7.49 (2H), 7.47 (2H), 7.46 (2H), 7.42 (1H), 7.41 (1H), 7.37 (3H), 0.66 (12H).

HRMS(FAB): calcd for C52H44Si2: 724.30, found: 725.09.

### Synthesis Example 8

### Synthesis of Compound 36

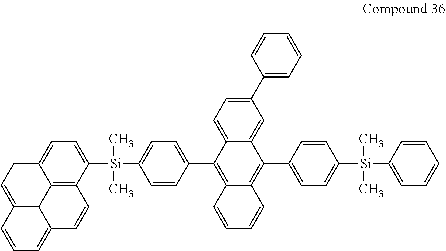 [SMILES: C[Si](C)(c1ccccc1)c1ccc(-c2c3ccccc3c(-c3ccc([Si](C)(C)c4ccc5c6c4C=CC4=CC=CC(=CC5)C46)cc3)c3ccc(-c4ccccc4)cc23)cc1]

Compound 36 was synthesized in the same manner as in the synthesis of Compound 6, except that 2-phenyl-9,10-dibromoanthracene, instead of 9,10-dibromoanthracene, was used.

1H NMR (300 MHz, a CDCl3) δ: 8.99 (1H), 8.42 (1H), 8.20 (2H), 8.12 (1H), 8.08 (1H), 8.02 (1H), 8.01 (1H), 7.93 (1H), 7.91 (1H), 7.87 (4H), 7.76 (1H), 7.75 (2H), 7.65 (4H), 7.59 (2H), 7.49 (2H), 7.47 (2H), 7.46 (2H), 7.42 (1H), 7.41 (1H), 7.37 (3H), 6.58 (1H), 6.44 (1H), 6.19 (1H), 6.00 (1H), 0.66 (12H).

HRMS(FAB): calcd for C58H48Si2: 800.33, found: 801.19.

### Synthesis Example 9

### Synthesis of Compound 43

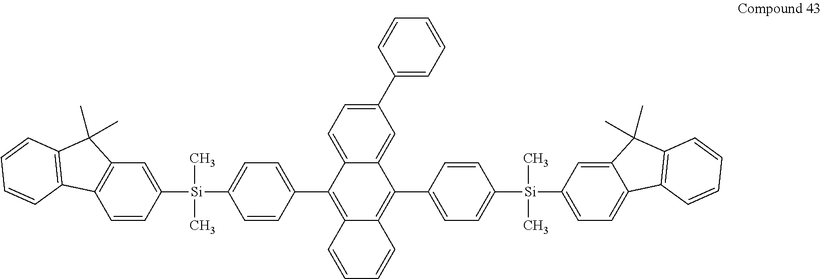 [SMILES: CC1(C)c2ccccc2-c2ccc([Si](C)(C)c3ccc(-c4c5ccccc5c(-c5ccc([Si](C)(C)c6ccc7c(c6)C(C)(C)c6ccccc6-7)cc5)c5cc(-c6ccccc6)ccc45)cc3)cc21]

Compound 43 was synthesized in the same manner as in the synthesis of Compound 13, except that 2-phenyl-9,10-dibromoanthracene, instead of 9,10-dibromoanthracene, was used.

1H NMR (300 MHz, a CDCl3) δ: 8.99 (1H), 8.42 (1H), 8.20 (2H), 8.00 (2H), 7.90 (2H), 7.87 (4H), 7.83 (2H), 7.75 (2H), 7.66 (2H), 7.65 (4H), 7.55 (2H), 7.49 (2H), 7.47 (2H), 7.42 (1H), 7.41 (1H), 7.38 (2H), 7.28 (2H), 1.69 (12H), 0.66 (12H).

HRMS (FAB): calcd for C66H58Si2: 906.41, found: 907.36.

### Synthesis Example 10

### Synthesis of Compound 49

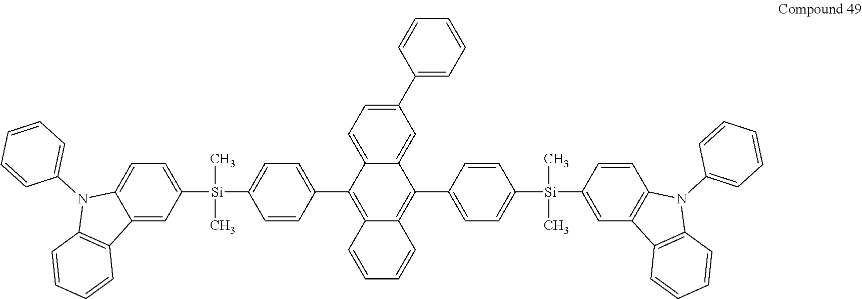 [SMILES: C[Si](C)(c1ccc(-c2c3ccccc3c(-c3ccc([Si](C)(C)c4ccc5c(c4)c4ccccc4n5-c4ccccc4)cc3)c3cc(-c4ccccc4)ccc23)cc1)c1ccc2c(c1)c1ccccc1n2-c1ccccc1]

Compound 49 was synthesized in the same manner as in the synthesis of Compound 19, except that 2-phenyl-9,10-dibromoanthracene, instead of 9,10-dibromoanthracene, was used.

1H NMR (300 MHz, a CDCl3) δ: 8.99 (1H), 8.55 (1H), 8.42 (1H), 8.20 (2H), 8.19 (1H), 8.04 (1H), 7.94 (1H), 7.87 (4H), 7.83 (2H), 7.75 (2H), 7.68 (1H), 7.65 (4H), 7.62 (4H), 7.58 (3H), 7.50 (5H), 7.49 (2H), 7.47 (2H), 7.42 (1H), 7.41 (1H), 7.36 (2H), 7.35 (1H), 7.20 (1H), 7.16 (1H), 0.66 (12H).

HRMS(FAB): calcd for C72H56N2Si2: 1004.40, found: 1005.42.

### Synthesis Example 11

### Synthesis of Compound 51

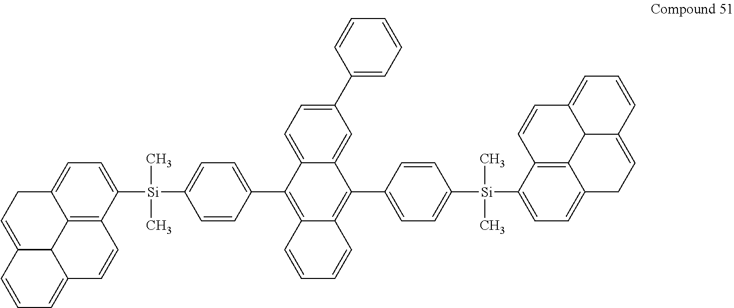 [SMILES: C[Si](C)(c1ccc(-c2c3ccccc3c(-c3ccc([Si](C)(C)c4ccc5c6c4C=CC4=CC=CC(=CC5)C46)cc3)c3cc(-c4ccccc4)ccc23)cc1)c1ccc2c3c1C=CC1=CC=CC(=CC2)C13]

Compound 51 was synthesized in the same manner as in the synthesis of Compound 21, except that 2-phenyl-9,10-dibromoanthracene, instead of 9,10-dibromoanthracene, was used.

1H NMR (300 MHz, a CDCl3) δ: 8.99 (1H), 8.42 (1H), 8.20 (2H), 7.93 (2H), 7.91 (2H), 7.87 (4H), 7.75 (2H), 7.65 (4H), 7.49 (2H), 7.47 (2H), 7.42 (3H), 7.41 (3H), 6.58 (2H), 6.44 (2H), 6.19 (2H), 6.00 (2H), 0.66 (12H).

HRMS (FAB): calcd for C68H54Si2: 926.38, found: 927.35.

### Synthesis Example 12

### Synthesis of Compound 55

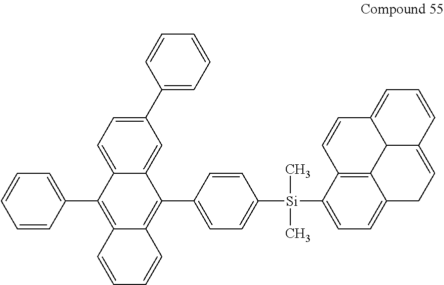 [SMILES: C[Si](C)(c1ccc(-c2c3ccccc3c(-c3ccccc3)c3ccc(-c4ccccc4)cc23)cc1)c1ccc2c3c1C=CC1=CC=CC(=CC2)C13]

Compound 55 was synthesized in the same manner as in the synthesis of Compound 24, except that 2-phenyl-9,10-dibromoanthracene, instead of 9,10-dibromoanthracene, was used.

1H NMR (300 MHz, a CDCl3) δ: 8.99 (1H), 8.42 (1H), 8.20 (2H), 7.93 (1H), 7.91 (1H), 7.87 (2H), 7.75 (2H), 7.65 (4H), 7.55 (2H), 7.49 (2H), 7.47 (2H), 7.42 (2H), 7.41 (3H), 6.58 (1H), 6.44 (1H), 6.19 (1H), 6.00 (1H), 0.66 (6H).

HRMS (FAB): calcd for C50H38Si: 666.27, found: 666.94.

### Synthesis Example 13

### Synthesis of Compound 103

<Synthesis of Compound 103-1>

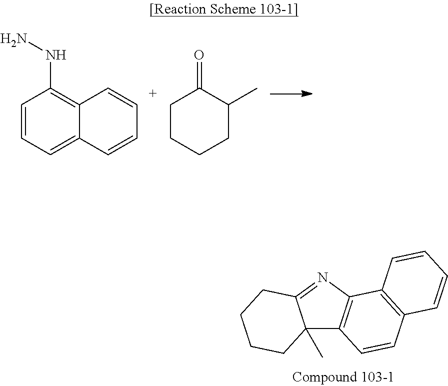

50 g (316.30 mmol) of 1-naphthylhydrazine and 170 mL of acetic acid were put into a 500-mL-round-bottomed flask, and heated to about 60° C., followed by dropwise adding 35.45 g (316.30 mmol) of 2-methylcyclohexanone into the heated flask to obtain a mixture, which was then refluxed for about 8 hours. After completion of the reaction, 100 mL of water was added into the reaction product, followed by basification with sodium hydroxide, and extraction with ethyl acetate to collect an organic layer. The organic layer was dried using magnesium sulfate, and then concentrated in a reduced pressure, followed by separation using column chromatography with hexane and ethyl acetate as eluents to obtain Compound 103-1 (62.47 g, 265.69 mmol, Yield: 84%).

<Synthesis of Compound 103-2>

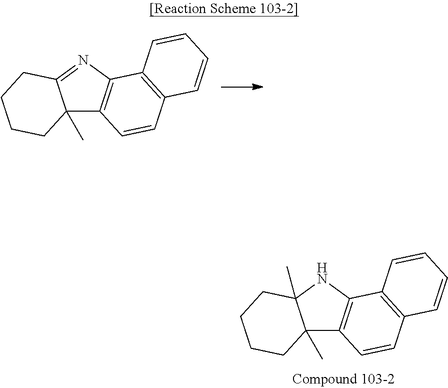 [SMILES: CC12CCCCC1=Nc1c2ccc2ccccc12 ; CC12CCCCC1(C)c1ccc3ccccc3c1N2]

50 g (212.64 mmol) of Compound 103-1 was put into a 2 L-round-bottomed flask in a nitrogen atmosphere, and dissolved in 570 mL of toluene, followed by cooling down to about −10° C. 202 mL (318.96 mmol) of 1.6M methyl lithium was slowly dropwise added into the solution, and reacted at about −10° C. for about 3 hours. After completion of the reaction, water was slowly added into the reaction product to quench the reaction. The resulting product was extracted with ethyl acetate to collect an organic layer. The organic layer was dried using magnesium sulfate, and then concentrated in a reduced pressure to remove the solvent, followed by purification using column chromatography with hexane and ethyl acetate as eluents to obtain Compound 103-2 (40.59 g, 161.61 mmol, Yield: 76%)

<Synthesis of Compound 103>

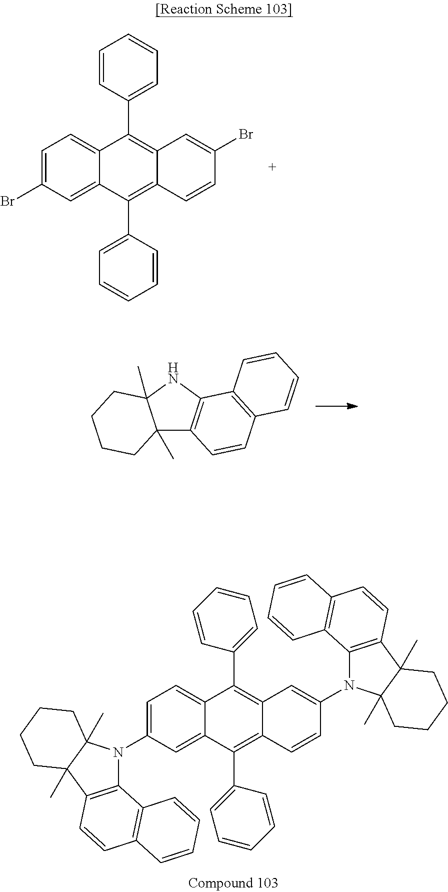 [SMILES: Brc1ccc2c(-c3ccccc3)c3cc(Br)ccc3c(-c3ccccc3)c2c1 ; CC12CCCCC1(C)c1ccc3ccccc3c1N2 ; CC12CCCCC1(C)N(c1ccc3c(-c4ccccc4)c4cc(N5c6c(ccc7ccccc67)C6(C)CCCCC56C)ccc4c(-c4ccccc4)c3c1)c1c2ccc2ccccc12]

10 g (20.58 mmol) of 2,6-dibromo-9,10-diphenylanthracene, 13.69 g (54.53 mmol) of Compound 103-2, 0.24 g (0.82 mmol) of palladium acetate (Pd(OAc)₂), 8.11 g (83.54 mmol) of sodium tert-butoxide (t-BuONa), 0.16 g (0.82 mmol) of (t-Bu)₃P, and 100 ml of toluene were put into a round-bottomed flask, and then reacted at a temperature of about 100° C. for about 2 hours. After termination of the reaction, the reaction product was filtered, followed by concentrating the filtrate and purification using column chromatography. After recrystallization with toluene and methanol, the resulting solid was filtrated and then dried to obtain Compound 103 (7.68 g, 9.26 mmol, Yield: 45%).

MS: m/z 829 [M]⁺

¹H NMR (CDCl₃) δ 8.12 (2H), 8.03 (2H), 7.65 (4H), 7.63 (2H), 7.55 (4H), 7.53 (2H), 7.41 (2H), 7.39 (2H), 7.38 (2H), 7.29 (2H), 7.09 (2H), 6.99 (2H), 2.00 (4H), 1.70 (4H), 1.53 (8H), 1.41 (6H), 1.35 (6H).

### Synthesis Example 14

### Synthesis of Compound 117

<Synthesis of Compound 117-1>

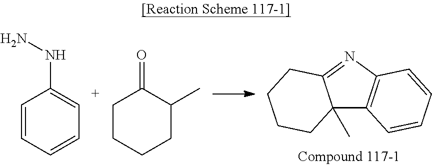

Compound 117-1 was synthesized in the same manner as in the synthesis of Compound 103-1, except that 50 g (462 mmol) of phenyl hydrazine, instead of 1-naphthylhydrazine, was used (72 g, 388.08 mmol, Yield: 84%).

<Synthesis of Compound 117-2>

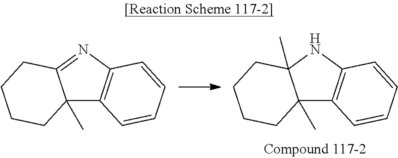

Compound 117-2 was synthesized in the same manner as in the synthesis of Compound 103-2, except that 50 g (308 mmol) of Compound 117-1, instead of Compound 103-1, was used (47 g, 234.08 mmol, Yield: 76%).

<Synthesis of Compound 117-3>

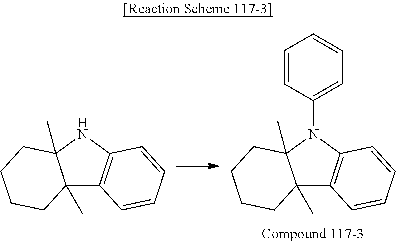 [SMILES: CC12CCCCC1(C)c1ccccc1N2 ; CC12CCCCC1(C)N(c1ccccc1)c1ccccc12]

40 g (199 mmol) of Compound 117-2, 48.6 g (238 mmol) of iodobenzene, 0.89 g (4 mmol) of tris(dibenzylidene acetone)dipalladium (0), 2.47 g (4 mmol) of 2,2-bisdiphenylphosphino-1,1′-binaphthyl, 38.19 g (397 mmol) of sodium tert-butoxide (t-BuONa), and 400 mL of toluene were put into a 1-L round-bottomed flask, and then refluxed for about 8 hours. After completion of the reaction, the reaction product was filtered through a Celite, and the resulting filtrate was concentrated in a reduced pressure to remove the solvent, followed by purification using column chromatography with hexane and ethyl acetate as eluents to obtain Compound 117-3 (44 g, 157.21 mmol, Yield: 79%)

<Synthesis of Compound 117-4>

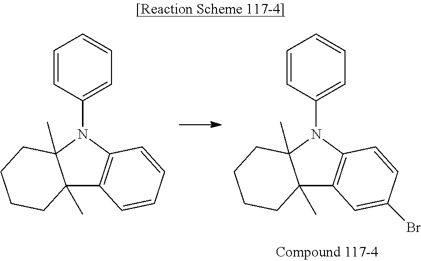 [SMILES: CC12CCCCC1(C)N(c1ccccc1)c1ccccc12 ; CC12CCCCC1(C)N(c1ccccc1)c1ccc(Br)cc12]

44 g (158 mmol) of Compound 117-3 and 130 mL of dimethylformamide were put into a 500-mL round-bottomed flask, followed by cooling down to about 0° C. A solution of 25.2 g (142 mmol) of N-bromosuccinimide dissolved in 200 mL of dimethylformamide was slowly dropwise added into the flask, followed by increasing the temperature to room temperature and stirring for about 2 hours. After completion of the reaction, water was added into the reaction product, followed by extraction with dichloromethane to collect an organic layer. The organic layer was dried using magnesium sulfate, and then concentrated in a reduced pressure to remove the solvent, followed by recrystallization with hexane to obtain Compound 117-4 (45 g, 126.4 mol, Yield: 80%).

<Synthesis of Compound 117-5>

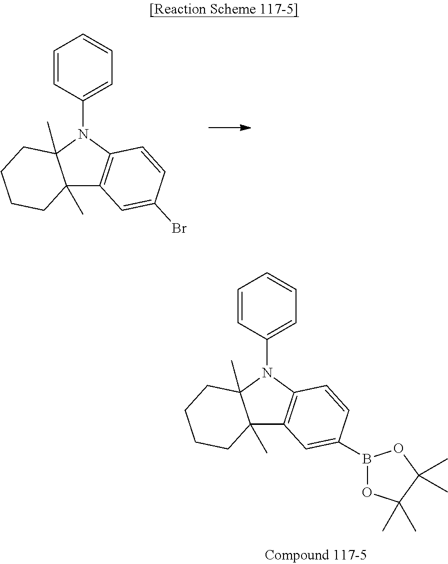 [SMILES: CC12CCCCC1(C)N(c1ccccc1)c1ccc(Br)cc12 ; CC1(C)OB(c2ccc3c(c2)C2(C)CCCCC2(C)N3c2ccccc2)OC1(C)C]

40 g (112 mmol) of Compound 117-4, 34 g (134 mmol) of bis(pinacolato)diboron, 2.73 g (3 mmol) of palladium(II) chloride-1-1′-bis(diphenylphospino)ferrocene, 32.9 g (335 mmol) of potassium acetate, and 480 mL of toluene were put into a 1-L round-bottomed flask, and then refluxed for about 8 hours. After completion of the reaction, the reaction product was filtered through a Celite, and the resulting filtrate was concentrated in a reduced pressure to remove the solvent, followed by purification using column chromatography with hexane and ethyl acetate as eluents to obtain Compound 117-5 (26 g, 64.96 mmol, Yield: 58%).

<Synthesis of Compound 117>

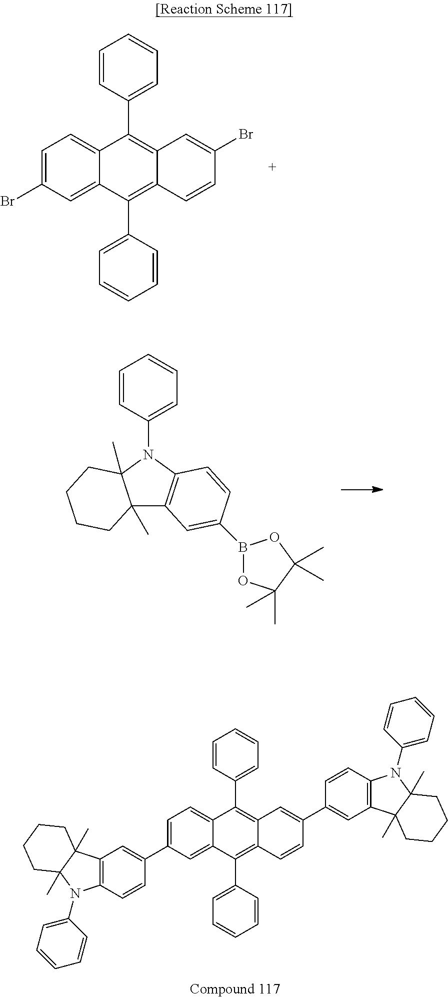 [SMILES: Brc1ccc2c(-c3ccccc3)c3cc(Br)ccc3c(-c3ccccc3)c2c1 ; CC1(C)OB(c2ccc3c(c2)C2(C)CCCCC2(C)N3c2ccccc2)OC1(C)C ; CC12CCCCC1(C)N(c1ccccc1)c1ccc(-c3ccc4c(-c5ccccc5)c5cc(-c6ccc7c(c6)C6(C)CCCCC6(C)N7c6ccccc6)ccc5c(-c5ccccc5)c4c3)cc12]

5.0 g (10.29 mmol) of 2,6-dibromo-9,10-diphenylanthracene, 9.30 g (23.97 mmol) of Compound 117-5, 0.45 g (0.34 mmol) of tetrakis(triphenylphospine)palladium, 4.12 g (29.72 mmol) of potassium carbonate, 25 mL of 1,4-dioxane, 25 mL of toluene, and 10 mL of water were put into a round-bottomed flask, and then refluxed. After completion of the reaction, water and hexane were added into the reaction product, followed by filtering the resulting crystals, and recrystallizing the crystals to obtain Compound 117 (6.07 g, 6.89 mmol, Yield: 67%).

MS: m/z 881[M]⁺

¹H NMR (CDCl₃) δ 8.97 (2H), 8.40 (2H), 7.89 (2H), 7.65 (4H), 7.55 (4H), 7.52 (2H), 7.41 (2H), 7.40 (4H), 7.35 (2H), 7.33 (4H), 7.29 (2H), 7.06 (2H), 2.00 (4H), 1.70 (4H), 1.53 (8H), 1.35 (12H).

### Example 1

As a substrate and anode, a corning 15 Ω/cm² (1200 Å) ITO glass substrate was cut to a size of 50 mm×50 mm×0.7 mm and then sonicated in isopropyl alcohol and pure water each for five minutes, and then cleaned by irradiation of ultraviolet rays for 30 minutes and exposure to ozone. The resulting glass substrate was loaded into a vacuum deposition device.

2-TNATA was deposited on the ITO glass layer (anode) of the substrate to form an HIL having a thickness of 600 Å on the anode, and then 4.4′-bis[N-(1-naphthyl)-N-phenylamino]biphenyl (NPS) was deposited on the HIL to form a HTL having a thickness of 300 Å.

Compound 32 (as a host) and Compound 103 (as a dopant) were co-deposited on the HTL in a weight ratio of about 95:5 to form an EML having a thickness of about 400 Å.

Compound 201 was deposited on the EML to form an ETL having a thickness of about 300 Å, and then LiF was deposited on the ETL to form an EIL having a thickness of about 10 Å. Then, Al was deposited on the EIL to form a second electrode (cathode) having a thickness of about 1100 Å, thereby completing the manufacture of an organic light-emitting device.

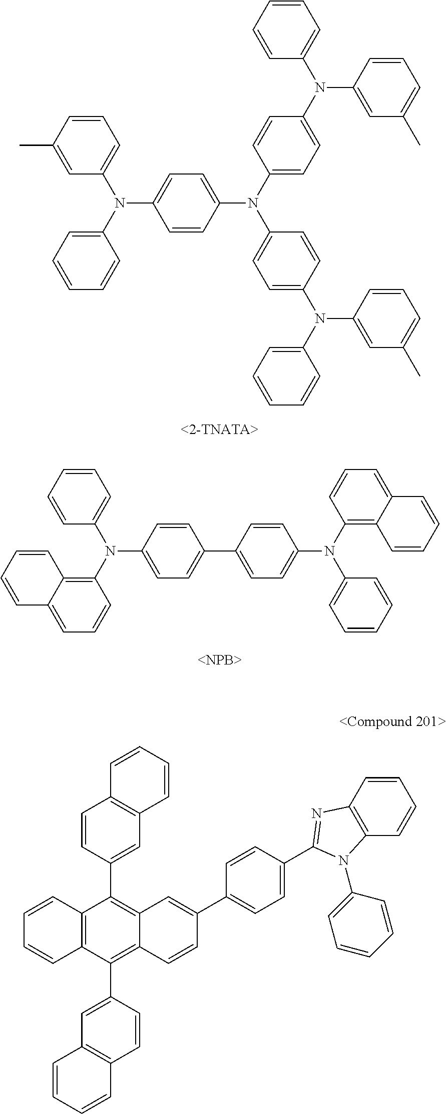

### Example 2

An organic light-emitting device was manufactured in the same manner as in Example 1, except that Compound 36, instead of Compound 32, was used to form the EML.

### Example 3

An organic light-emitting device was manufactured in the same manner as in Example 1, except that Compound 43, instead of Compound 32, was used to form the EML.

### Example 4

An organic light-emitting device was manufactured in the same manner as in Example 1, except that Compound 49, instead of Compound 32, was used to form the EML.

### Example 5

An organic light-emitting device was manufactured in the same manner as in Example 1, except that Compound 51, instead of Compound 32, was used to form the EML.

### Example 6

An organic light-emitting device was manufactured in the same manner as in Example 1, except that Compound 55, instead of Compound 32, was used to form the EML.

### Example 7

An organic light-emitting device was manufactured in the same manner as in Example 1, except that Compound 117, instead of Compound 103, was used to form the EML.

### Example 8

An organic light-emitting device was manufactured in the same manner as in Example 7, except that Compound 36, instead of Compound 32, was used to form the EML.

### Example 9

An organic light-emitting device was manufactured in the same manner as in Example 7, except that Compound 43, instead of Compound 32, was used to form the EML.

### Example 10

An organic light-emitting device was manufactured in the same manner as in Example 7, except that Compound 49, instead of Compound 32, was used to form the EML.

### Example 11

An organic light-emitting device was manufactured in the same manner as in Example 7, except that Compound 51, instead of Compound 32, was used to form the EML.

### Example 12

An organic light-emitting device was manufactured in the same manner as in Example 7, except that Compound 55, instead of Compound 32, was used to form the EML.

### Comparative Example 1

An organic light-emitting device was manufactured in the same manner as in Example 1, except that Host A below, instead of Compound 32, was used to form the EML.

<Host A>

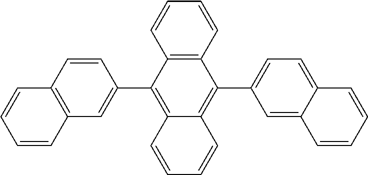 [SMILES: c1ccc2cc(-c3c4ccccc4c(-c4ccc5ccccc5c4)c4ccccc34)ccc2c1]

### Comparative Example 2

An organic light-emitting device was manufactured in the same manner as in Example 7, except that Host A above, instead of Compound 32, was used to form the EML.

### Comparative Example 3

An organic light-emitting device was manufactured in the same manner as in Example 1, except that Host B below and dopant A, instead of Compound 32 and Compound 103, respectively, were used to form the EML.

<Host B>

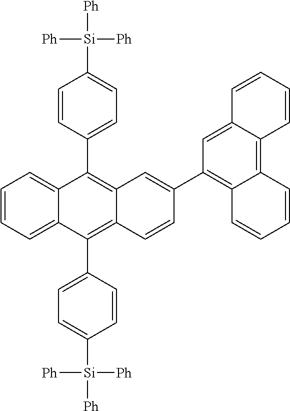 [SMILES: c1ccc([Si](c2ccccc2)(c2ccccc2)c2ccc(-c3c4ccccc4c(-c4ccc([Si](c5ccccc5)(c5ccccc5)c5ccccc5)cc4)c4cc(-c5cc6ccccc6c6ccccc56)ccc34)cc2)cc1]

<Dopant A>

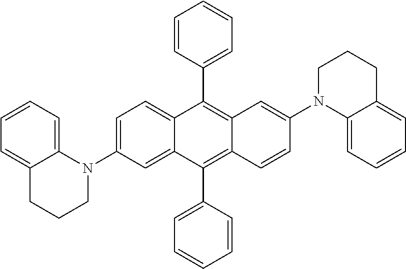 [SMILES: c1ccc(-c2c3ccc(N4CCCc5ccccc54)cc3c(-c3ccccc3)c3ccc(N4CCCc5ccccc54)cc23)cc1]

### Comparative Example 4

An organic light-emitting device was manufactured in the same manner as in Example 1, except that Host A below and Dopant B below, instead of Compound 32 and Compound 103, respectively, were used to form the EML.

<Dopant B>

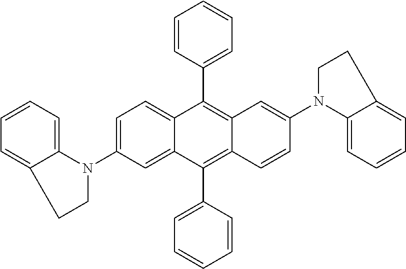 [SMILES: c1ccc(-c2c3ccc(N4CCc5ccccc54)cc3c(-c3ccccc3)c3ccc(N4CCc5ccccc54)cc23)cc1]

### Evaluation Example

Driving voltages, current densities, efficiencies, and color purities of the organic light-emitting devices of Examples 1 to 12 and Comparative Examples 1 to 4 were measured using a PR650 (Spectroscan) Source Measurement Unit (available from Photo Research, Inc.) while supplying power using a Kethley Source-Measure Unit (SMU 236). The results are shown in Table 1 below. In Table 1, T95 lifetime indicates the time taken until an initial luminocity (assumed as 100%) measured at a current density of about 10 mA/cm² is reduced to 95%.

TABLE 1

| | | | Driving | | Color | | T95 |
|---|---|---|---|---|---|---|---|
| | | | voltage | Efficiency | coordinates | | lifetime |
| Example | Host | Dopant | (V) | (cd/A) | CIE x | CIE y | [hr] |
| Example 1 | Compound 32 | Compound 103 | 5.0 | 28.4 | 0.23 | 0.62 | 400 |
| Example 2 | Compound 36 | Compound 103 | 5.4 | 33.4 | 0.24 | 0.62 | 550 |
| Example 3 | Compound 43 | Compound 103 | 4.8 | 26.7 | 0.24 | 0.62 | 400 |
| Example 4 | Compound 49 | Compound 103 | 4.8 | 25.8 | 0.24 | 0.62 | 400 |
| Example 5 | Compound 51 | Compound 103 | 5.4 | 34.5 | 0.25 | 0.62 | 600 |
| Example 6 | Compound 55 | Compound 103 | 5.4 | 32.8 | 0.24 | 0.62 | 550 |
| Example 7 | Compound 32 | Compound 117 | 5.1 | 26.5 | 0.24 | 0.62 | 400 |
| Example 8 | Compound 36 | Compound 117 | 5.4 | 32.7 | 0.24 | 0.62 | 560 |
| Example 9 | Compound 43 | Compound 117 | 4.8 | 24.8 | 0.24 | 0.62 | 400 |
| Example 10 | Compound 49 | Compound 117 | 4.8 | 22.7 | 0.25 | 0.62 | 400 |
| Example 11 | Compound 51 | Compound 117 | 5.4 | 32.8 | 0.24 | 0.62 | 650 |
| Example 12 | Compound 55 | Compound 117 | 5.4 | 30.5 | 0.23 | 0.62 | 570 |
| Comparative | Host A | Compound 93 | 5.6 | 22.4 | 0.24 | 0.62 | 340 |
| Example 1 | | | | | | | |
| Comparative | Host A | Compound 117 | 5.5 | 20.5 | 0.26 | 0.61 | 300 |
| Example 2 | | | | | | | |
| Comparative | Host B | Dopant A | 6.2 | 20.1 | 0.24 | 0.62 | 250 |
| Example 3 | | | | | | | |
| Comparative | Host A | Dopant B | 6.0 | 21.5 | 0.24 | 0.62 | 220 |
| Example 4 | | | | | | | |

Referring to Table 1, the organic light-emitting devices of Examples 1 to 12 were found to have lower driving voltages, higher efficiencies, improved lifetimes, and better color purity characteristics, compared to the organic light-emitting devices of Comparative Examples 1 to 4.

By way of summation and review, one or more embodiments include an organic light-emitting device (OLED) with improved efficiency and improved lifetime.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope thereof as set forth in the following claims.

What is claimed is:

1. An organic light-emitting device, comprising: a first electrode; a second electrode opposite to the first electrode; and an organic layer between the first electrode and the second electrode, and the organic layer including an emission layer that includes at least one silane-based compound represented by Formula 1 below and at least one anthracene-based compound represented by Formula 20 below. 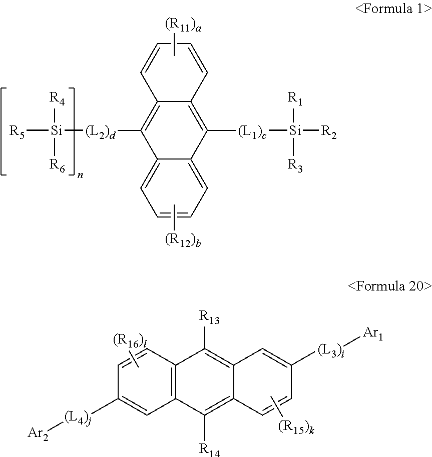
wherein, in Formulae 1 and 20 above,
n is 0 or 1;
R₁ to R₆ are each independently selected from a substituted or unsubstituted C₁-C₆₀ alkyl group, a 3- to 10-membered substituted or unsubstituted non-condensed ring group, and a substituted or unsubstituted condensed ring group in which at least two rings are fused to each other, wherein when n is 0, at least one of R₁ to R₃ is a substituted or unsubstituted condensed ring group in which at least two rings are fused to each other, and when n is 1 at least one of R₁ to R₆ is a substituted or unsubstituted condensed ring group in which at least two rings are fused to each other;
L₁ to L₄ are each independently selected from a substituted or unsubstituted C₃-C₁₀ cycloalkylene group, a substituted or unsubstituted C₃-C₁₀ cycloalkenylene group, a substituted or unsubstituted C₃-C₁₀ heterocycloalkylene group, a substituted or unsubstituted C₃-C₁₀ heterocycloalkenylene group, a substituted or unsubstituted C₆-C₆₀ arylene group, and a substituted or unsubstituted C₂-C₆₀ heteroarylene group;
c and d are each independently an integer from 1 to 3;
R₁₁ to R₁₆ are each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthiol group, a substituted or unsubstituted C₂-C₆₀ heteroaryl group, —N(Q₁)(Q₂), and —Si(Q₃)(Q₄)(Q₅) (where Q₁ to Q₅ are each independently selected from a hydrogen atom, a C₁-C₁₀ alkyl group, a C₆-C₂₀ aryl group, and a C₂-C₂₀ heteroaryl group);
a and b are each independently an integer from 1 to 4;
l and k are each independently an integer from 1 to 3;
i and j are each independently an integer from 0 to 3; and
Ar₁ and Ar₂ are each independently one of the groups represented by Formulae 7A to 7F below: 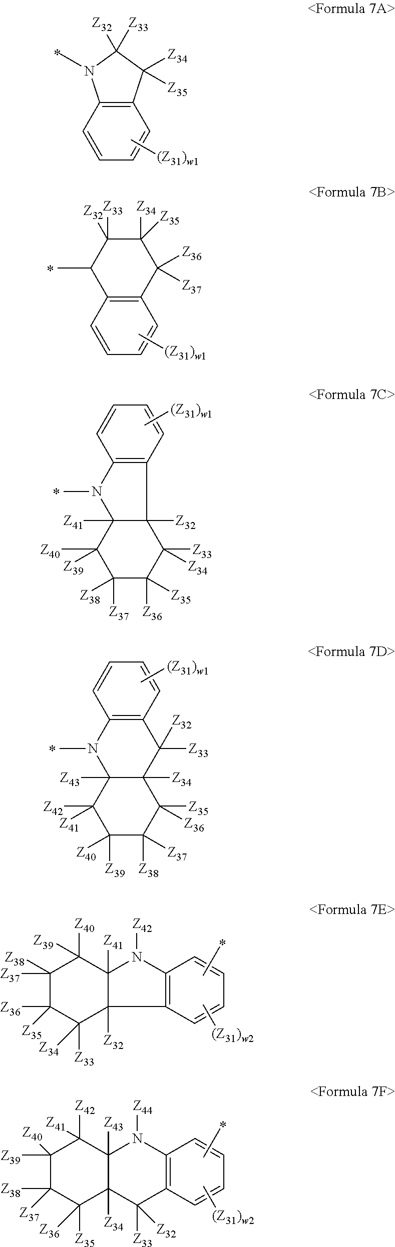
wherein, in Formulae 7A to 7F above,
Z₃₁ to Z₄₄ are each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₃-C₁₀ cycloalkenyl group, a substituted or unsubstituted C₃-C₁₀ heterocycloalkyl group, a substituted or unsubstituted C₃-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthiol group, a substituted or unsubstituted C₂-C₆₀ heteroaryl group, —N(Q₅₁)(Q₅₂), and —Si(Q₅₃)(Q₅₄)(Q₅₅) (where Q₅₁ to Q₅₅ are each independently selected from a hydrogen atom, a C₁-C₁₀ alkyl group, a C₆-C₂₀ aryl group, and a C₂-C₂₀ heteroaryl group), wherein at least two of Z₃₁ to Z₄₄ are optionally linked to form a C₆-C₂₀ saturated ring or a C₆-C₂₀ unsaturated ring;
w1 is an integer from 1 to 4;
w2 is an integer from 1 to 5; and
* indicates a binding site to L₃ or L₄, or to an anthracene core when i or j is 0.

2. The organic light-emitting device as claimed in claim 1, wherein a weight ratio of the silane-based compound to the anthracene-based compound in the emission layer is from about 99.9:0.01 to about 80:20.

3. The organic light-emitting device as claimed in claim 1, wherein R₁ to R₆ in Formula 1 are each independently selected from
i) a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexenyl group, a cyclohexadienyl group, a cyclocycloheptadienyl group, a thiophenyl group, a furanyl group, a pyrrolyl group, an imidazolyl group, a pyrazolyl group, an isothiazolyl group, an isoxazolyl group, a thiazolyl group, an oxazolyl group, an oxadiazolyl group, a thiadiazolyl group, a triazolyl group, a phenyl group, a pyridinyl group, a pyrazinyl group, a pyrimindinyl group, a pyridazinyl group, a triazinyl group, a pentalenyl group, an indenyl group, a naphthyl group, an azulenyl group, a heptalenyl group, a biphenylenyl group, an indacenyl group, an acenaphthylenyl group, a fluorenyl group, a spiro-fluorenyl group, a carbazolyl group, an anthryl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxatinyl group, and a phenanthridinyl group; and
ii) a C₁-C₂₀ alkyl group, a cyclopropyl group, a cyclobutyl group, a cyclopentyl group, a cyclohexyl group, a cycloheptyl group, a cyclooctyl group, a cyclopentenyl group, a cyclopentadienyl group, a cyclohexcenyl group, a cyclohexadienyl group, a cyclocycloheptadienyl group, a thiophenyl group, a furanyl group, a pyrrolyl group, an imidazolyl group, a pyrazolyl group, an isothiazolyl group, an isoxazolyl group, a thiazolyl group, an oxazolyl group, an oxadiazolyl group, a thiadiazolyl group, a triazolyl group, a phenyl group, a pyridinyl group, a pyrazinyl group, a pyrimidinyl group, a pyridazinyl group, a triazinyl group, a pentalenyl group, an indenyl group, a naphthyl group, an azulenyl group, a heptalenyl group, a biphenylenyl group, an indacenyl group, an acenaphthylenyl group, a fluorenyl group, a spiro-fluorenyl group, a carbazolyl group, an anthryl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxatinyl group, and a phenanthridinyl group, each substituted with at least one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₁₁)(Q₁₂) (where Q₁₁ and Q₁₂ are each independently a hydrogen atom, a C₁-C₁₀ alkyl group, a C₆-C₂₀ aryl group, or a C₂-C₂₀ heteroaryl group),
wherein at least one of R₁ to R₃ when n is 0, or at least one of R₁ to R₆ when n is 1 are each independently selected from
i) a pentalenyl group, an indenyl group, a naphthyl group, an azulenyl group, a heptalenyl group, a biphenylenyl group, an indacenyl group, an acenaphthylenyl group, a fluorenyl group, a spiro-fluorenyl group, a carbazolyl group, an anthryl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxatinyl group, and a phenanthridinyl group; and
ii) a pentalenyl group, an indenyl group, a naphthyl group, an azulenyl group, a heptalenyl group, a biphenylenyl group, an indacenyl group, an acenaphthylenyl group, a fluorenyl group, a spiro-fluorenyl group, a carbazolyl group, an anthryl group, a phenalenyl group, a phenanthrenyl group, a perylenyl group, a fluoranthenyl group, a naphthacenyl group, a picenyl group, a pentaphenyl group, a hexacenyl group, a dibenzofuranyl group, a dibenzothiophenyl group, a phenothiazinyl group, a phenoxazinyl group, a dihydrophenazinyl group, a phenoxatinyl group, and a phenanthridinyl group, each substituted with at least one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₁₁)(Q₁₂) (where Q₁₁ and Q₁₂ are each independently a hydrogen atom, a C₁-C₁₀ alkyl group, a C₆-C₂₀ aryl group, or a C₂-C₂₀ heteroaryl group).

4. The organic light-emitting device as claimed in claim 1, wherein, in Formula 1, R₁ to R₆ are each independently selected from
i) a methyl group, an ethyl group, a n-propyl group, an i-propyl group, a n-butyl group, an i-butyl group, a t-butyl group, a pentyl group, a hexyl group, a heptyl group, an octyl group, a nonyl group, and a decyl group;
ii) a methyl group, an ethyl group, a n-propyl group, an i-propyl group, a n-butyl group, an i-butyl group, a t-butyl group, a pentyl group, a hexyl group, a heptyl group, an octyl group, a nonyl group, and a decyl group, each substituted with at least one selected from a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₁₁)(Q₁₂) (where Q₁₁ and Q₁₂ are each independently, a hydrogen atom, a C₁-C₁₀ alkyl group, a C₆-C₂₀ aryl group or a C₂-C₂₀ heteroaryl group);
iii) groups represented by Formulae 2A to 2T below; and
iv) groups represented by Formulae 3A to 3R below,
wherein at least one of R₁ to R₃ when n is 0, or at least one of R₁ to R₆ when n is 1 are each independently selected from groups represented by Formulae 3A to 3R below: 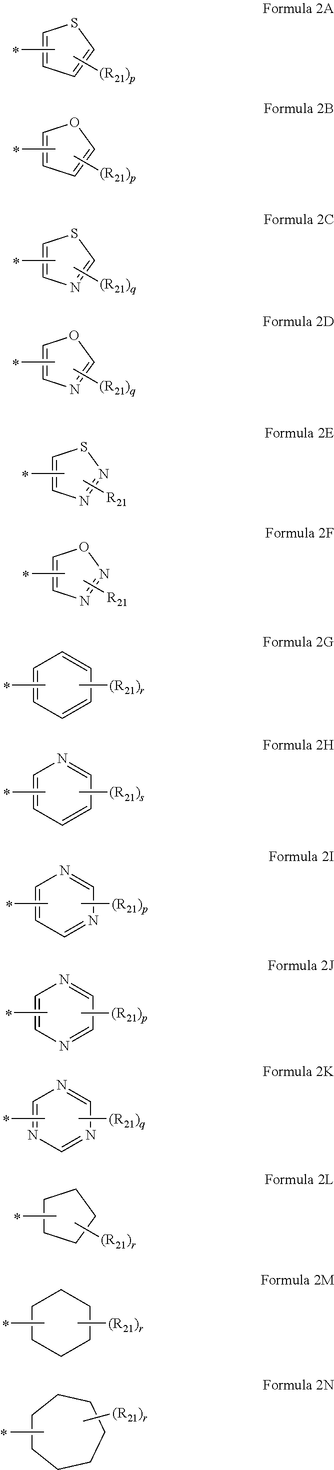 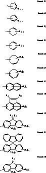 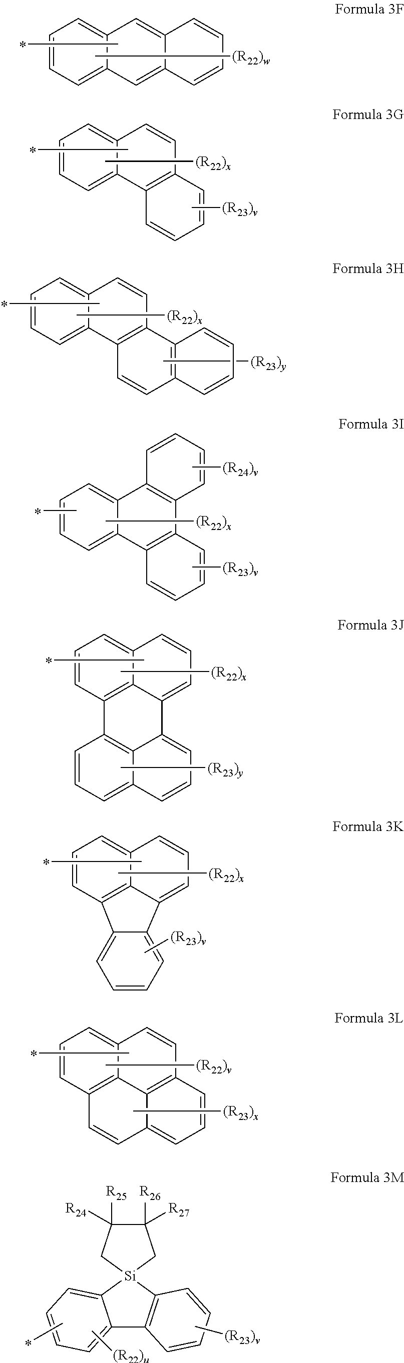 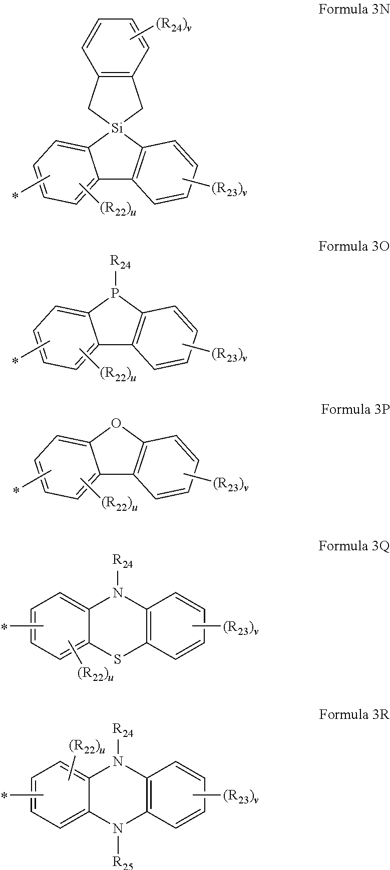
wherein, in Formulae 2A to 2T, and Formulae 3A to 3R,
R₂₁ to R₂₇ are each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₂₁)(Q₂₂) (where Q₂₁ and Q₂₂ are each independently a hydrogen atom, a C₁-C₁₀ alkyl group, a C₆-C₂₀ aryl group, or a C₂-C₂₀ heteroaryl group);
p and u are each independently an integer from 1 to 3;
q is 1 or 2;
r and x are each independently an integer from 1 to 5;
s and v are each independently an integer from 1 to 4;
t is an integer from 1 to 7;
w is an integer from 1 to 9;
y is an integer from 1 to 6; and
* indicates a binding site to Si atom.

5. The organic light-emitting device as claimed in claim 1, wherein R₁ to R₆ in Formula 1 are each independently one selected from
a methyl group, an ethyl group, an n-propyl group, an i-propyl group, an n-butyl group, an i-butyl group, a t-butyl group, a pentyl group, a hexyl group, a heptyl group, an octyl group, a nonyl group, and a decyl group;
a methyl group, an ethyl group, an n-propyl group, an i-propyl group, an n-butyl group, an i-butyl group, a t-butyl group, a pentyl group, a hexyl group, a heptyl group, an octyl group, a nonyl group, and a decyl group, each substituted with at least one of a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a phenyl group, a naphthyl group, and an anthryl group;
a group represented by Formula 2G below; and
groups represented by Formulae 4A to 4J below,
wherein at least one of R₁ to R₃ when n is 0, or at least one of R₁ to R₆ when n is 1 are each independently selected from groups represented by Formulae 4A to 4J below: 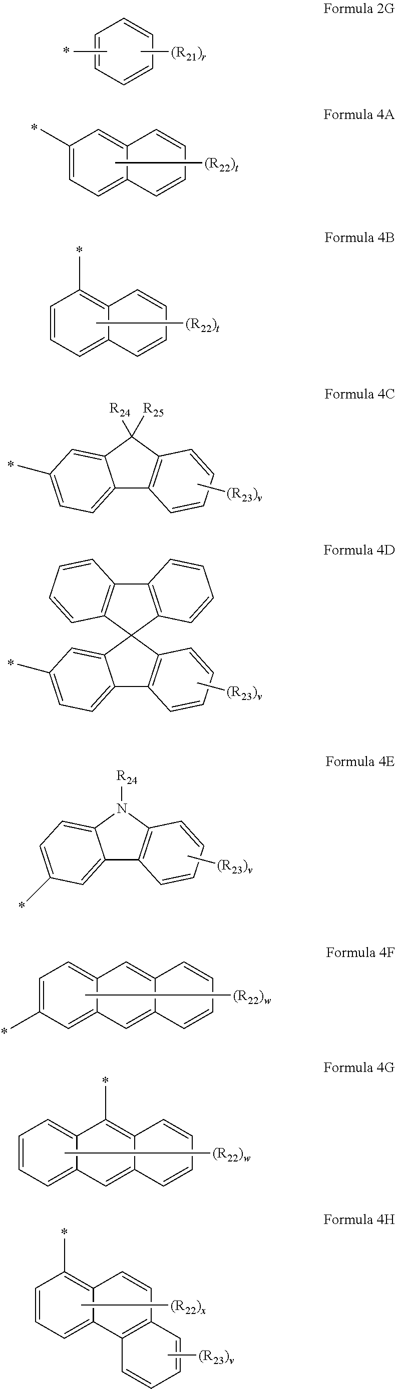 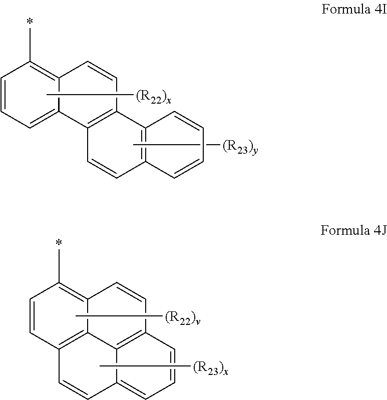
wherein, in Formula 2G, and Formulae 4A to 4J above,
R₂₁ to R₂₅ are each independently selected from a hydrogen atom, a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthryl group, a dimethyl-fluorenyl group, a phenyl-carbazolyl group, a pyrenyl group, a chrysenyl group, a benzothiazolyl group, a benzoxazolyl group, a phenyl-benzoimidazolyl group, or —N(Q₂₁)(Q₂₂), where Q₂₁ and Q₂₂ are each independently a hydrogen atom, a C₁-C₁₀ alkyl group, a phenyl group, a naphthyl group, or an anthryl group;
r and x are each independently an integer from 1 to 5;
v is an integer from 1 to 4;
t is an integer from 1 to 7;
w is an integer from 1 to 9;
y is an integer from 1 to 6; and
* indicates a binding site to a Si atom.

6. The organic light-emitting device as claimed in claim 1, wherein L₁ to L₄ in Formulae 1 and 20 are each independently selected from groups represented by Formulae 5A to 5J below: 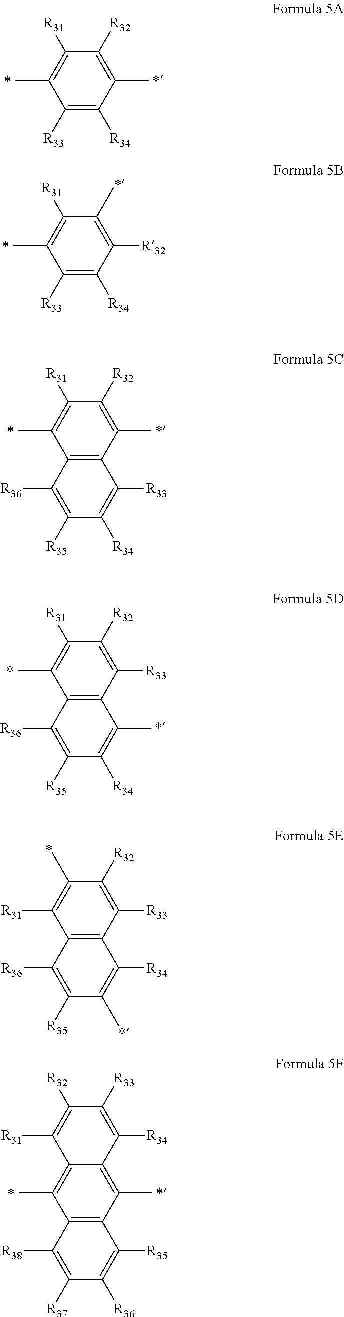 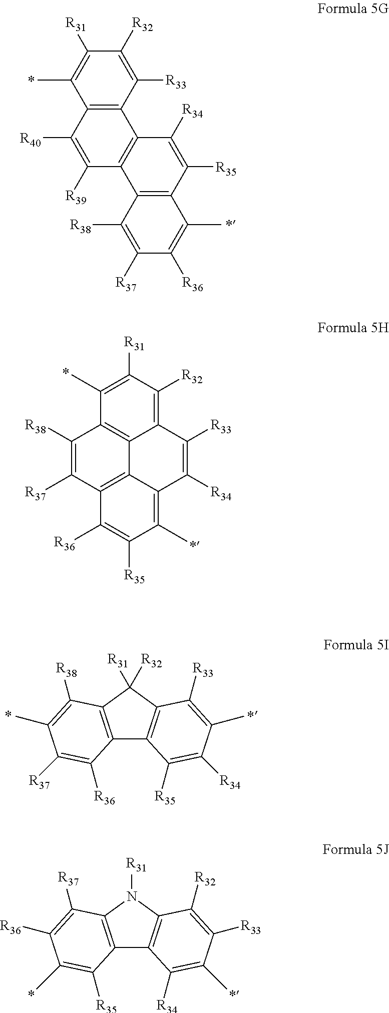
wherein, in Formulae 5A to 5J, R₃₁ to R₄₀ are each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₃₁)(Q₃₂) (where Q₃₁ and Q₃₂ are each independently a hydrogen atom, a C₁-C₁₀ alkyl group, a C₆-C₂₀ aryl group, or a C₂-C₂₀ heteroaryl group);
* indicates a binding site to an anthracene core in Formulae 1 and 20, and
*¹ indicates a binding site to Si in Formula 1, or to Ar₁ or Ar₂ in Formula 20.

7. The organic light-emitting device as claimed in claim 1, wherein R₁₁ to R₁₆ in Formulae 1 and 20 are each independently selected from
i) a C₆-C₆₀ aryl group; and
ii) a C₆-C₆₀ aryl group substituted with at least one of a deuterium atom, a halogen atom, a hydroxyl group, a cyano group, a nitro group, a C₁-C₆₀ alkyl group, and —Si(Q₄₁)(Q₄₂)(Q₄₃) (where Q₄₁ to Q₄₃ are each independently a hydrogen atom, a C₁-C₁₀ alkyl group, a C₆-C₂₀ aryl group, or a C₂-C₂₀ heteroaryl group).

8. The organic light-emitting device as claimed in claim 1, wherein R₁₁ to R₁₆ in Formulae 1 and 20 are each independently selected from
i) a phenyl group; and
ii) a phenyl group substituted with at least one of a deuterium atom, —F, a cyano group, a nitro group, a methyl group, an ethyl group, a tert-butyl group, and —Si(Q₄₁)(Q₄₂)(Q₄₃) (where Q₄₁ to Q₄₃ are each independently a methyl group, an ethyl group, or a phenyl group).

9. The organic light-emitting device as claimed in claim 1, wherein, in Formula 1,
n is 1;
R₁, R₃, R₄, and R₆ are each independently a substituted or unsubstituted C₁-C₆₀ alkyl group; and
R₂ and R₅ are each independently selected from a 3- to 10-membered substituted or unsubstituted non-condensed ring group, and a substituted or unsubstituted condensed ring group in which at least two rings are fused to each other, wherein at least one of R₂ and R₅ is a substituted or unsubstituted condensed ring group in which at least two rings are fused to each other.

10. The organic light-emitting device as claimed in claim 1, wherein, in Formula 1,
n is 0;
R₁ and R₃ are each independently a substituted or unsubstituted C₁-C₆₀ alkyl group; and
R₂ is a substituted or unsubstituted condensed ring group in which at least two rings are fused to each other.

11. The organic light-emitting device as claimed in claim 1, wherein the silane-based compound is a compound represented by Formula 1a below: 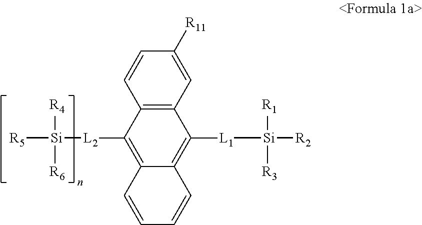
wherein, in Formula 1a above,
R₁ to R₆ are each independently one selected from
a methyl group, an ethyl group, an n-propyl group, an i-propyl group, an n-butyl group, an i-butyl group, a t-butyl group, a pentyl group, a hexyl group, a heptyl group, an octyl group, a nonyl group, and a decyl group; and
a methyl group, an ethyl group, an n-propyl group, an i-propyl group, an n-butyl group, an i-butyl group, a t-butyl group, a pentyl group, a hexyl group, a heptyl group, an octyl group, a nonyl group, and a decyl group, each substituted with at least one of a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a phenyl group, a naphthyl group, and an anthryl group;
a group represented by Formula 2G below; and
groups represented by Formulae 4A to 4J below;
wherein at least one of R₁ to R₃ when n is 0, or at least one of R₁ to R₆ when n is 1 are each independently selected from groups represented by Formulae 4A to 4J below: 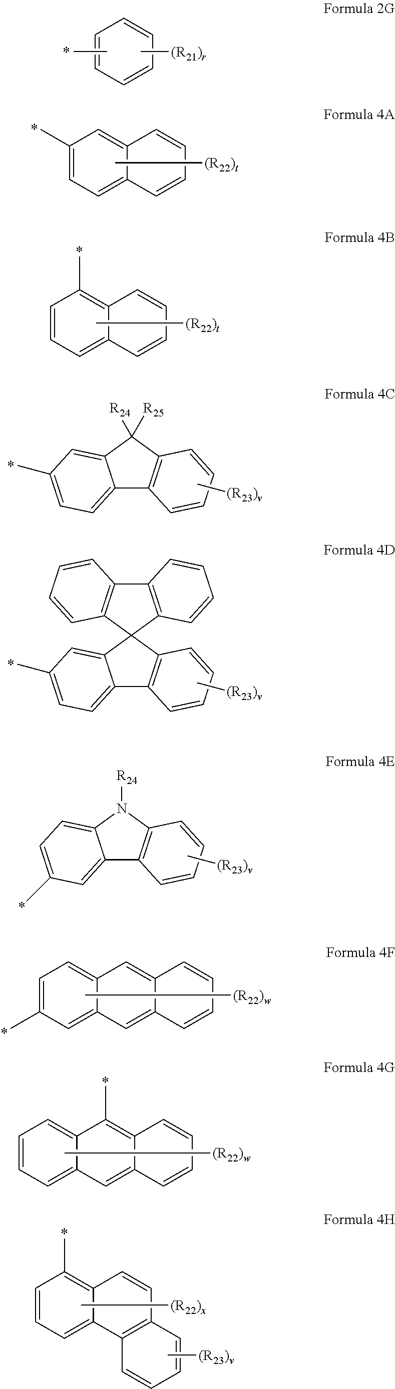 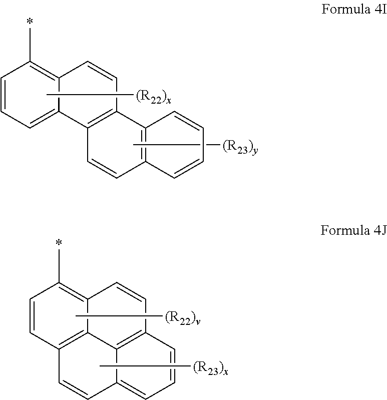
wherein, in Formula 2G, and Formulae 4A to 4J,
R₂₁ to R₂₅ are each independently selected from a hydrogen atom, a deuterium atom, a halogen atom, a hydroxyl group, a cyano group, a nitro group, an amino group, an amidino group, a hydrazine, a hydrazone, a carboxylic group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthryl group, a dimethyl-fluorenyl group, a phenyl-carbazolyl group, a pyrenyl group, a chrysenyl group, a benzothiazolyl group, a benzoxazolyl group, a phenyl-benzoimidazolyl group, or —N(Q₂₁)(Q₁₁), where Q₂₁ and Q₂₂ are each independently a hydrogen atom, a C₁-C₁₀ alkyl group, a phenyl group, a naphthyl group, or an anthryl group;
r and x are each independently an integer from 1 to 5;
v is an integer from 1 to 4;
t is an integer from 1 to 7;
w is an integer from 1 to 9;
y is an integer from 1 to 6;
* indicates a binding site to Si atom;
L₁ and L₂ are each independently selected from groups represented by Formulae 5A to 5J below: 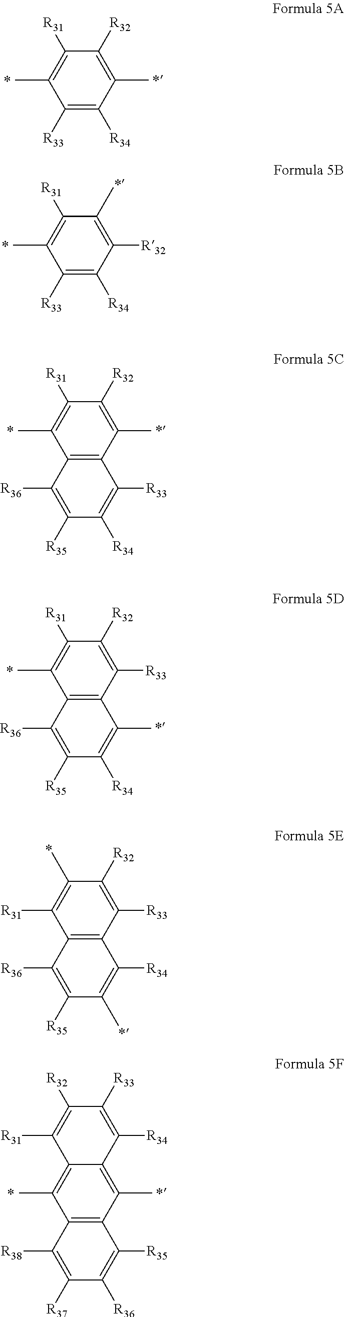 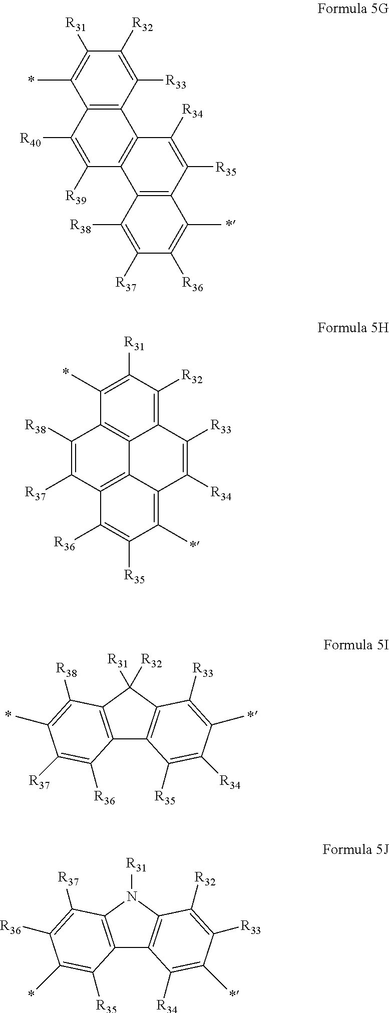
wherein, in Formulae 5A to 5J above,
R₃₁ to R₄₀ are each independently selected from a hydrogen atom, a deuterium atom, a halogen atom, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₆₀ aryl group, a C₆-C₆₀ aryloxy group, a C₆-C₆₀ arylthiol group, a C₂-C₆₀ heteroaryl group, and —N(Q₃₁)(Q₃₂) (where Q₃₁ and Q₃₂ are each independently a hydrogen atom, a C₁-C₁₀ alkyl group, a C₆-C₂₀ aryl group, or a C₂-C₂₀ heteroaryl group);
*¹ indicated a binding site to Si;
indicates a binding site to an anthracene core; and
R₁₁ is selected from
i) a phenyl group; and
ii) a phenyl group substituted with at least one of a deuterium atom, —F, a cyano group, a nitro group, a methyl group, an ethyl group, a tert-butyl group, and —Si(Q₄₁)(Q₄₂)(Q₄₃) (where Q₄₁ to Q₄₃ are each independently a methyl group, an ethyl group, or a phenyl group).

12. The organic light-emitting device as claimed in claim 1, wherein the silane-based compound is one of Compounds 1 to 60 below:

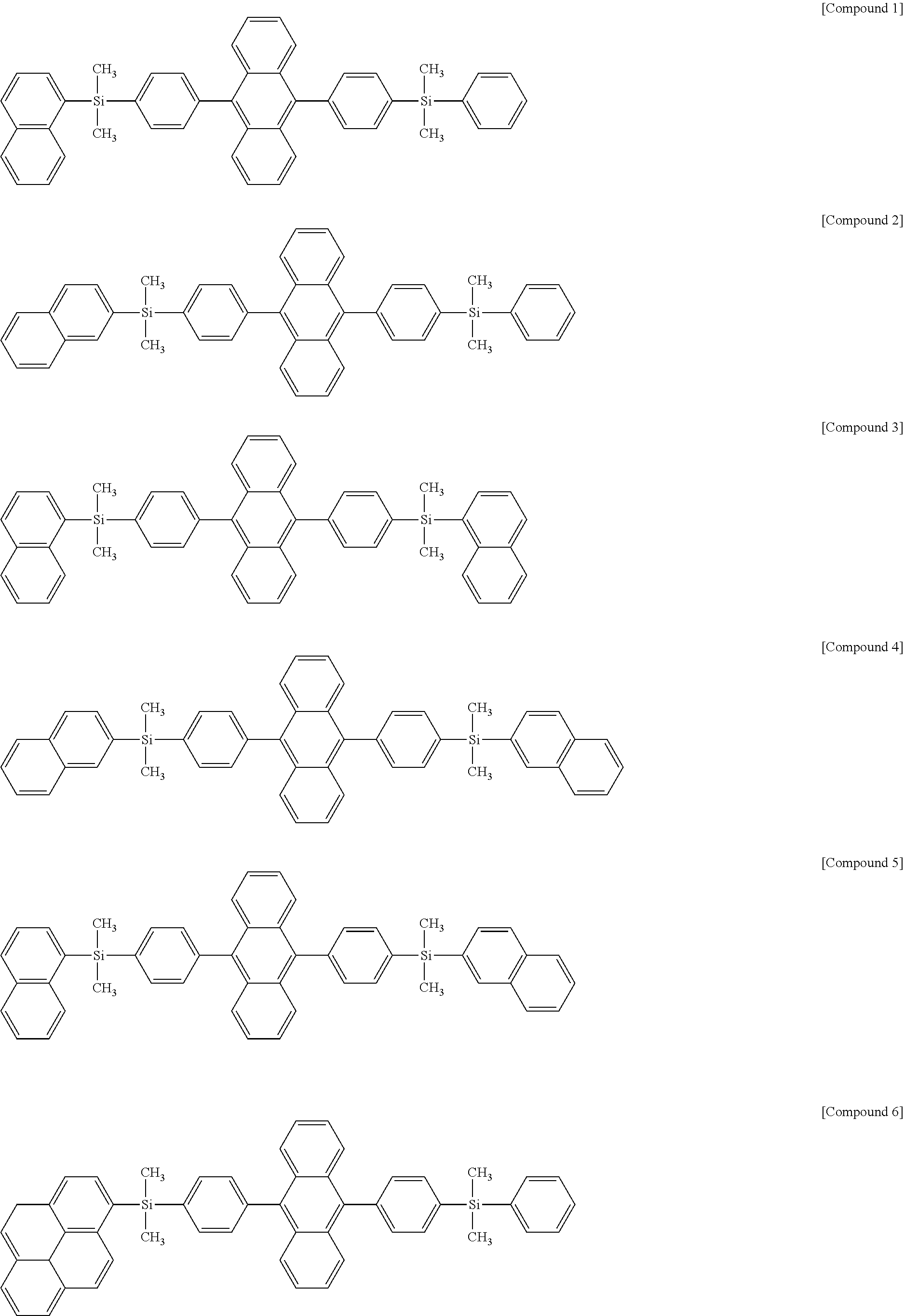

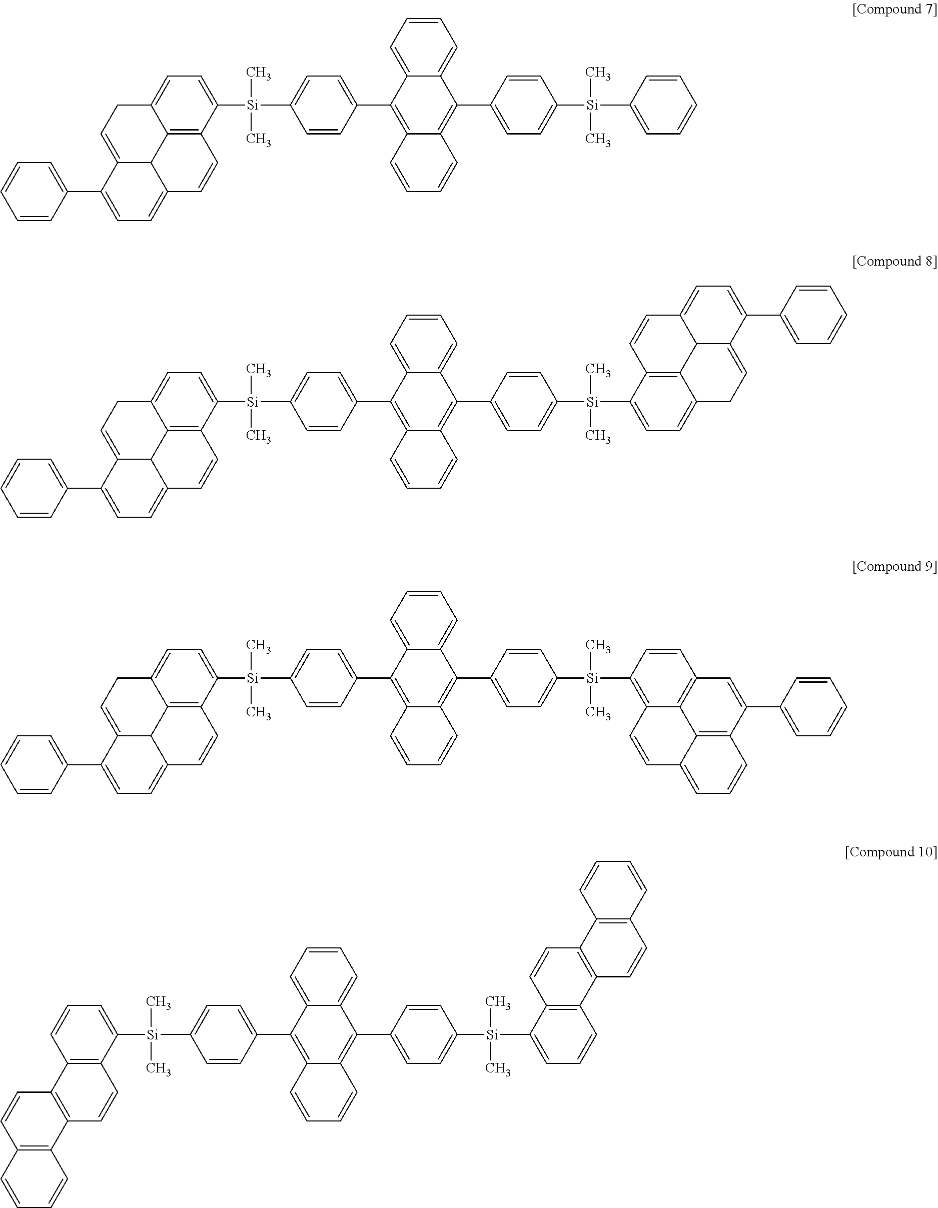

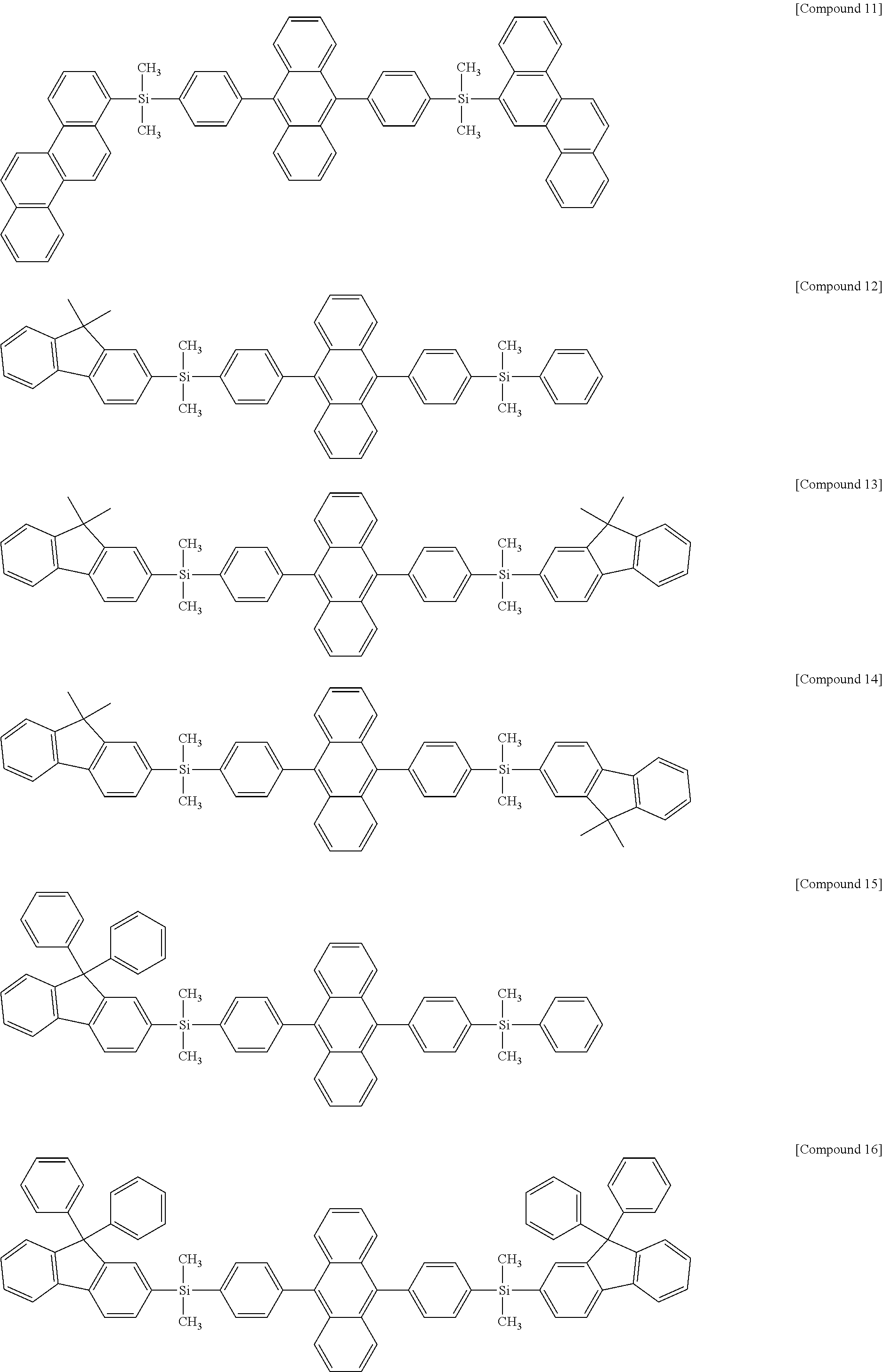

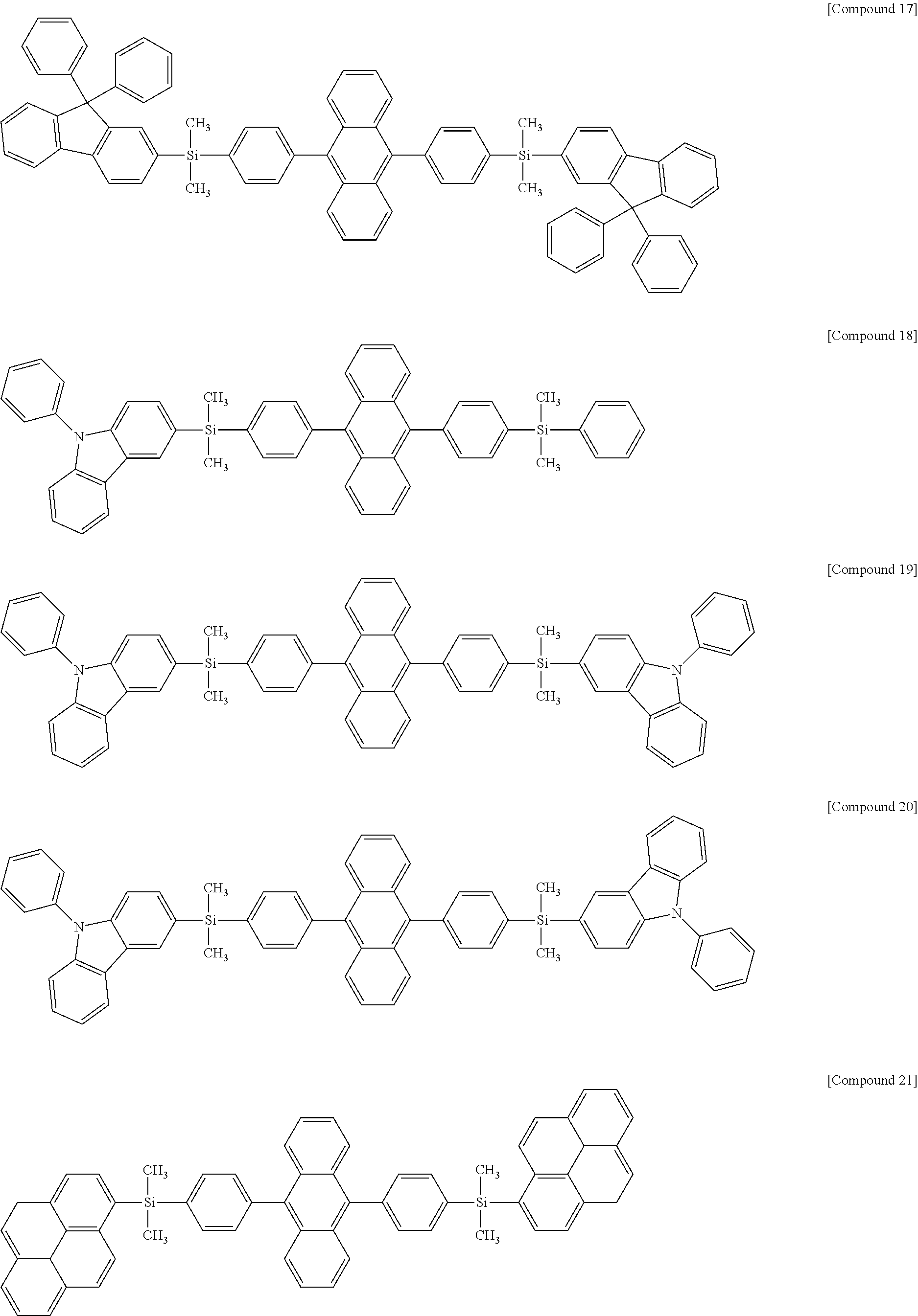

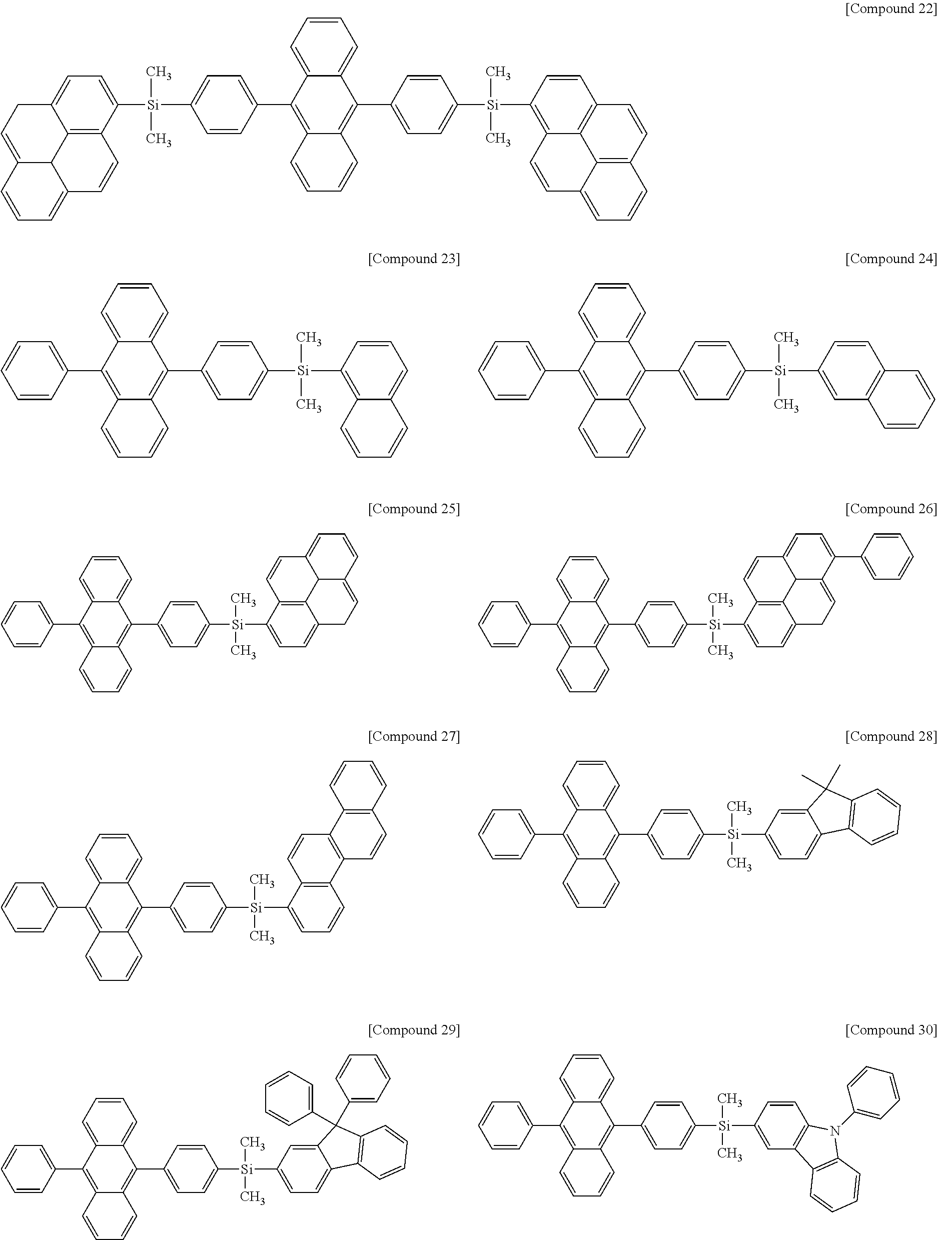

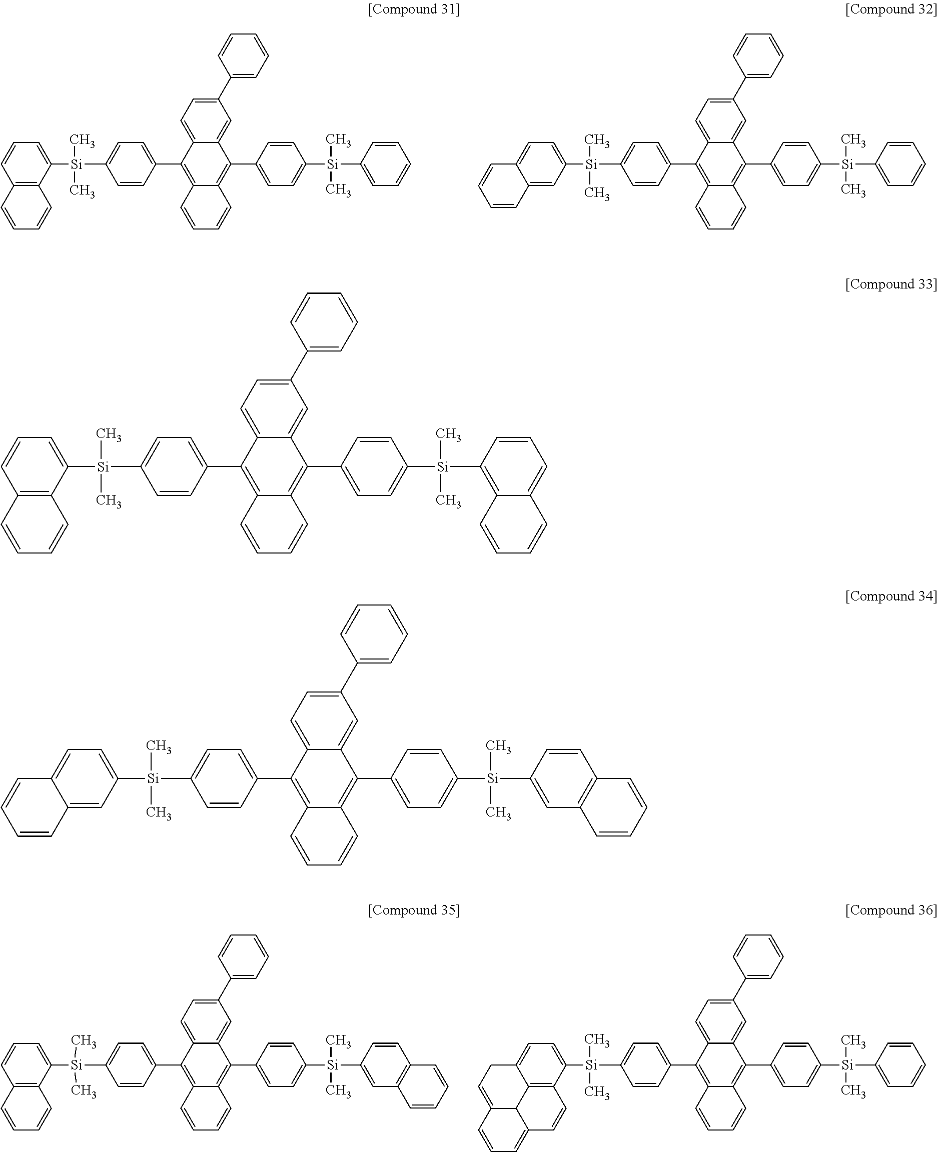

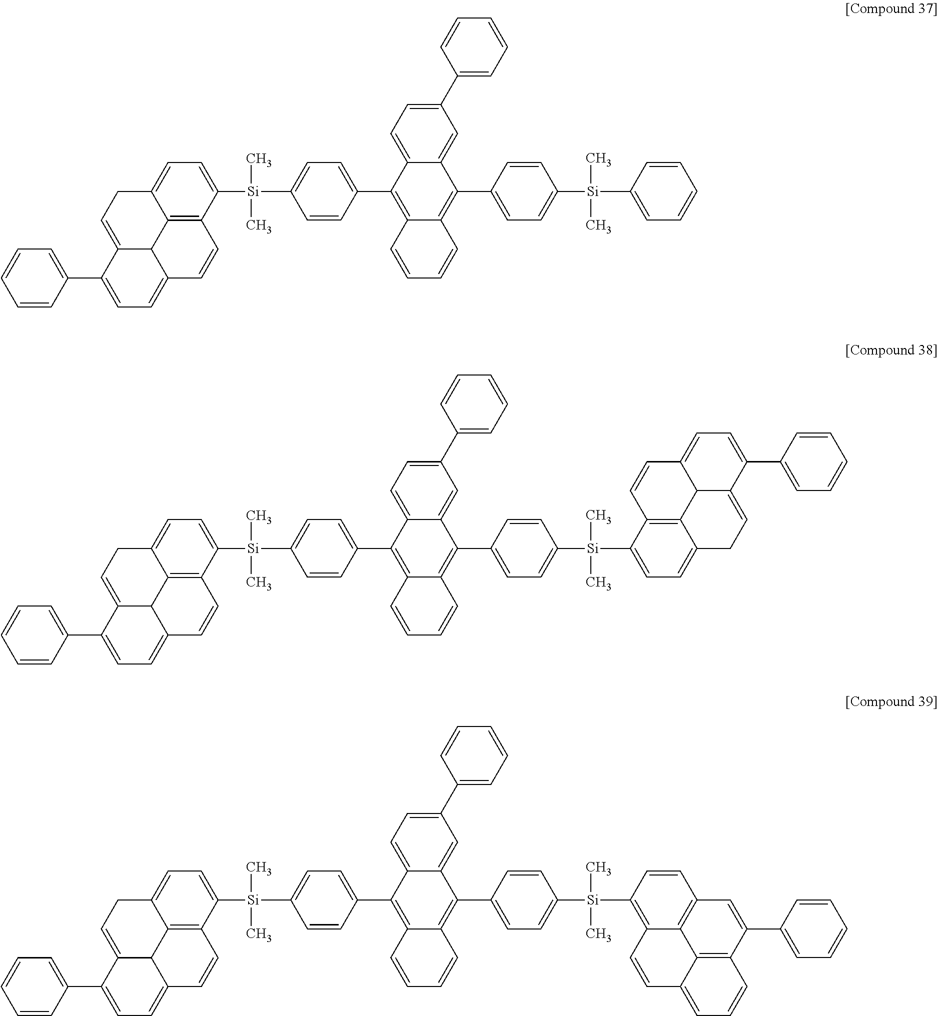 [SMILES: C[Si](C)(c1ccccc1)c1ccc(-c2c3ccccc3c(-c3ccc([Si](C)(C)c4ccc5c6c4C=CC4=CC=C(c7ccccc7)C(=CC5)C46)cc3)c3ccc(-c4ccccc4)cc23)cc1 ; C[Si](C)(c1ccc(-c2c3ccccc3c(-c3ccc([Si](C)(C)c4ccc5c6c4C=CC4=CC=C(c7ccccc7)C(=CC5)C46)cc3)c3cc(-c4ccccc4)ccc23)cc1)c1ccc2c3c1C=CC1=CC=C(c4ccccc4)C(=CC2)C13 ; C[Si](C)(c1ccc(-c2c3ccccc3c(-c3ccc([Si](C)(C)c4ccc5cc(-c6ccccc6)c6cccc7ccc4c5c76)cc3)c3cc(-c4ccccc4)ccc23)cc1)c1ccc2c3c1C=CC1=CC=C(c4ccccc4)C(=CC2)C13]

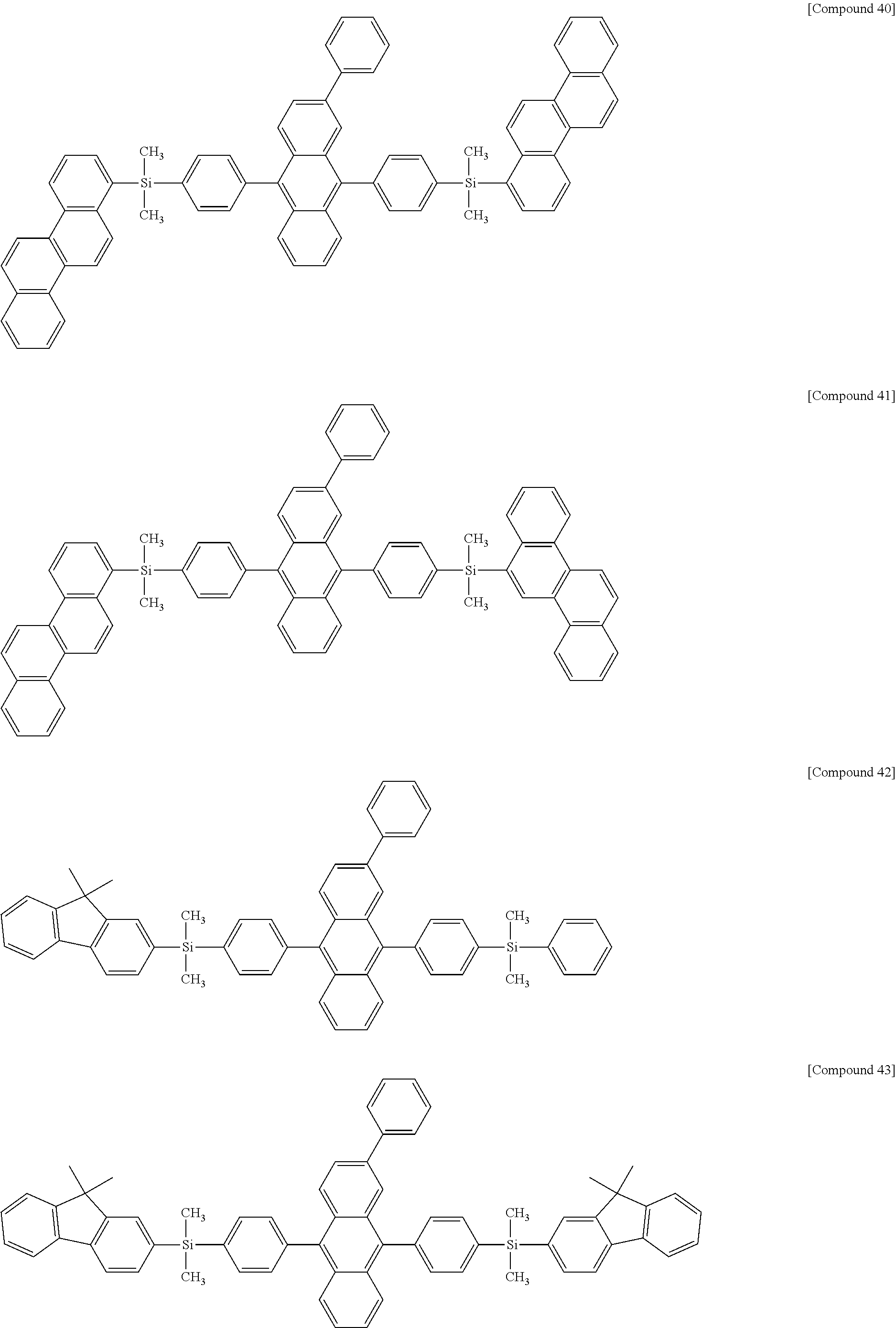

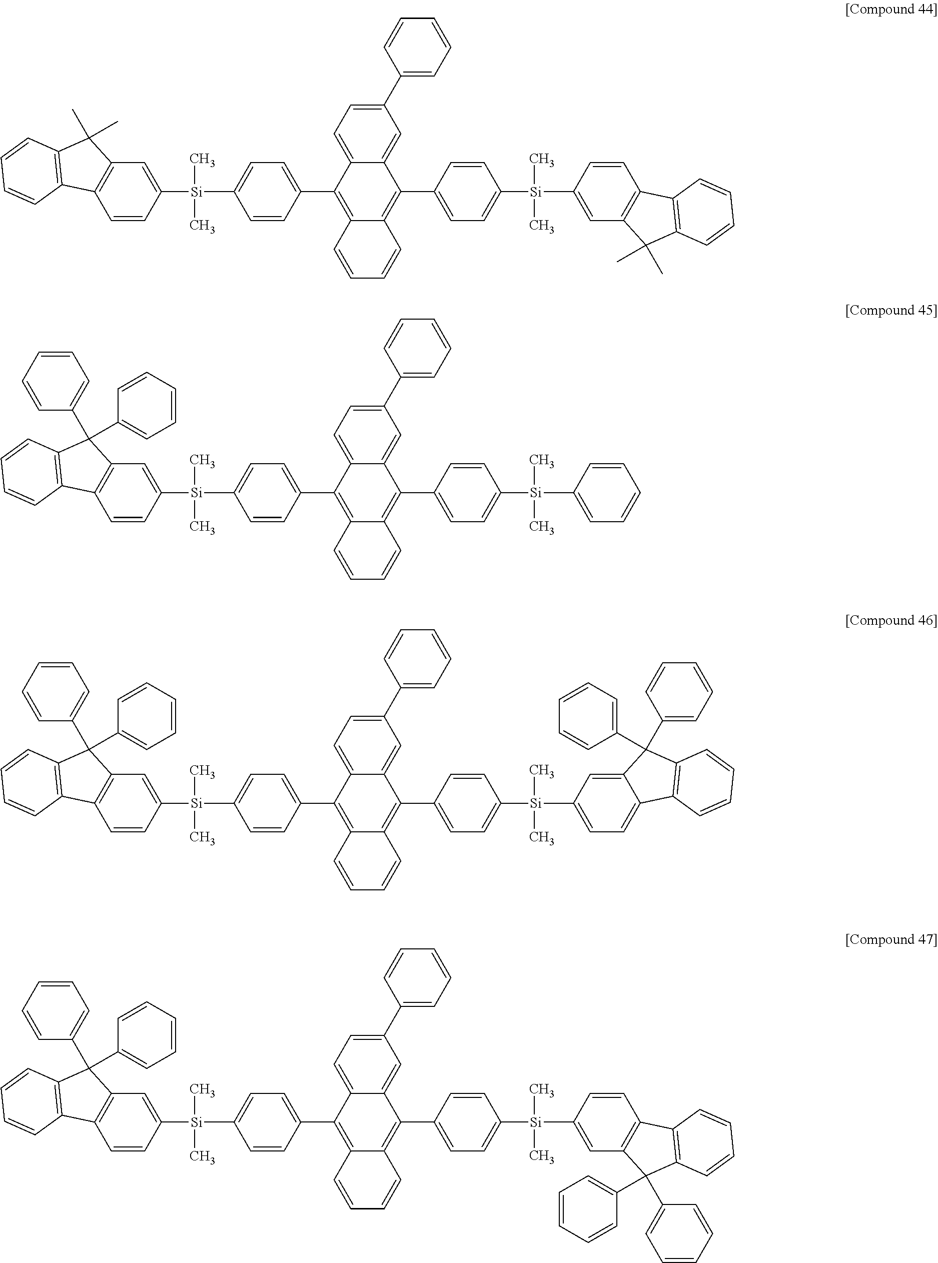

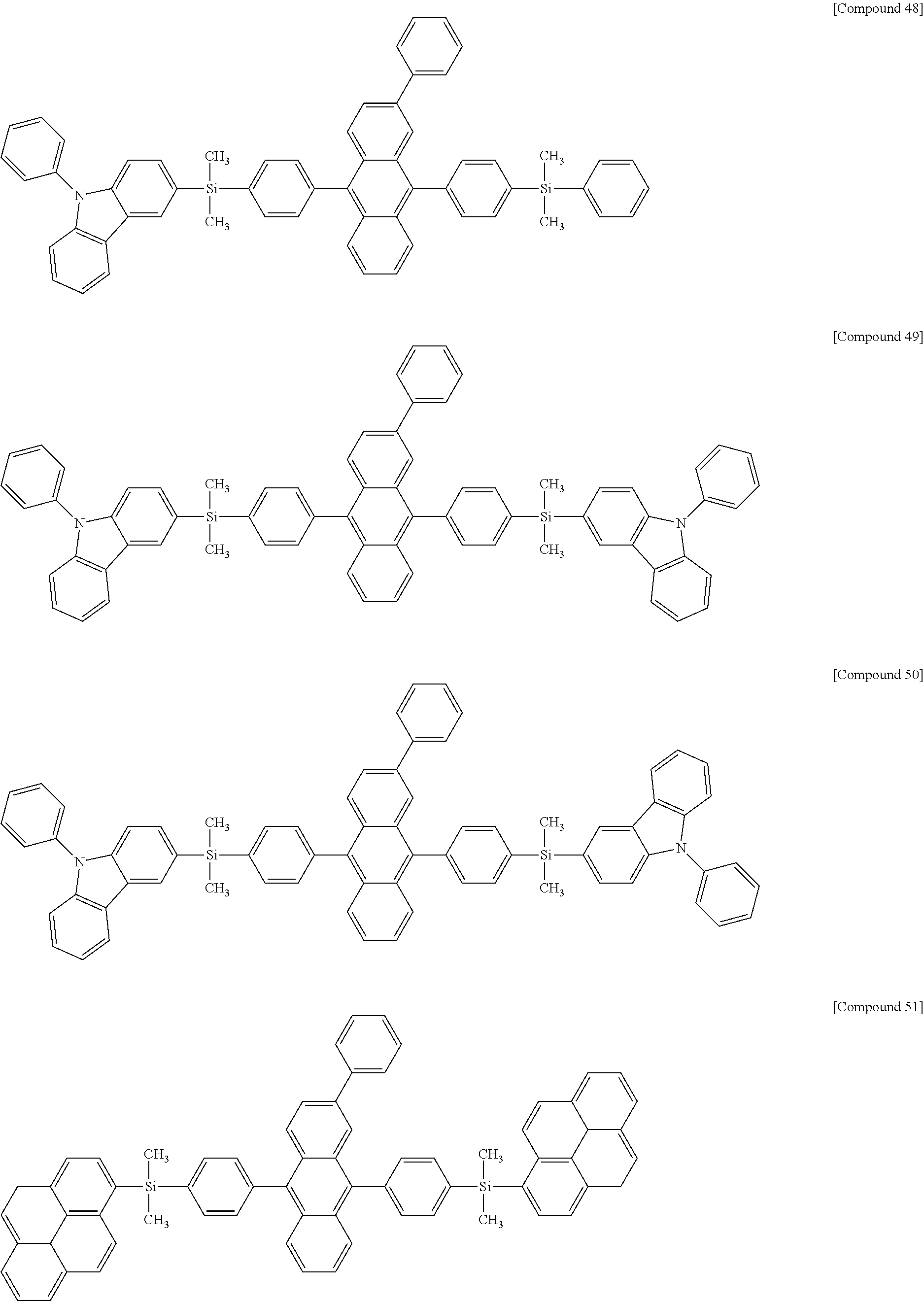

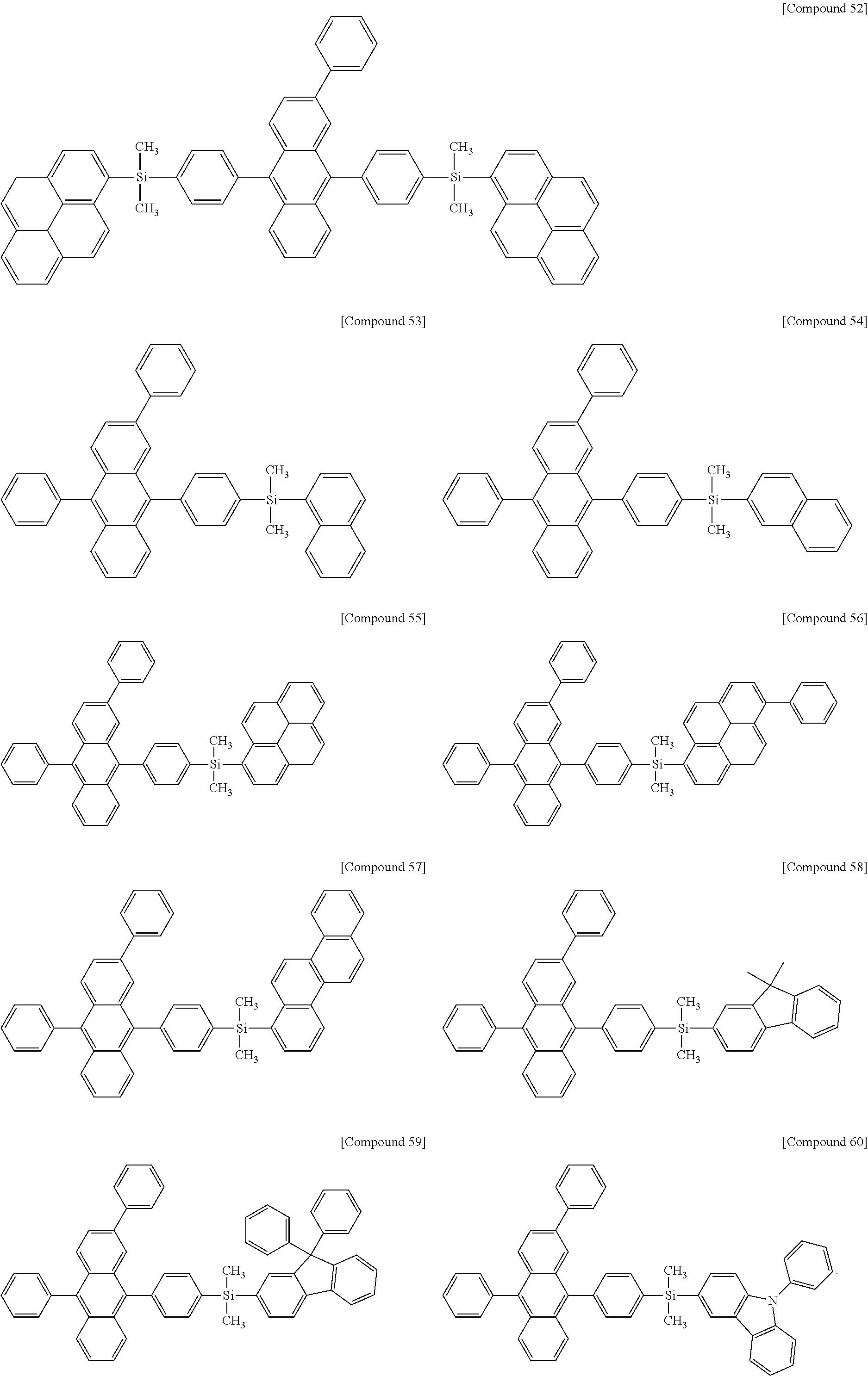

13. The organic light-emitting device as claimed in claim 1, wherein, in Formula 20, i is 0, and j is 0.

14. The organic light-emitting device as claimed in claim 1, wherein Z₃₁ to Z₄₄ in Formulae 7A to 7F are each independently selected from
i) a hydrogen atom, a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and —Si(Q₅₃)(Q₅₄)(Q₅₅) (where Q₅₃ to Q₅₅ are each independently a methyl group, or a phenyl group);
ii) a C₁-C₂₀ alkyl group substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;
iii) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group;
iv) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one of a methyl group, an ethyl group, a n-propyl group, an iso-propyl group, and a tert-butyl group that are each substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; and
v) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one selected from a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a n-propyl group, an iso-propyl group, a tert-butyl group, a phenyl group, a naphthyl group, an anthryl group, a fluorenyl group, a carbazolyl group, a pyridinyl group, a pyrimidinyl group, a pyrazinyl group, a triazinyl group, and —Si(Q₅₃)(Q₅₄)(Q₅₅) (where Q₅₃ to Q₅₅ are each independently a methyl group, or a phenyl group).

15. The organic light-emitting device as claimed in claim 1, wherein Ar₁ and Ar₂ are each independently selected from groups represented by Formulae 7A(1) to 7A(3), 7B(1) to 7B(3), 7C(1) to 7C(6), 7D(1), 7D(2), 7E(1), and 7F(1): 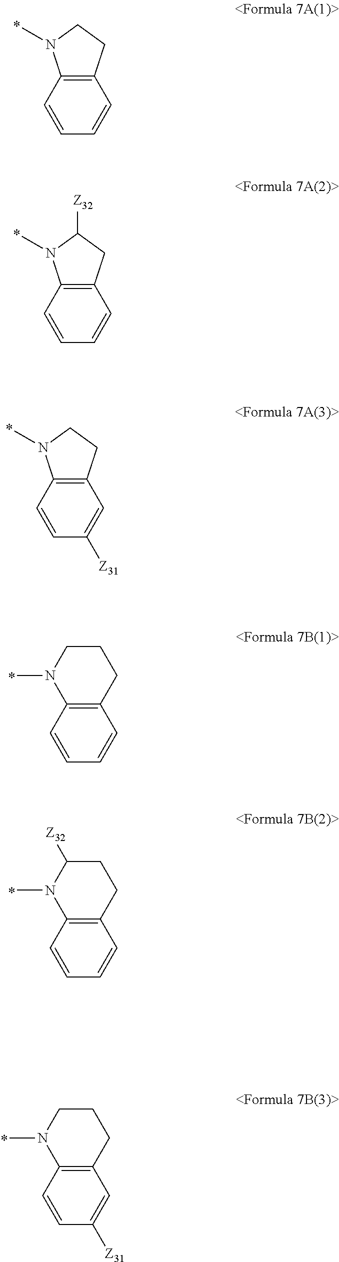 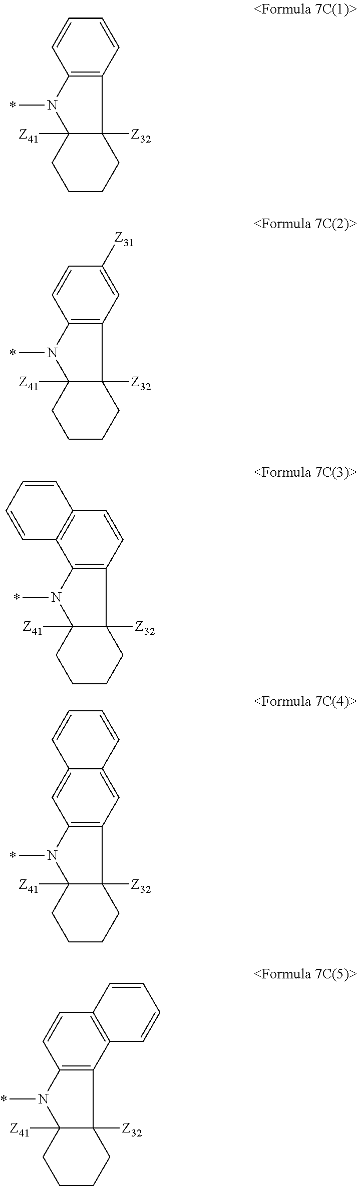 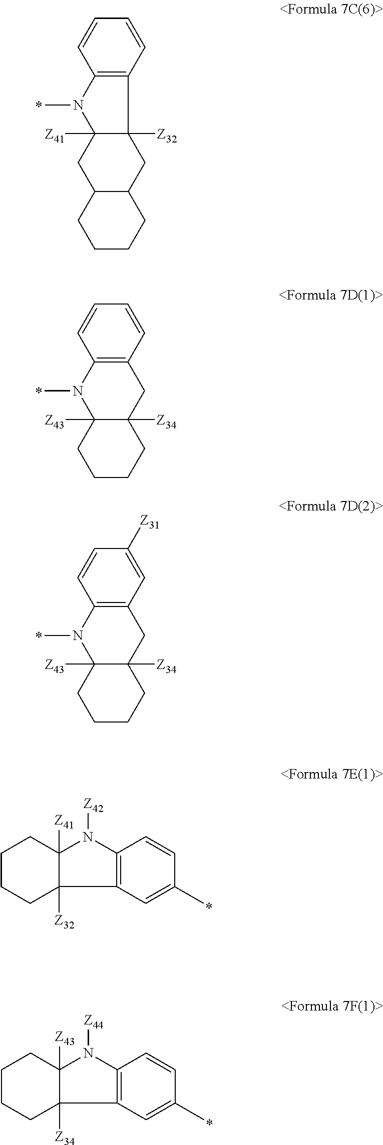
wherein, in Formulae 7A(1) to 7A(3), 7B(1) to 7B(3), 7C(1) to 7C(6), 7D(1), 7D(2), 7E(1), and 7F(1),
Z₃₁, Z₃₂, Z₃₄, and Z₄₁ to Z₄₄ are each independently selected from
i) a hydrogen atom, a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and —Si(Q₅₃)(Q₅₄)(Q₅₅) (where Q₅₃ to Q₅₅ are each independently a methyl group or a phenyl group);
ii) a C₁-C₂₀ alkyl group substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;
iii) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group;
iv) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one of a methyl group, an ethyl group, a n-propyl group, an iso-propyl group, and a tert-butyl group that are each substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; and
v) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one selected from a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a n-propyl group, an iso-propyl group, a tert-butyl group, a phenyl group, a naphthyl group, an anthryl group, a fluorenyl group, a carbazolyl group, a pyridinyl group, a pyrimidinyl group, a pyrazinyl group, a triazinyl group, and —Si(Q₅₃)(Q₅₄)(Q₅₅) (where Q₅₃ to Q₅₅ are each independently a methyl group or a phenyl group).

16. The organic light-emitting device as claimed in claim 1, wherein R₁₃ and R₁₄ in Formula 20 are identical to each other.

17. The organic light-emitting device as claimed in claim 1, wherein Ar₁ and Ar₂ in Formula 20 are identical to each other.

18. The organic light-emitting device as claimed in claim 1, wherein the anthracene-based compound is a compound represented by Formula 20a below: 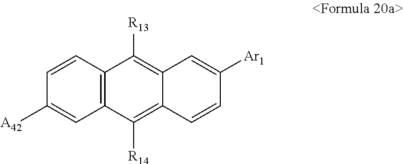
wherein, in Formula 20a above,
R₁₃ and R₁₄ are each independently selected from
i) a phenyl group, and
ii) a phenyl group substituted with at least one selected from a deuterium atom, —F, a cyano group, a nitro group, a methyl group, an ethyl group, a tert-butyl group, and —Si(Q₄₁)(Q₄₂)(Q₄₃) (where Q₄₁ to Q₄₃ are each independently a methyl group, an ethyl group, or a phenyl group); and
Ar₁ and Ar₂ are each independently selected from groups represented by Formulae 7A(1) to 7A(3), 7B(1) to 7B(3), 7C(1) to 7C(6), 7D(1), 7D(2), 7E(1), and 7F(1): 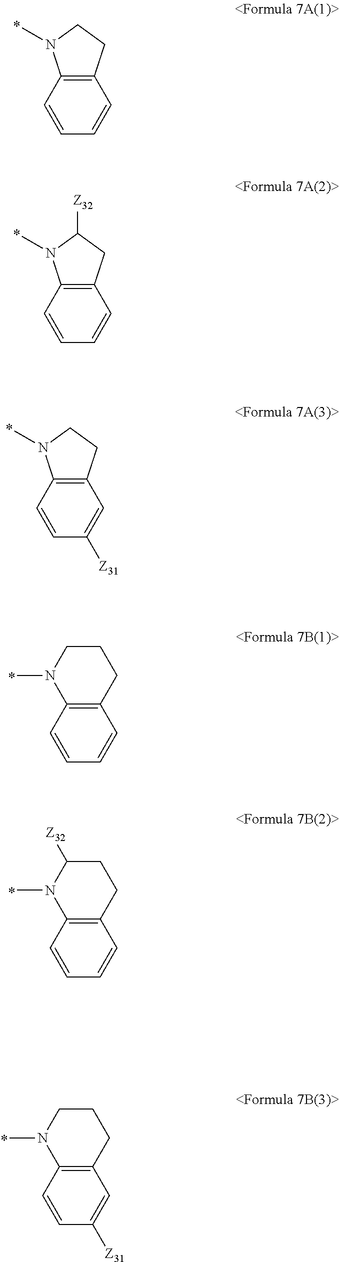 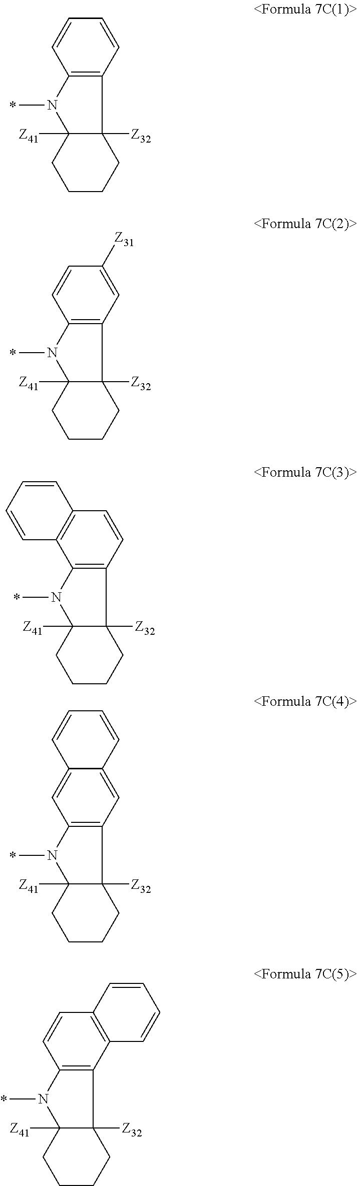 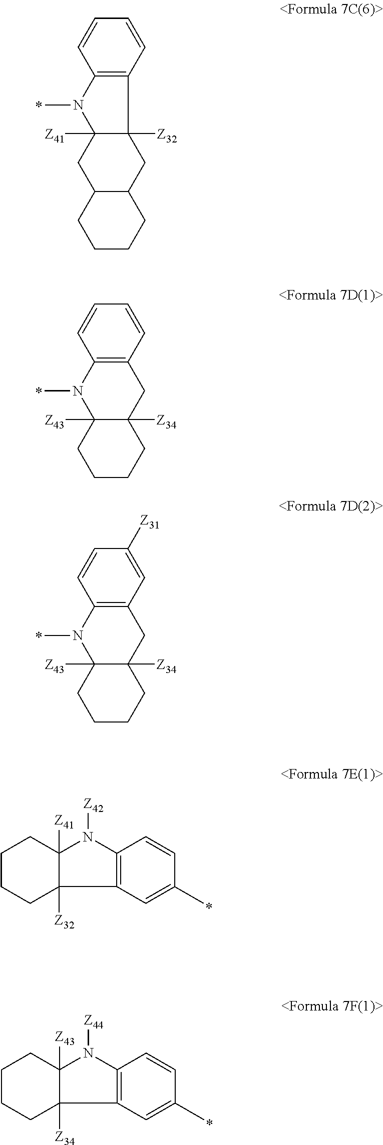
where, in Formulae 7A(1) to 7A(3), 7B(1) to 7B(3), 7C(1) to 7C(6), 7D(1), 7D(2), 7E(1), and 7F(1),
Z₃₁, Z₃₂, Z₃₄, and Z₄₁ to Z₄₄ are each independently selected from
i) a hydrogen atom, a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₂₀ alkyl group, and —Si(Q₅₃)(Q₅₄)(Q₅₅) (where Q₅₃ to Q₅₅ are each independently a methyl group or a phenyl group);
ii) a C₁-C₂₀ alkyl group substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof;
iii) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group;
iv) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one of a methyl group, an ethyl group, a n-propyl group, an iso-propyl group, and a tert-butyl group that are each substituted with at least one of a deuterium atom, —F, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; and
v) a phenyl group, a naphthyl group, a fluorenyl group, a spiro-fluorenyl group, a phenalenyl group, a phenanthrenyl group, an anthryl group, a fluoranthenyl group, a pyrenyl group, a chrysenyl group, a pyridinyl group, a pyrazinyl group, a pyrimidinyl group, a pyridazinyl group, a quinolinyl group, an isoquinolinyl group, a carbazolyl group, a furanyl group, a benzofuranyl group, a thiophenyl group, and a benzothiophenyl group, each substituted with at least one selected from a deuterium atom, —F, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a methyl group, an ethyl group, a n-propyl group, an iso-propyl group, a tert-butyl group, a phenyl group, a naphthyl group, an anthryl group, a fluorenyl group, a carbazolyl group, a pyridinyl group, a pyrimidinyl group, a pyrazinyl group, a triazinyl group, and —Si(Q₅₃)(Q₅₄)(Q₅₅) (where Q₅₃ to Q₅₅ are each independently a methyl group or a phenyl group).

19. The organic light-emitting device as claimed in claim 1, wherein the anthracene-based compound is one of Compounds 61 to 136 below. 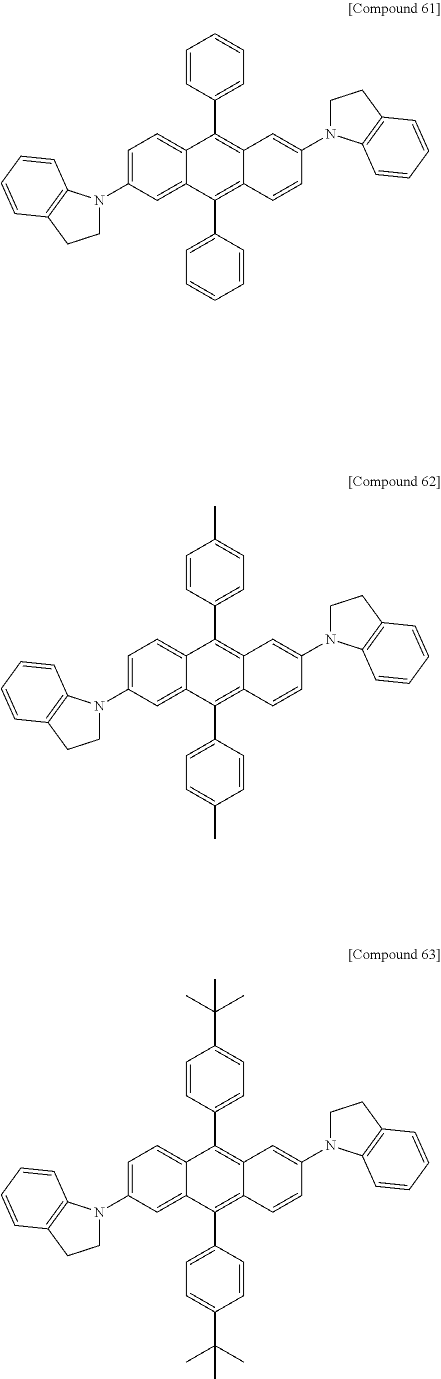 [SMILES: c1ccc(-c2c3ccc(N4CCc5ccccc54)cc3c(-c3ccccc3)c3ccc(N4CCc5ccccc54)cc23)cc1 ; Cc1ccc(-c2c3ccc(N4CCc5ccccc54)cc3c(-c3ccc(C)cc3)c3ccc(N4CCc5ccccc54)cc23)cc1 ; CC(C)(C)c1ccc(-c2c3ccc(N4CCc5ccccc54)cc3c(-c3ccc(C(C)(C)C)cc3)c3ccc(N4CCc5ccccc54)cc23)cc1] 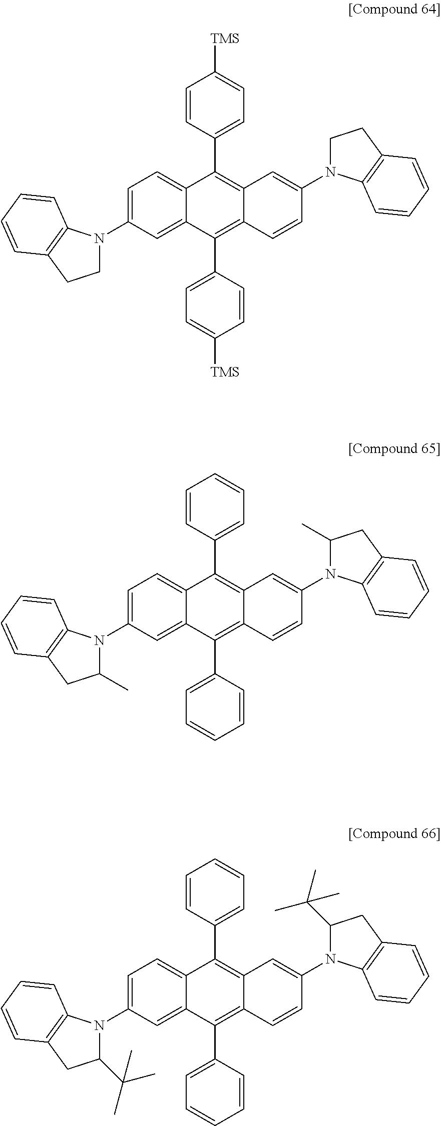 [SMILES: C[Si](C)(C)c1ccc(-c2c3ccc(N4CCc5ccccc54)cc3c(-c3ccc([Si](C)(C)C)cc3)c3ccc(N4CCc5ccccc54)cc23)cc1 ; CC1Cc2ccccc2N1c1ccc2c(-c3ccccc3)c3cc(N4c5ccccc5CC4C)ccc3c(-c3ccccc3)c2c1 ; CC(C)(C)C1Cc2ccccc2N1c1ccc2c(-c3ccccc3)c3cc(N4c5ccccc5CC4C(C)(C)C)ccc3c(-c3ccccc3)c2c1] 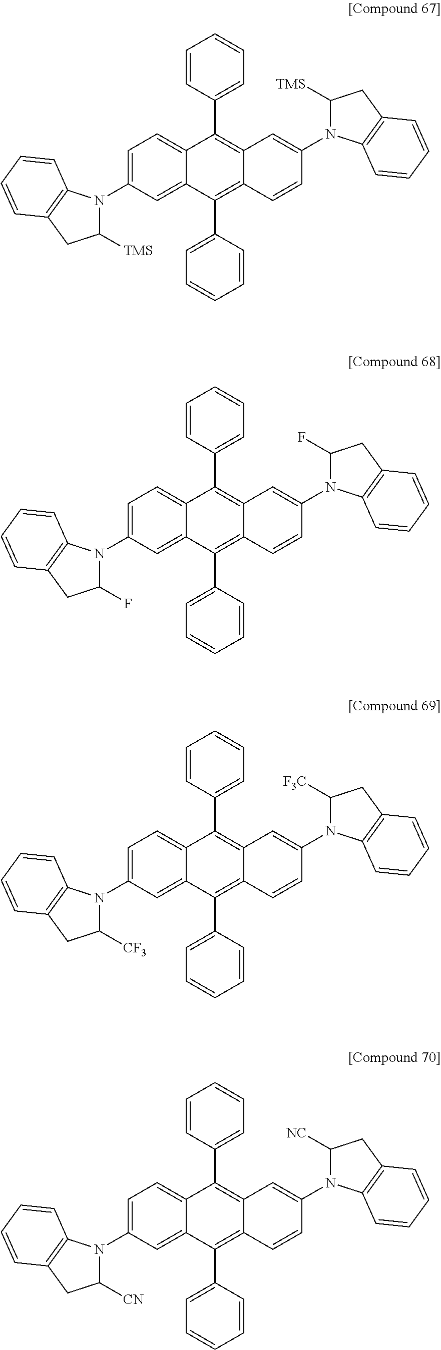 [SMILES: C[Si](C)(C)C1Cc2ccccc2N1c1ccc2c(-c3ccccc3)c3cc(N4c5ccccc5CC4[Si](C)(C)C)ccc3c(-c3ccccc3)c2c1 ; FC1Cc2ccccc2N1c1ccc2c(-c3ccccc3)c3cc(N4c5ccccc5CC4F)ccc3c(-c3ccccc3)c2c1 ; FC(F)(F)C1Cc2ccccc2N1c1ccc2c(-c3ccccc3)c3cc(N4c5ccccc5CC4C(F)(F)F)ccc3c(-c3ccccc3)c2c1 ; N#CC1Cc2ccccc2N1c1ccc2c(-c3ccccc3)c3cc(N4c5ccccc5CC4C#N)ccc3c(-c3ccccc3)c2c1] 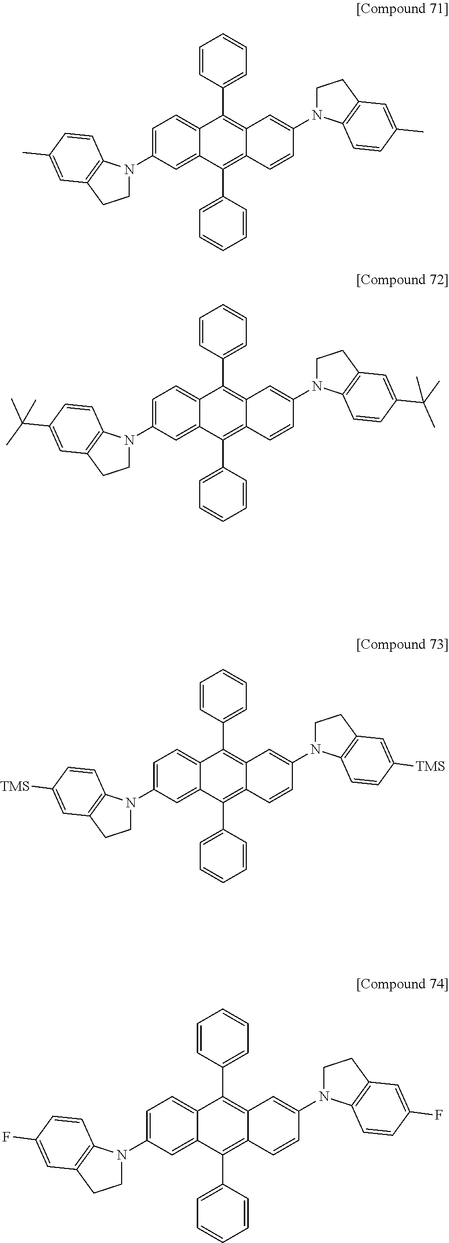 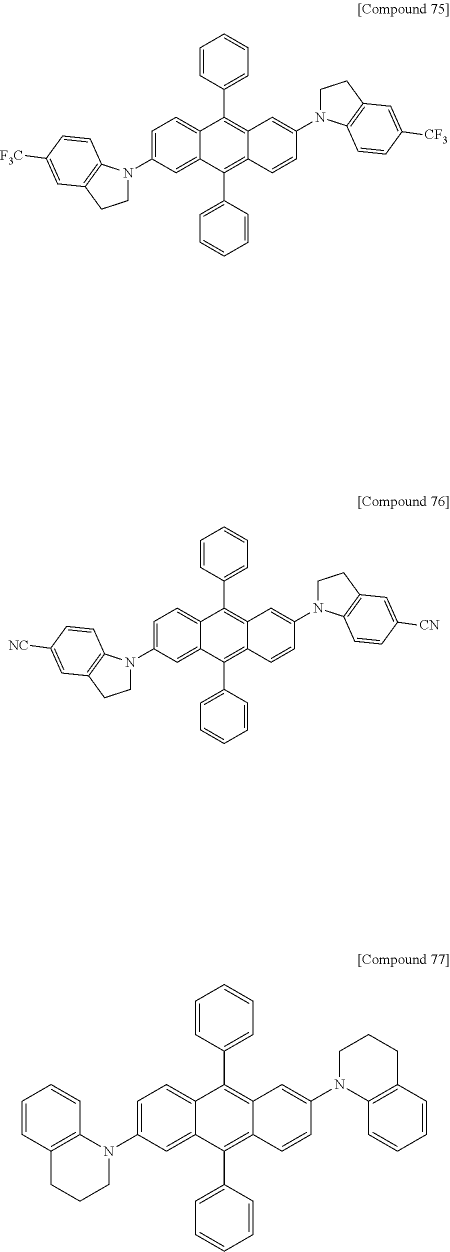 [SMILES: FC(F)(F)c1ccc2c(c1)CCN2c1ccc2c(-c3ccccc3)c3cc(N4CCc5cc(C(F)(F)F)ccc54)ccc3c(-c3ccccc3)c2c1 ; N#Cc1ccc2c(c1)CCN2c1ccc2c(-c3ccccc3)c3cc(N4CCc5cc(C#N)ccc54)ccc3c(-c3ccccc3)c2c1 ; c1ccc(-c2c3ccc(N4CCCc5ccccc54)cc3c(-c3ccccc3)c3ccc(N4CCCc5ccccc54)cc23)cc1] 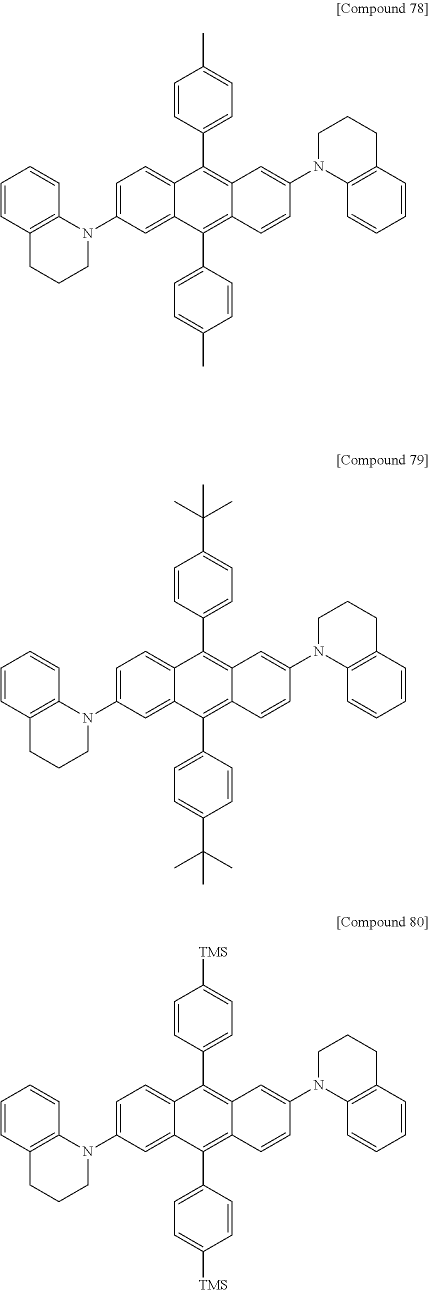 [SMILES: Cc1ccc(-c2c3ccc(N4CCCc5ccccc54)cc3c(-c3ccc(C)cc3)c3ccc(N4CCCc5ccccc54)cc23)cc1 ; CC(C)(C)c1ccc(-c2c3ccc(N4CCCc5ccccc54)cc3c(-c3ccc(C(C)(C)C)cc3)c3ccc(N4CCCc5ccccc54)cc23)cc1 ; C[Si](C)(C)c1ccc(-c2c3ccc(N4CCCc5ccccc54)cc3c(-c3ccc([Si](C)(C)C)cc3)c3ccc(N4CCCc5ccccc54)cc23)cc1] 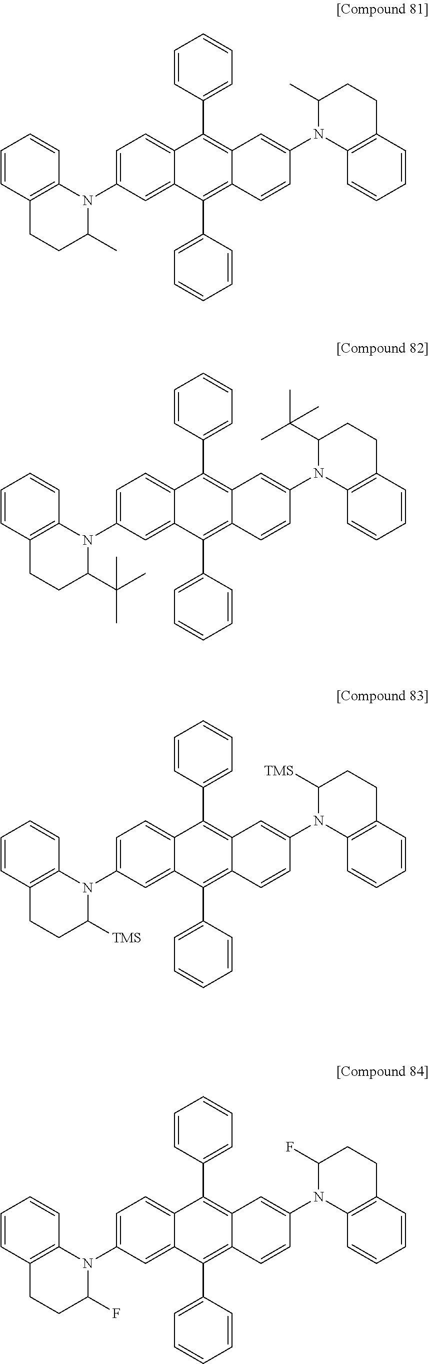 [SMILES: CC1CCc2ccccc2N1c1ccc2c(-c3ccccc3)c3cc(N4c5ccccc5CCC4C)ccc3c(-c3ccccc3)c2c1 ; CC(C)(C)C1CCc2ccccc2N1c1ccc2c(-c3ccccc3)c3cc(N4c5ccccc5CCC4C(C)(C)C)ccc3c(-c3ccccc3)c2c1 ; C[Si](C)(C)C1CCc2ccccc2N1c1ccc2c(-c3ccccc3)c3cc(N4c5ccccc5CCC4[Si](C)(C)C)ccc3c(-c3ccccc3)c2c1 ; FC1CCc2ccccc2N1c1ccc2c(-c3ccccc3)c3cc(N4c5ccccc5CCC4F)ccc3c(-c3ccccc3)c2c1] 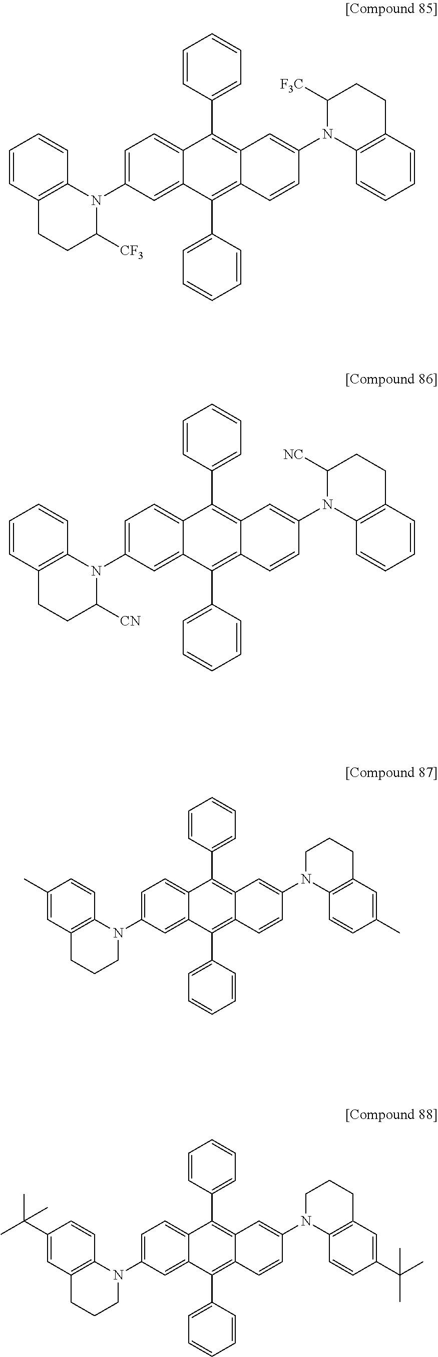 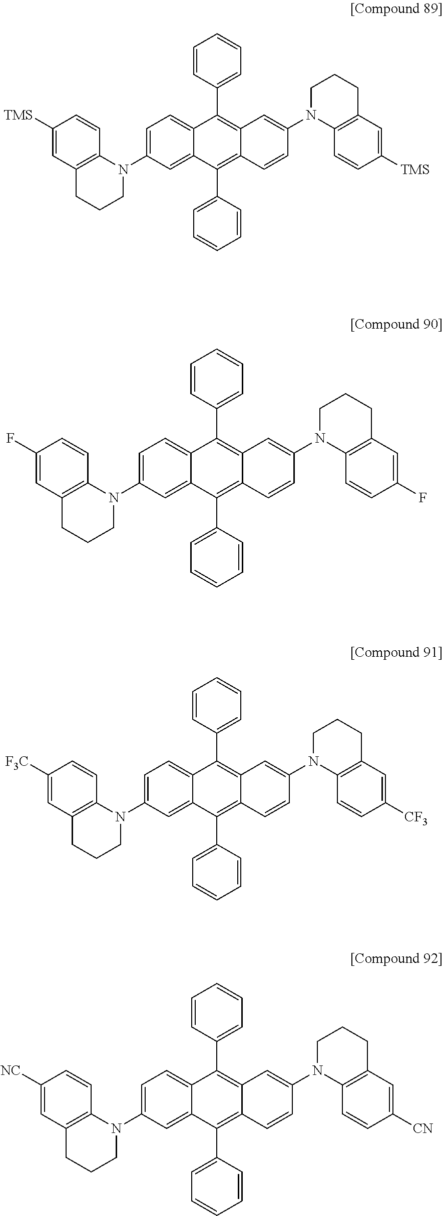 [SMILES: C[Si](C)(C)c1ccc2c(c1)CCCN2c1ccc2c(-c3ccccc3)c3cc(N4CCCc5cc([Si](C)(C)C)ccc54)ccc3c(-c3ccccc3)c2c1 ; Fc1ccc2c(c1)CCCN2c1ccc2c(-c3ccccc3)c3cc(N4CCCc5cc(F)ccc54)ccc3c(-c3ccccc3)c2c1 ; FC(F)(F)c1ccc2c(c1)CCCN2c1ccc2c(-c3ccccc3)c3cc(N4CCCc5cc(C(F)(F)F)ccc54)ccc3c(-c3ccccc3)c2c1 ; N#Cc1ccc2c(c1)CCCN2c1ccc2c(-c3ccccc3)c3cc(N4CCCc5cc(C#N)ccc54)ccc3c(-c3ccccc3)c2c1] 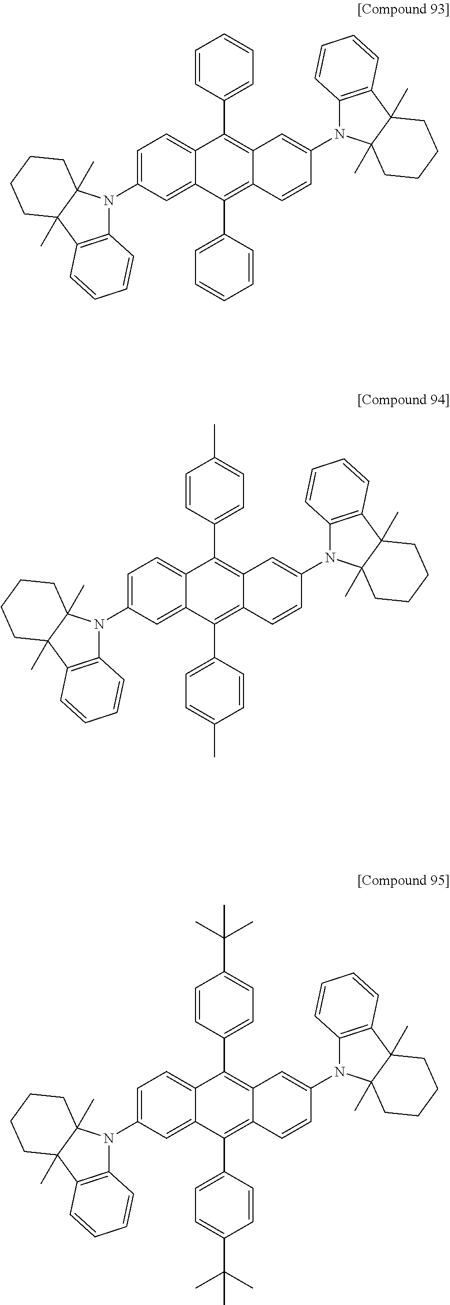 [SMILES: CC12CCCCC1(C)N(c1ccc3c(-c4ccccc4)c4cc(N5c6ccccc6C6(C)CCCCC56C)ccc4c(-c4ccccc4)c3c1)c1ccccc12 ; Cc1ccc(-c2c3ccc(N4c5ccccc5C5(C)CCCCC45C)cc3c(-c3ccc(C)cc3)c3ccc(N4c5ccccc5C5(C)CCCCC45C)cc23)cc1 ; CC(C)(C)c1ccc(-c2c3ccc(N4c5ccccc5C5(C)CCCCC45C)cc3c(-c3ccc(C(C)(C)C)cc3)c3ccc(N4c5ccccc5C5(C)CCCCC45C)cc23)cc1] 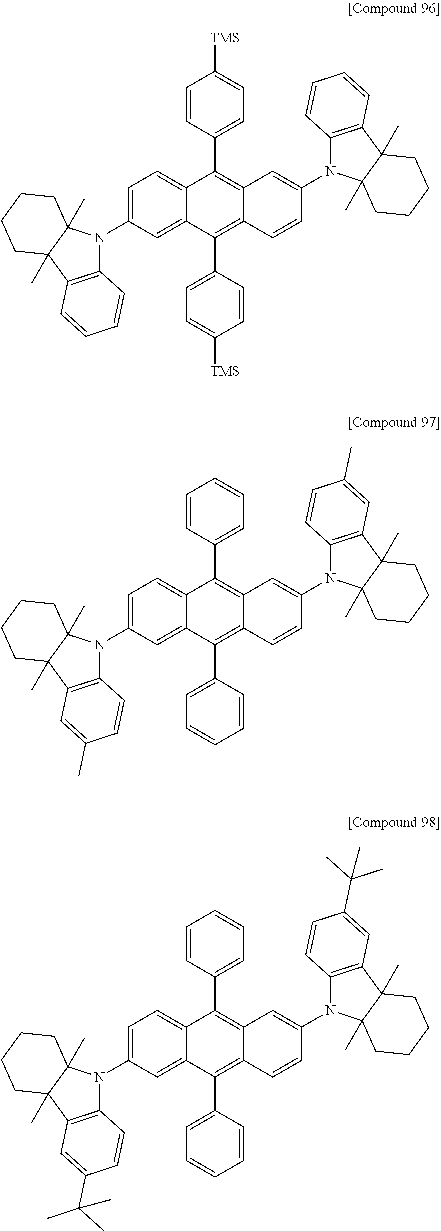 [SMILES: CC12CCCCC1(C)N(c1ccc3c(-c4ccc([Si](C)(C)C)cc4)c4cc(N5c6ccccc6C6(C)CCCCC56C)ccc4c(-c4ccc([Si](C)(C)C)cc4)c3c1)c1ccccc12 ; Cc1ccc2c(c1)C1(C)CCCCC1(C)N2c1ccc2c(-c3ccccc3)c3cc(N4c5ccc(C)cc5C5(C)CCCCC45C)ccc3c(-c3ccccc3)c2c1 ; CC(C)(C)c1ccc2c(c1)C1(C)CCCCC1(C)N2c1ccc2c(-c3ccccc3)c3cc(N4c5ccc(C(C)(C)C)cc5C5(C)CCCCC45C)ccc3c(-c3ccccc3)c2c1] 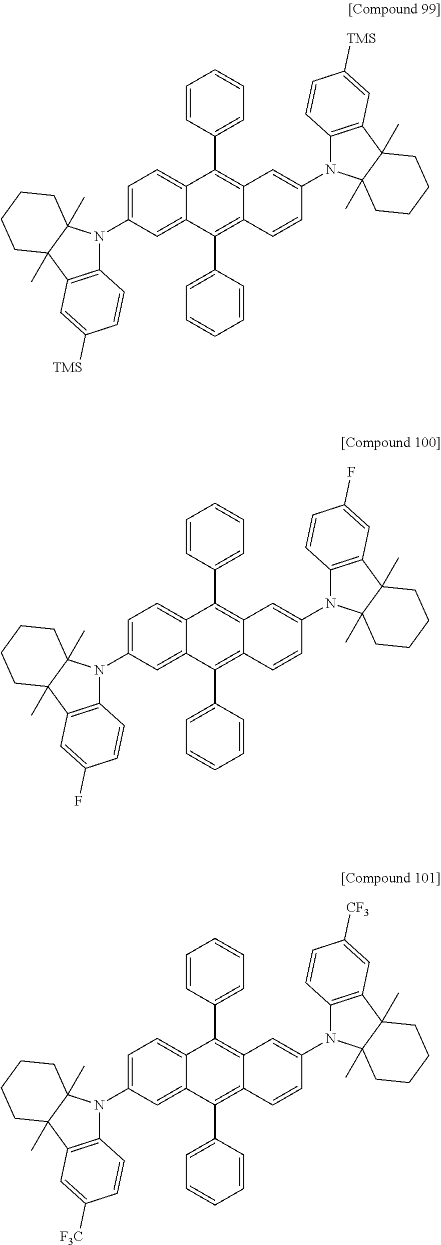 [SMILES: CC12CCCCC1(C)N(c1ccc3c(-c4ccccc4)c4cc(N5c6ccc([Si](C)(C)C)cc6C6(C)CCCCC56C)ccc4c(-c4ccccc4)c3c1)c1ccc([Si](C)(C)C)cc12 ; CC12CCCCC1(C)N(c1ccc3c(-c4ccccc4)c4cc(N5c6ccc(F)cc6C6(C)CCCCC56C)ccc4c(-c4ccccc4)c3c1)c1ccc(F)cc12 ; CC12CCCCC1(C)N(c1ccc3c(-c4ccccc4)c4cc(N5c6ccc(C(F)(F)F)cc6C6(C)CCCCC56C)ccc4c(-c4ccccc4)c3c1)c1ccc(C(F)(F)F)cc12] 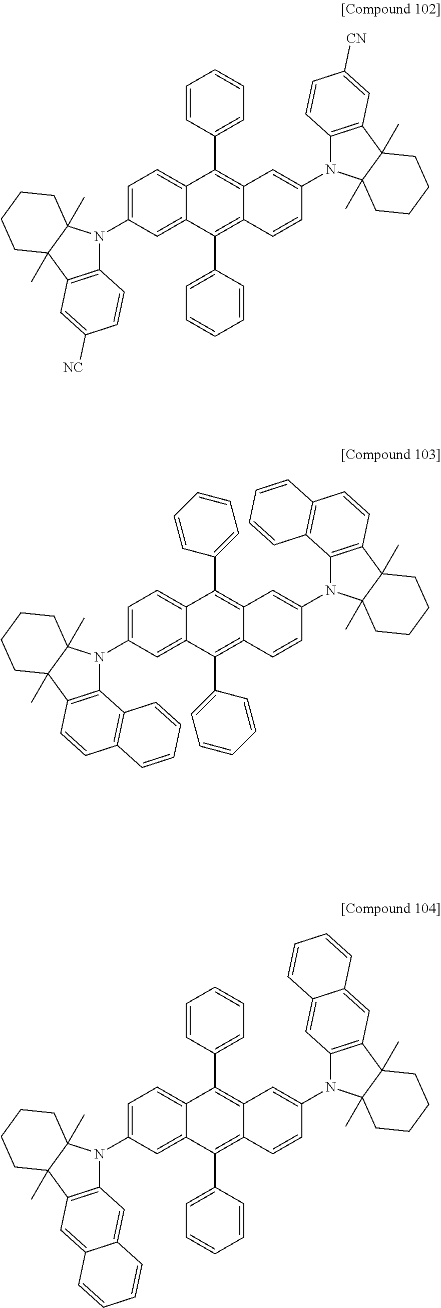 [SMILES: CC12CCCCC1(C)N(c1ccc3c(-c4ccccc4)c4cc(N5c6ccc(C#N)cc6C6(C)CCCCC56C)ccc4c(-c4ccccc4)c3c1)c1ccc(C#N)cc12 ; CC12CCCCC1(C)N(c1ccc3c(-c4ccccc4)c4cc(N5c6c(ccc7ccccc67)C6(C)CCCCC56C)ccc4c(-c4ccccc4)c3c1)c1c2ccc2ccccc12 ; CC12CCCCC1(C)N(c1ccc3c(-c4ccccc4)c4cc(N5c6cc7ccccc7cc6C6(C)CCCCC56C)ccc4c(-c4ccccc4)c3c1)c1cc3ccccc3cc12] 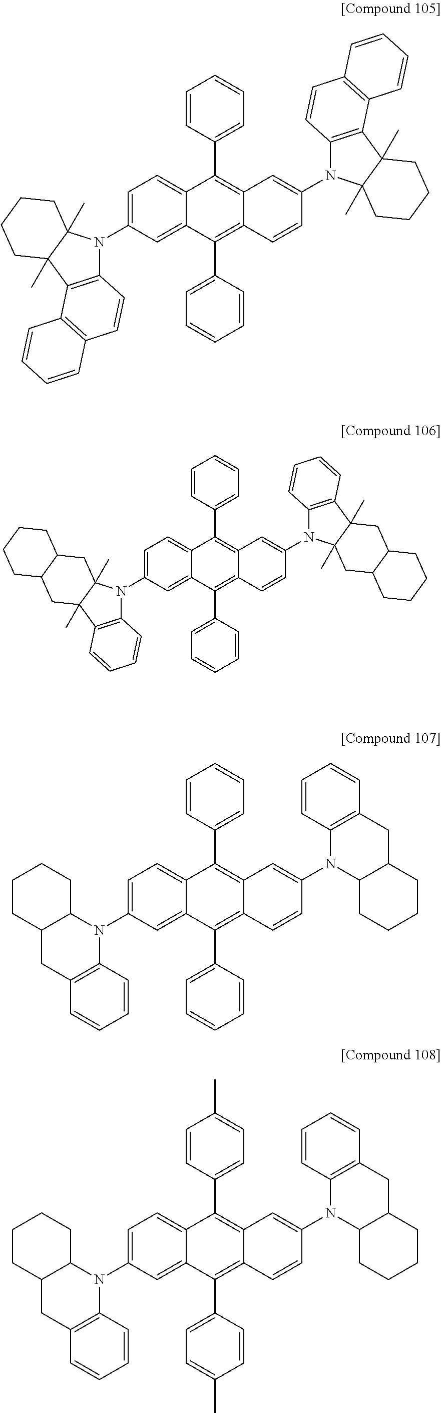 [SMILES: CC12CCCCC1(C)N(c1ccc3c(-c4ccccc4)c4cc(N5c6ccc7ccccc7c6C6(C)CCCCC56C)ccc4c(-c4ccccc4)c3c1)c1ccc3ccccc3c12 ; CC12CC3CCCCC3CC1(C)N(c1ccc3c(-c4ccccc4)c4cc(N5c6ccccc6C6(C)CC7CCCCC7CC56C)ccc4c(-c4ccccc4)c3c1)c1ccccc12 ; c1ccc(-c2c3ccc(N4c5ccccc5CC5CCCCC54)cc3c(-c3ccccc3)c3ccc(N4c5ccccc5CC5CCCCC54)cc23)cc1 ; Cc1ccc(-c2c3ccc(N4c5ccccc5CC5CCCCC54)cc3c(-c3ccc(C)cc3)c3ccc(N4c5ccccc5CC5CCCCC54)cc23)cc1] 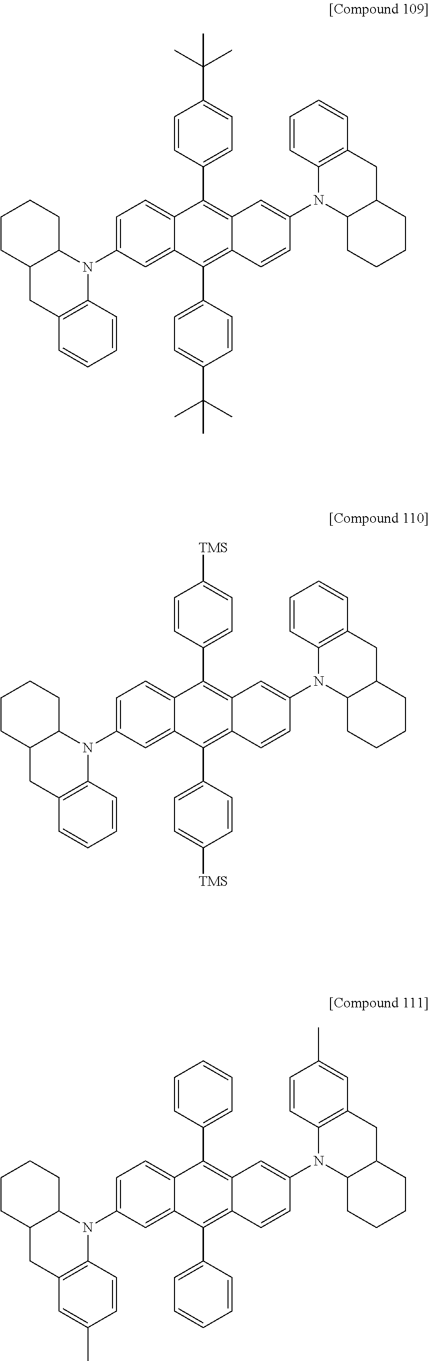 [SMILES: CC(C)(C)c1ccc(-c2c3ccc(N4c5ccccc5CC5CCCCC54)cc3c(-c3ccc(C(C)(C)C)cc3)c3ccc(N4c5ccccc5CC5CCCCC54)cc23)cc1 ; C[Si](C)(C)c1ccc(-c2c3ccc(N4c5ccccc5CC5CCCCC54)cc3c(-c3ccc([Si](C)(C)C)cc3)c3ccc(N4c5ccccc5CC5CCCCC54)cc23)cc1 ; Cc1ccc2c(c1)CC1CCCCC1N2c1ccc2c(-c3ccccc3)c3cc(N4c5ccc(C)cc5CC5CCCCC54)ccc3c(-c3ccccc3)c2c1] 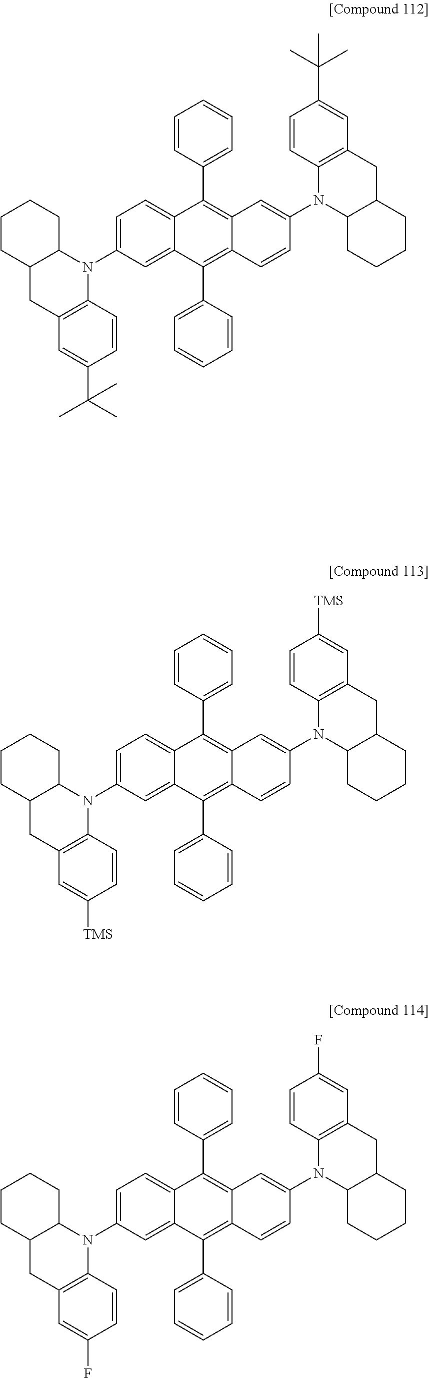 [SMILES: CC(C)(C)c1ccc2c(c1)CC1CCCCC1N2c1ccc2c(-c3ccccc3)c3cc(N4c5ccc(C(C)(C)C)cc5CC5CCCCC54)ccc3c(-c3ccccc3)c2c1 ; C[Si](C)(C)c1ccc2c(c1)CC1CCCCC1N2c1ccc2c(-c3ccccc3)c3cc(N4c5ccc([Si](C)(C)C)cc5CC5CCCCC54)ccc3c(-c3ccccc3)c2c1 ; Fc1ccc2c(c1)CC1CCCCC1N2c1ccc2c(-c3ccccc3)c3cc(N4c5ccc(F)cc5CC5CCCCC54)ccc3c(-c3ccccc3)c2c1] 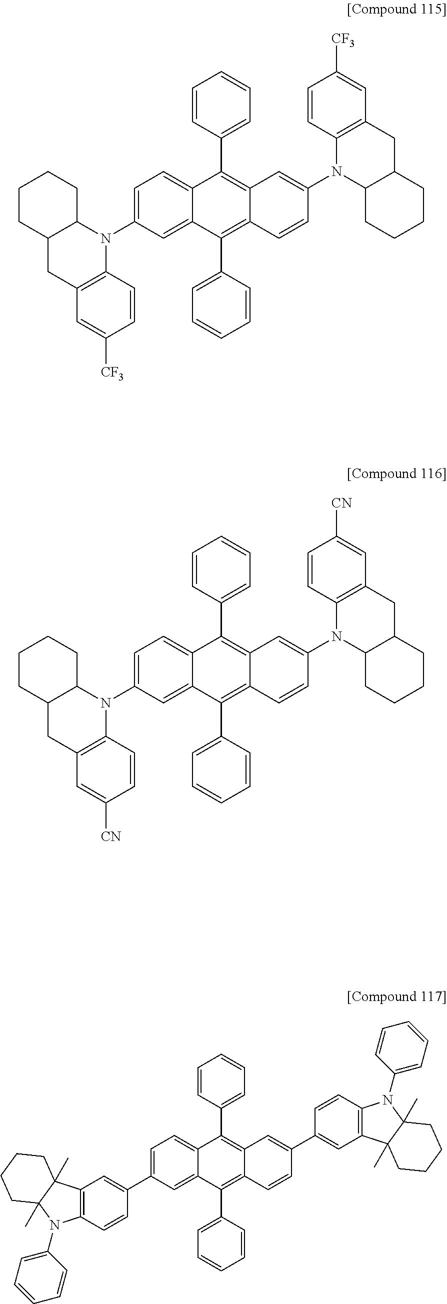 [SMILES: FC(F)(F)c1ccc2c(c1)CC1CCCCC1N2c1ccc2c(-c3ccccc3)c3cc(N4c5ccc(C(F)(F)F)cc5CC5CCCCC54)ccc3c(-c3ccccc3)c2c1 ; N#Cc1ccc2c(c1)CC1CCCCC1N2c1ccc2c(-c3ccccc3)c3cc(N4c5ccc(C#N)cc5CC5CCCCC54)ccc3c(-c3ccccc3)c2c1 ; CC12CCCCC1(C)N(c1ccccc1)c1ccc(-c3ccc4c(-c5ccccc5)c5cc(-c6ccc7c(c6)C6(C)CCCCC6(C)N7c6ccccc6)ccc5c(-c5ccccc5)c4c3)cc12] 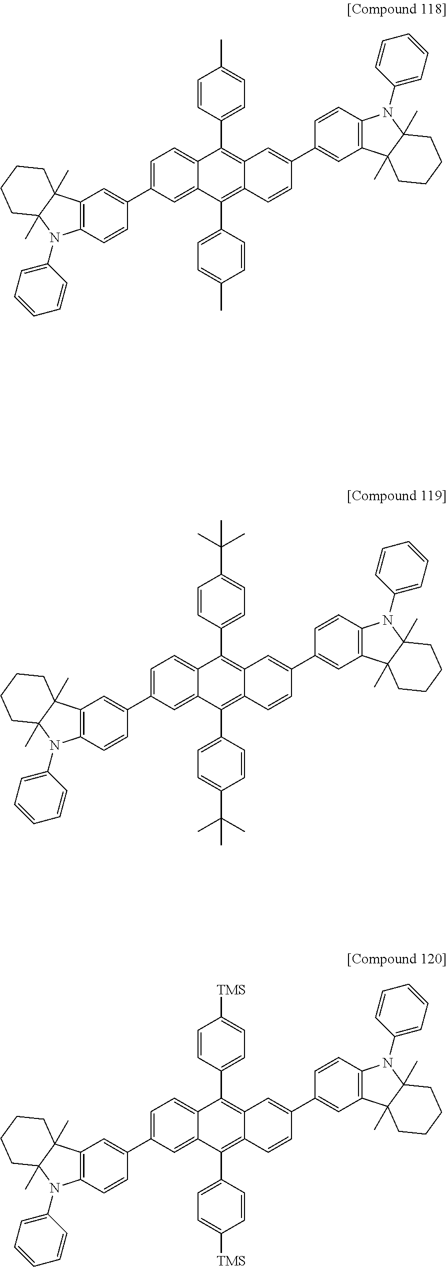 [SMILES: Cc1ccc(-c2c3ccc(-c4ccc5c(c4)C4(C)CCCCC4(C)N5c4ccccc4)cc3c(-c3ccc(C)cc3)c3ccc(-c4ccc5c(c4)C4(C)CCCCC4(C)N5c4ccccc4)cc23)cc1 ; CC(C)(C)c1ccc(-c2c3ccc(-c4ccc5c(c4)C4(C)CCCCC4(C)N5c4ccccc4)cc3c(-c3ccc(C(C)(C)C)cc3)c3ccc(-c4ccc5c(c4)C4(C)CCCCC4(C)N5c4ccccc4)cc23)cc1 ; CC12CCCCC1(C)N(c1ccccc1)c1ccc(-c3ccc4c(-c5ccc([Si](C)(C)C)cc5)c5cc(-c6ccc7c(c6)C6(C)CCCCC6(C)N7c6ccccc6)ccc5c(-c5ccc([Si](C)(C)C)cc5)c4c3)cc12] 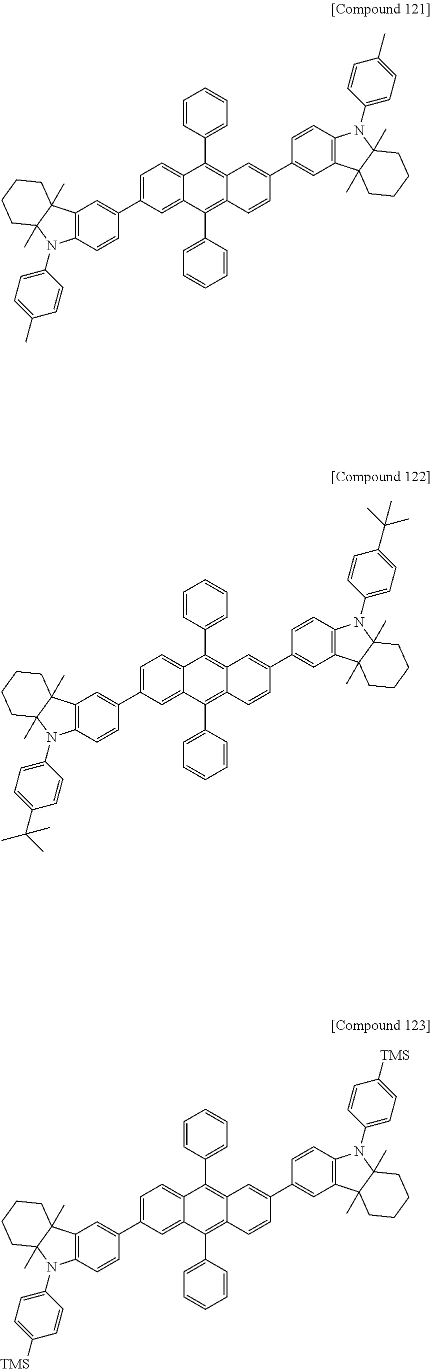 [SMILES: Cc1ccc(N2c3ccc(-c4ccc5c(-c6ccccc6)c6cc(-c7ccc8c(c7)C7(C)CCCCC7(C)N8c7ccc(C)cc7)ccc6c(-c6ccccc6)c5c4)cc3C3(C)CCCCC23C)cc1 ; CC(C)(C)c1ccc(N2c3ccc(-c4ccc5c(-c6ccccc6)c6cc(-c7ccc8c(c7)C7(C)CCCCC7(C)N8c7ccc(C(C)(C)C)cc7)ccc6c(-c6ccccc6)c5c4)cc3C3(C)CCCCC23C)cc1 ; CC12CCCCC1(C)N(c1ccc([Si](C)(C)C)cc1)c1ccc(-c3ccc4c(-c5ccccc5)c5cc(-c6ccc7c(c6)C6(C)CCCCC6(C)N7c6ccc([Si](C)(C)C)cc6)ccc5c(-c5ccccc5)c4c3)cc12] 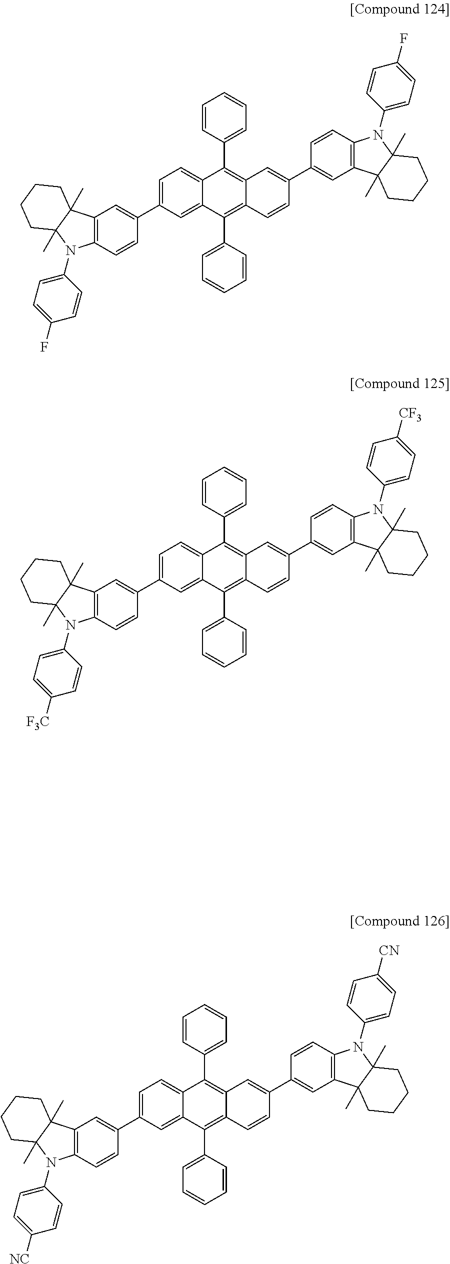 [SMILES: CC12CCCCC1(C)N(c1ccc(F)cc1)c1ccc(-c3ccc4c(-c5ccccc5)c5cc(-c6ccc7c(c6)C6(C)CCCCC6(C)N7c6ccc(F)cc6)ccc5c(-c5ccccc5)c4c3)cc12 ; CC12CCCCC1(C)N(c1ccc(C(F)(F)F)cc1)c1ccc(-c3ccc4c(-c5ccccc5)c5cc(-c6ccc7c(c6)C6(C)CCCCC6(C)N7c6ccc(C(F)(F)F)cc6)ccc5c(-c5ccccc5)c4c3)cc12 ; CC12CCCCC1(C)N(c1ccc(C#N)cc1)c1ccc(-c3ccc4c(-c5ccccc5)c5cc(-c6ccc7c(c6)C6(C)CCCCC6(C)N7c6ccc(C#N)cc6)ccc5c(-c5ccccc5)c4c3)cc12] 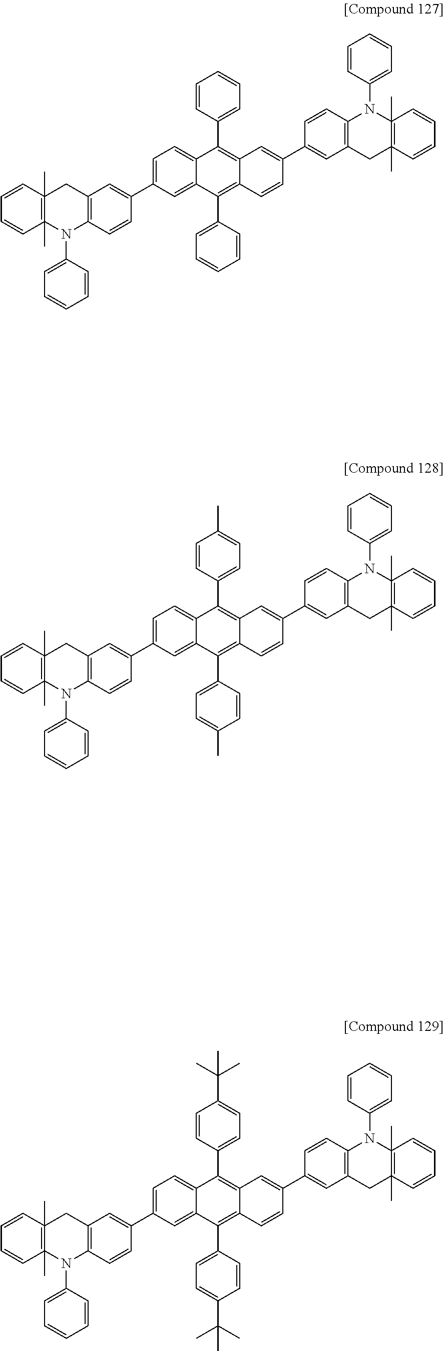 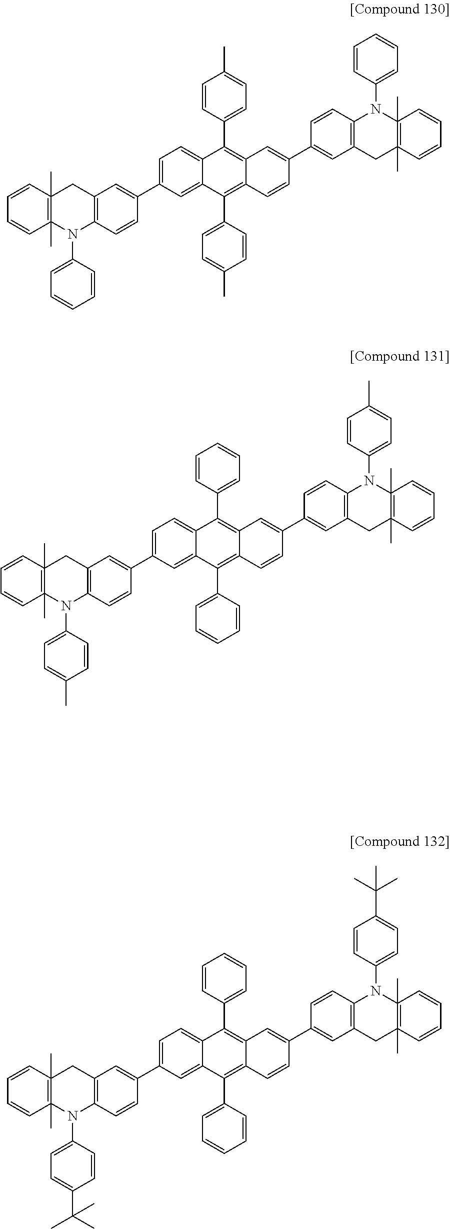 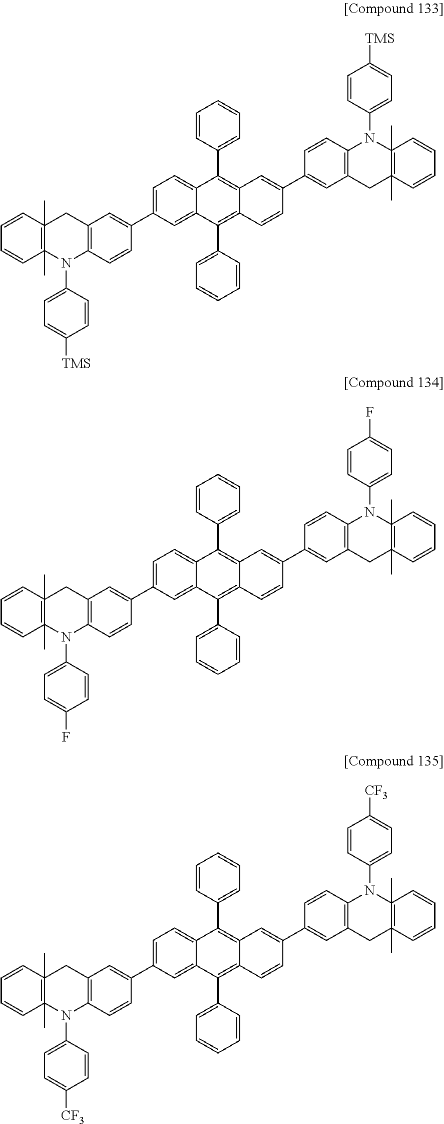 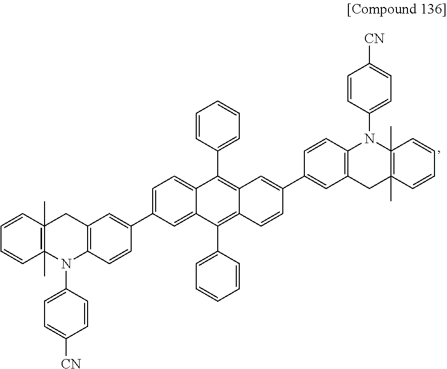
where TMS represents trimethylsilyl.

20. An organic light-emitting device, comprising: a first electrode; a second electrode; and an organic layer between the first electrode and the second electrode, the organic layer including an emission layer that includes at least one of Compounds 1 to 60 below and at least one of Compounds 61 to 136 below: 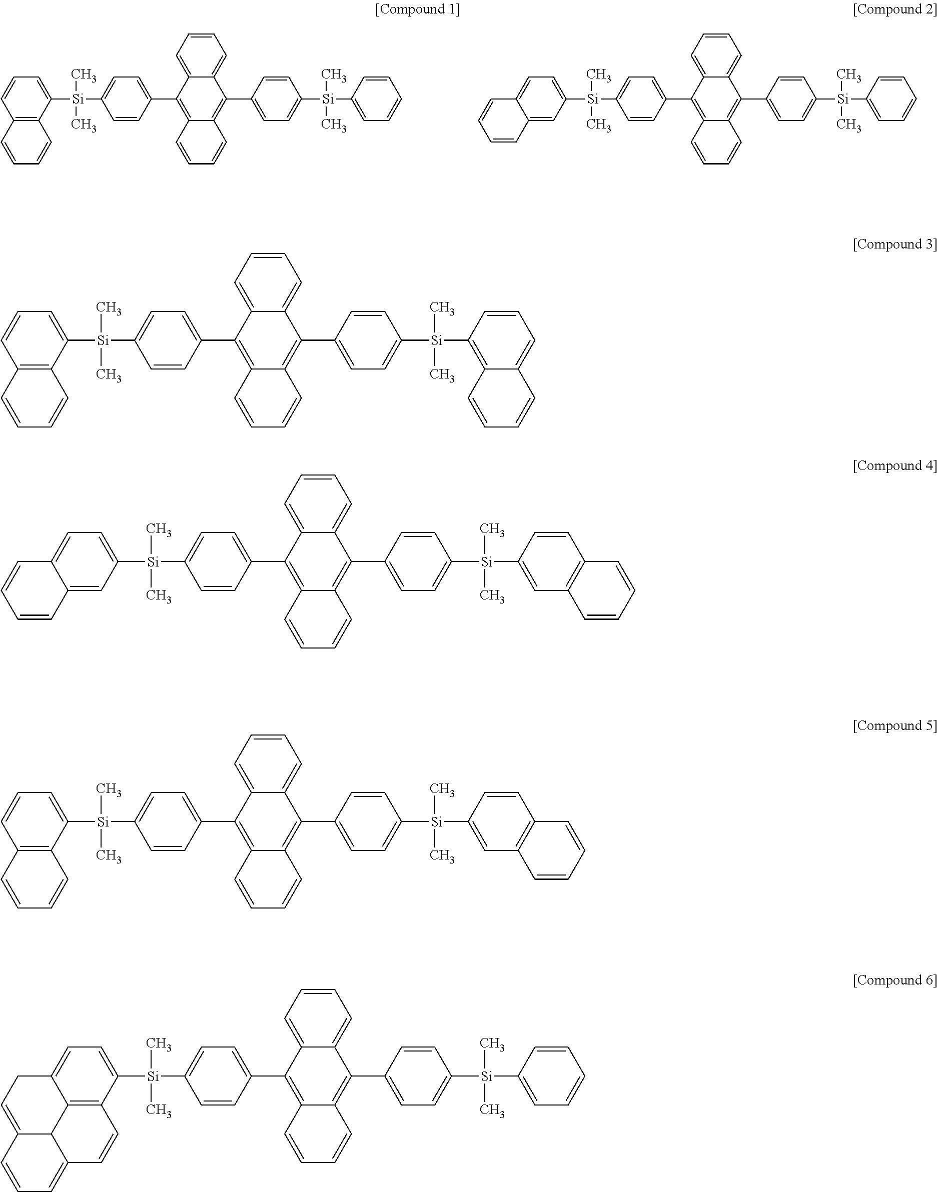 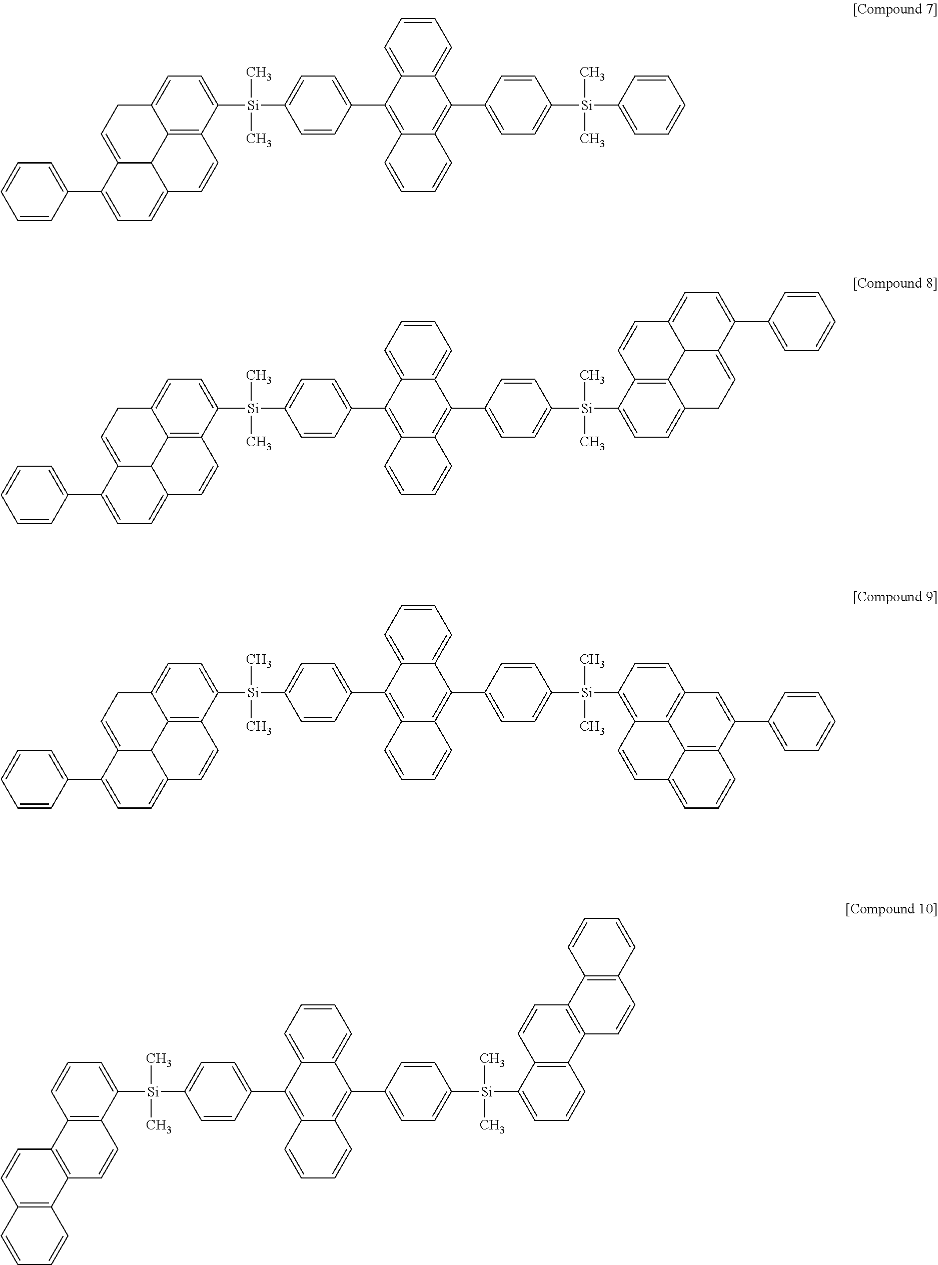 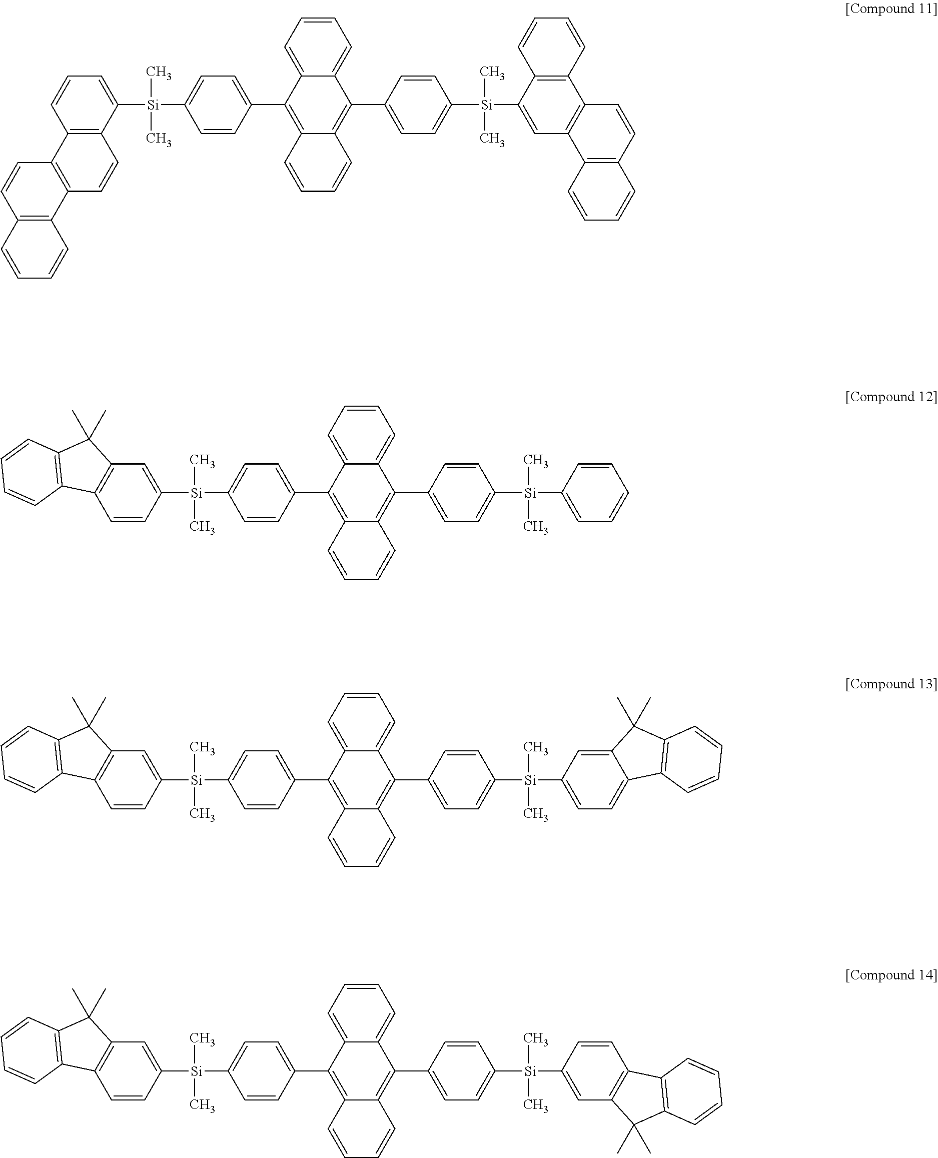 [SMILES: C[Si](C)(c1ccc(-c2c3ccccc3c(-c3ccc([Si](C)(C)c4cc5c6ccccc6ccc5c5ccccc45)cc3)c3ccccc23)cc1)c1cccc2c1ccc1c3ccccc3ccc21 ; CC1(C)c2ccccc2-c2ccc([Si](C)(C)c3ccc(-c4c5ccccc5c(-c5ccc([Si](C)(C)c6ccccc6)cc5)c5ccccc45)cc3)cc21 ; CC1(C)c2ccccc2-c2ccc([Si](C)(C)c3ccc(-c4c5ccccc5c(-c5ccc([Si](C)(C)c6ccc7c(c6)C(C)(C)c6ccccc6-7)cc5)c5ccccc45)cc3)cc21 ; CC1(C)c2ccccc2-c2ccc([Si](C)(C)c3ccc(-c4c5ccccc5c(-c5ccc([Si](C)(C)c6ccc7c(c6)C(C)(C)c6ccccc6-7)cc5)c5ccccc45)cc3)cc21] 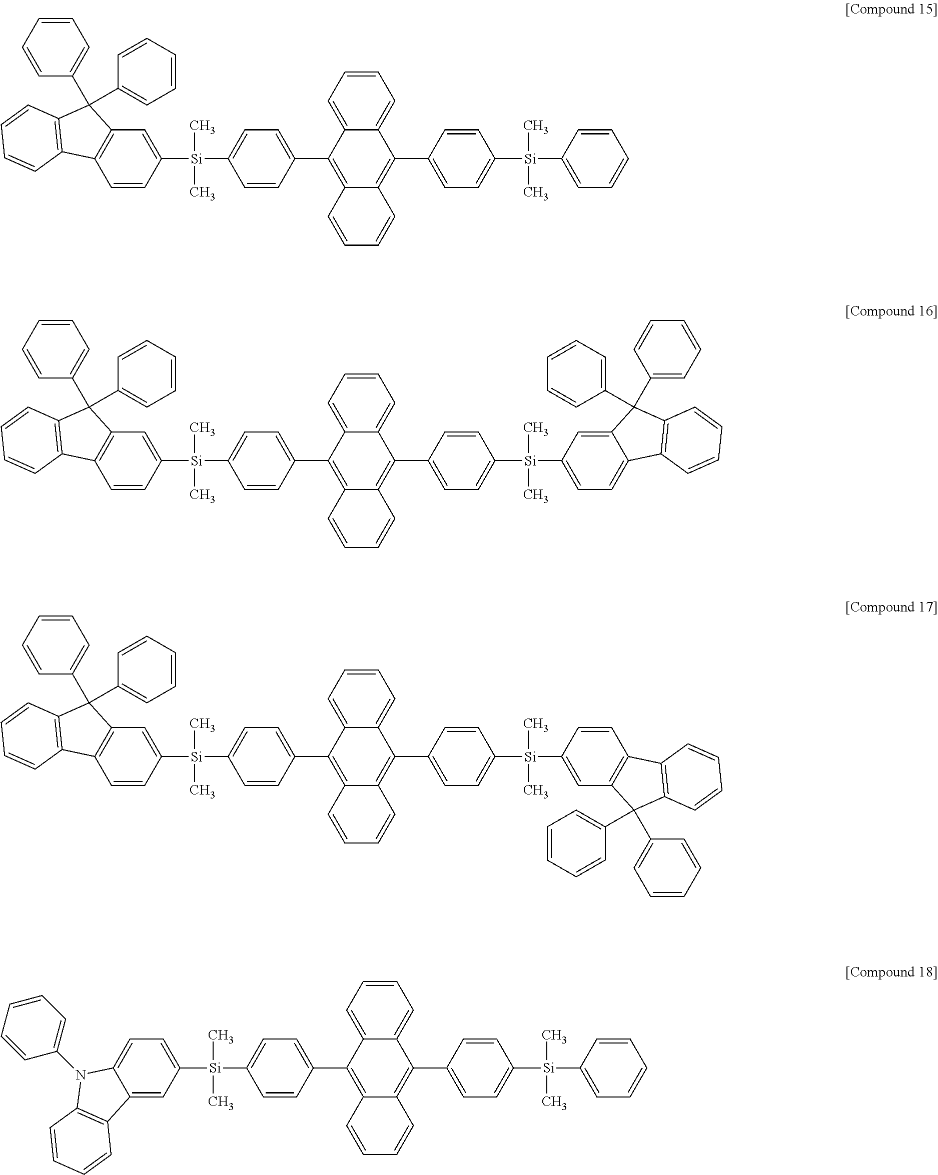 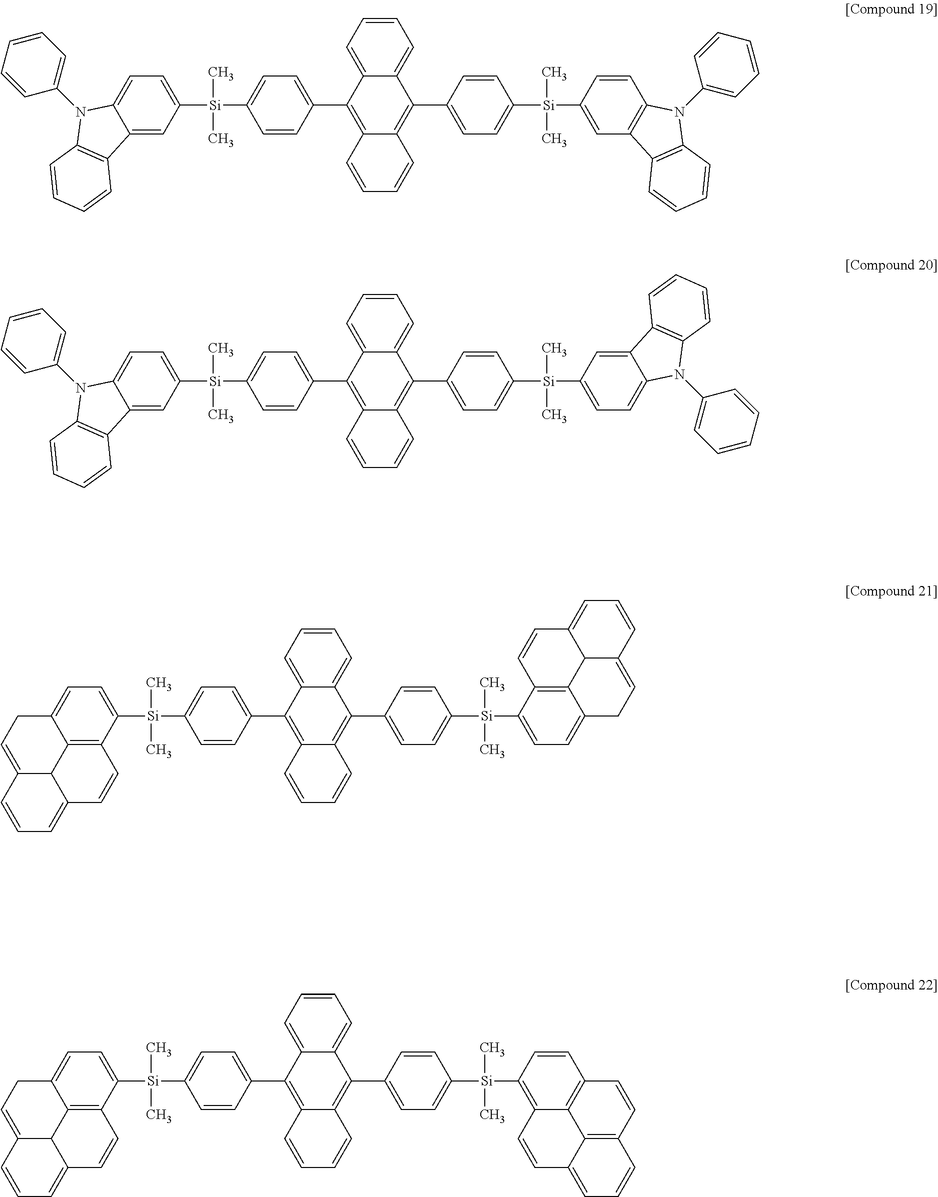 [SMILES: C[Si](C)(c1ccc(-c2c3ccccc3c(-c3ccc([Si](C)(C)c4ccc5c(c4)c4ccccc4n5-c4ccccc4)cc3)c3ccccc23)cc1)c1ccc2c(c1)c1ccccc1n2-c1ccccc1 ; C[Si](C)(c1ccc(-c2c3ccccc3c(-c3ccc([Si](C)(C)c4ccc5c(c4)c4ccccc4n5-c4ccccc4)cc3)c3ccccc23)cc1)c1ccc2c(c1)c1ccccc1n2-c1ccccc1 ; C[Si](C)(c1ccc(-c2c3ccccc3c(-c3ccc([Si](C)(C)c4ccc5c6c4C=CC4=CC=CC(=CC5)C46)cc3)c3ccccc23)cc1)c1ccc2c3c1C=CC1=CC=CC(=CC2)C13 ; C[Si](C)(c1ccc(-c2c3ccccc3c(-c3ccc([Si](C)(C)c4ccc5ccc6cccc7ccc4c5c67)cc3)c3ccccc23)cc1)c1ccc2c3c1C=CC1=CC=CC(=CC2)C13] 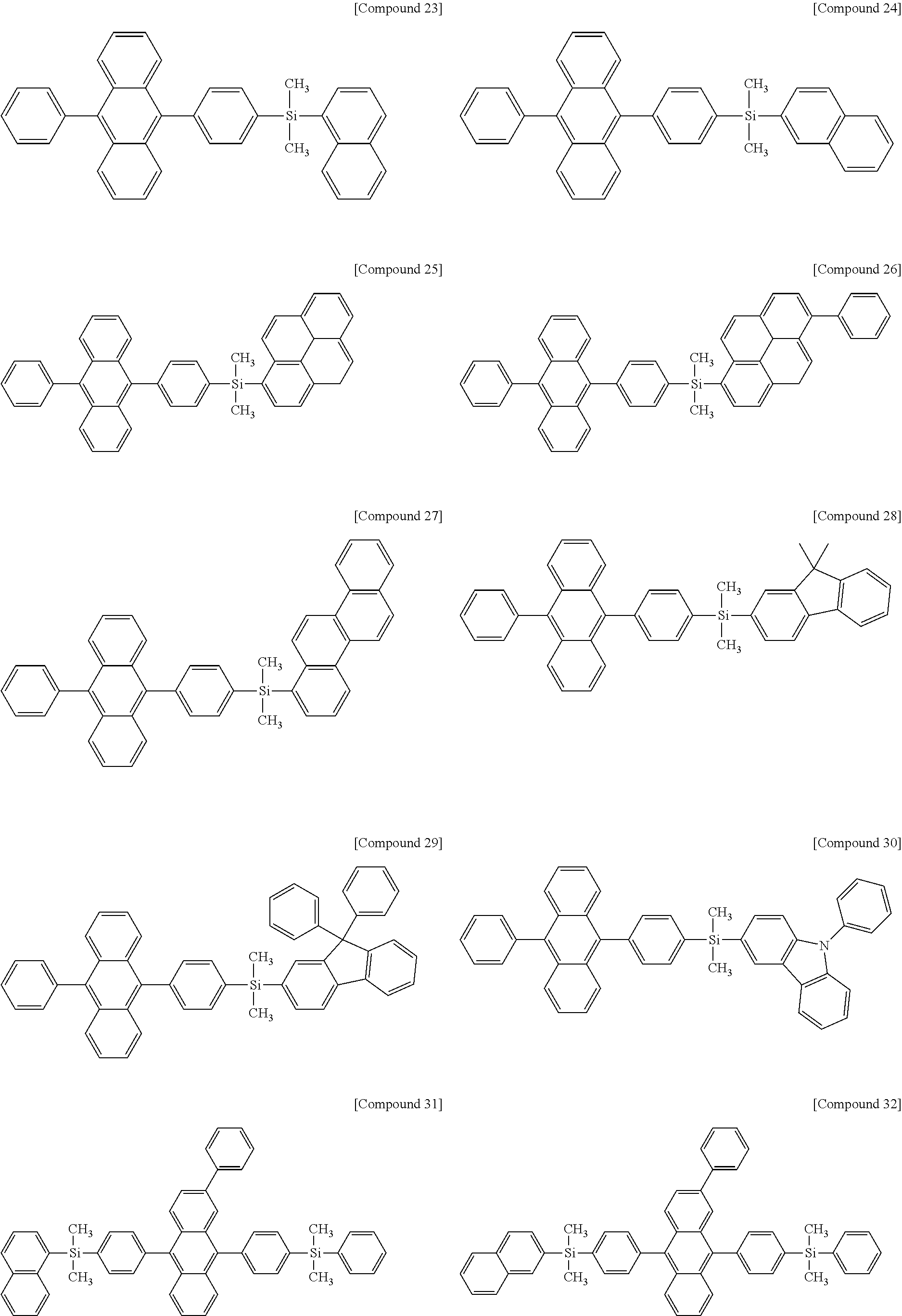 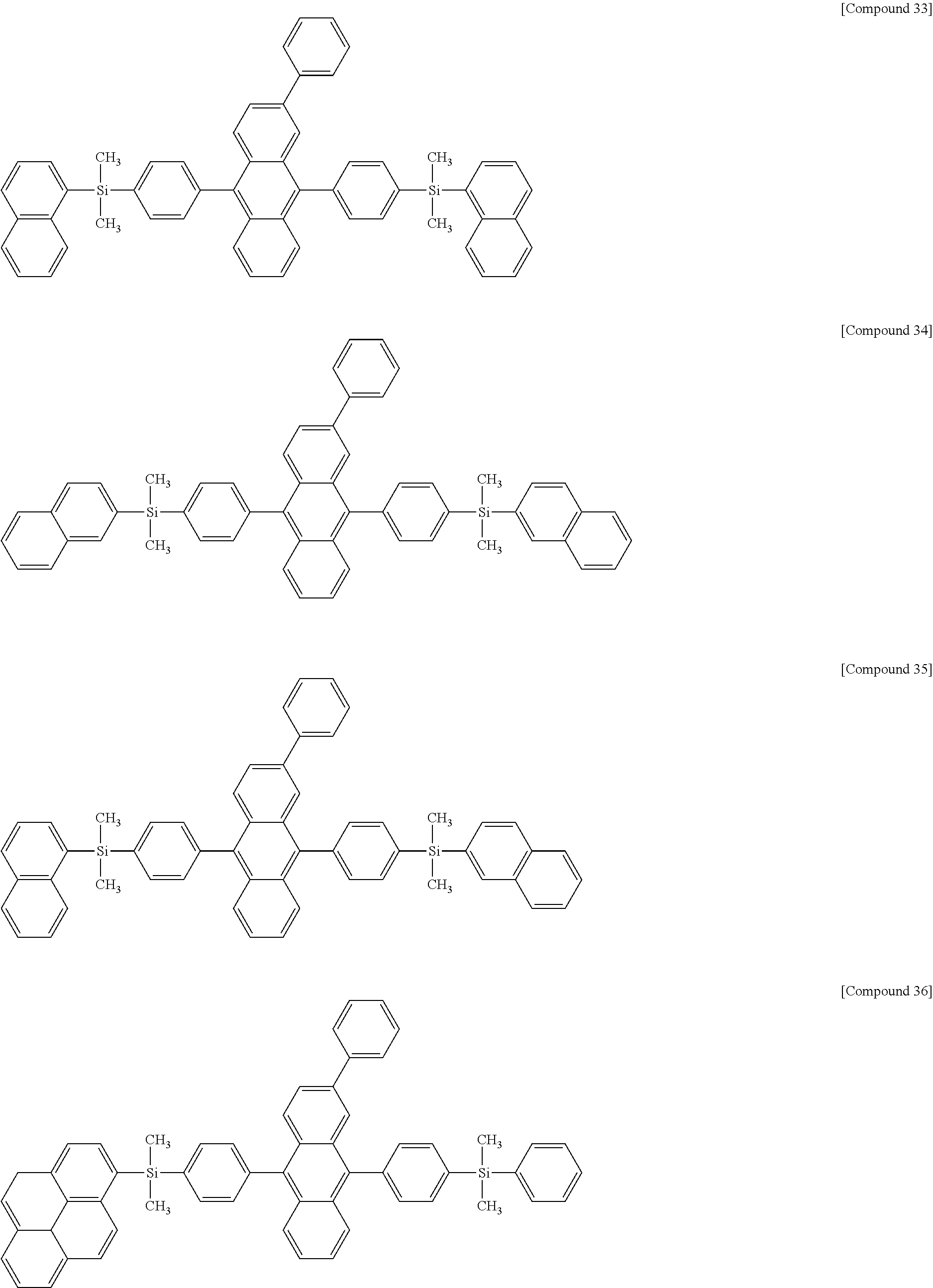 [SMILES: C[Si](C)(c1ccc(-c2c3ccccc3c(-c3ccc([Si](C)(C)c4cccc5ccccc45)cc3)c3cc(-c4ccccc4)ccc23)cc1)c1cccc2ccccc12 ; C[Si](C)(c1ccc(-c2c3ccccc3c(-c3ccc([Si](C)(C)c4ccc5ccccc5c4)cc3)c3cc(-c4ccccc4)ccc23)cc1)c1ccc2ccccc2c1 ; C[Si](C)(c1ccc(-c2c3ccccc3c(-c3ccc([Si](C)(C)c4cccc5ccccc45)cc3)c3ccc(-c4ccccc4)cc23)cc1)c1ccc2ccccc2c1 ; C[Si](C)(c1ccccc1)c1ccc(-c2c3ccccc3c(-c3ccc([Si](C)(C)c4ccc5c6c4C=CC4=CC=CC(=CC5)C46)cc3)c3ccc(-c4ccccc4)cc23)cc1] 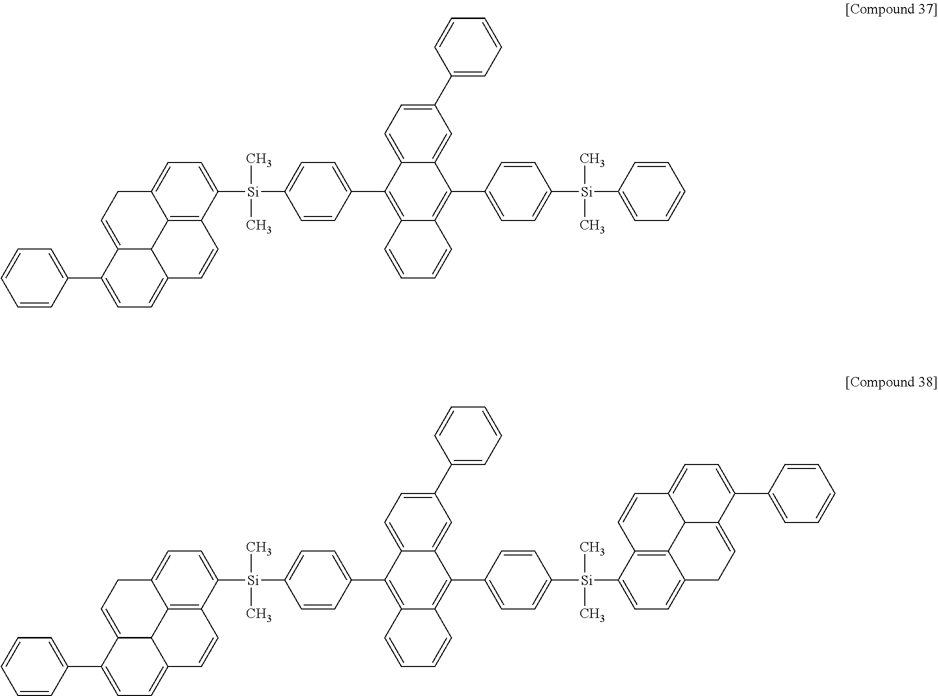 [SMILES: C[Si](C)(c1ccccc1)c1ccc(-c2c3ccccc3c(-c3ccc([Si](C)(C)c4ccc5c6c4C=CC4=CC=C(c7ccccc7)C(=CC5)C46)cc3)c3ccc(-c4ccccc4)cc23)cc1 ; C[Si](C)(c1ccc(-c2c3ccccc3c(-c3ccc([Si](C)(C)c4ccc5c6c4C=CC4=CC=C(c7ccccc7)C(=CC5)C46)cc3)c3cc(-c4ccccc4)ccc23)cc1)c1ccc2c3c1C=CC1=CC=C(c4ccccc4)C(=CC2)C13] 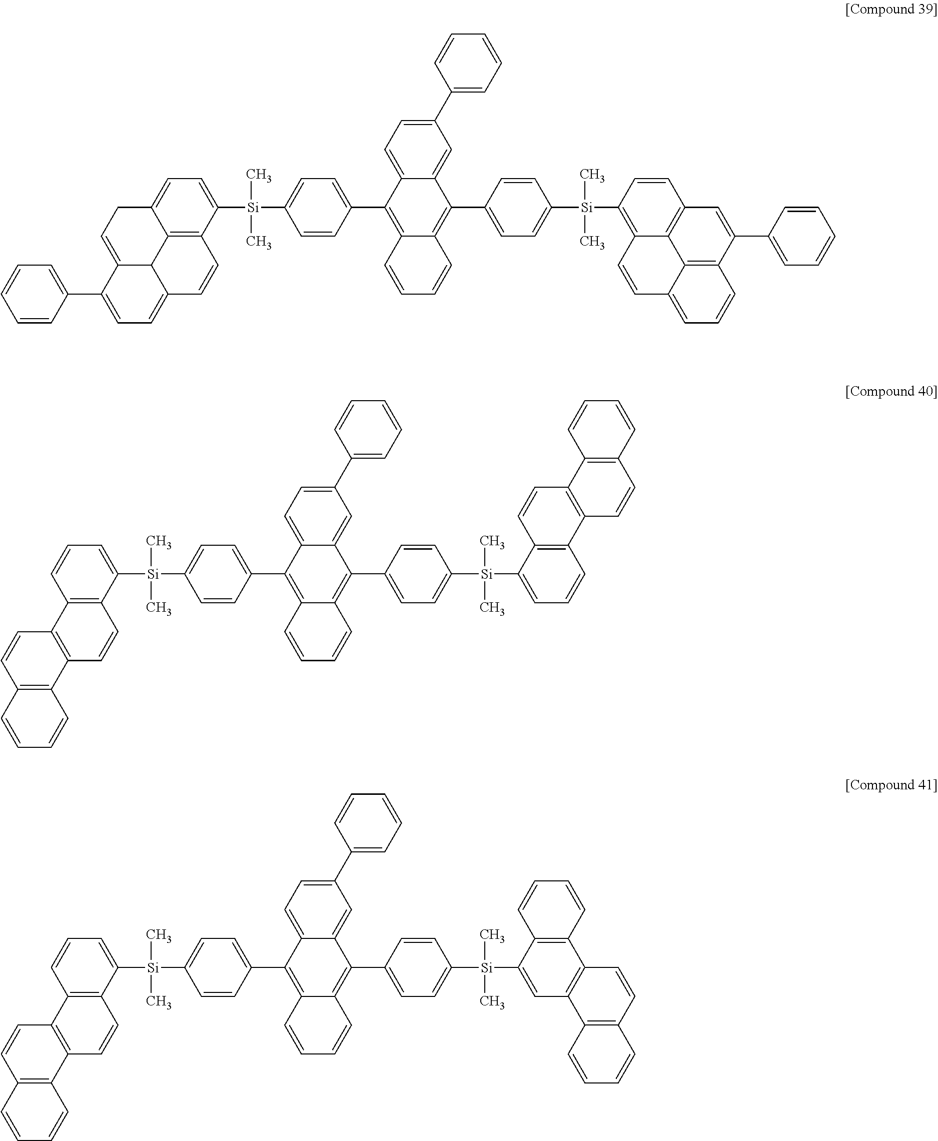 [SMILES: C[Si](C)(c1ccc(-c2c3ccccc3c(-c3ccc([Si](C)(C)c4ccc5cc(-c6ccccc6)c6cccc7ccc4c5c76)cc3)c3cc(-c4ccccc4)ccc23)cc1)c1ccc2c3c1C=CC1=CC=C(c4ccccc4)C(=CC2)C13 ; C[Si](C)(c1ccc(-c2c3ccccc3c(-c3ccc([Si](C)(C)c4cccc5c4ccc4c6ccccc6ccc54)cc3)c3cc(-c4ccccc4)ccc23)cc1)c1cccc2c1ccc1c3ccccc3ccc21 ; C[Si](C)(c1ccc(-c2c3ccccc3c(-c3ccc([Si](C)(C)c4cc5c6ccccc6ccc5c5ccccc45)cc3)c3cc(-c4ccccc4)ccc23)cc1)c1cccc2c1ccc1c3ccccc3ccc21] 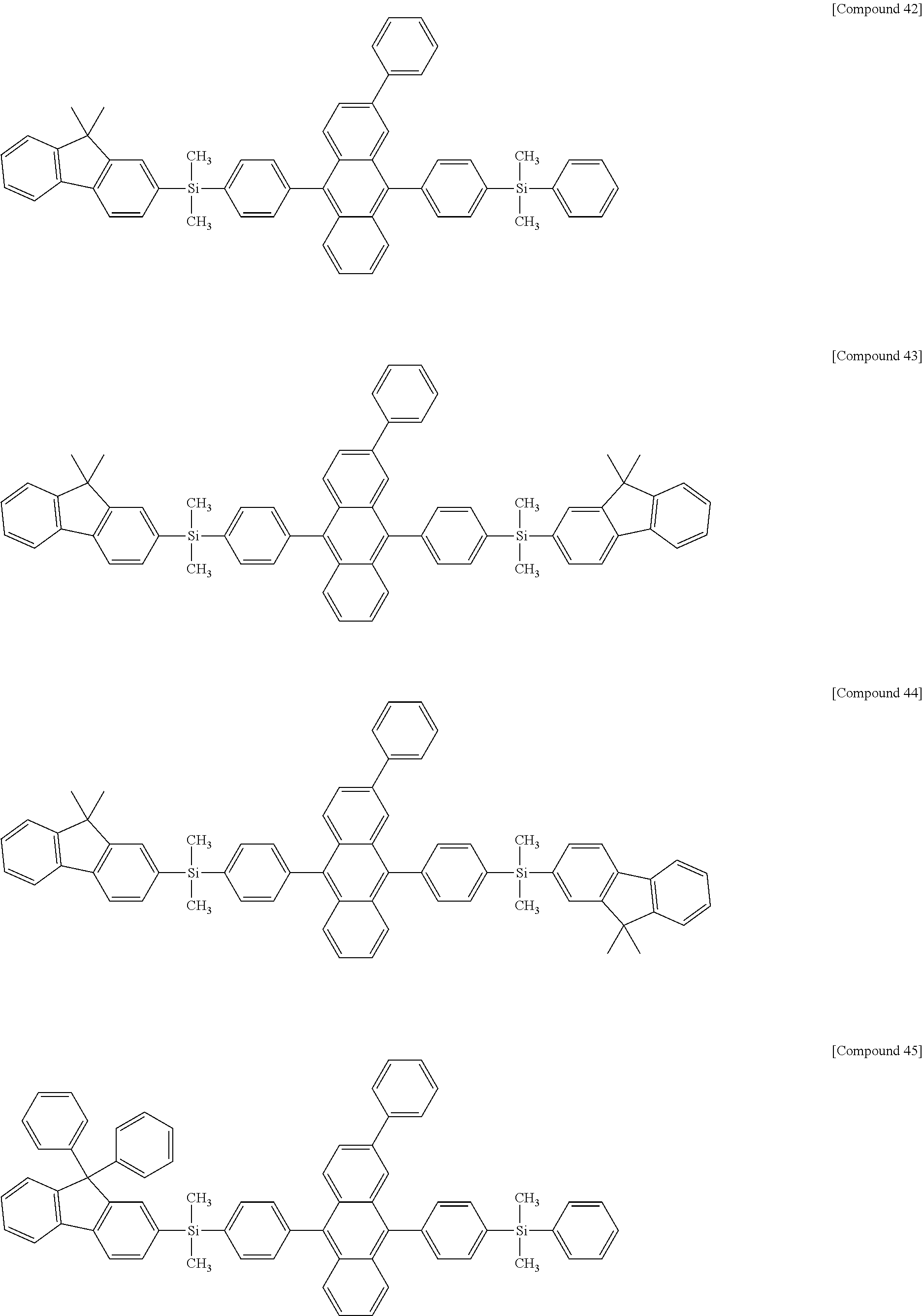 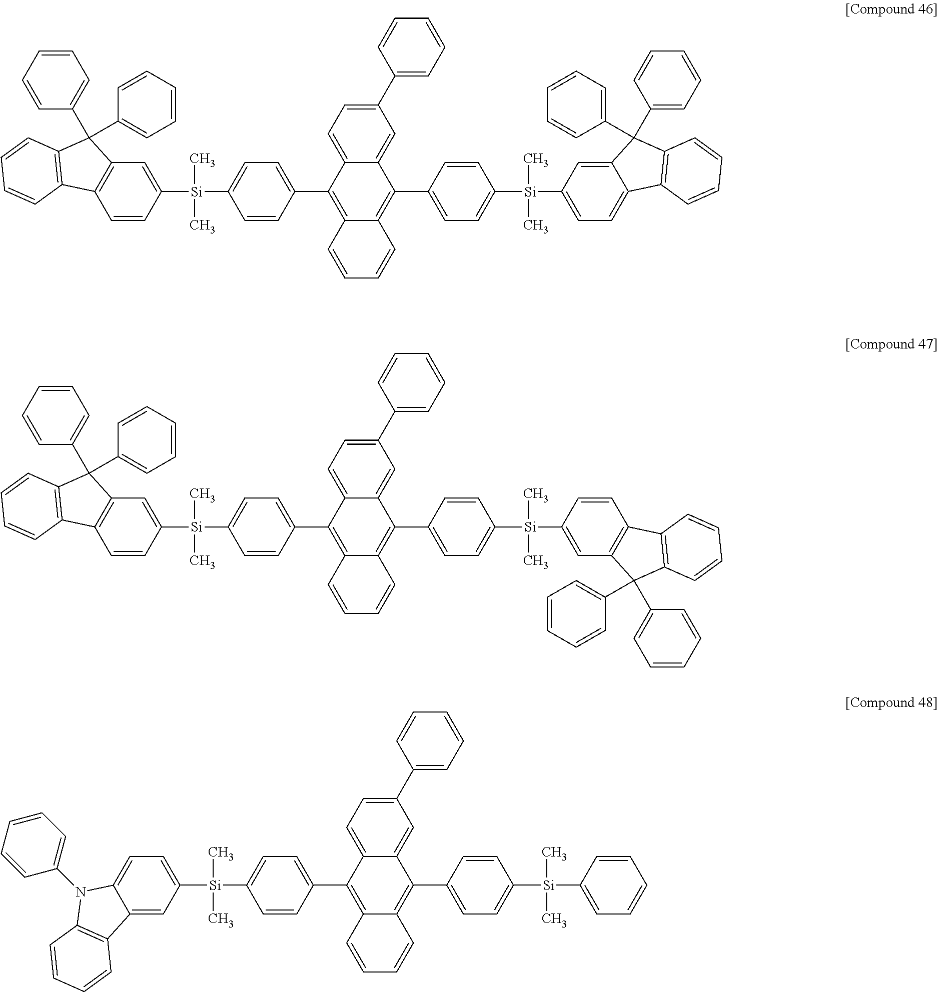 [SMILES: C[Si](C)(c1ccc(-c2c3ccccc3c(-c3ccc([Si](C)(C)c4ccc5c(c4)C(c4ccccc4)(c4ccccc4)c4ccccc4-5)cc3)c3cc(-c4ccccc4)ccc23)cc1)c1ccc2c(c1)C(c1ccccc1)(c1ccccc1)c1ccccc1-2 ; C[Si](C)(c1ccc(-c2c3ccccc3c(-c3ccc([Si](C)(C)c4ccc5c(c4)C(c4ccccc4)(c4ccccc4)c4ccccc4-5)cc3)c3cc(-c4ccccc4)ccc23)cc1)c1ccc2c(c1)C(c1ccccc1)(c1ccccc1)c1ccccc1-2 ; C[Si](C)(c1ccccc1)c1ccc(-c2c3ccccc3c(-c3ccc([Si](C)(C)c4ccc5c(c4)c4ccccc4n5-c4ccccc4)cc3)c3ccc(-c4ccccc4)cc23)cc1] 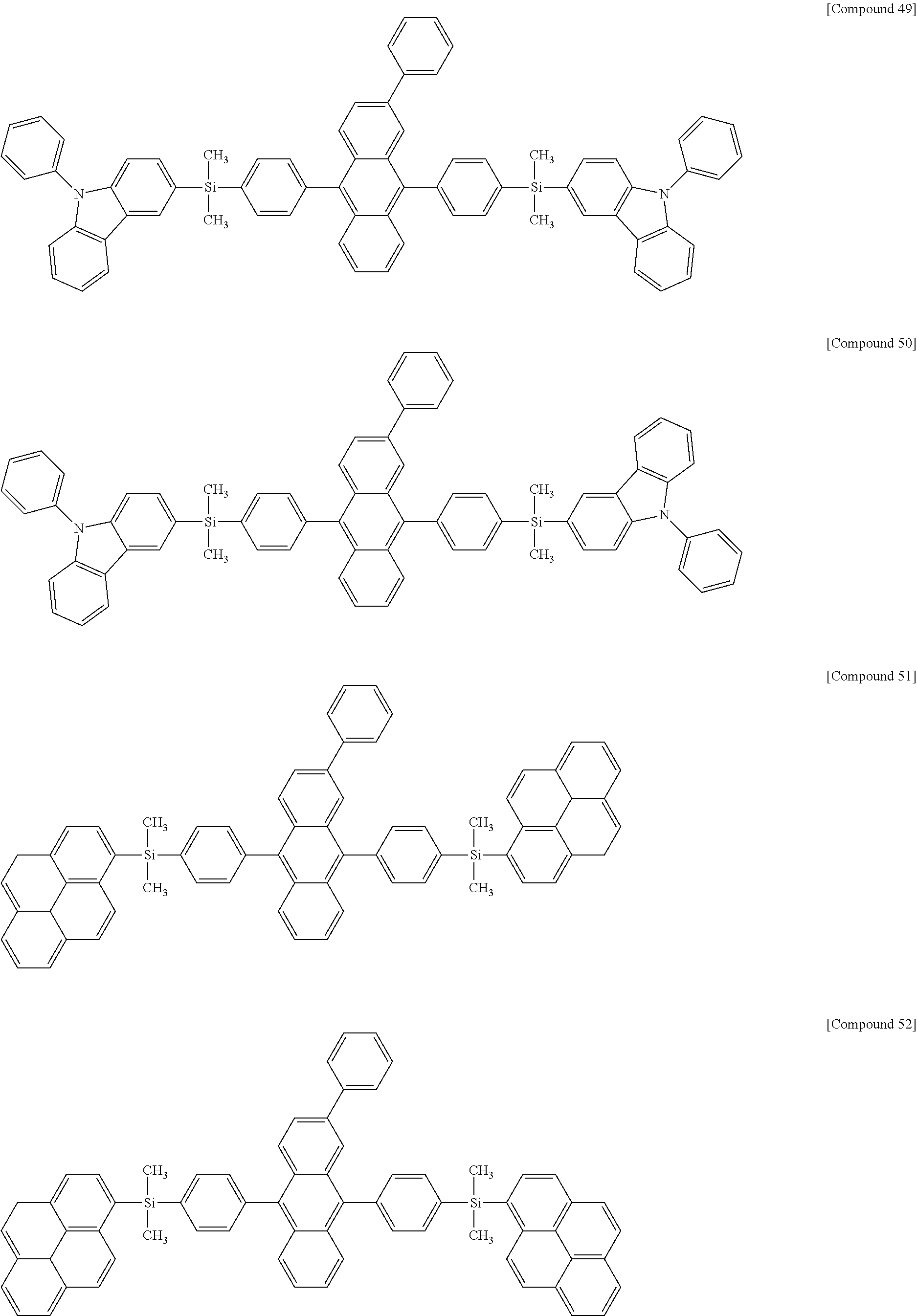 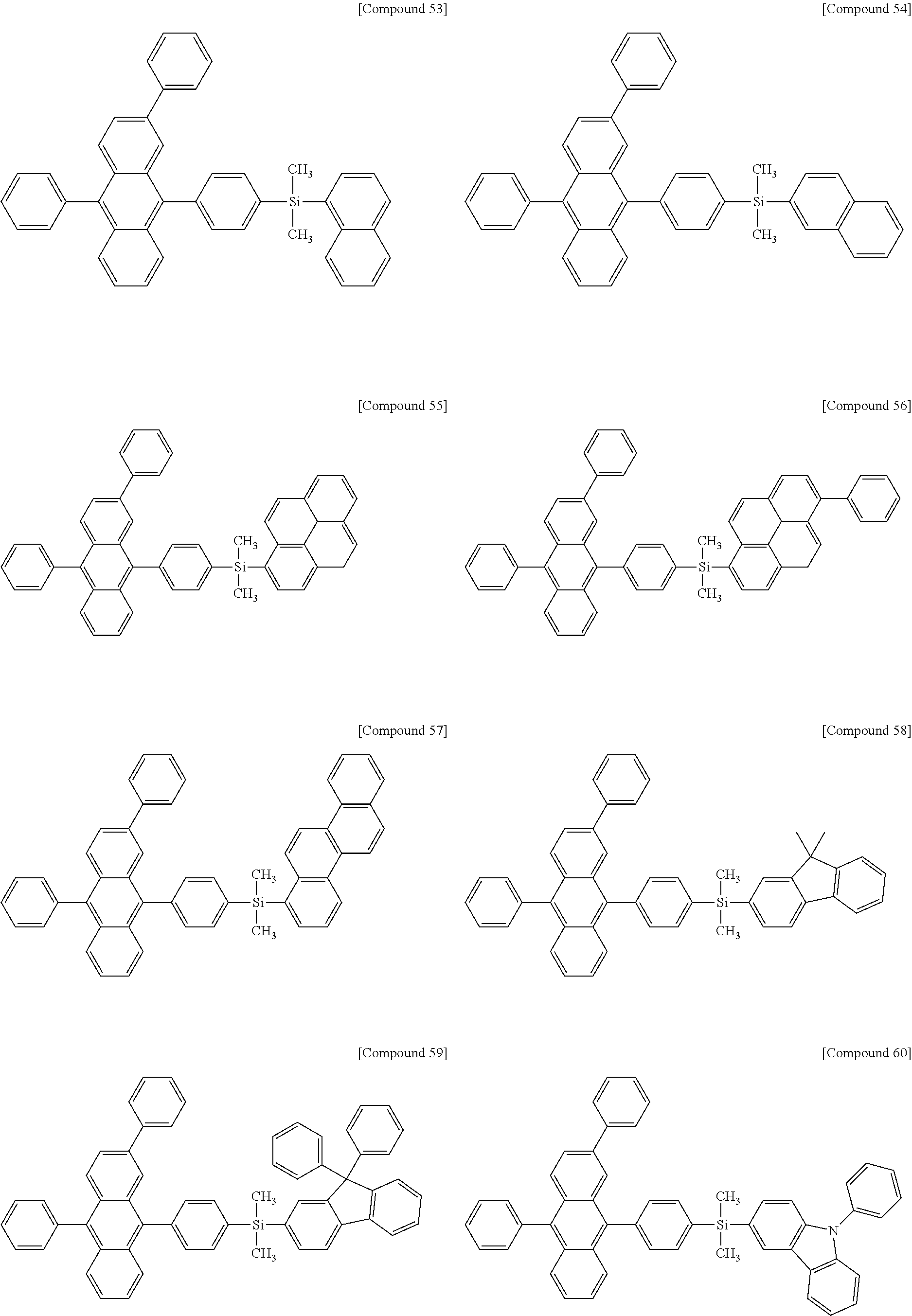 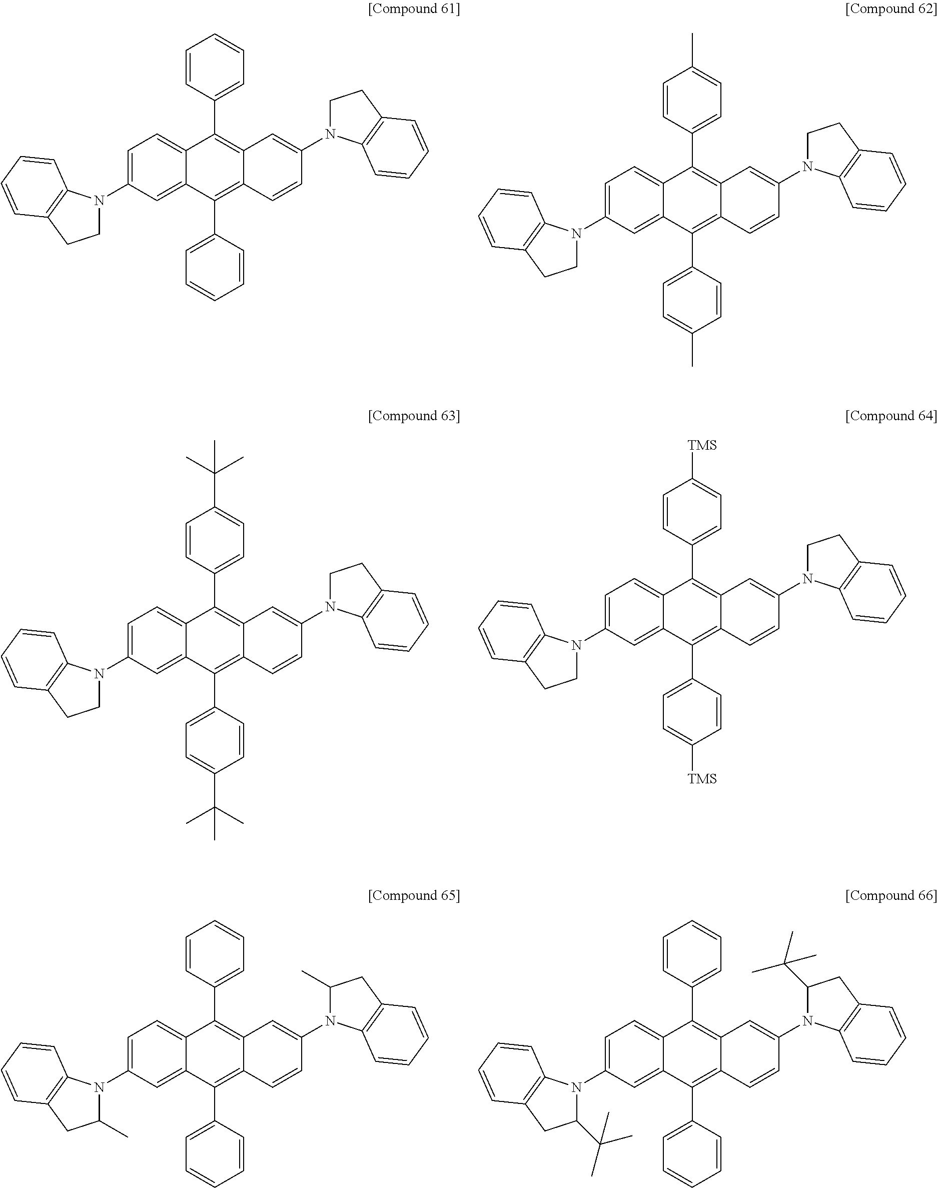 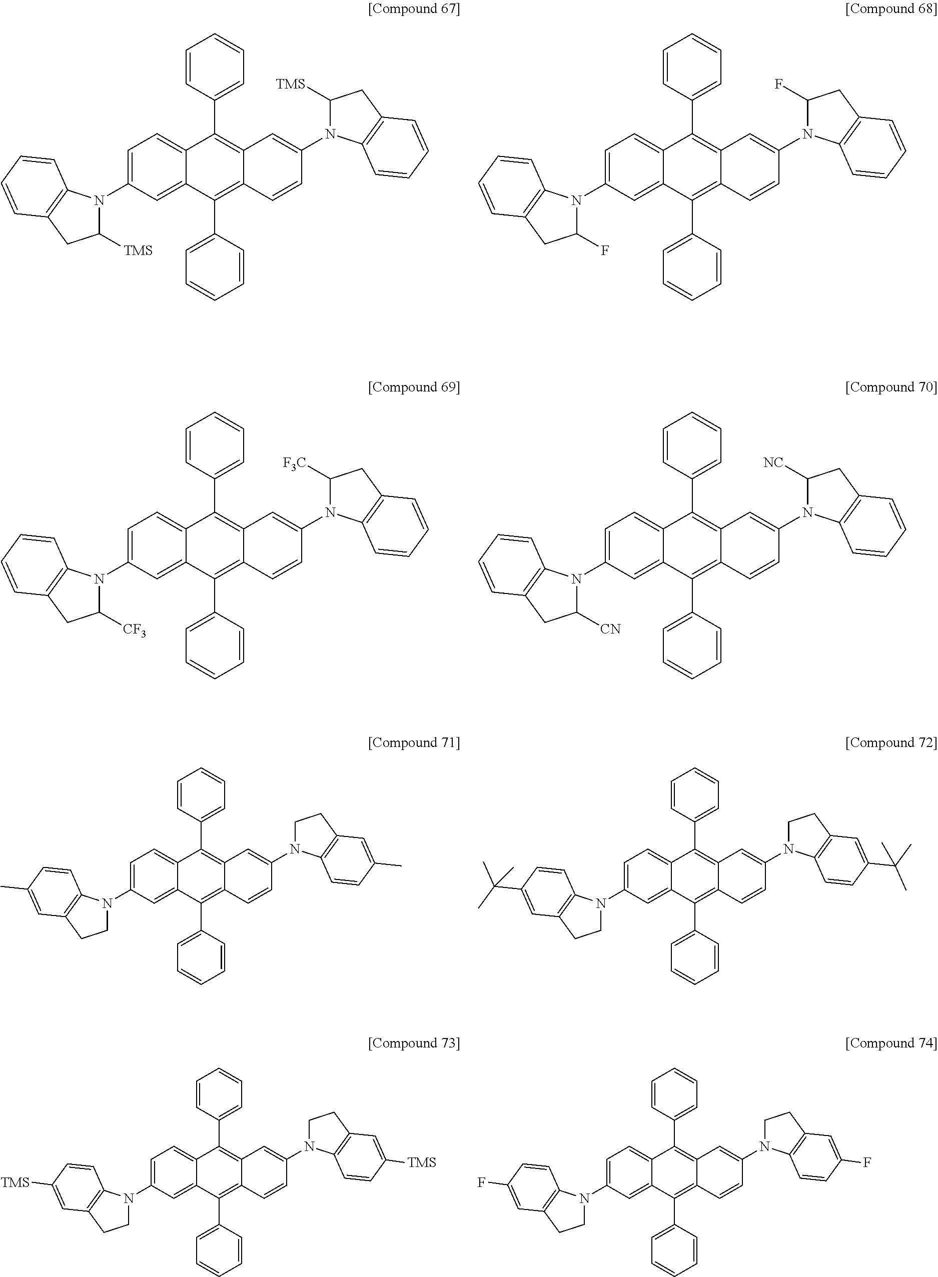 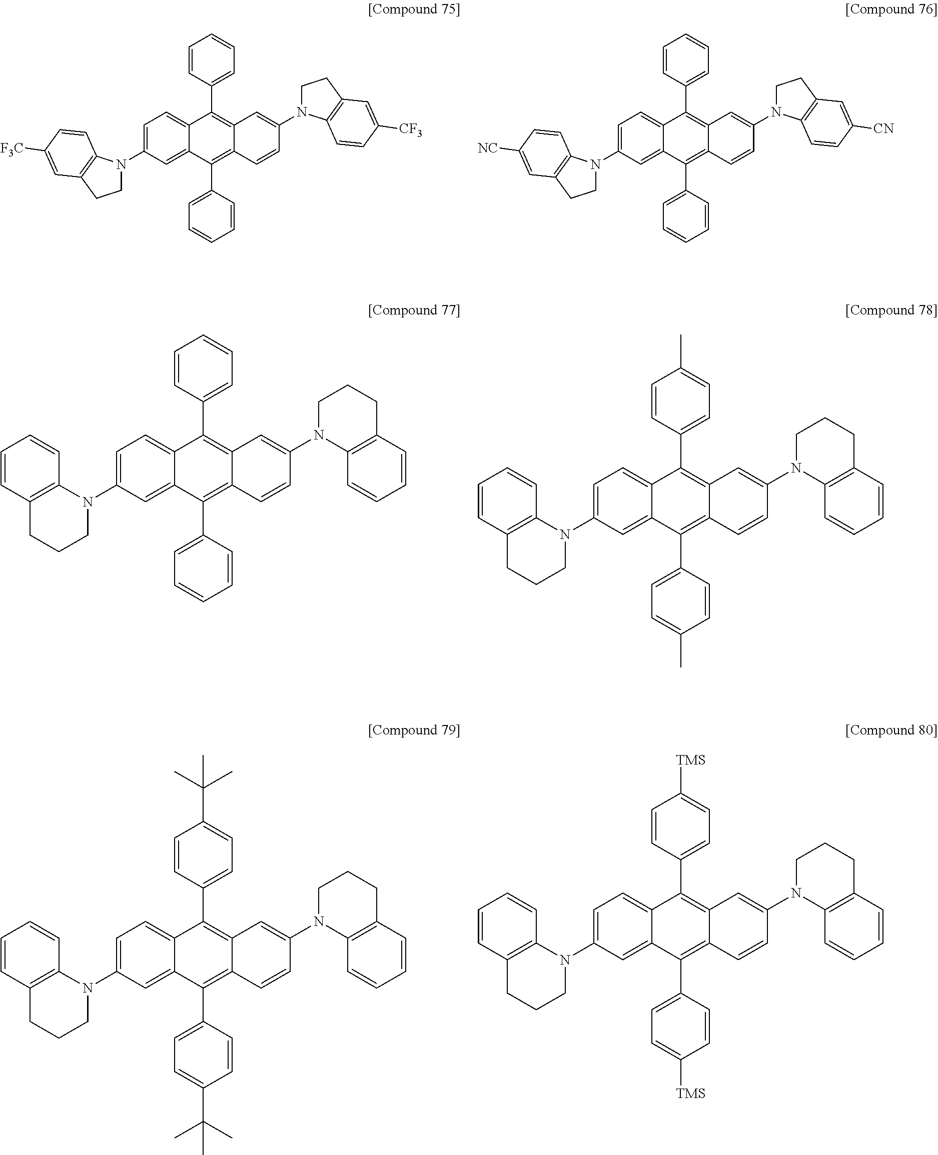 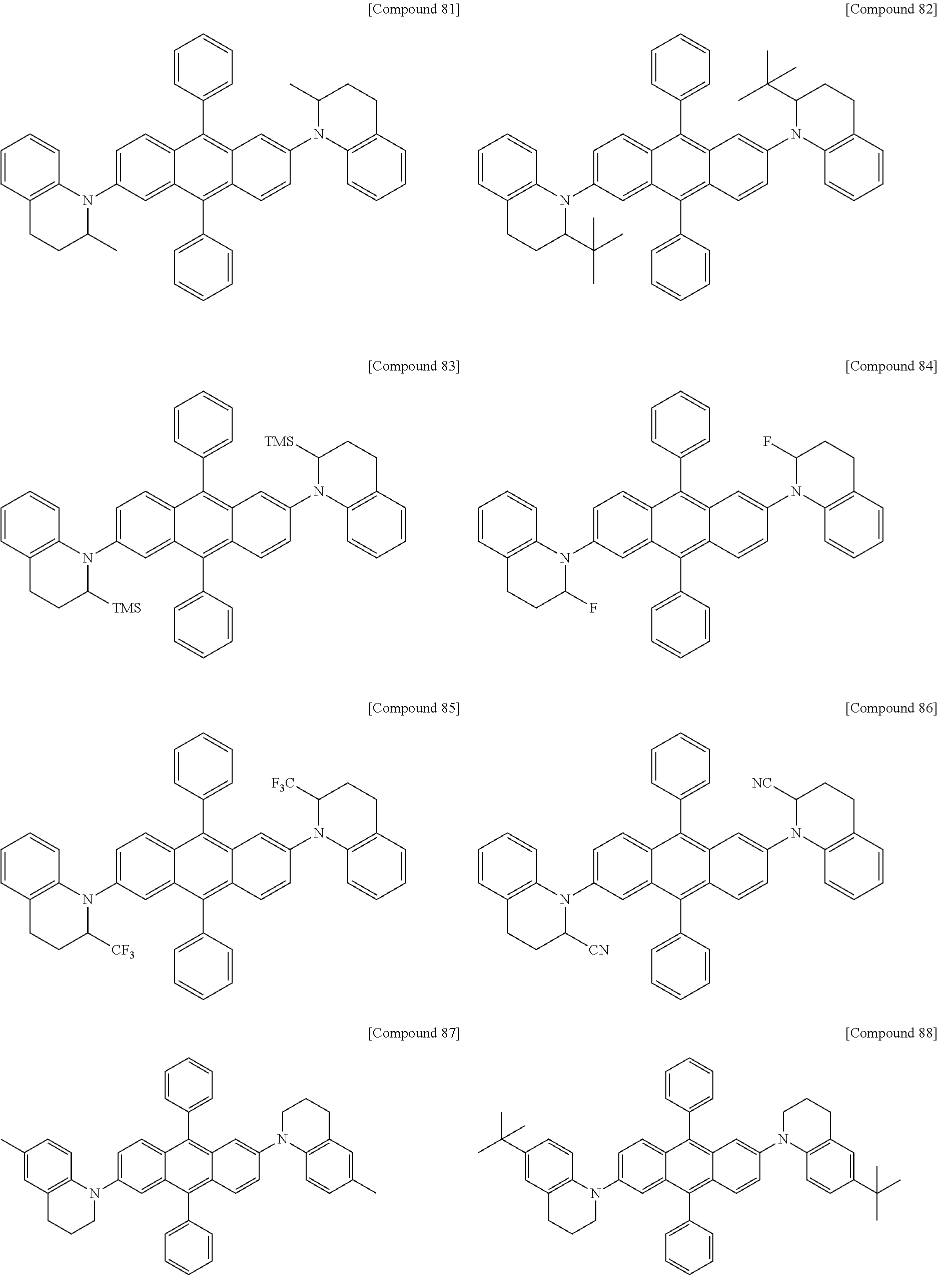 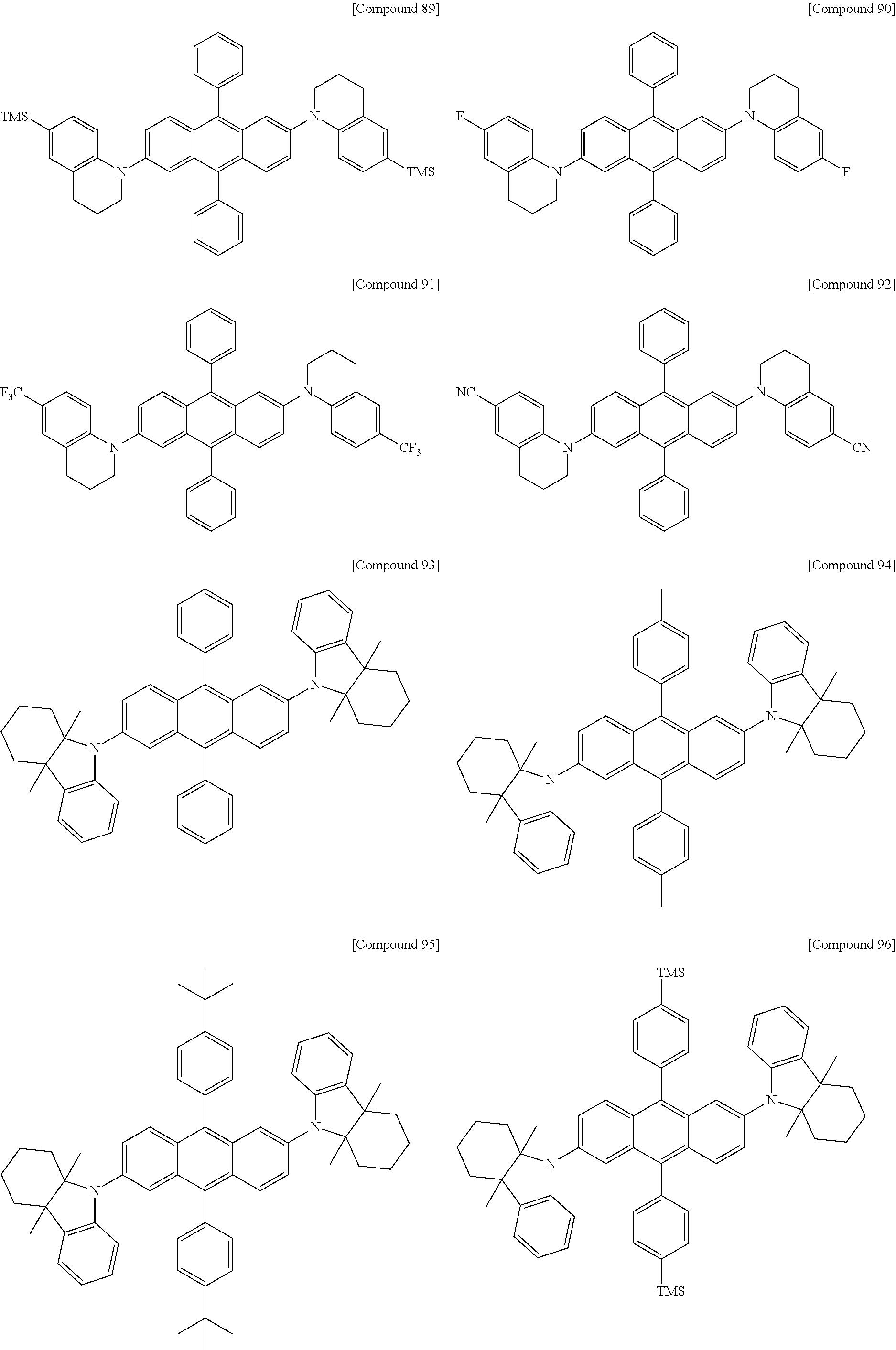 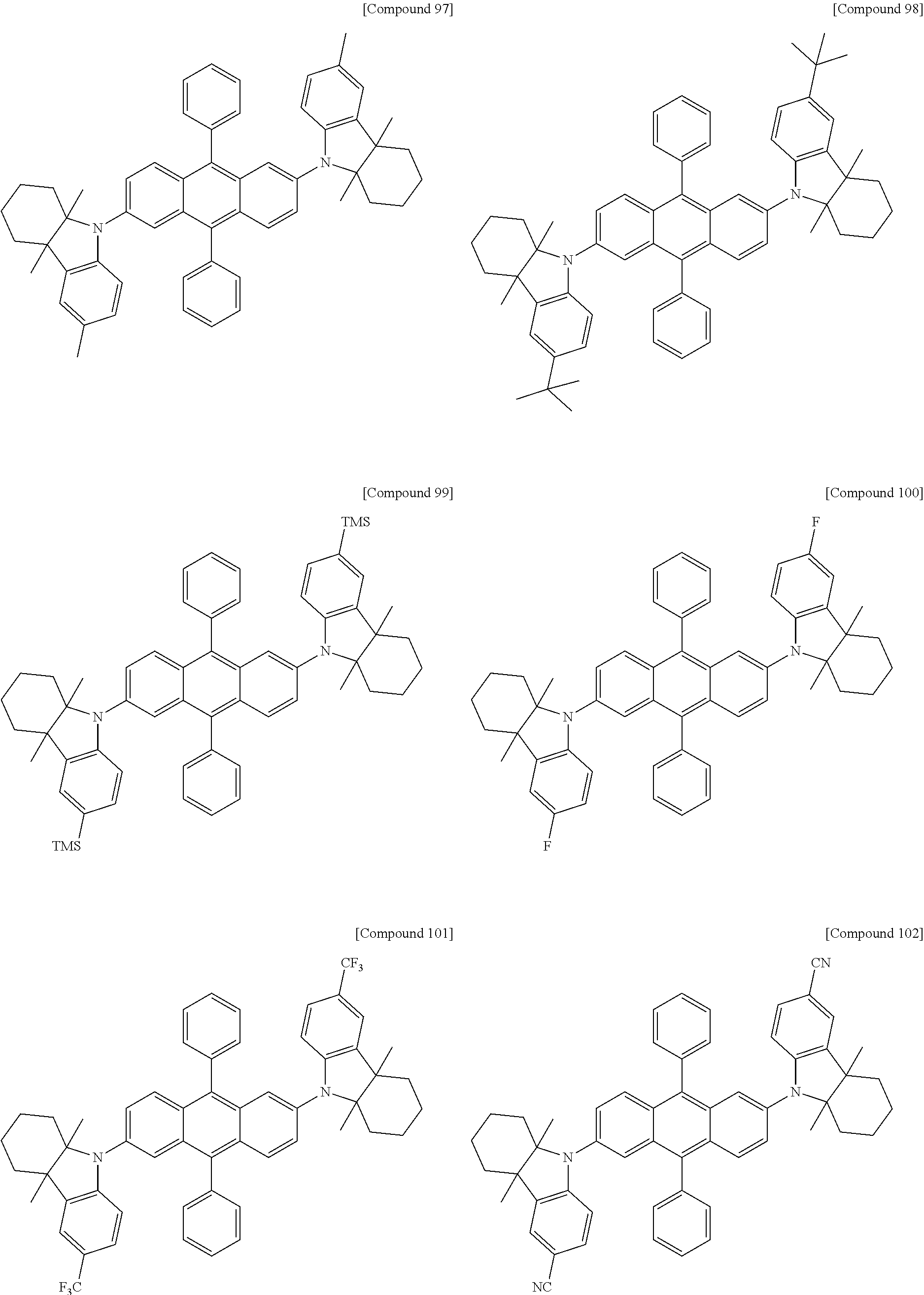 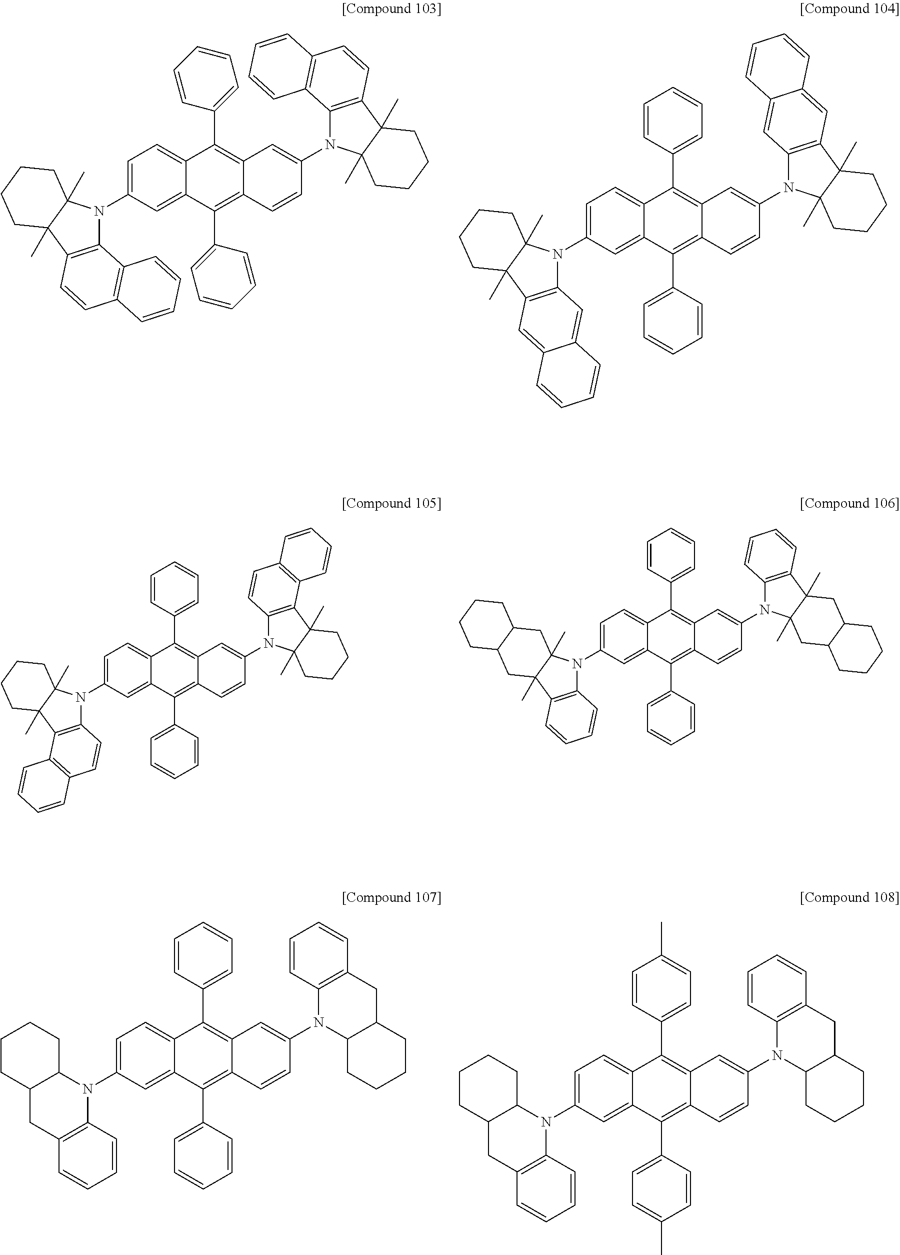 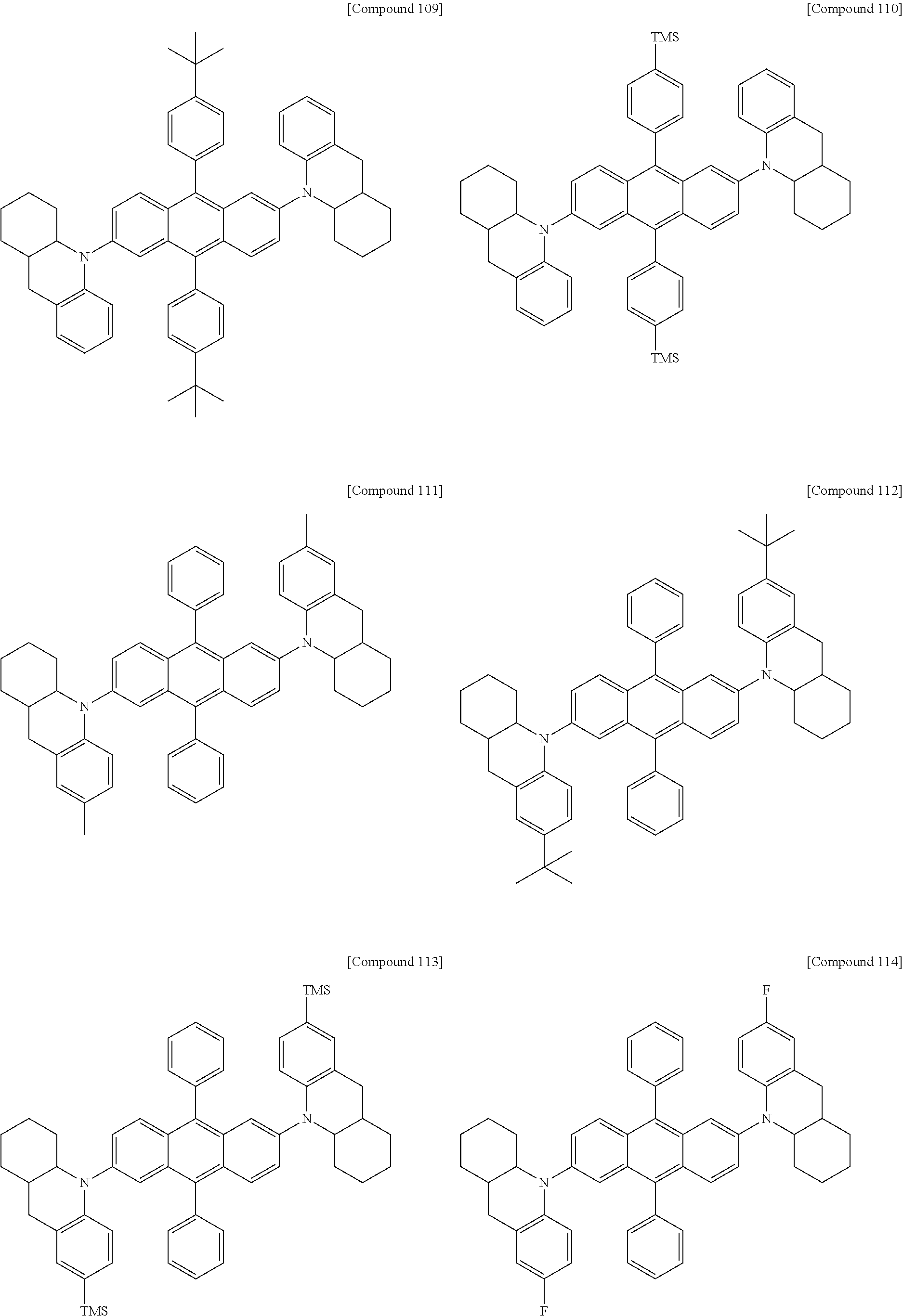 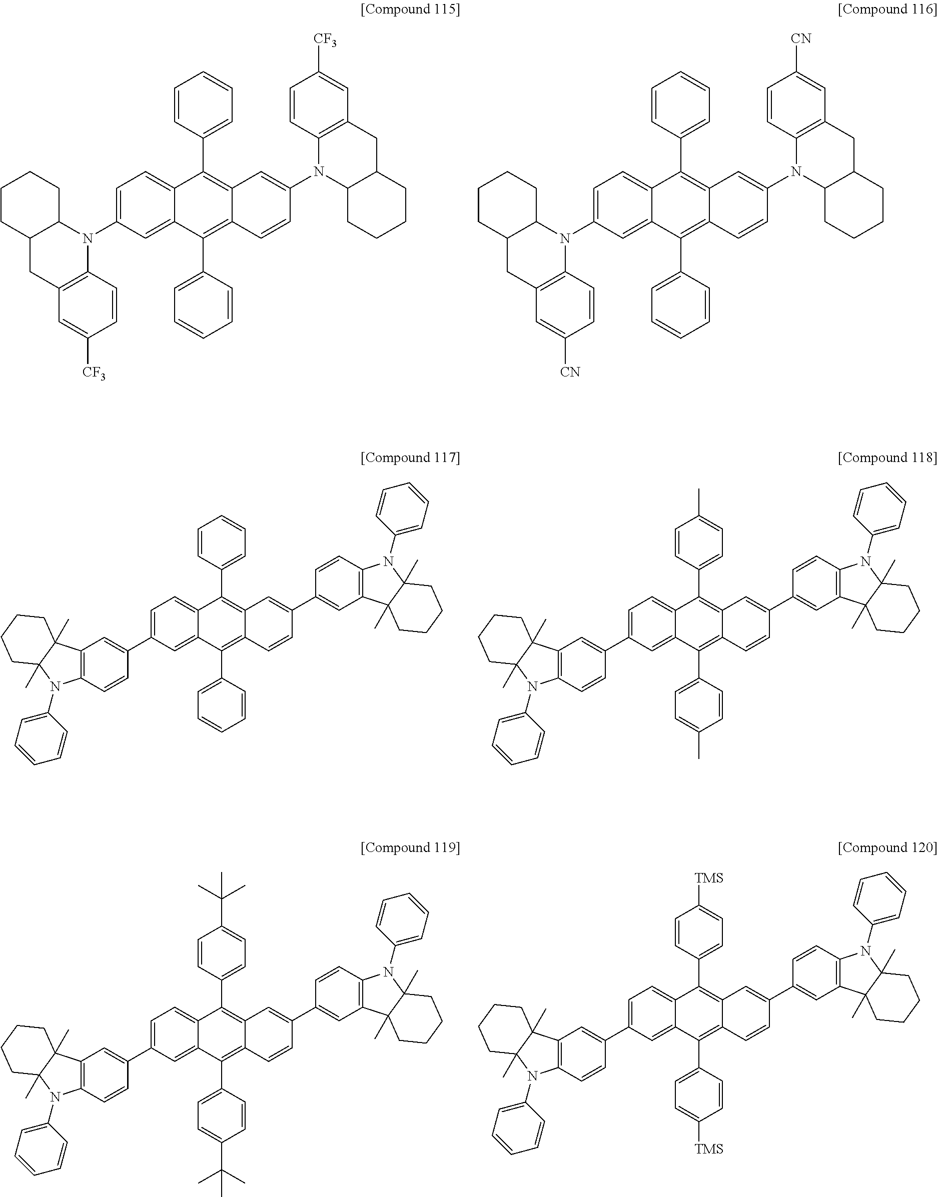 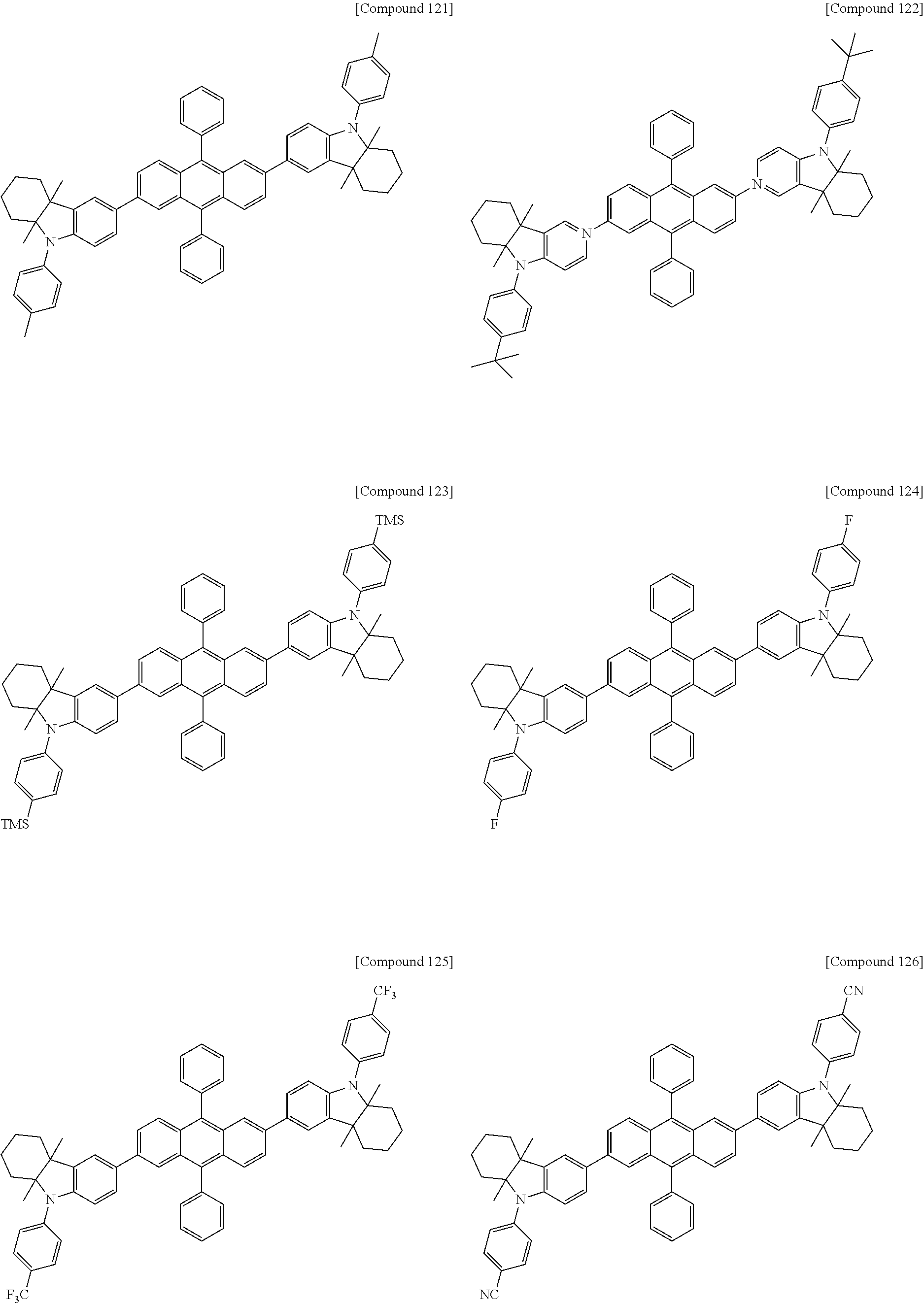 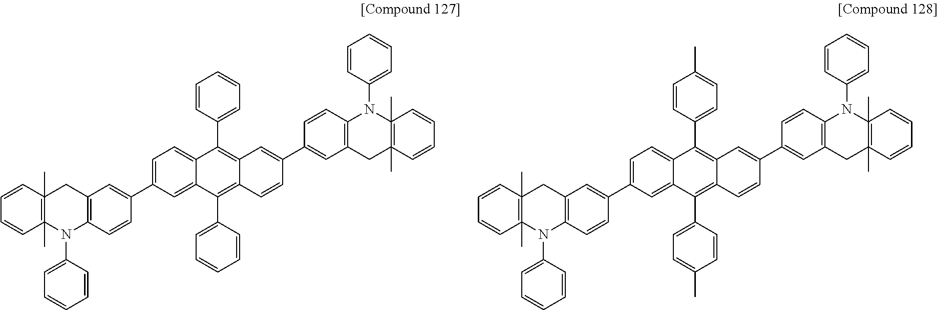 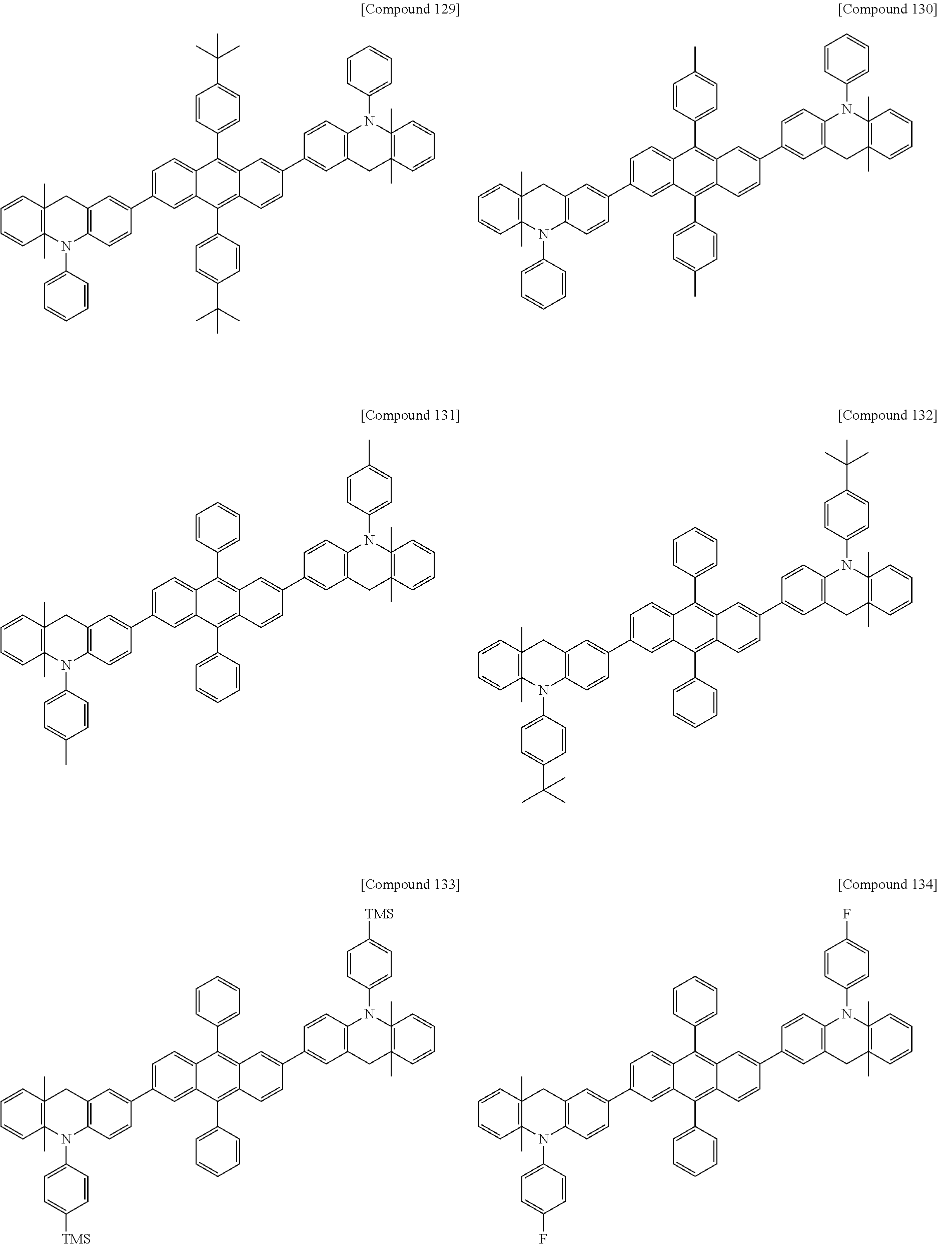 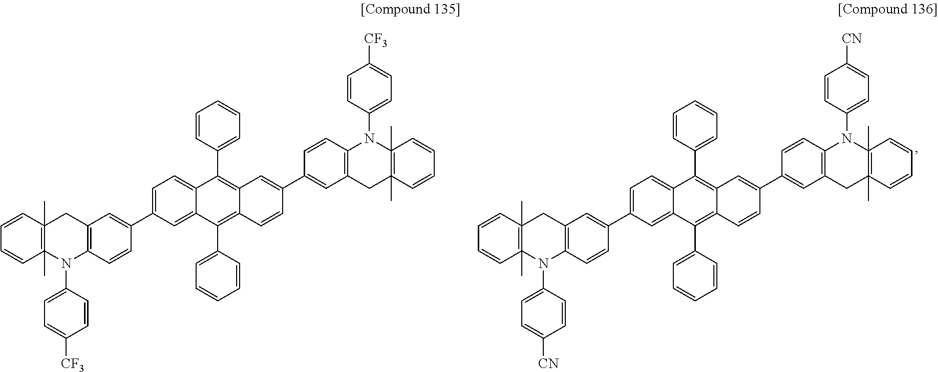
where TMS represents trimethylsilyl.
